(19) United States
(12) Patent Application Publication
(10) Pub. No.: US 2024/0114787 A1
(43) Pub. Date: Apr. 4, 2024

(54) LIGHT EMITTING ELEMENT AND POLYCYCLIC COMPOUND FOR THE SAME

(71) Applicant: Samsung Display Co., Ltd., Yongin-si (KR)

(72) Inventors: Yuji SUZAKI, Yokohama (JP); Tetsuji HAYANO, Yokohama (JP); Yuma AOKI, Yokohama (JP)

(73) Assignee: Samsung Display Co., Ltd., Yongin-si (KR)

(21) Appl. No.: 18/347,056

(22) Filed: Jul. 5, 2023

(30) Foreign Application Priority Data
Aug. 25, 2022 (KR) 10-2022-0106926

(51) Int. Cl. H10K 85/60; C07F 5/02; C09K 11/06

(52) U.S. Cl. CPC H10K 85/658; C07F 5/027; C09K 11/06; H10K 50/12

(57) ABSTRACT

Embodiments provide a light emitting element which includes a first electrode, a second electrode disposed on the first electrode, and an emission layer disposed between the first electrode and the second electrode, wherein the emission layer includes a polycyclic compound represented by Formula 1, which is explained in the specification.

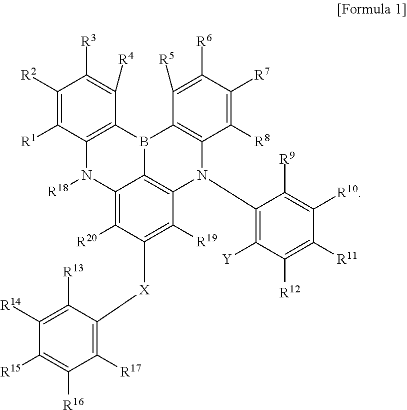

### CROSS-REFERENCE TO RELATED APPLICATION(S)

This application claims priority to and benefits of Korean Patent Application No. 10-2022-0106926 under 35 U.S.C. § 119, filed on Aug. 25, 2022, in the Korean Intellectual Property Office, the entire contents of which are incorporated herein by reference.

### BACKGROUND

### 1. Technical Field

The disclosure relates to a light emitting element including a novel polycyclic compound in an emission layer.

### 2. Description of the Related Art

Active development continues for organic electroluminescence display devices and the like as image display devices. Organic electroluminescence display devices and the like are display devices which include so-called self-luminescent light emitting elements in which holes and electrons respectively injected from a first electrode and a second electrode recombine in an emission layer, and thus a luminescent material in the emission layer emits light to accomplish display.

For the application of light emitting elements to display devices, there is a demand for light emitting elements having high luminous efficiency and a long life, and continuous development is required on materials for light emitting elements that are capable of stably achieving such characteristics.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

The disclosure provides a light emitting element having increased luminous efficiency and longer element service life.

The disclosure also provides a polycyclic compound that may be used as a material for a light emitting element having excellent luminous efficiency and element service life.

An embodiment provides a light emitting element which may include a first electrode, a second electrode disposed on the first electrode, and an emission layer disposed between the first electrode and the second electrode, wherein the emission layer may include a polycyclic compound represented by Formula 1.

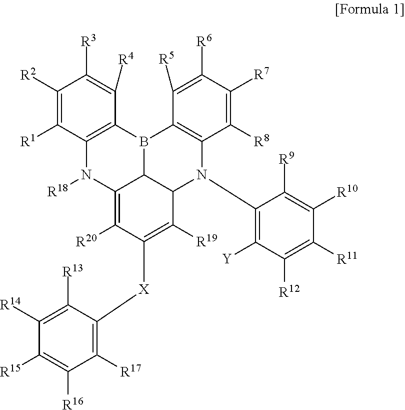

In Formula 1 X may be O, S, or C(R²¹)(R²²); R¹ to R²² may each independently be a hydrogen atom, a deuterium atom, a halogen atom, a cyano group, a hydroxy group, a substituted or unsubstituted thio group, a substituted or unsubstituted oxy group, a substituted or unsubstituted silyl group, a substituted or unsubstituted amino group, a substituted or unsubstituted alkyl group having 1 to 20 carbon atoms, a substituted or unsubstituted alkenyl group having 2 to 20 carbon atoms, a substituted or unsubstituted cycloalkyl group having 3 to 30 ring-forming carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring; Y may be a hydroxy group, a substituted or unsubstituted thio group, a substituted or unsubstituted oxy group, a substituted or unsubstituted arylthioxy group, a substituted or unsubstituted silyl group, a substituted or unsubstituted amine group, a substituted or unsubstituted cycloalkyl group having 3 to 30 ring-forming carbon atoms, a substituted or unsubstituted aryl group having 6 to 30 ring-forming carbon atoms, or a substituted or unsubstituted heteroaryl group having 2 to 30 ring-forming carbon atoms; a case where Y is a dimethylpyridine group may be excluded, and a case where R¹⁸ is bonded to R¹ or R²⁰ to form a ring may be excluded.

In an embodiment, the polycyclic compound may be represented by Formula 2, which is explained below.

In an embodiment, the polycyclic compound may be represented by Formula 2-a or Formula 2-b, which are explained below.

In an embodiment, Y may be a substituted or unsubstituted phenylthio group, a substituted or unsubstituted phenoxy group, a substituted or unsubstituted methoxy group, a substituted or unsubstituted t-butoxy group, a substituted or unsubstituted diethylamino group, a substituted or unsubstituted diphenylamino group, a substituted or unsubstituted cyclohexyl group, a substituted or unsubstituted phenyl group, a substituted or unsubstituted naphthyl group, a substituted or unsubstituted benzothiazole group, a substituted or unsubstituted benzoxazole group, a substituted or unsubstituted indole group, a substituted or unsubstituted benzothiophene group, or a substituted or unsubstituted benzofuran group.

In an embodiment, the polycyclic compound may be represented by Formula 3, which is explained below.

In an embodiment, at least one of Y and R¹ to R²² may be a deuterium atom or may include a substituent including a deuterium atom.

In an embodiment, the polycyclic compound may be represented by one of Formula 4-1 to Formula 4-3, which are explained below.

In an embodiment, R¹ to R⁸ may each independently be a hydrogen atom, a deuterium atom, a substituted or unsubstituted silyl group, a substituted or unsubstituted methyl group, a substituted or unsubstituted i-propyl group, a substituted or unsubstituted t-butyl group, a substituted or unsubstituted pentyl group, a substituted or unsubstituted cyclohexyl group, a substituted or unsubstituted phenyl group, a substituted or unsubstituted naphthyl group, or a substituted or unsubstituted carbazole group.

In an embodiment, R¹³ to R¹⁷ may each independently be a hydrogen atom, a deuterium atom, a halogen atom, a cyano group, a substituted or unsubstituted methoxy group, a substituted or unsubstituted methyl group, a substituted or unsubstituted i-propyl group, a substituted or unsubstituted t-butyl group, a substituted or unsubstituted cyclopropyl group, a substituted or unsubstituted phenyl group, or a substituted or unsubstituted carbazole group, or are bonded to an adjacent group to form a dibenzothiophene group or a dibenzofuran group.

In an embodiment, at least one of R²¹ or R²² may be a substituted or unsubstituted alkyl group having 1 to 10 carbon atoms, or a substituted or unsubstituted aryl group having 6 to 10 ring-forming carbon atoms; and the remainder of R²¹ or R²² may be a hydrogen atom or a deuterium atom.

In an embodiment, the emission layer may include a dopant and a host, and the dopant may include the polycyclic compound.

In an embodiment, the polycyclic compound may include at least one compound selected from Compound Group 1, which is explained below.

In an embodiment, a polycyclic compound may be represented by Formula 1, which is explained below.

In an embodiment, Formula 1 may be represented by Formula 2, which is explained below.

In an embodiment, Formula 2 may be represented by Formula 2-a or Formula 2-b, which are explained below.

In an embodiment, in the polycyclic compound, Y may be a substituted or unsubstituted phenylthio group, a substituted or unsubstituted phenoxy group, a substituted or unsubstituted methoxy group, a substituted or unsubstituted t-butoxy group, a substituted or unsubstituted diethylamino group, a substituted or unsubstituted diphenylamino group, a substituted or unsubstituted cyclohexyl group, a substituted or unsubstituted phenyl group, a substituted or unsubstituted naphthyl group, a substituted or unsubstituted benzothiazole group, a substituted or unsubstituted benzoxazole group, a substituted or unsubstituted indole group, a substituted or unsubstituted benzothiophene group, or a substituted or unsubstituted benzofuran group.

In an embodiment, Formula 1 may be represented by Formula 3, which is explained below.

In an embodiment, Formula 1 may be represented by Formulas 4-1 to 4-3, which are explained below.

In an embodiment, in the polycyclic compound, R¹³ to R¹⁷ are each independently a hydrogen atom, a deuterium atom, a halogen atom, a cyano group, a substituted or unsubstituted methoxy group, a substituted or unsubstituted methyl group, a substituted or unsubstituted i-propyl group, a substituted or unsubstituted t-butyl group, a substituted or unsubstituted cyclopropyl group, a substituted or unsubstituted phenyl group, a substituted or unsubstituted carbazole group, or are bonded to an adjacent group to form a dibenzothiophene group or a dibenzofuran group.

In an embodiment, the polycyclic compound may be selected from Compound Group 1, which is explained below.

It is to be understood that the embodiments above are described in a generic and explanatory sense only and not for the purpose of limitation, and the disclosure is not limited to the embodiments described above.

### BRIEF DESCRIPTION OF THE DRAWINGS

The accompanying drawings are included to provide a further understanding of the embodiments, and are incorporated in and constitute a part of this specification. The drawings illustrate embodiments of the disclosure and principles thereof The above and other aspects and features of the disclosure will become more apparent by describing in detail embodiments thereof with reference to the accompanying drawings, in which:

FIG. 1 is a schematic plan view showing a display device according to an embodiment;

FIG. 2 is a schematic cross-sectional view of a display device according to an embodiment;

FIG. 3 is a schematic cross-sectional view showing a light emitting element according to an embodiment;

FIG. 4 is a schematic cross-sectional view showing a light emitting element according to an embodiment;

FIG. 5 is a schematic cross-sectional view showing a light emitting element according to an embodiment;

FIG. 6 is a schematic cross-sectional view showing a light emitting element according to an embodiment;

FIG. 7 is a schematic cross-sectional view of a display device according to an embodiment;

FIG. 8 is a schematic cross-sectional view of a display device according to an embodiment;

FIG. 9 is a schematic cross-sectional view showing a display device according to an embodiment; and

FIG. 10 is a schematic cross-sectional view showing a display device according to an embodiment.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

In the drawings, the sizes, thicknesses, ratios, and dimensions of the elements may be exaggerated for ease of description and for clarity. Like reference numbers and/or like reference characters refer to like elements throughout.

In the description, it will be understood that when an element (or region, layer, part, etc.) is referred to as being “on”, “connected to”, or “coupled to” another element, it can be directly on, connected to, or coupled to the other element, or one or more intervening elements may be present therebetween. In a similar sense, when an element (or region, layer, part, etc.) is described as “covering” another element, it can directly cover the other element, or one or more intervening elements may be present therebetween.

In the description, when an element is “directly on,” “directly connected to,” or “directly coupled to” another element, there are no intervening elements present. For example, “directly on” may mean that two layers or two elements are disposed without an additional element such as an adhesion element therebetween.

It will be understood that the terms “connected to” or “coupled to” may refer to a physical, electrical and/or fluid connection or coupling, with or without intervening elements.

As used herein, the expressions used in the singular such as “a,” “an,” and “the,” are intended to include the plural forms as well, unless the context clearly indicates otherwise.

As used herein, the term “and/or” includes any and all combinations of one or more of the associated listed items. For example, “A and/or B” may be understood to mean “A, B, or A and B.” The terms “and” and “or” may be used in the conjunctive or disjunctive sense and may be understood to be equivalent to “and/or”.

In the specification and the claims, the term “at least one of” is intended to include the meaning of “at least one selected from the group of” for the purpose of its meaning and interpretation. For example, “at least one of A and B” may be understood to mean “A, B, or A and B.” When preceding a list of elements, the term, “at least one of,” modifies the entire list of elements and does not modify the individual elements of the list.

It will be understood that, although the terms first, second, etc. may be used herein to describe various elements, these elements should not be limited by these terms. These terms are only used to distinguish one element from another element. Thus, a first element could be termed a second element without departing from the teachings of the disclosure. Similarly, a second element could be termed a first element, without departing from the scope of the disclosure.

The spatially relative terms “below”, “beneath”, “lower”, “above”, “upper”, or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

The terms “about” or “approximately” as used herein is inclusive of the stated value and means within an acceptable range of deviation for the recited value as determined by one of ordinary skill in the art, considering the measurement in question and the error associated with measurement of the recited quantity (i.e., the limitations of the measurement system). For example, “about” may mean within one or more standard deviations, or within ±20%, ±10%, or ±5% of the stated value.

It should be understood that the terms “comprises,” “comprising,” “includes,” “including,” “have,” “having,” “contains,” “containing,” and the like are intended to specify the presence of stated features, integers, steps, operations, elements, components, or combinations thereof in the disclosure, but do not preclude the presence or addition of one or more other features, integers, steps, operations, elements, components, or combinations thereof.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

In the disclosure, the term “substituted or unsubstituted” may describe that a group that is substituted or unsubstituted with at least one substituent selected from the group consisting of a deuterium atom, a halogen atom, a cyano group, a nitro group, an amino group, a silyl group, oxy group, thio group, sulfinyl group, sulfonyl group, carbonyl group, a boron group, a phosphine oxide group, a phosphine sulfide group, an alkyl group, an alkenyl group, an alkynyl group, a hydrocarbon ring group, an aryl group, and a heterocyclic group. Each of the substituents listed above may itself be substituted or unsubstituted. For example, a biphenyl group may be interpreted as an aryl group or it may be interpreted as a phenyl group substituted with a phenyl group.

In the disclosure, the term “bonded to an adjacent group to form a ring” may be interpreted as a group that is bonded to an adjacent group to form a substituted or unsubstituted hydrocarbon ring or a substituted or unsubstituted heterocycle. The hydrocarbon ring may be an aliphatic hydrocarbon ring or an aromatic hydrocarbon ring. The heterocycle may be an aliphatic heterocycle or an aromatic heterocycle. The hydrocarbon ring and the heterocycle may each independently be monocyclic or polycyclic. A ring that is formed by adjacent groups being bonded to each other may itself be connected to another ring to form a spiro structure.

In the disclosure, the term “adjacent group” may be interpreted as a substituent that is substituted for an atom which is connected (e.g., directly connected) to an atom substituted with a corresponding substituent, as another substituent substituted for an atom which is substituted with a corresponding substituent, or as a substituent sterically positioned at the nearest position to a corresponding substituent. For example, two methyl groups in 1,2-dimethylbenzene may be interpreted as mutually “adjacent groups” and two ethyl groups in 1,1-diethylcyclopentane may be interpreted as mutually “adjacent groups”. For example, two methyl groups in 4,5-dimethylphenanthrene may be interpreted as mutually “adjacent groups”.

In the disclosure, examples of a halogen atom may include a fluorine atom, a chlorine atom, a bromine atom, and an iodine atom.

In the disclosure, an alkyl group may be linear, branched, or cyclic. The number of carbon atoms in an alkyl group may be 1 to 50, 1 to 30, 1 to 20, 1 to 10, or 1 to 6. Examples of an alkyl group may include a methyl group, an ethyl group, an n-propyl group, an isopropyl group, an n-butyl group, an s-butyl group, a t-butyl group, an i-butyl group, a 2-ethylbutyl group, a 3,3-a dimethylbutyl group, an n-pentyl group, an i-pentyl group, a neopentyl group, a t-pentyl group, a cyclopentyl group, a 1-methylpentyl group, a 3-methylpentyl group, a 2-ethylpentyl group, a 4-methyl-2-pentyl group, an n-hexyl group, a 1-methylhexyl group, a 2-ethylhexyl group, a 2-butylhexyl group, a cyclohexyl group, a 4-methylcyclohexyl group, a 4-t-butylcyclohexyl group, an n-heptyl group, a 1-methylheptyl group, a 2,2-dimethylheptyl group, a 2-ethylheptyl group, a 2-butylheptyl group, an n-octyl group, a t-octyl group, a 2-ethyloctyl group, a 2-butyloctyl group, a 2-hexyloctyl group, a 3,7-dimethyloctyl group, a cyclooctyl group, an n-nonyl group, an n-decyl group, an adamantyl group, a 2-ethyldecyl group, a 2-butyldecyl group, a 2-hexyldecyl group, a 2-octyldecyl group, an n-undecyl group, an n-dodecyl group, a 2-ethyldodecyl group, a 2-butyldodecyl group, a 2-hexyldocecyl group, a 2-octyldodecyl group, an n-tridecyl group, an n-tetradecyl group, an n-pentadecyl group, an n-hexadecyl group, a 2-ethylhexadecyl group, a 2-butylhexadecyl group, a 2-hexylhexadecyl group, a 2-octylhexadecyl group, an n-heptadecyl group, an n-octadecyl group, an n-nonadecyl group, an n-eicosyl group, a 2-ethyleicosyl group, a 2-butyleicosyl group, a 2-hexyleicosyl group, a 2-octyleicosyl group, an n-henicosyl group, an n-docosyl group, an n-tricosyl group, an n-tetracosyl group, an n-pentacosyl group, an n-hexacosyl group, an n-heptacosyl group, an n-octacosyl group, an n-nonacosyl group, an n-triacontyl group, and the like, but are not limited thereto.

In the disclosure, a cycloalkyl group may be a cyclic alkyl group. The number of carbon atoms in a cycloalkyl group may be 3 to 50, 3 to 30, 3 to 20, or 3 to 10. Examples of a cycloalkyl group may include a cyclopropyl group, a cyclobutyl group, a cyclopentyl group, a cyclohexyl group, a 4-methylcyclohexyl group, a 4-t-butylcyclohexyl group, a cycloheptyl group, a cyclooctyl group, a cyclononyl group, a cyclodecyl group, a norbornyl group, a 1-adamantyl group, a 2-adamantyl group, an isobornyl group, a bicycloheptyl group, and the like, but are not limited thereto.

In the disclosure, an alkenyl group may be a hydrocarbon group that includes at least one carbon-carbon double bond in the middle or end of an alkyl group having 2 or more carbon atoms. An alkenyl group may be linear or branched. The number of carbon atoms in an alkenyl group is not limited, but may be 2 to 30, 2 to 20, or 2 to 10. Examples of an alkenyl group may include a vinyl group, a 1-butenyl group, a 1-pentenyl group, a 1,3-butadienyl aryl group, a styrenyl group, a styryl vinyl group, and the like, but are not limited thereto.

In the disclosure, an alkynyl group may be a hydrocarbon group that includes at least one carbon-carbon triple bond in the middle or end of an alkyl group having 2 or more carbon atoms. An alkynyl group may be linear or branched. The number of carbon atoms in an alkynyl group is not limited, but may be 2 to 30, 2 to 20, or 2 to 10. Examples of an alkynyl group may include an ethynyl group, a propynyl group, and the like, but are not limited thereto.

In the disclosure, a hydrocarbon ring group may be any functional group or substituent derived from an aliphatic hydrocarbon ring. For example, a hydrocarbon ring group may be a saturated hydrocarbon ring group having 5 to 20 ring-forming carbon atoms.

In the disclosure, an aryl group may be any functional group or substituent derived from an aromatic hydrocarbon ring. An aryl group may be monocyclic or polycyclic. The number of ring-forming carbon atoms in an aryl group may be 6 to 60, 6 to 30, 6 to 20, or 6 to 15. Examples of an aryl group may include a phenyl group, a naphthyl group, a fluorenyl group, an anthracenyl group, a phenanthryl group, a biphenyl group, a terphenyl group, a quaterphenyl group, a quinquephenyl group, a sexiphenyl group, a triphenylenyl group, a pyrenyl group, a benzofluoranthenyl group, a chrysenyl group, and the like, but are not limited thereto.

In the disclosure, a fluorenyl group may be substituted, and two substituents may be bonded to each other to form a spiro structure. Examples of substituted fluorenyl groups are as follows, but embodiments are not limited thereto.

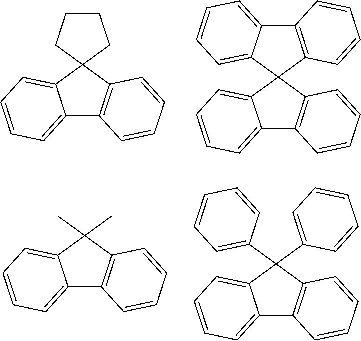

In the disclosure, a heterocyclic group may be any functional group or substituent derived from a ring that includes at least one of B, O, N, P, Si, or S as a heteroatom. A heterocyclic group may be an aliphatic heterocyclic group or an aromatic heterocyclic group. An aromatic heterocyclic group may be a heteroaryl group. The aliphatic heterocycle and the aromatic heterocycle may each independently be monocyclic or polycyclic. When the heterocyclic group contains two or more heteroatoms, the two or more heteroatoms may be the same as or different from each other.

In the disclosure, an aliphatic heterocyclic group may contain at least one of B, O, N, P, Si, or S as a heteroatom. The number of ring-forming carbon atoms in an aliphatic heterocyclic group may be 2 to 30, 2 to 20, or 2 to 10. Examples of an aliphatic heterocyclic group may include an oxirane group, a thiirane group, a pyrrolidine group, a piperidine group, a tetrahydrofuran group, a tetrahydrothiophene group, a thiane group, a tetrahydropyran group, a 1,4-dioxane group, and the like, but are not limited to thereto

In the disclosure, a heteroaryl group may include at least one of B, O, N, P, Si, or S as a heteroatom. When a heteroaryl group contains two or more heteroatoms, the two or more heteroatoms may be the same as or different from each other. A heteroaryl group may be monocyclic or polycyclic. The number of ring-forming carbon atoms in a heteroaryl group may be 2 to 60, 2 to 30, 2 to 20, or 2 to 10. Examples of a heteroaryl group may include a thiophene group, a furan group, a pyrrole group, an imidazole group, a pyridine group, a bipyridine group, a pyrimidine group, a triazine group, a triazole group, an acridyl group, a pyridazine group, a pyrazinyl group, a quinoline group, a quinazoline group, a quinoxaline group, a phenoxazine group, a phthalazine group, a pyrido pyrimidine group, a pyrido pyrazine group, a pyrazino pyrazine group, an isoquinoline group, an indole group, a carbazole group, an N-arylcarbazole group, an N-heteroarylcarbazole group, an N-alkylcarbazole group, a benzoxazole group, a benzoimidazole group, a benzothiazole group, a benzocarbazole group, a benzothiophene group, a dibenzothiophene group, a thienothiophene group, a benzofuran group, a phenanthroline group, a thiazole group, an isoxazole group, an oxazole group, an oxadiazole group, a thiadiazole group, a phenothiazine group, a dibenzosilole group, a dibenzofuran group, and the like, but are not limited thereto.

In the disclosure, the above description of an aryl group may be applied to an arylene group, except that the arylene group is a divalent group. The above description of a heteroaryl group may be applied to a heteroarylene group, except that the heteroarylene group is a divalent group.

In the disclosure, a silyl group may be an alkyl silyl group or an aryl silyl group. Examples of a silyl group may include a trimethylsilyl group, a triethylsilyl group, a t-butyldimethylsilyl group, a vinyldimethylsilyl group, a propyldimethylsilyl group, a triphenylsilyl group, a diphenylsilyl group, a phenylsilyl group, and the like, but are not limited thereto.

In the disclosure, the number of carbon atoms in an amino group is not limited, but may be 1 to 30. An amino group may be an alkyl amino group, an aryl amino group, or a heteroaryl amino group. Examples of an amino group may include a methylamino group, a dimethylamino group, a phenylamino group, a diphenylamino group, a naphthylamino group, a 9-methyl-anthracenylamino group, a triphenylamino group, and the like, but are not limited thereto.

In the disclosure, the number of carbon atoms in a carbonyl group is not limited, but may be 1 to 40, 1 to 30, or 1 to 20. For example, a carbonyl group may have one of the following structures, but is not limited thereto.

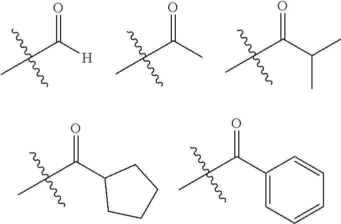

In the disclosure, the number of carbon atoms in a sulfinyl group or a sulfonyl group is not limited, but may be 1 to 30. A sulfinyl group may be an alkyl sulfinyl group or an aryl sulfinyl group. A sulfonyl group may be an alkyl sulfonyl group or an aryl sulfonyl group.

In the disclosure, a thio group may be an alkyl thio group or an aryl thio group. A thio group may be a sulfur atom that is bonded to an alkyl group or an aryl group as defined above. Examples of a thio group may include a methylthio group, an ethylthio group, a propylthio group, a pentylthio group, a hexylthio group, an octylthio group, a dodecylthio group, a cyclopentylthio group, a cyclohexylthio group, a phenylthio group, a naphthylthio group, and the like, but are not limited to thereto.

In the disclosure, an oxy group may be an oxygen atom that is bonded to an alkyl group or aryl group as defined above. An oxy group may be an alkoxy group or an aryl oxy group. The alkoxy group may be linear, branched, or cyclic. The number of carbon atoms in an alkoxy group is not limited, but may be, for example, 1 to 20, or 1 to 10. Examples of an oxy group may include a methoxy group, an ethoxy group, an n-propoxy group, an isopropoxy group, a butoxy group, a pentyloxy group, a hexyloxy group, an octyloxy group, a nonyloxy group, a decyloxy group, a benzyloxy group, and the like, but are not limited thereto.

In the disclosure, a thioxy group may be an alkyl thioxy group or an aryl thioxy group. Examples of an alkyl thioxy group may include a methylthioxy group, an ethylthioxy group, a tert-butylthioxy group, a hexylthioxy group, an octylthioxy group, and the like, and examples of an aryl thioxy group may include a phenylthioxy group, a 2-methylphenylthioxy group, a 4-tert-butylphenylthioxy group, and the like, but are not limited thereto.

In the disclosure, a boron group may refer be a boron atom that is bonded to an alkyl group or an aryl group as defined above. A boron group may be an alkyl boron group or an aryl boron group. Examples of a boron group may include a dimethyl boron group, a diethyl boron group, a t-butylmethyl boron group, a diphenyl boron group, a phenyl boron group, and the like, but are not limited thereto.

In the disclosure, the number of carbon atoms in an amine group is not limited, but may be 1 to 30. An amine group may be an alkyl amine group or an aryl amine group. Examples of an amine group may include a methylamine group, a dimethylamine group, a phenylamine group, a diphenylamine group, a naphthylamine group, a 9-methyl-anthracenylamine group, a triphenylamine group, and the like, but are not limited thereto.

In the disclosure, the above-described examples of the alkyl group may also apply to the alkyl group in an alkylthio group, an alkyl sulfoxy group, an alkylaryl group, an alkylamino group, an alkyl boron group, an alkyl silyl group, and an alkyl amine group.

In the disclosure, the above-described examples of the aryl group may also apply to the aryl group in an aryloxy group, an arylthio group, an aryl sulfoxy group, an arylamino group, an aryl boron group, an aryl silyl group, and an aryl amine group.

In the disclosure, a direct linkage may be a single bond.

In the disclosure, the symbols

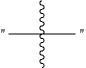

and “ [symbol] *” each represents a bonding site to a neighboring atom.

Hereinafter, embodiments of the disclosure will be described with reference to the accompanying drawings.

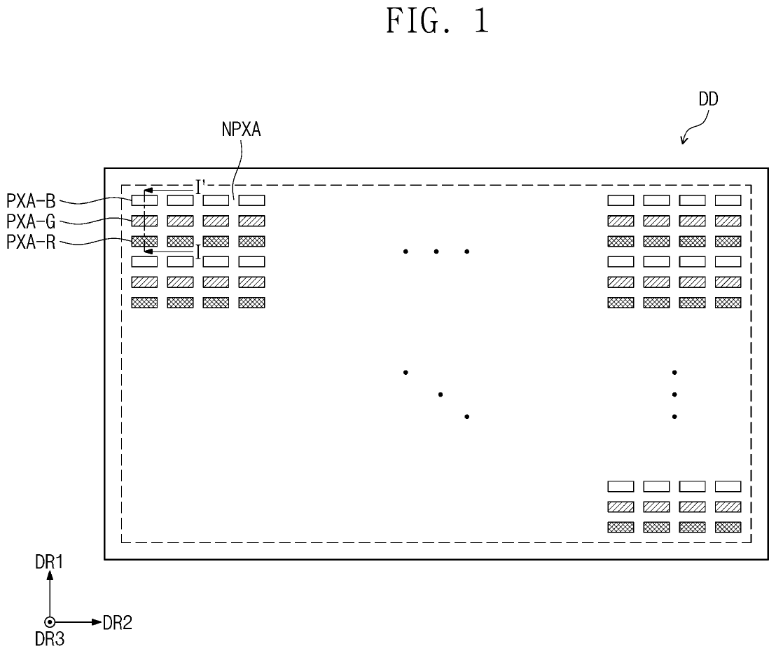

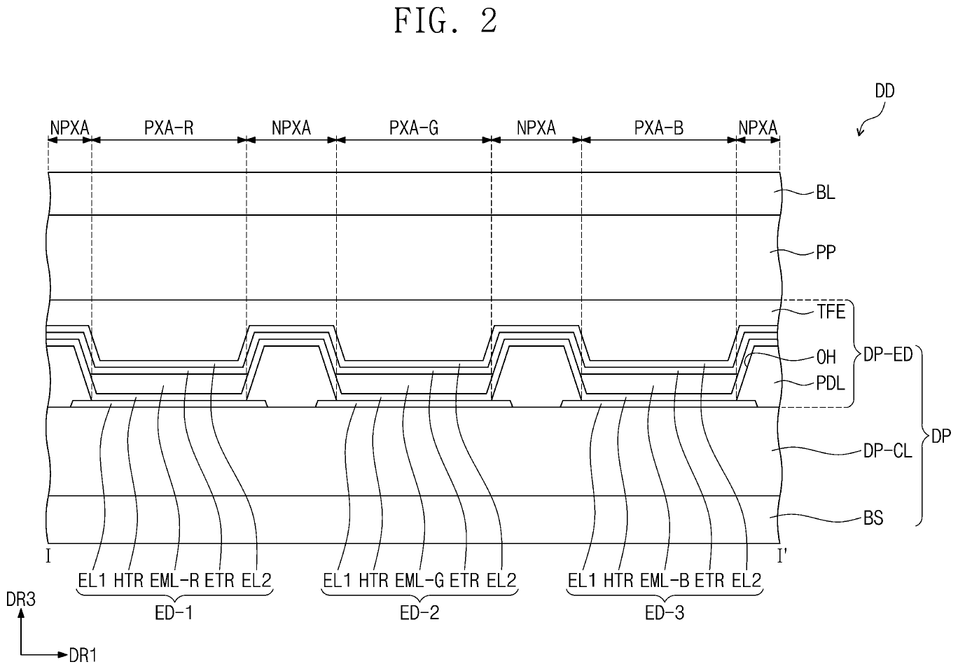

FIG. 1 is a schematic plan view of an embodiment of a display device DD. FIG. 2 is a schematic cross-sectional view of a display device DD according to an embodiment. FIG. 2 is a schematic cross-sectional view showing a portion corresponding to line I-I′ of FIG. 1.

The display device DD may include a display panel DP and an optical layer PP disposed on the display panel DP. The display panel DP may include light emitting elements ED-1, ED-2, and ED-3. The display device DD may include multiples of each of the light emitting elements ED-1, ED-2, and ED-3. The optical layer PP may be disposed on the display panel DP and may control light reflected at the display panel DP from an external light. The optical layer PP may include, for example, a polarizing layer or a color filter layer. Although not shown in the drawings, in an embodiment the optical layer PP may be omitted from the display device DD.

A base substrate BL may be disposed on the optical layer PP. The base substrate BL may provide a base surface on which the optical layer PP is disposed. The base substrate BL may be a glass substrate, a metal substrate, a plastic substrate, and the like. However, embodiments are not limited thereto, and the base substrate BL may include an inorganic layer, an organic layer, or a composite material layer. Although not shown in the drawings, in an embodiment the base substrate BL may be omitted.

The display device DD according to an embodiment may further include a filling layer (not shown). The filling layer (not shown) may be disposed between a display element layer DP-ED and the base substrate BL. The filling layer (not shown) may be an organic material layer. The filling layer (not shown) may include at least one of an acrylic resin, a silicone-based resin, and an epoxy-based resin.

The display panel DP may include a base layer BS, a circuit layer DP-CL provided on the base layer BS, and a display element layer DP-ED. The display element layer DP-ED may include pixel defining films PDL, light emitting elements ED-1, ED-2, and ED-3 disposed between the pixel defining films PDL, and an encapsulation layer TFE disposed on the light emitting elements ED-1, ED-2, and ED-3.

The base layer BS may provide a base surface on which the display element layer DP-ED is disposed. The base layer BS may be a glass substrate, a metal substrate, a plastic substrate, and the like. However, embodiments are not limited thereto, and the base layer BS may include an inorganic layer, an organic layer, or a composite material layer.

In an embodiment, the circuit layer DP-CL may be disposed on the base layer BS, and the circuit layer DP-CL may include transistors (not shown). The transistors (not shown) may each include a control electrode, an input electrode, and an output electrode. For example, the circuit layer DP-CL may include a switching transistor and a driving transistor for driving the light emitting elements ED-1, ED-2, and ED-3 of the display element layer DP-ED.

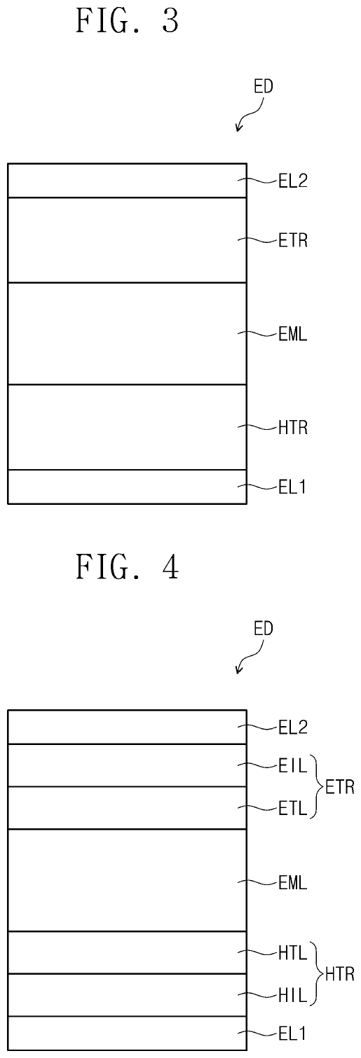

The light emitting elements ED-1, ED-2, and ED-3 may each have a structure of a light emitting element ED of an embodiment according to any of FIGS. 3 to 6, which will be described later. The light emitting elements ED-1, ED-2, and ED-3 may each include a first electrode EL1, a hole transport region HTR, emission layers EML-R, EML-G, and EML-B, an electron transport region ETR, and a second electrode EL2.

FIG. 2 shows an embodiment in which the emission layers EML-R, EML-G, and EML-B of the light emitting elements ED-1, ED-2, and ED-3 are disposed in openings OH defined in the pixel defining films PDL, and the hole transport region HTR, the electron transport region ETR, and the second electrode EL2 are each provided as a common layer throughout the light emitting elements ED-1, ED-2, and ED-3. However, embodiments are not limited thereto. Although not shown in FIG. 2, in an embodiment, the hole transport region HTR and the electron transport region ETR may each be provided by being patterned inside the openings OH defined in the pixel defining films PDL. For example, in an embodiment, the hole transport region HTR, the emission layers EML-R, EML-G, and EML-B, and the electron transport region ETR, and the like of the light emitting elements ED-1, ED-2, and ED-3 may each be patterned and provided through an inkjet printing method.

The encapsulation layer TFE may cover the light emitting elements ED-1, ED-2, and ED-3. The encapsulation layer TFE may seal the display element layer DP-ED. The encapsulation layer TFE may be a thin film encapsulation layer. The encapsulation layer TFE may be a single layer or formed of multiple layers. The encapsulation layer TFE may include at least one insulating layer. The encapsulation layer TFE according to an embodiment may include at least one inorganic film (hereinafter, an encapsulation inorganic film). The encapsulation layer TFE, according to an embodiment, may include at least one organic film (hereinafter, an encapsulation organic film) and at least one encapsulation inorganic film.

The encapsulation inorganic film protects the display element layer DP-ED from moisture and/or oxygen, and the encapsulation organic film protects the display element layer DP-ED from foreign substances such as dust particles. The encapsulation inorganic film may include silicon nitride, silicon oxy nitride, silicon oxide, titanium oxide, aluminum oxide, and the like, but is not limited thereto. The encapsulation organic film may include an acrylic compound, an epoxy-based compound, and the like. The encapsulation organic film may include a photopolymerizable organic material, and is not limited.

The encapsulation layer TFE may be disposed on the second electrode EL2, and may be disposed to fill the openings OH.

Referring to FIGS. 1 and 2, the display device DD may include non-light emitting regions NPXA and light emitting regions PXA-R, PXA-G, and PXA-B. The light emitting regions PXA-R, PXA-G, and PXA-B may each be a region emitting light generated from each of the light emitting elements ED-1, ED-2, and ED-3. The light emitting regions PXA-R, PXA-G, and PXA-B may be spaced apart from each other in a plan view.

The light emitting regions PXA-R, PXA-G, and PXA-B may each be a region separated by the pixel defining films PDL. The non-light emitting regions NPXA may be regions between neighboring light emitting regions PXA-R, PXA-G, and PXA-B, and may correspond to the pixel defining films PDL. For example, in an embodiment, the light emitting regions PXA-R, PXA-G, and PXA-B may each respectively correspond to a pixel. The pixel defining films PDL may separate the light emitting elements ED-1, ED-2, and ED-3. The emission layers EML-R, EML-G, and EML-B of the light emitting elements ED-1, ED-2 and ED-3 may be disposed in the openings OH defined by the pixel defining films PDL and separated from each other.

The light emitting regions PXA-R, PXA-G, and PXA-B may be arranged into groups according to the color of light generated from the light emitting elements ED-1, ED-2, and ED-3. In the display device DD according to an embodiment shown in FIGS. 1 and 2, three light emitting regions PXA-R, PXA-G, and PXA-B which emit red light, green light, and blue light, are shown as an example. For example, the display device DD of an embodiment may include a red light emitting region PXA-R, a green light emitting region PXA-G, and a blue light emitting region PXA-B, which are distinct from one another.

In the display device DD according to an embodiment, the light emitting elements ED-1, ED-2, and ED-3 may emit light having different wavelength ranges from each other. For example, in an embodiment, the display device DD may include a first light emitting element ED-1 emitting red light, a second light emitting element ED-2 emitting green light, and a third light emitting element ED-3 emitting blue light. In an embodiment, the red light emitting region PXA-R, the green light emitting region PXA-G, and the blue light emitting region PXA-B of the display device DD may respectively correspond to the first light emitting element ED-1, the second light emitting element ED-2, and the third light emitting element ED-3.

However, embodiments are not limited thereto, and the first to third light emitting elements ED-1, ED-2 and ED-3 may each emit light in a same wavelength range or at least one light emitting element may emit light in a wavelength range that is different from the others. For example, the first to third light emitting elements ED-1, ED-2, and ED-3 may each emit blue light.

The light emitting regions PXA-R, PXA-G, and PXA-B in the display device DD according to an embodiment may be arranged in the form of a stripe. Referring to FIG. 1, the red light emitting regions PXA-R, the green light emitting regions PXA-G, and the blue light emitting regions PXA-B may each be arranged along a second directional axis DR2. In an embodiment, the red light emitting region PXA-R, the green light emitting region PXA-G, and the blue light emitting region PXA-B may be alternately arranged in turn along a first directional axis DR1.

In FIGS. 1 and 2 the light emitting regions PXA-R, PXA-G, and PXA-B are all similar in size, but embodiments are not limited thereto, and the light emitting regions PXA-R, PXA-G and PXA-B may be different in size from each other according to a wavelength range of emitted light. In an embodiment, areas of the light emitting regions PXA-R, PXA-G, and PXA-B may be areas in a plan view that are defined by the first directional axis DR1 and the second directional axis DR2.

An arrangement of the light emitting regions PXA-R, PXA-G, and PXA-B is not limited to what is shown in FIG. 1, and the order in which the red light emitting region PXA-R, the green light emitting region PXA-G, and the blue light emitting region PXA-B are arranged may include various combinations according to display quality characteristics that are required for the display device DD. For example, the light emitting regions PXA-R, PXA-G, and PXA-B may be arranged in the form of a pentile configuration (such as a PENTILE™ configuration) or in a diamond configuration (such as a Diamond Pixel™ configuration).

The areas of each of the light emitting regions PXA-R, PXA-G, and PXA-B may be different in size from one another. For example, in an embodiment, the green light emitting region PXA-G may be smaller than the blue light emitting region PXA-B in size, but embodiments are not limited thereto.

In the display device DD shown in FIG. 2, at least one of the first to third light emitting elements ED-1, ED-2, and ED-3 may include a polycyclic compound according to an embodiment.

FIGS. 3 to 6 are each a schematic cross-sectional view showing a light emitting element ED according to an embodiment. The light emitting elements ED according to an embodiment may each include a first electrode EL1, a second electrode EL2 facing the first electrode EL1, and at least one functional layer disposed between the first electrode EL1 and the second electrode EL2. The light emitting element ED according to an embodiment may include a polycyclic compound, which will be described later, in at least one functional layer. The polycyclic compound according to an embodiment may be referred to as a first compound herein.

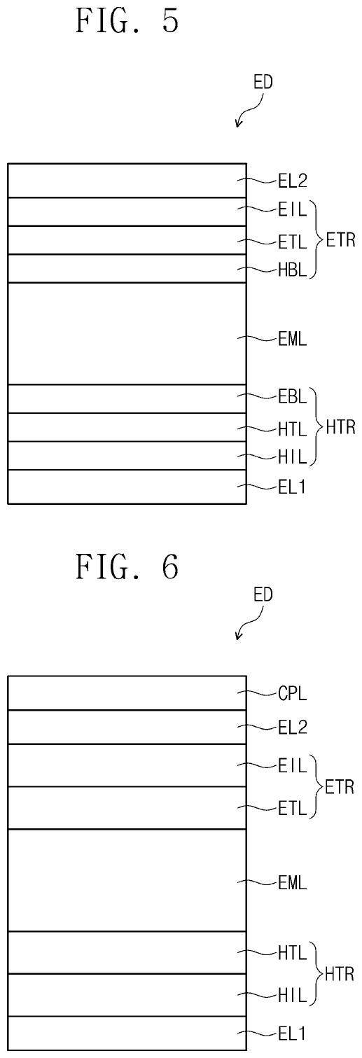

The light emitting element ED may include a hole transport region HTR, an emission layer EML, and an electron transport region ETR, which may be stacked in that order, as the at least one functional layer. Referring to FIG. 3, a light emitting element ED may include a first electrode EL1, a hole transport region HTR, an emission layer EML, an electron transport region ETR, and a second electrode EL2. The light emitting element ED may include a polycyclic compound according to an embodiment, which will be described later, in the emission layer EML. In an embodiment, the display device DD (FIG. 2) may include light emitting regions, and the emission layer EML constituting at least one light emitting region may include the polycyclic compound according to an embodiment, which will be described later. In comparison with FIG. 3, FIG. 4 shows a schematic cross-sectional view of a light emitting element ED according to an embodiment in which the hole transport region HTR includes a hole injection layer HIL and a hole transport layer HTL, and the electron transport region ETR includes an electron injection layer EIL and an electron transport layer ETL. In comparison with FIG. 3, FIG. 5 shows a schematic cross-sectional view of a light emitting element ED according to an embodiment in which the hole transport region HTR includes a hole injection layer HIL, a hole transport layer HTL, and an electron blocking layer EBL, and the electron transport region ETR includes an electron injection layer EIL, an electron transport layer ETL, and a hole blocking layer HBL. In comparison with FIG. 4, FIG. 6 shows a schematic cross-sectional view of a light emitting element ED according to an embodiment, in which a capping layer CPL disposed on the second electrode EL2 is provided.

In the light emitting element ED according to an embodiment, the first electrode EL1 has conductivity. The first electrode EL1 may be formed of a metal material, a metal alloy, or a conductive compound. The first electrode EL1 may be an anode or a cathode. However, embodiments are not limited thereto. The first electrode EL1 may be a pixel electrode. The first electrode EL1 may be a transmissive electrode, a transflective electrode, or a reflective electrode. The first electrode may include at least one of Ag, Mg, Cu, Al, Pt, Pd, Au, Ni, Nd, Ir, Cr, Li, Ca, LiF, Mo, Ti, W, In, Sn, Zn, an oxide thereof, a compound thereof, or a mixture thereof.

When the first electrode EL1 is a transmissive electrode, the first electrode EL1 may include a transparent metal oxide such as indium tin oxide (ITO), indium zinc oxide (IZO), zinc oxide (ZnO), and indium tin zinc oxide (ITZO). When the first electrode EL1 is a transflective electrode or the reflective electrode, the first electrode EL1 may include Ag, Mg, Cu, Al, Pt, Pd, Au, Ni, Nd, Ir, Cr, Li, Ca, LiF/Ca (a stack structure of LiF and Ca), LiF/Al (a stack structure of LiF and Al), Mo, Ti, W, a compound thereof, or a mixture thereof (e.g., a mixture of Ag and Mg). In another embodiment, first electrode EL1 may have a multilayer structure including a reflective film or a transflective film formed of the above-described materials, and a transparent conductive film formed of indium tin oxide (ITO), indium zinc oxide (IZO), zinc oxide (ZnO), indium tin zinc oxide (ITZO), and the like. For example, the first electrode EL1 may have a three-layer structure of ITO/Ag/ITO, but embodiments are not limited thereto. The first electrode EL1 may include the above-described metal materials, a combination of two or more metal materials selected from the above-described metal materials, or oxides of the above-described metal materials. The first electrode EL1 may have a thickness in a range of about 700 Å to about 10,000 Å. For example, the first electrode EL1 may have a thickness in a range of 1000 Å to about 3,000 Å.

The hole transport region HTR is provided on the first electrode ELL The hole transport region HTR may be a layer consisting of a single material, a layer including different materials, or a structure including multiple layers including different materials.

The hole transport region HTR may include at least one of a hole injection layer HIL, a hole transport layer HTL, a buffer layer (not shown), a light emitting auxiliary layer (not shown), and an electron blocking layer EBL. Although not shown in the drawings, in an embodiment, the hole transport region HTR may include multiple hole transport layers that are stacked.

For example, the hole transport region HTR may have a single-layer structure formed of a hole injection layer HIL or a hole transport layer HTL, or may have a single-layer structure formed of a hole injection material or a hole transport material. In an embodiment, the hole transport region HTR may have a single-layer structure formed of different materials, or may have a structure in which a hole injection layer HIL/hole transport layer HTL, a hole injection layer HIL/hole transport layer HTL/buffer layer (not shown), a hole injection layer HIL/buffer layer (not shown), or a hole transport layer HTL/buffer layer (not shown) are stacked in its respective stated order from the first electrode EL1, but embodiments are not limited thereto.

The hole transport region HTR may have, for example, a thickness in a range of about 50 Å to about 15,000 Å. The hole transport region HTR may be formed using various methods such as a vacuum deposition method, a spin coating method, a cast method, a Langmuir-Blodgett (LB) method, an inkjet printing method, a laser printing method, and a laser induced thermal imaging (LITI) method.

In the light emitting element ED according to an embodiment, the hole transport region HTR may include a compound represented by Formula H-1:

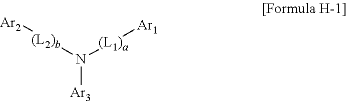

In Formula H-1, L₁ and L₂ may each independently be a direct linkage, a substituted or unsubstituted arylene group having 6 to 30 ring-forming carbon atoms, or a substituted or unsubstituted heteroarylene group having 2 to 30 ring-forming carbon atoms. In Formula H-1, a and b may each independently be an integer from 0 to 10. If a or b is 2 or greater, multiple L₁ groups and L₂ groups may each independently be a substituted or unsubstituted arylene group having 6 to 30 ring-forming carbon atoms, or a substituted or unsubstituted heteroarylene group having 2 to 30 ring-forming carbon atoms.

In Formula H-1, Ar₁ and Ar₂ may each independently be a substituted or unsubstituted aryl group having 6 to 30 ring-forming carbon atoms, or a substituted or unsubstituted heteroaryl group having 2 to 30 ring-forming carbon atoms. In Formula H-1, Ar₃ may be a substituted or unsubstituted aryl group having 6 to 30 ring-forming carbon atoms.

In an embodiment, the compound represented by Formula H-1 may be a monoamine compound. In another embodiment, the compound represented by Formula H-1 may be a diamine compound in which at least one of Ar-₁ to Ar₃ includes an amine group as a substituent. In still another embodiment, the compound represented by Formula H-1 may be a carbazole-based compound in which at least one of Ar₁ or Ar₂ includes a substituted or unsubstituted carbazole group, or may be a fluorene-based compound in which at least one of Ar₁ or Ar₂ includes a substituted or unsubstituted fluorene group.

The compound represented by Formula H-1 may be any compound selected from Compound Group H. However, the compounds listed in Compound Group H are only presented as examples, and the compound represented by Formula H is not limited to Compound Group H.

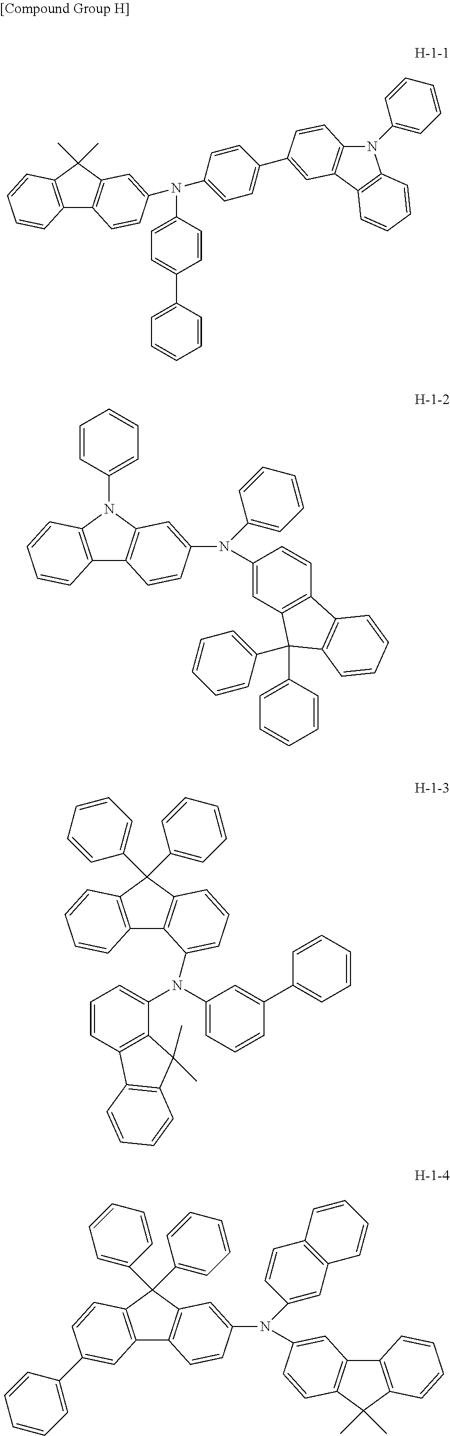 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(N(c2ccc3c(c2)C(c2ccccc2)(c2ccccc2)c2ccccc2-3)c2ccc3c4ccccc4n(-c4ccccc4)c3c2)cc1 ; CC1(C)c2ccccc2-c2cccc(N(c3cccc(-c4ccccc4)c3)c3cccc4c3-c3ccccc3C4(c3ccccc3)c3ccccc3)c21 ; CC1(C)c2ccccc2-c2cc(N(c3ccc4c(c3)C(c3ccccc3)(c3ccccc3)c3ccc(-c5ccccc5)cc3-4)c3ccc4ccccc4c3)ccc21]

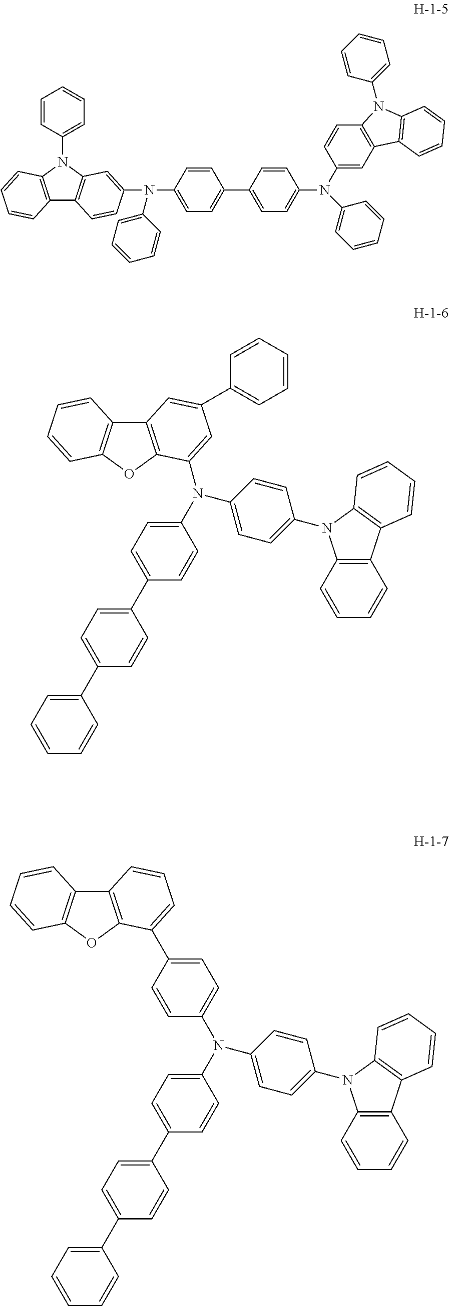 [SMILES: c1ccc(N(c2ccc(-c3ccc(N(c4ccccc4)c4ccc5c6ccccc6n(-c6ccccc6)c5c4)cc3)cc2)c2ccc3c(c2)c2ccccc2n3-c2ccccc2)cc1 ; c1ccc(-c2ccc(-c3ccc(N(c4ccc(-n5c6ccccc6c6ccccc65)cc4)c4cc(-c5ccccc5)cc5c4oc4ccccc45)cc3)cc2)cc1 ; c1ccc(-c2ccc(-c3ccc(N(c4ccc(-c5cccc6c5oc5ccccc56)cc4)c4ccc(-n5c6ccccc6c6ccccc65)cc4)cc3)cc2)cc1]

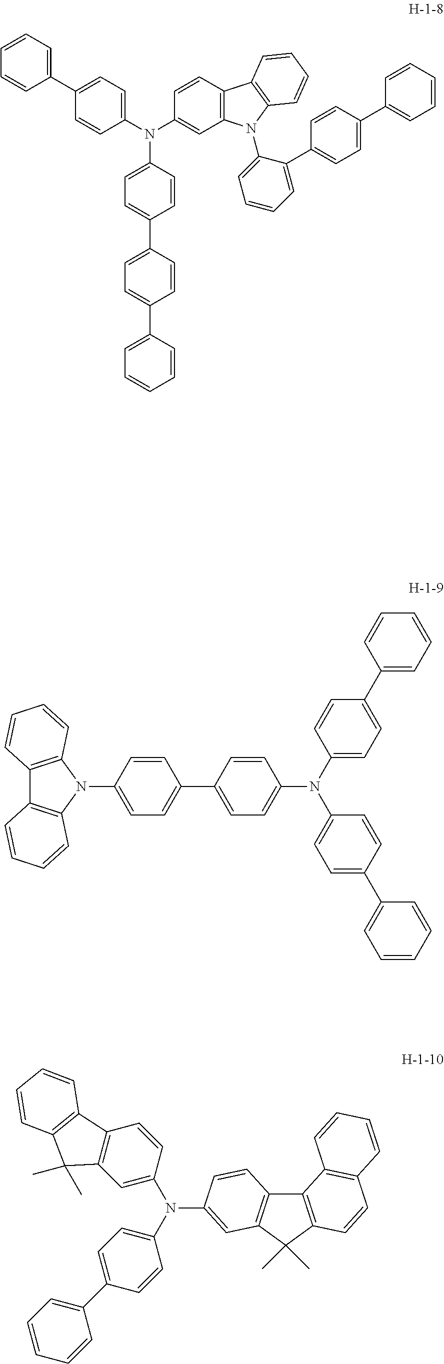 [SMILES: c1ccc(-c2ccc(-c3ccc(N(c4ccc(-c5ccccc5)cc4)c4ccc5c6ccccc6n(-c6ccccc6-c6ccc(-c7ccccc7)cc6)c5c4)cc3)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1 ; CC1(C)c2ccccc2-c2ccc(N(c3ccc(-c4ccccc4)cc3)c3ccc4c(c3)C(C)(C)c3ccc5ccccc5c3-4)cc21]

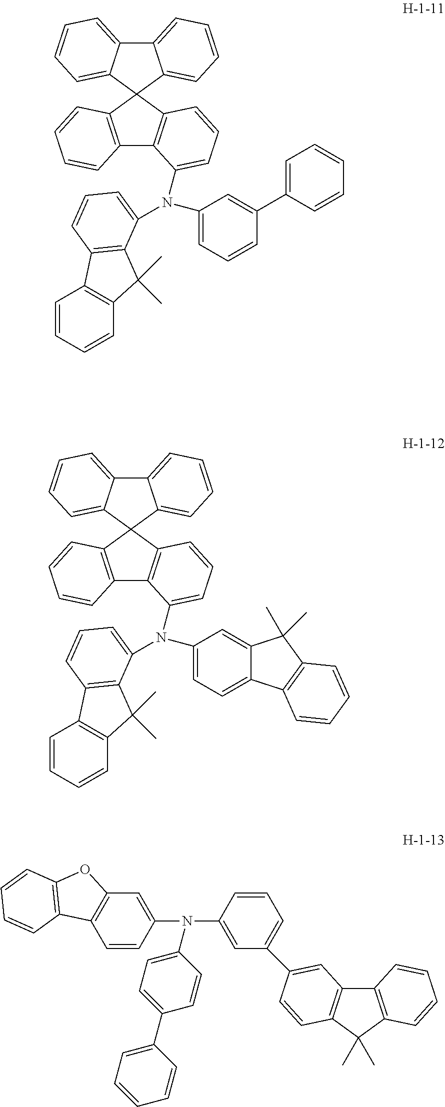 [SMILES: CC1(C)c2ccccc2-c2cccc(N(c3cccc(-c4ccccc4)c3)c3cccc4c3-c3ccccc3C43c4ccccc4-c4ccccc43)c21 ; CC1(C)c2ccccc2-c2ccc(N(c3cccc4c3-c3ccccc3C43c4ccccc4-c4ccccc43)c3cccc4c3C(C)(C)c3ccccc3-4)cc21 ; CC1(C)c2ccccc2-c2cc(-c3cccc(N(c4ccc(-c5ccccc5)cc4)c4ccc5c(c4)oc4ccccc45)c3)ccc21]

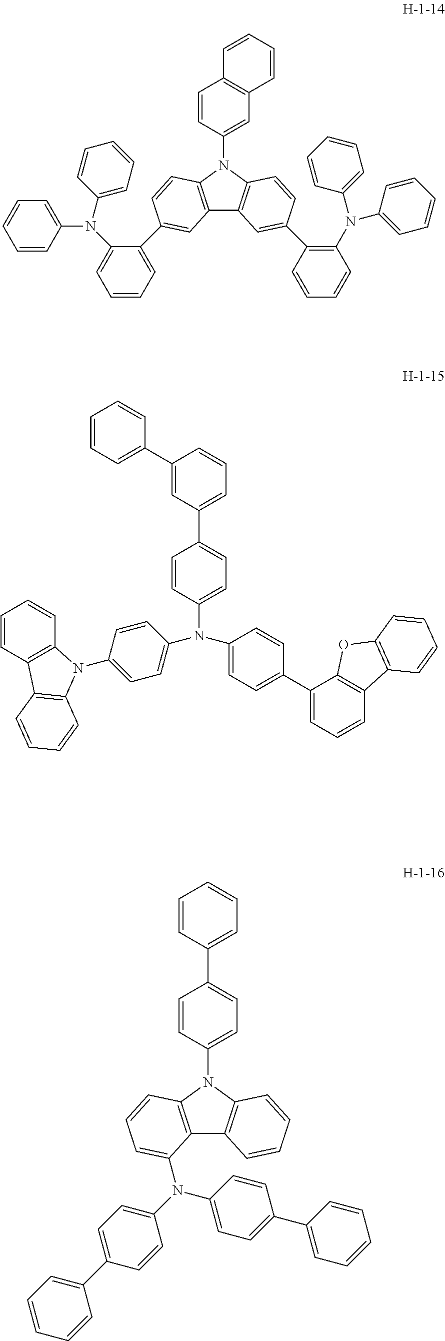 [SMILES: c1ccc(N(c2ccccc2)c2ccccc2-c2ccc3c(c2)c2cc(-c4ccccc4N(c4ccccc4)c4ccccc4)ccc2n3-c2ccc3ccccc3c2)cc1 ; c1ccc(-c2cccc(-c3ccc(N(c4ccc(-c5cccc6c5oc5ccccc56)cc4)c4ccc(-n5c6ccccc6c6ccccc65)cc4)cc3)c2)cc1 ; c1ccc(-c2ccc(N(c3ccc(-c4ccccc4)cc3)c3cccc4c3c3ccccc3n4-c3ccc(-c4ccccc4)cc3)cc2)cc1]

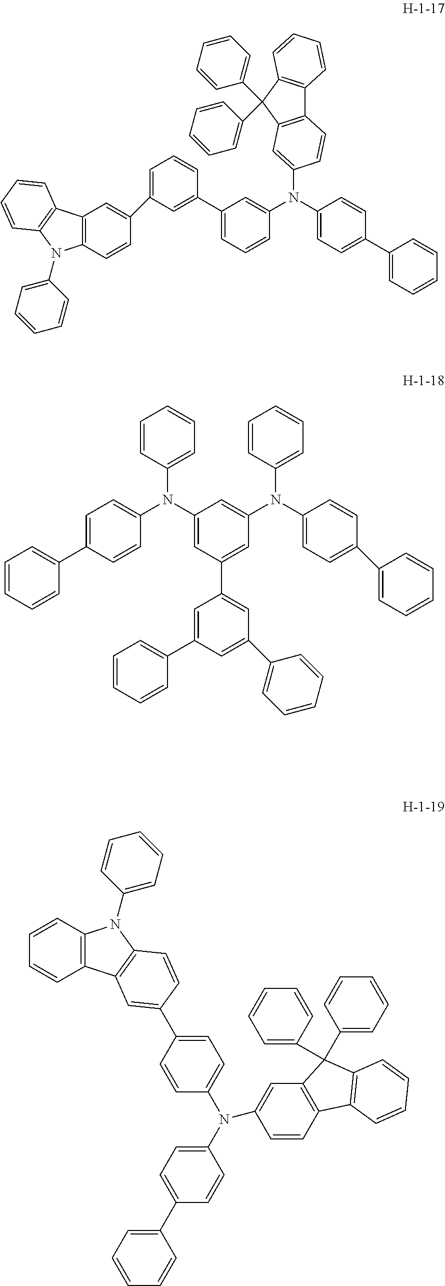 [SMILES: c1ccc(-c2ccc(N(c3cccc(-c4cccc(-c5ccc6c(c5)c5ccccc5n6-c5ccccc5)c4)c3)c3ccc4c(c3)C(c3ccccc3)(c3ccccc3)c3ccccc3-4)cc2)cc1 ; c1ccc(-c2ccc(N(c3ccccc3)c3cc(-c4cc(-c5ccccc5)cc(-c5ccccc5)c4)cc(N(c4ccccc4)c4ccc(-c5ccccc5)cc4)c3)cc2)cc1 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

The hole transport region HTR may further include a phthalocyanine compound such as copper phthalocyanine, N¹,N¹′-([1,1′-biphenyl]-4,4′-diyl)bis(N¹-phenyl-N⁴,N⁴-di-m-tolylbenzene-1,4-diamine) (DNTPD), 4,4′,4″-[tris(3-methylphenyl)phenylamino]triphenylamine (m-MTDATA), 4,4′4″-tris(N,N-diphenylamino)triphenylamine (TDATA), 4,4′,4″-tris[N(1-naphthyl)-N-phenylamino]-triphenyl amine (1-TNATA), 4,4′,4″-tris[N(2-naphthyl)-N-phenylamino]-triphenylamine (2-TNATA), poly(3,4-ethylenedioxythiophene)/poly(4-styrene sulfonate) (PEDOT/PSS), polyaniline/dodecylbenzenesulfonic acid (PANI/DBSA), polyaniline/camphor sulfonic acid (PANI/CSA), polyaniline/poly(4-styrene sulfonate) (PANI/PSS), N,N′-di(naphthalene-1-yl)-N,N′-diphenyl-benzidine (NPB or NPD, α-NPD), triphenylamine-containing polyetherketone (TPAPEK), 4-isopropyl-4′-methyldiphenyliodonium[tetrakis(pentafluorophenyl)borate], dipyrazino[2,3-f: 2′,3′-h]quinoxaline-2,3,6,7,10,11-hexacarbonitrile (HATCN), and the like.

The hole transport region HTR may include carbazole-based derivatives such as N-phenyl carbazole and polyvinyl carbazole, fluorene-based derivatives, triphenylamine-based derivatives such as 4,4′,4″-tris(N-carbazolyl)triphenylamine (TCTA), N,N′-bis(3-methylphenyl)-N,N′-diphenyl-[1,1′-biphenyl]-4,4′-diamine (TPD), N,N′-di(naphthalene-1-yl)-N,N′-diphenyl-benzidine (NPB), 4,4 ‘-Cyclohexylidene bis[N,N-bis(4-methylphenyl)benzenamine] (TAPC), 4,4’-bis[N,N′-(3-tolyl)amino]-3,3′-dimethylbiphenyl (HMTPD), 1,3-bis(N-carbazolyl)benzene (mCP), and the like.

The hole transport region HTR may include 9-(4-tert-Butylphenyl)-3,6-bis(triphenylsilyl)-9H-carbazole (CzSi), 9-phenyl-9H-3,9′-bicarbazole (CCP), 1,3-bis(1,8-dimethyl-9H-carbazol-9-yl)benzene (mDCP), and the like.

The hole transport region HTR may include the compounds of the hole transport region described above in at least one of a hole injection layer HIL, a hole transport layer HTL, or an electron blocking layer EBL.

The hole transport region HTR may have a thickness in a range of about 100 Å to about 10,000 Å. For example, the hole transport region HTR may have a thickness in a range of about 100 Å to about 5,000 Å. When the hole transport region HTR includes the hole injection layer HIL, the hole injection layer HIL may have a thickness in a range of, for example, about 30 Å to about 1,000 Å. When the hole transport region HTR includes the hole transport layer HTL, the hole transport layer HTL may have a thickness in a range of about 30 Å to about 1000 Å. When the hole transport region HTR includes the electron blocking layer EBL, the electron blocking layer EBL may have a thickness in a range of, for example, about 10 Å to about 1,000 Å. When the thicknesses of the hole transport region HTR, the hole injection layer HIL, the hole transport layer HTL, and the electron blocking layer EBL satisfy the above-described ranges, satisfactory hole transport properties may be obtained without a substantial increase in driving voltage.

The hole transport region HTR may further include, in addition to the above-described materials, a charge generation material to increase conductivity. The charge generation material may be uniformly or non-uniformly dispersed in the hole transport region HTR. The charge generation material may be, for example, a p-dopant. The p-dopant may include at least one of a halogenated metal compound, a quinone derivative, a metal oxide, or a cyano group-containing compound, but is not limited thereto. For example, the p-dopant may include a halogenated metal compound such as CuI and RbI, a quinone derivative such as tetracyanoquinodimethane (TCNQ) and 2,3,5,6-tetrafluoro-7,7,8,8-tetracyanoquinodimethane (F4-TCNQ), a metal oxide such as a tungsten oxide and a molybdenum oxide, a cyano group-containing compound such as dipyrazino[2,3-f: 2′,3′-h]quinoxaline-2,3,6,7,10,11-hexacarbonitrile (HATCN) or 4-[[2,3-bis[cyano-(4-cyano-2,3,5,6-tetrafluorophenyl)methylidene]cyclopropylidene]-cyanomethyl]-2,3,5,6-tetrafluorobenzonitrile (NDP9), and the like, but is not limited thereto.

As described above, the hole transport region HTR may further include at least one of a buffer layer (not shown), a light emitting auxiliary layer (not shown), or an electron blocking layer EBL in addition to a hole injection layer HIL and a hole transport layer HTL. The buffer layer (not shown) may compensate for a resonance distance according to wavelengths of light emitted from an emission layer EML, and may thus increase luminous efficiency. Materials which may be included in the hole transport region HTR may be used as materials included in the buffer layer (not shown). The electron blocking layer EBL may prevent electrons from being injected from the electron transport region ETR to the hole transport region HTR. The light emitting auxiliary layer (not shown) may improve charge balance between holes and electrons. When the hole transport region HTR includes the electron blocking layer EBL, the electron blocking layer EBL may function as a light emitting auxiliary layer.

The emission layer EML is provided on the hole transport region HTR. The emission layer EML may have a thickness in a range of about 100 Å to about 1,000 Å. For example, the emission layer EML may have a thickness in a range of about 100 Å to about 300 Å. The emission layer EML may be a layer consisting of a single material, a layer including different materials, or a structure including layers including different materials.

In the light emitting element ED according to an embodiment, the emission layer EML may include a first compound. The first compound corresponds to a polycyclic compound according to an embodiment. The polycyclic compound may include a fused ring core that includes one boron atom (B) and two nitrogen atoms (N) as ring-forming atoms. In the polycyclic compound, the fused ring core may have a structure in which one boron atom and first to third aromatic rings are fused through two nitrogen atoms. The first to third aromatic rings may be substituted or unsubstituted benzene rings.

The first aromatic ring and the second aromatic ring may be symmetrical to each other with respect to a boron atom in the fused ring core. The third aromatic ring may be bonded to the boron atom and to the two nitrogen atoms in the fused ring core.

The polycyclic compound according to an embodiment may be one in which sterically bulky first and second substituents are bonded (e.g., directly bonded or indirectly bonded) to the fused ring core. The first substituent may be a benzene ring in which at least one hydrogen atom is substituted with another substituent, and the second substituent may be a substituted or unsubstituted benzene ring. In the polycyclic compound according to an embodiment, the first substituent may be bonded (e.g., directly bonded) to the fused ring core, and the second substituent may be bonded (e.g., indirectly bonded) to the fused ring core through a linker. In the polycyclic compound according to an embodiment, the first substituent may be connected (e.g., directly connected) to any one of two nitrogen atoms in the fused ring core. The first substituent may be one in which a 1-1 substituent is connected at an ortho position with respect to a nitrogen atom in the core portion. In the polycyclic compound, the second substituent may be connected at a para position with respect to a boron atom in the fused ring core through a linker. The polycyclic compound may include first and second substituents connected (e.g., directly or indirectly connected) to the fused ring core, and may thus be used as a light emitting material exhibiting improved luminous properties.

The polycyclic compound according to an embodiment may be represented by Formula 1. In the polycyclic compound according to an embodiment represented by Formula 1, the benzene ring to which R⁹ to R¹² and Y are connected may correspond to the first substituent described above, and the benzene ring to which R¹³ to R¹⁷ are connected may correspond to the second substituent described above.

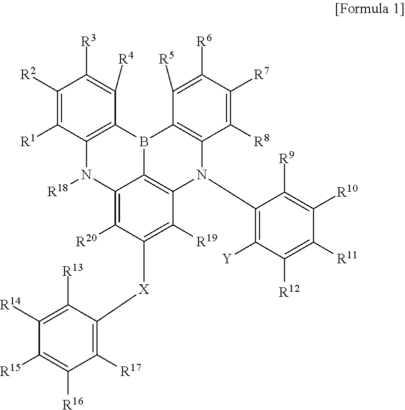

In Formula 1, X may be O, S, or C(R²¹)(R²²). In Formula 1, R¹ to R²² may each independently be a hydrogen atom, a deuterium atom, a halogen atom, a cyano group, a hydroxy group, a substituted or unsubstituted thio group, a substituted or unsubstituted oxy group, a substituted or unsubstituted silyl group, a substituted or unsubstituted amino group, a substituted or unsubstituted alkyl group having 1 to 20 carbon atoms, a substituted or unsubstituted alkenyl group having 2 to 20 carbon atoms, a substituted or unsubstituted cycloalkyl group having 3 to 30 ring-forming carbon atoms, a substituted or unsubstituted aryl group having 6 to 30 ring-forming carbon atoms, or a substituted or unsubstituted heteroaryl group having 2 to 30 ring-forming carbon atoms, may be bonded to an adjacent group to form a ring. In Formula 1, a case where R¹⁸ is bonded to R¹ or R²⁰ to form a ring may be excluded.

In an embodiment, R¹ to R⁸ may each independently be a hydrogen atom, a deuterium atom, a substituted or unsubstituted silyl group, a substituted or unsubstituted alkyl group having 1 to 20 carbon atoms, a substituted or unsubstituted cycloalkyl group having 3 to 30 ring-forming carbon atoms, a substituted or unsubstituted aryl group having 6 to 30 ring-forming carbon atoms, or a substituted or unsubstituted heteroaryl group having 2 to 30 ring-forming carbon atoms. For example, R¹ to R⁸ may each independently be a hydrogen atom, a deuterium atom, a substituted or unsubstituted silyl group, a substituted or unsubstituted methyl group, a substituted or unsubstituted i-propyl group, a substituted or unsubstituted t-butyl group, a substituted or unsubstituted pentyl group, a substituted or unsubstituted cyclohexyl group, a substituted or unsubstituted phenyl group, a substituted or unsubstituted naphthyl group, or a substituted or unsubstituted carbazole group. When R¹ to R⁸ are each substituted, R¹ to R⁸ may be substituted with a deuterium atom, a substituted or unsubstituted methyl group, or a substituted or unsubstituted phenyl group.

In an embodiment, R⁹ to R¹² may each independently be a hydrogen atom, a deuterium atom, a cyano group, a substituted or unsubstituted oxy group, a substituted or unsubstituted alkyl group having 1 to 20 carbon atoms, a substituted or unsubstituted cycloalkyl group having 3 to 30 ring-forming carbon atoms, or a substituted or unsubstituted aryl group having 6 to 30 ring-forming carbon atoms. For example, R⁹ to R¹² may each independently be a hydrogen atom, a deuterium atom, a cyano group, a substituted or unsubstituted methoxy group, a substituted or unsubstituted phenoxy group, a substituted or unsubstituted methyl group, a substituted or unsubstituted cyclohexyl group, or a substituted or unsubstituted phenyl group. When R⁹ to R¹² are each substituted, R⁹ to R¹² may be substituted with a deuterium atom.

In an embodiment, R¹³ to R¹⁷ may each independently be a hydrogen atom, a deuterium atom, a halogen atom, a cyano group, a substituted or unsubstituted oxy group, a substituted or unsubstituted alkyl group having 1 to 20 carbon atoms, a substituted or unsubstituted cycloalkyl group having 3 to 30 ring-forming carbon atoms, a substituted or unsubstituted aryl group having 6 to 30 ring-forming carbon atoms, a substituted or unsubstituted heteroaryl group having 2 to 30 ring-forming carbon atoms, or bonded to an adjacent group to form a ring. For example, R¹³ to R¹⁷ may each independently be a hydrogen atom, a deuterium atom, a halogen atom, a cyano group, a substituted or unsubstituted methoxy group, a substituted or unsubstituted methyl group, a substituted or unsubstituted i-propyl group, a substituted or unsubstituted t-butyl group, a substituted or unsubstituted cyclopropyl group, a substituted or unsubstituted phenyl group, a substituted or unsubstituted biphenyl group, or a substituted or unsubstituted carbazole group, or may be bonded to an adjacent group to form a substituted or unsubstituted cyclohexyl group, a substituted or unsubstituted dibenzothiophene group, or a substituted or unsubstituted dibenzofuran group. For example, R¹³ and R¹⁴, R¹⁴ and R¹⁵, R¹⁵ and R¹⁶, or R¹⁶ and R¹⁷ may be bonded to each other to form a substituted or unsubstituted cyclohexyl group, a substituted or unsubstituted dibenzothiophene group, or a substituted or unsubstituted dibenzofuran group. When R¹³ to R¹⁷ are each substituted, R¹³ to R¹⁷ may be substituted with a deuterium atom, a methyl group, or a phenyl group.

In an embodiment, R¹⁸ may independently be a substituted or unsubstituted aryl group having 6 to 30 ring-forming carbon atoms. For example, R¹⁸ may be a substituted or unsubstituted phenyl group. In an embodiment, R¹⁹ and R²⁰ may each independently be a hydrogen atom or a deuterium atom. In an embodiment, R²¹ and R²² may each independently be a hydrogen atom, a deuterium atom, a substituted or unsubstituted alkyl group having 1 to 20 carbon atoms, or a substituted or unsubstituted aryl group having 6 to 30 ring-forming carbon atoms. R²¹ and R²² may each independently be a hydrogen atom, a deuterium atom, a substituted or unsubstituted methyl group, or a substituted or unsubstituted phenyl group. In an embodiment, at least one of R²¹ or R²² may be a substituted or unsubstituted alkyl group having 1 to 10 carbon atoms or a substituted or unsubstituted aryl group having 6 to 10 ring-forming carbon atoms; and the remainder of R²¹ or R²² may be a hydrogen atom or a deuterium atom.

In Formula 1, Y may correspond to the 1-1 substituent bonded to the first substituent described above. In Formula 1, Y may be a hydroxy group, a substituted or unsubstituted thio group, a substituted or unsubstituted oxy group, a substituted or unsubstituted arylthioxy group, a substituted or unsubstituted silyl group, a substituted or unsubstituted amine group, a substituted or unsubstituted cycloalkyl group having 3 to 30 ring-forming carbon atoms, a substituted or unsubstituted aryl group having 6 to 30 ring-forming carbon atoms, or a substituted or unsubstituted heteroaryl group having 2 to 30 ring-forming carbon atoms. For example, in an embodiment, Y may be a substituted or unsubstituted phenylthio group, a substituted or unsubstituted phenoxy group, a substituted or unsubstituted methoxy group, a substituted or unsubstituted t-butoxy group, a substituted or unsubstituted diethylamino group, a substituted or unsubstituted diphenylamino group, a substituted or unsubstituted cyclohexyl group, a substituted or unsubstituted phenyl group, a substituted or unsubstituted naphthyl group, a substituted or unsubstituted benzothiazole group, a substituted or unsubstituted benzoxazole group, a substituted or unsubstituted indole group, a substituted or unsubstituted benzothiophene group, or a substituted or unsubstituted benzofuran group. In an embodiment, when Y is substituted, Y may be substituted with a deuterium atom or a phenyl group, but embodiments are not limited thereto. When Y is substituted with another substituent, a case where Y is substituted with an alkyl group may be excluded. In an embodiment, in the polycyclic compound represented by Formula 1, a case where Y is a pyridine group substituted with two methyl groups (e.g., a dimethylpyridine group) may be excluded.

The polycyclic compound according to an embodiment may include a deuterium atom as a substituent. For example, in an embodiment, in the polycyclic compound represented by Formula 1, at least one of Y and R¹ to R²² may include a deuterium atom or a substituent including a deuterium atom. However, this is only an example, and embodiments are not limited thereto.

In an embodiment, the polycyclic compound represented by Formula 1 may be represented by Formula 2. Formula 2 represents an embodiment where R¹⁸ in Formula 1 is further defined. Formula 2 shows a polycyclic compound according to an embodiment, in which R¹⁸ of Formula 1 is a substituted or unsubstituted phenyl group, as an example. In Formula 2, X, Y, R¹ to R¹⁷, R¹⁹, and R²⁰ are the same as defined in Formula 1.

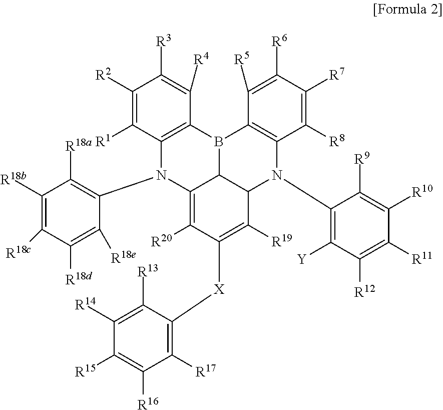

In Formula 2, R^{18a} to R^{18e} may each independently be a hydrogen atom, a deuterium atom, a cyano group, a substituted or unsubstituted thio group, a substituted or unsubstituted oxy group, a substituted or unsubstituted amino group, a substituted or unsubstituted alkyl group having 1 to 10 carbon atoms, a substituted or unsubstituted cycloalkyl group having 3 to 10 ring-forming carbon atoms, a substituted or unsubstituted aryl group having 6 to 10 ring-forming carbon atoms, or a substituted or unsubstituted heteroaryl group having 2 to 10 ring-forming carbon atoms. For example, R^{18a} to R^{18e} may be a hydrogen atom, a deuterium atom, a cyano group, a substituted or unsubstituted phenylthio group, a substituted or unsubstituted methoxy group, a substituted or unsubstituted t-butoxy group, a substituted or unsubstituted phenoxy group, a substituted or unsubstituted diethylamino group, a substituted or unsubstituted diphenylamino group, a substituted or unsubstituted methyl group, a substituted or unsubstituted t-butyl group, a substituted or unsubstituted phenyl group, a substituted or unsubstituted biphenyl group, a substituted or unsubstituted cyclohexyl group, a substituted or unsubstituted naphthyl group, a substituted or unsubstituted benzothiazole group, a substituted or unsubstituted benzoxazole group, a substituted or unsubstituted indole group, a substituted or unsubstituted benzothiophene group, or a substituted or unsubstituted benzofuran group. However, embodiments are not limited thereto.

In an embodiment, the polycyclic compound represented by Formula 2 may be represented by Formula 2-a or Formula 2-b. Formulas 2-a and 2-b each further define R¹ to R⁸, R¹⁹ and R²⁰ in Formula 2. In Formulas 2-a and 2-b, X, Y, R⁹ to R¹⁷, and R^{18a} to R^{18e} are the same as defined in Formulas 1 and 2.

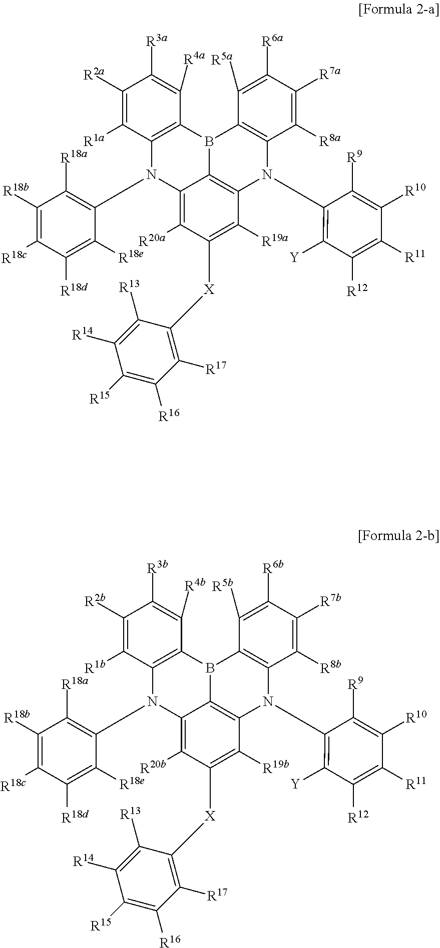

In Formulas 2-a and 2-b, R^{1a}, R^{2a}, R^{4a}, R^{5a}, R^{7a}, R^{8a}, R^{19a}, R^{20a}, R^{1b}, R^{3b}, R^{4b}, R^{5b}, R^{6b}, R^{8b}, R^{19b}, and R^{20b} may each independently be a hydrogen atom or a deuterium atom.

In Formulas 2-a and 2-b, R^{3a}, R^{6a}, R^{2b}, and R^{7b} may each independently be a hydrogen atom, a deuterium atom, a substituted or unsubstituted silyl group, a substituted or unsubstituted alkyl group having 1 to 10 carbon atoms, a substituted or unsubstituted cycloalkyl group having 3 to 15 ring-forming carbon atoms, a substituted or unsubstituted aryl group having 6 to 15 ring-forming carbon atoms, or a substituted or unsubstituted hetero aryl group having 2 to 15, ring-forming carbon atoms. For example, R^{3a}, R^{6a}, R^{2b}, and R^{7b} may each independently be a hydrogen atom, a deuterium atom, a trimethylsilyl group, a dimethylphenylsilyl group, a substituted or unsubstituted methyl group, a substituted or unsubstituted i-propyl group, a substituted or unsubstituted t-butyl group, a substituted or unsubstituted pentyl group, a substituted or unsubstituted cyclohexyl group, a substituted or unsubstituted phenyl group, a substituted or unsubstituted naphthyl group, or a substituted or unsubstituted carbazole group. When R^{3a}, R^{6a}, R^{2b}, and R^{7b} are each substituted, R^{3a}, R^{6a}, R^{2b}, and R^{7b} may be substituted with a deuterium atom, a substituted or unsubstituted methyl group, or a substituted or unsubstituted phenyl group.

The polycyclic compound according to an embodiment represented by Formula 1 may be represented by Formula 3. Formula 3 further defines the 1-1 substituent connected to the first substituent in the polycyclic compound represented by Formula 1. Formula 3 corresponds to the polycyclic compound according to an embodiment in which Y of Formula 1 is a substituted or unsubstituted phenyl group.

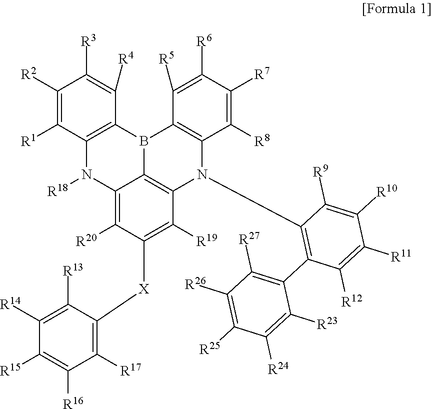

In Formula 3 R²³ to R²⁷ may each independently be a hydrogen atom or a deuterium atom. In Formula 3, X and R¹ to R²⁰ are the same as defined in Formula 1.

The polycyclic compound according to an embodiment represented by Formula 1 may be represented by any one of Formulas 4-1 to 4-3. In Formulas 4-1 to 4-3, Y is the same as defined in Formula 1.

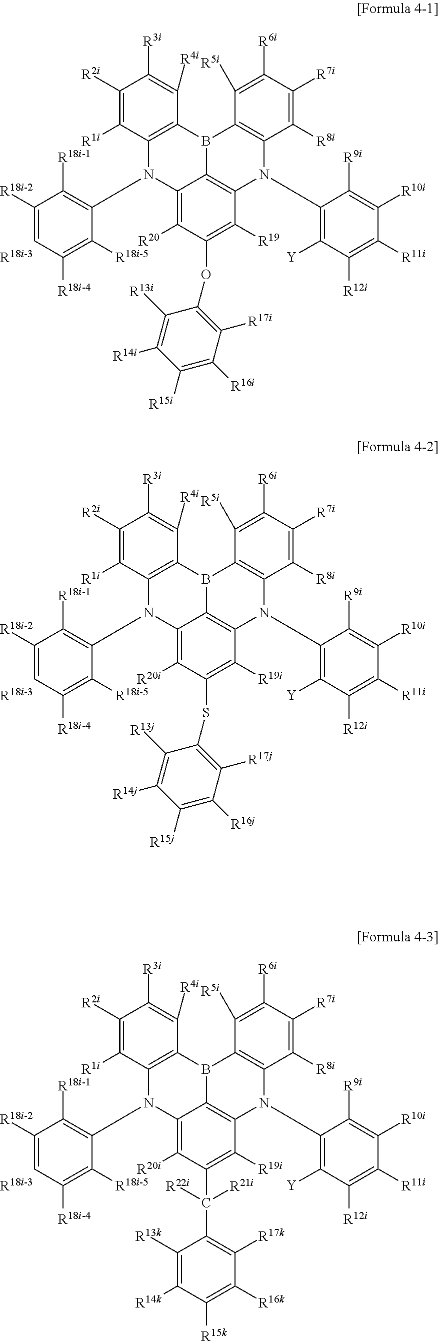

In Formula 4-1, R¹³ⁱ to R¹⁷ⁱ may each independently be a hydrogen atom, a deuterium atom, a halogen atom, a substituted or unsubstituted alkyl group having 1 to 10 carbon atoms, a substituted or unsubstituted aryl group having 6 to 15 ring-forming carbon atoms, or a substituted or unsubstituted heteroaryl group having 2 to 15 ring-forming carbon atoms, or may be bonded to an adjacent group to form a ring. For example, R¹³ⁱ to R¹⁷ⁱ may each independently be a hydrogen atom, a deuterium atom, a halogen atom, a substituted or unsubstituted methyl group, a substituted or unsubstituted phenyl group, a substituted or unsubstituted carbazole group, a substituted or unsubstituted dibenzofuran group, or a substituted or unsubstituted dibenzothiophene group. In an embodiment, R¹³ⁱ to R¹⁷ⁱ may be bonded to an adjacent group to form a substituted or unsubstituted cyclohexyl group, a substituted or unsubstituted dibenzothiophene group, or a substituted or unsubstituted dibenzofuran group. For example, any pair of R¹³ⁱ and R¹⁴ⁱ, R¹⁴ⁱ and R¹⁵ⁱ, R¹⁵ⁱ and R¹⁶ⁱ, and R¹⁶ⁱ and R¹⁷ⁱ may be bonded to each other to form a substituted or unsubstituted cyclohexyl group, a substituted or unsubstituted dibenzothiophene group, or a substituted or unsubstituted dibenzofuran group.

In Formula 4-2, R^{13j} to R^{17j} may each independently be a hydrogen atom, a deuterium atom, a halogen atom, a cyano group, a substituted or unsubstituted oxy group, a substituted or unsubstituted alkyl group having 1 to 10 carbon atoms, or a substituted or unsubstituted aryl group having 6 to 15 ring-forming carbon atoms. For example, R^{13j} to R^{17j} may each independently be a hydrogen atom, a deuterium atom, a halogen atom, a cyano group, a substituted or unsubstituted methoxy group, a substituted or unsubstituted phenoxy group, a substituted or unsubstituted methyl group, a substituted or unsubstituted i-propyl group, or a substituted or unsubstituted phenyl group.

In Formula 4-3, R^{13k} to R^{17k} may each independently be a hydrogen atom, a deuterium atom, a halogen atom, a cyano group, a substituted or unsubstituted alkyl group having 1 to 10 carbon atoms, a substituted or unsubstituted cycloalkyl group having 3 to 10 ring-forming carbon atoms, or a substituted or unsubstituted aryl group having 6 to 15 ring-forming carbon atoms. For example, R^{13k} to R^{17k} may each independently be a hydrogen atom, a deuterium atom, a halogen atom, a cyano group, a substituted or unsubstituted methyl group, a substituted or unsubstituted i-propyl group, a substituted or unsubstituted cyclopropyl group, a substituted or unsubstituted phenyl group, or a substituted or unsubstituted biphenyl group.

In Formula 4-3, R²¹ⁱ and R²²ⁱ may each independently be a hydrogen atom, a deuterium atom, a substituted or unsubstituted alkyl group having 1 to 10 carbon atoms, or a substituted or unsubstituted aryl group having 6 to 15 ring-forming carbon atoms. In an embodiment, at least one of R²¹ⁱ or R²²ⁱ may be a substituted or unsubstituted alkyl group having 1 to 10 carbon atoms, or a substituted or unsubstituted aryl group having 6 to 15 ring-forming carbon atoms, and the remainder of R²¹ⁱ or R²²ⁱ may be a hydrogen atom or a deuterium atom. For example, R²¹ⁱ and R²²ⁱ may each independently be a hydrogen atom, a deuterium atom, a substituted or unsubstituted methyl group, or a substituted or unsubstituted phenyl group.

In Formulas 4-1 to 4-3, R¹ⁱ to R⁸ⁱ may each independently be a hydrogen atom, a deuterium atom, a substituted or unsubstituted silyl group, a substituted or unsubstituted alkyl group having 1 to 20 carbon atoms, a substituted or unsubstituted cycloalkyl group having 3 to 30 ring-forming carbon atoms, a substituted or unsubstituted aryl group having 6 to 30 ring-forming carbon atoms, or a substituted or unsubstituted heteroaryl group having 2 to 30 ring-forming carbon atoms. For example, R¹ⁱ to R⁸ⁱ may each independently be a hydrogen atom, a deuterium atom, a substituted or unsubstituted silyl group, a substituted or unsubstituted methyl group, a substituted or unsubstituted i-propyl group, a substituted or unsubstituted t-butyl group, a substituted or unsubstituted pentyl group, a substituted or unsubstituted cyclohexyl group, a substituted or unsubstituted phenyl group, a substituted or unsubstituted naphthyl group, or a substituted or unsubstituted carbazole group. When R¹ⁱ to R⁸ⁱ are each substituted, R¹ⁱ to R⁸ⁱ may be substituted with a deuterium atom, a substituted or unsubstituted methyl group, or a substituted or unsubstituted phenyl group.

In Formulas 4-1 to 4-3, R⁹ⁱ to R¹²ⁱ may each independently be a hydrogen atom, a deuterium atom, a cyano group, a substituted or unsubstituted oxy group, a substituted or unsubstituted alkyl group having 1 to 20 carbon atoms, a substituted or unsubstituted cycloalkyl group having 3 to 30 ring-forming carbon atoms, or a substituted or unsubstituted aryl group having 6 to 30 ring-forming carbon atoms. For example, R⁹ⁱ to R¹²ⁱ may each independently be a hydrogen atom, a deuterium atom, a cyano group, a substituted or unsubstituted methoxy group, a substituted or unsubstituted phenoxy group, a substituted or unsubstituted methyl group, or a substituted or unsubstituted cyclohexyl group, or a substituted or unsubstituted phenyl group. When R⁹ⁱ to R¹²ⁱ are each substituted, R⁹ⁱ to R¹²ⁱ may be substituted with a deuterium atom.

In Formulas 4-1 to 4-3, R¹⁸ⁱ⁻¹ to R¹⁸ⁱ⁻⁵ may each independently be a hydrogen atom, a deuterium atom, a cyano group, a substituted or unsubstituted thio group, a substituted or unsubstituted oxy group, a substituted or unsubstituted amino group, a substituted or unsubstituted alkyl group having 1 to 20 carbon atoms, a substituted or unsubstituted cycloalkyl group having 3 to 30 ring-forming carbon atoms, a substituted or unsubstituted aryl group having 6 to 30 ring-forming carbon atoms, or a substituted or unsubstituted heteroaryl group having 2 to 30 ring-forming carbon atoms. For example, R¹⁸ⁱ⁻¹ to R¹⁸ⁱ⁻⁵ may be a hydrogen atom, a deuterium atom, a cyano group, a substituted or unsubstituted methoxy group, a substituted or unsubstituted t-butoxy group, a substituted or unsubstituted phenoxy group, a substituted or unsubstituted phenylthio group, a substituted or unsubstituted diethylamino group, a substituted or unsubstituted diphenylamino group, a substituted or unsubstituted methyl group, a substituted or unsubstituted t-butyl group, a substituted or unsubstituted phenyl group, a substituted or unsubstituted biphenyl group, a substituted or unsubstituted cyclohexyl group, a substituted or unsubstituted naphthyl group, a substituted or unsubstituted benzothiazole group, a substituted or unsubstituted benzoxazole group, a substituted or unsubstituted indole group, a substituted or unsubstituted benzothiophene group, or a substituted or unsubstituted benzofuran group. In Formulas 4-1 to 4-3, R¹⁹ⁱ and R²⁰ⁱ may each independently be a hydrogen atom or a deuterium atom. For example, R¹⁹ⁱ and R²⁰ⁱ may both be hydrogen atoms or deuterium atoms.

The polycyclic compound according to an embodiment may be any compound selected from Compound Group 1. The light emitting element ED according to an embodiment may include at least one compound selected from Compound Group 1. In Compound Group 1, D represents a deuterium atom, Me represents a methyl group, and Et represents an ethyl group. In Compound Group 1, F represents a fluorine atom, Cl represents a chlorine atom, and Ph represents a phenyl group.

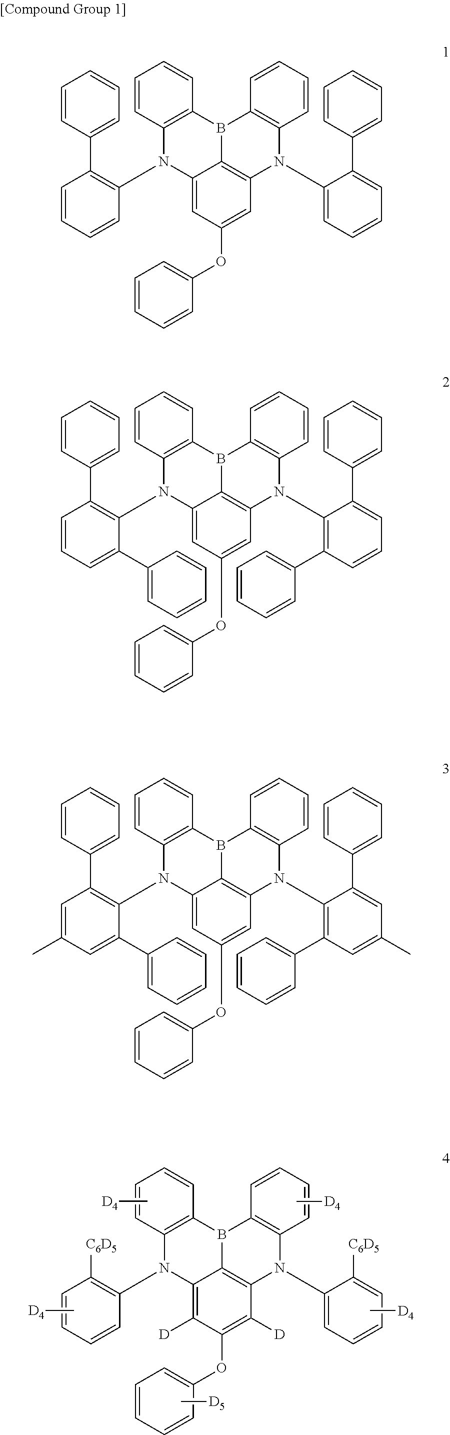

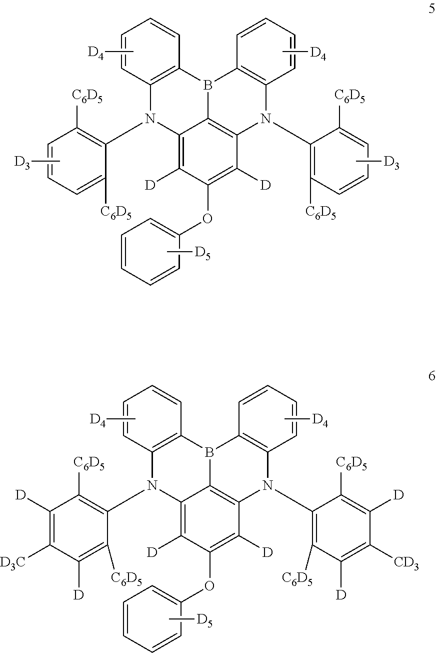

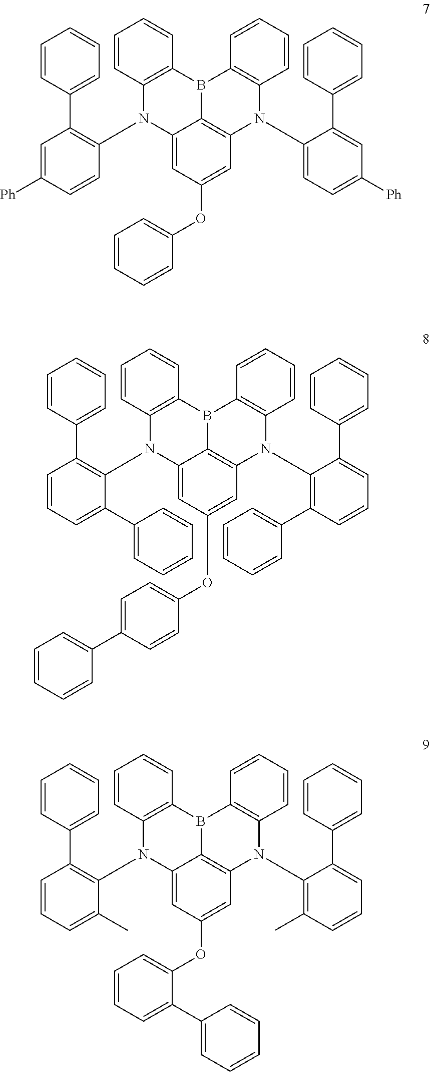 [SMILES: c1ccc(Oc2cc3c4c(c2)N(c2ccc(-c5ccccc5)cc2-c2ccccc2)c2ccccc2B4c2ccccc2N3c2ccc(-c3ccccc3)cc2-c2ccccc2)cc1 ; c1ccc(-c2ccc(Oc3cc4c5c(c3)N(c3c(-c6ccccc6)cccc3-c3ccccc3)c3ccccc3B5c3ccccc3N4c3c(-c4ccccc4)cccc3-c3ccccc3)cc2)cc1 ; Cc1cccc(-c2ccccc2)c1N1c2ccccc2B2c3ccccc3N(c3c(C)cccc3-c3ccccc3)c3cc(Oc4ccccc4-c4ccccc4)cc1c32]

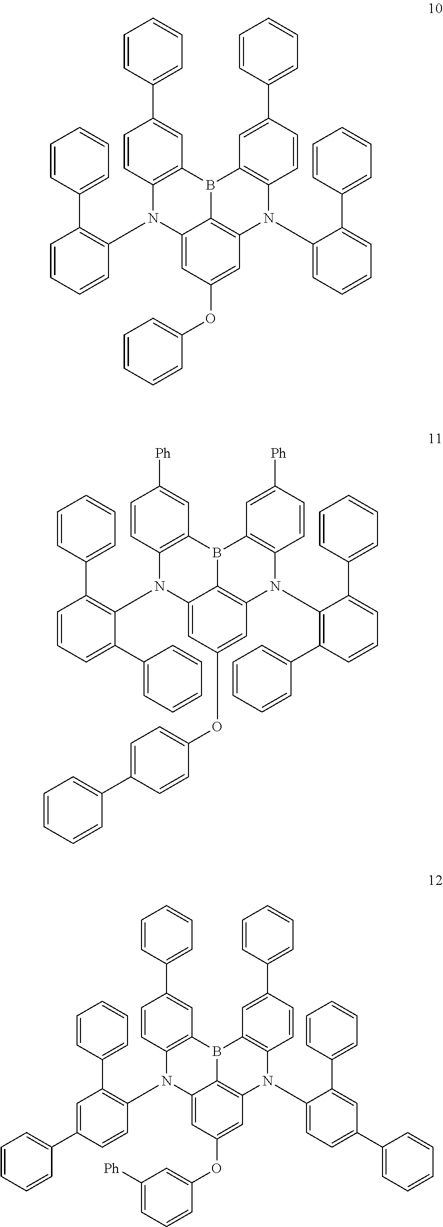 [SMILES: c1ccc(Oc2cc3c4c(c2)N(c2ccccc2-c2ccccc2)c2ccc(-c5ccccc5)cc2B4c2cc(-c4ccccc4)ccc2N3c2ccccc2-c2ccccc2)cc1 ; c1ccc(-c2ccc(Oc3cc4c5c(c3)N(c3c(-c6ccccc6)cccc3-c3ccccc3)c3ccc(-c6ccccc6)cc3B5c3cc(-c5ccccc5)ccc3N4c3c(-c4ccccc4)cccc3-c3ccccc3)cc2)cc1 ; c1ccc(-c2cccc(Oc3cc4c5c(c3)N(c3ccc(-c6ccccc6)cc3-c3ccccc3)c3ccc(-c6ccccc6)cc3B5c3cc(-c5ccccc5)ccc3N4c3ccc(-c4ccccc4)cc3-c3ccccc3)c2)cc1]

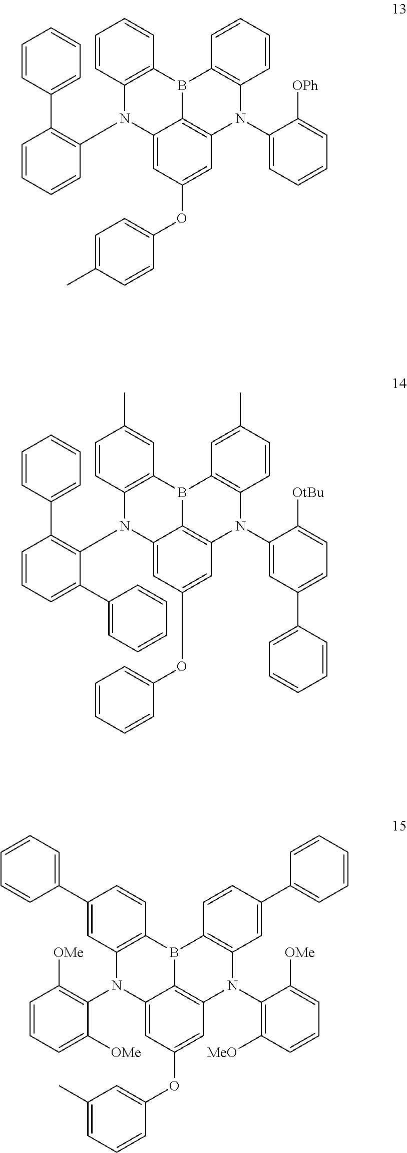 [SMILES: Cc1ccc(Oc2cc3c4c(c2)N(c2ccccc2-c2ccccc2)c2ccccc2B4c2ccccc2N3c2ccccc2Oc2ccccc2)cc1 ; Cc1ccc2c(c1)B1c3cc(C)ccc3N(c3c(-c4ccccc4)cccc3-c3ccccc3)c3cc(Oc4ccccc4)cc(c31)N2c1cc(-c2ccccc2)ccc1OC(C)(C)C ; COc1cccc(OC)c1N1c2cc(-c3ccccc3)ccc2B2c3ccc(-c4ccccc4)cc3N(c3c(OC)cccc3OC)c3cc(Oc4cccc(C)c4)cc1c32]

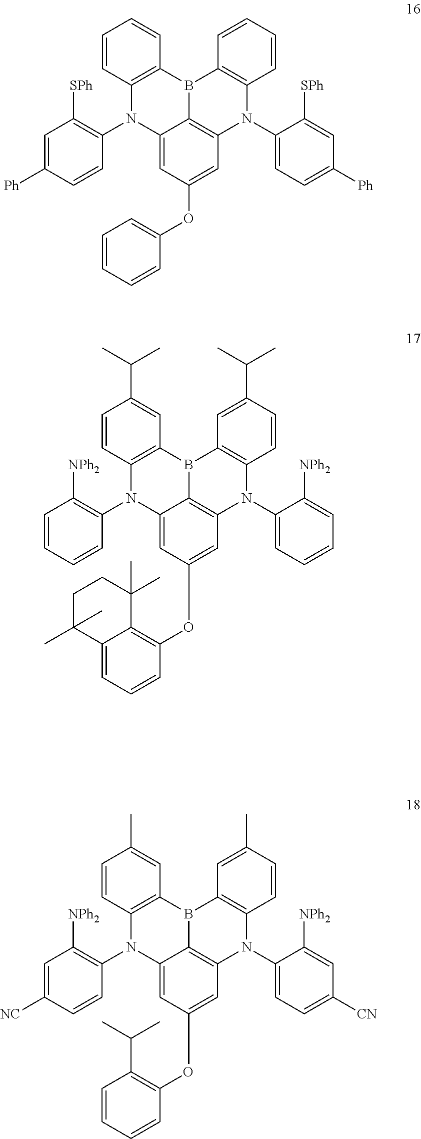

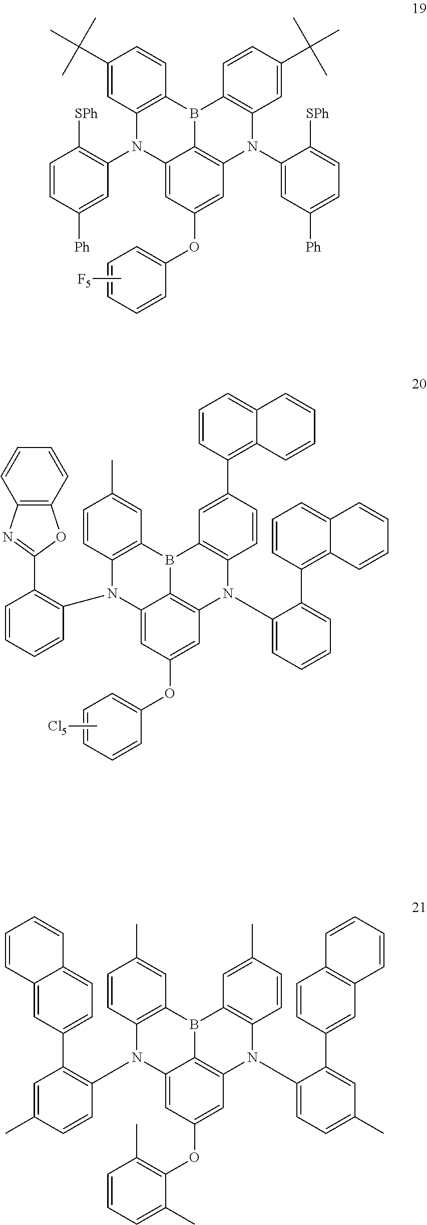

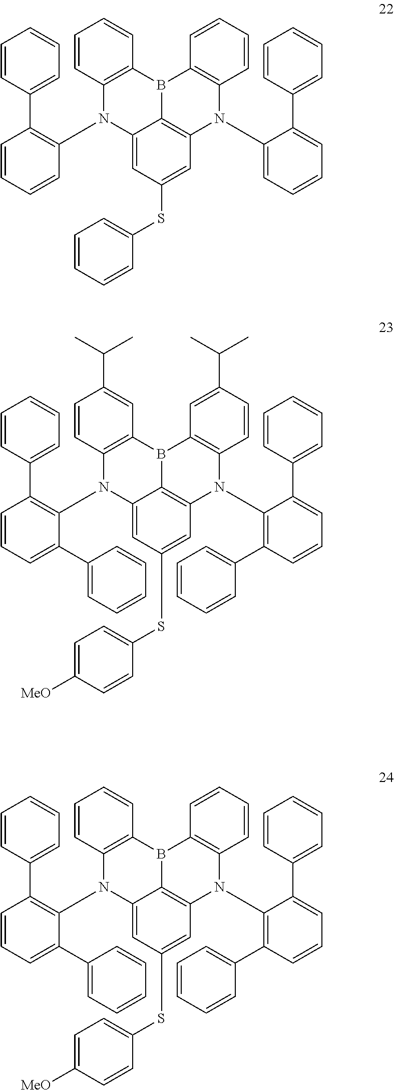 [SMILES: c1ccc(Sc2cc3c4c(c2)N(c2ccccc2-c2ccccc2)c2ccccc2B4c2ccccc2N3c2ccccc2-c2ccccc2)cc1 ; COc1ccc(Sc2cc3c4c(c2)N(c2c(-c5ccccc5)cccc2-c2ccccc2)c2ccc(C(C)C)cc2B4c2cc(C(C)C)ccc2N3c2c(-c3ccccc3)cccc2-c2ccccc2)cc1 ; COc1ccc(Sc2cc3c4c(c2)N(c2c(-c5ccccc5)cccc2-c2ccccc2)c2ccccc2B4c2ccccc2N3c2c(-c3ccccc3)cccc2-c2ccccc2)cc1]

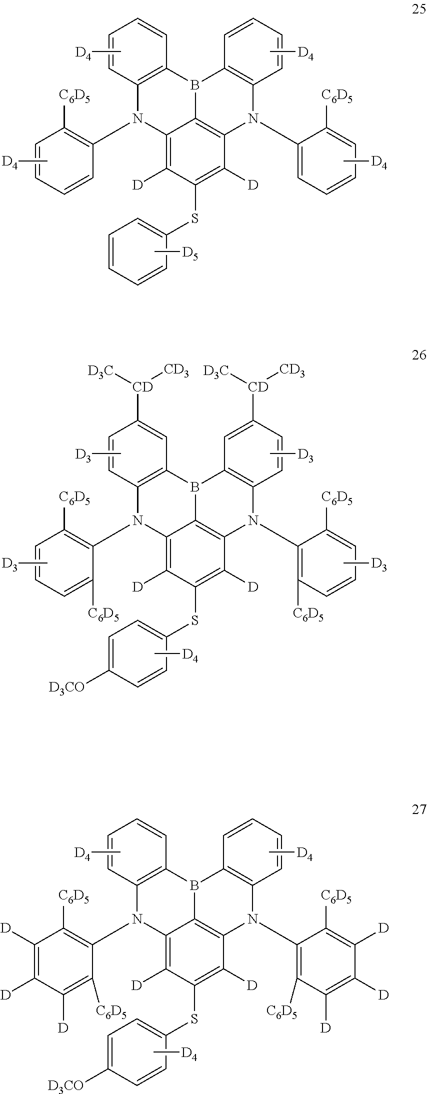

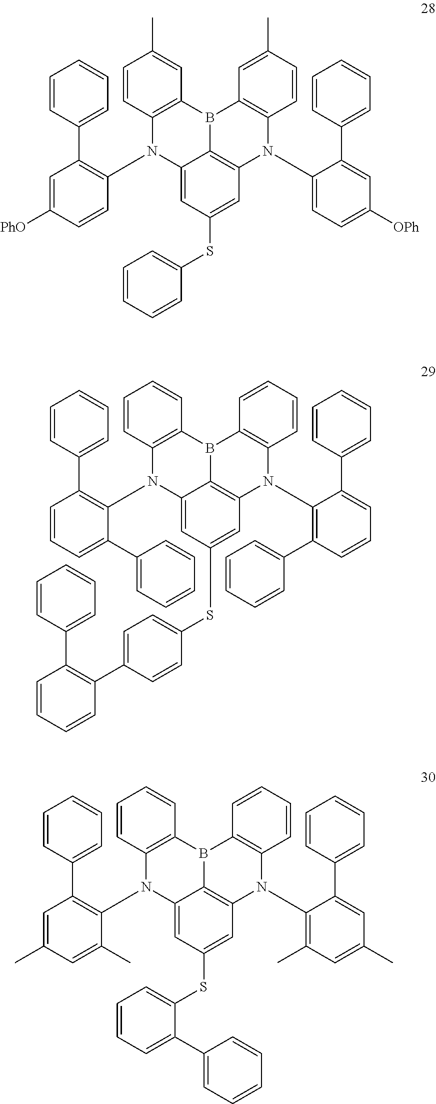

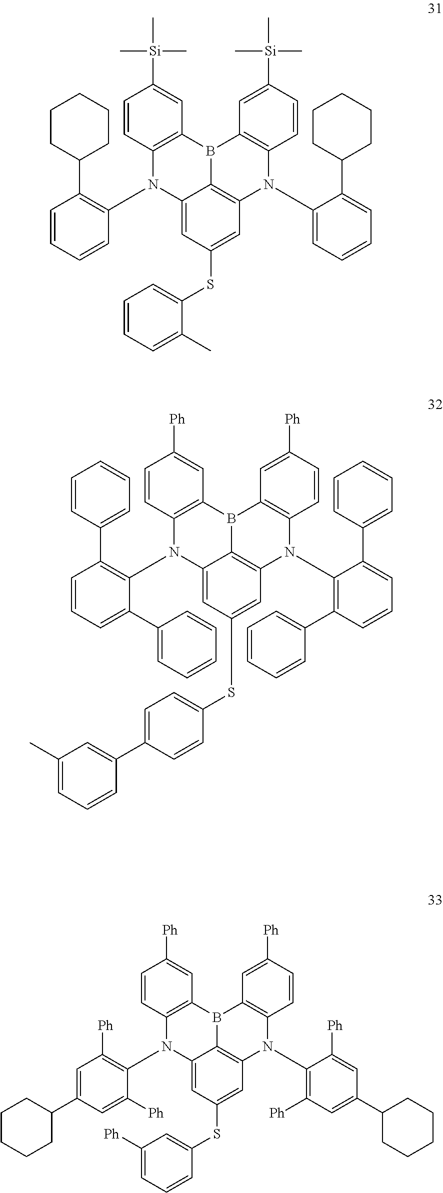 [SMILES: Cc1ccccc1Sc1cc2c3c(c1)N(c1ccccc1C1CCCCC1)c1ccc([Si](C)(C)C)cc1B3c1cc([Si](C)(C)C)ccc1N2c1ccccc1C1CCCCC1 ; Cc1cccc(-c2ccc(Sc3cc4c5c(c3)N(c3c(-c6ccccc6)cccc3-c3ccccc3)c3ccc(-c6ccccc6)cc3B5c3cc(-c5ccccc5)ccc3N4c3c(-c4ccccc4)cccc3-c3ccccc3)cc2)c1 ; c1ccc(-c2cccc(Sc3cc4c5c(c3)N(c3c(-c6ccccc6)cc(C6CCCCC6)cc3-c3ccccc3)c3ccc(-c6ccccc6)cc3B5c3cc(-c5ccccc5)ccc3N4c3c(-c4ccccc4)cc(C4CCCCC4)cc3-c3ccccc3)c2)cc1]

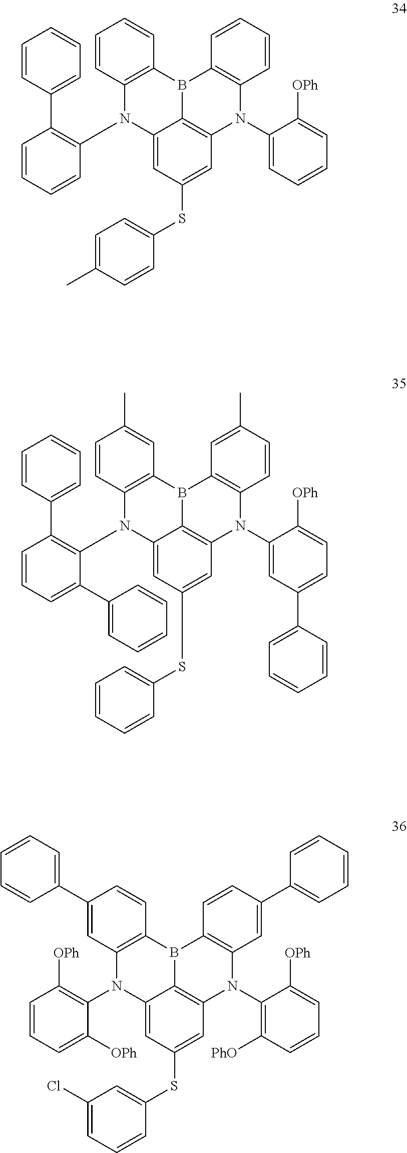 [SMILES: Cc1ccc(Sc2cc3c4c(c2)N(c2ccccc2-c2ccccc2)c2ccccc2B4c2ccccc2N3c2ccccc2Oc2ccccc2)cc1 ; Cc1ccc2c(c1)B1c3cc(C)ccc3N(c3c(-c4ccccc4)cccc3-c3ccccc3)c3cc(Sc4ccccc4)cc(c31)N2c1cc(-c2ccccc2)ccc1Oc1ccccc1 ; Clc1cccc(Sc2cc3c4c(c2)N(c2c(Oc5ccccc5)cccc2Oc2ccccc2)c2cc(-c5ccccc5)ccc2B4c2ccc(-c4ccccc4)cc2N3c2c(Oc3ccccc3)cccc2Oc2ccccc2)c1]

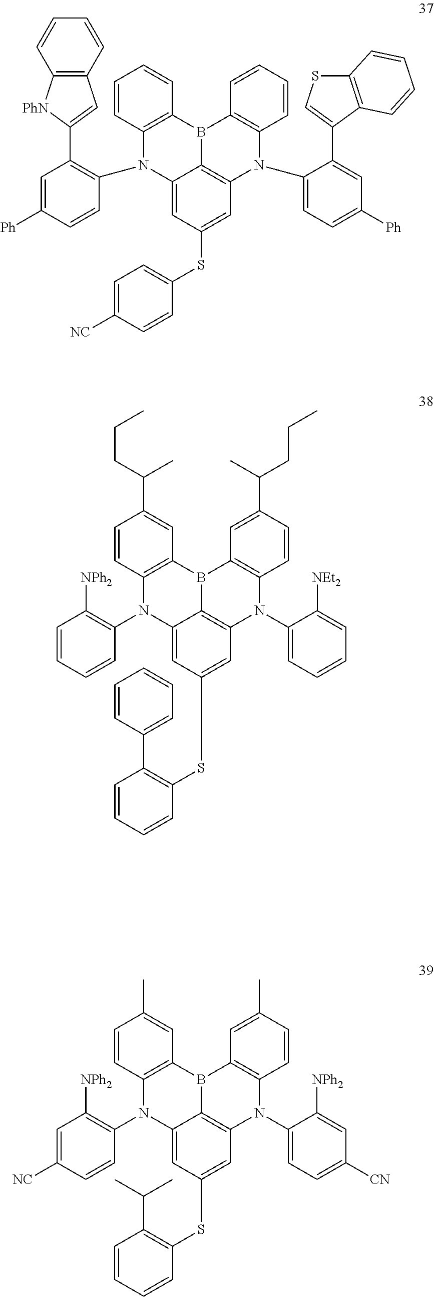

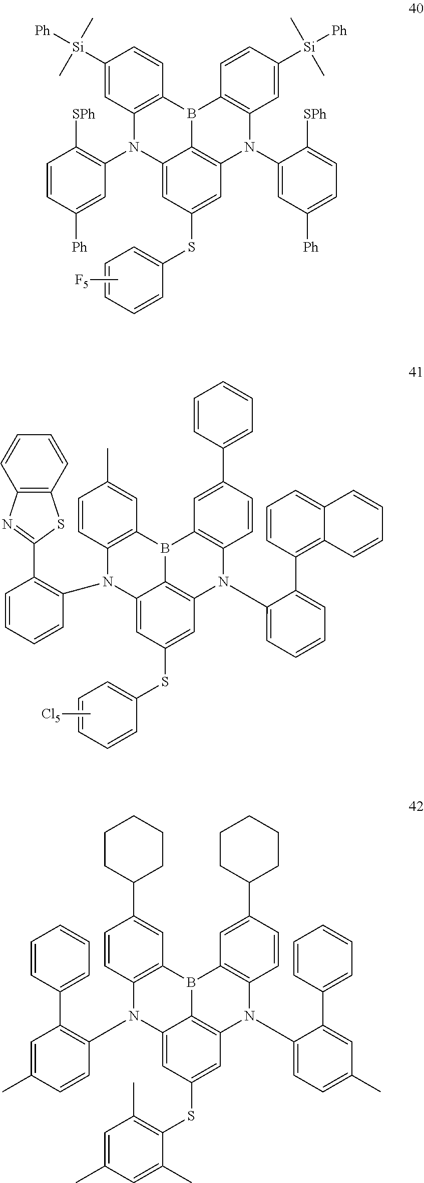

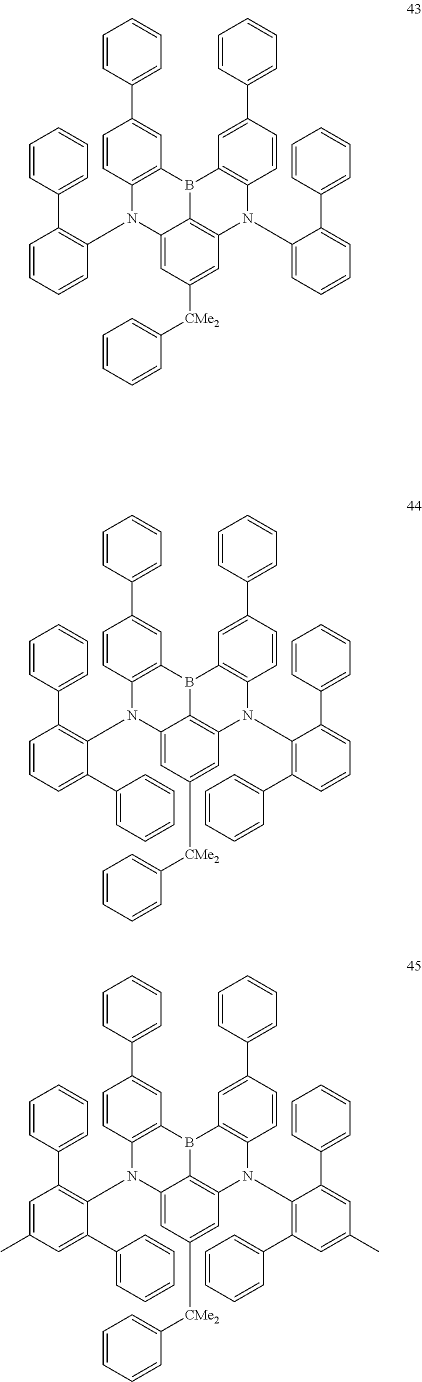

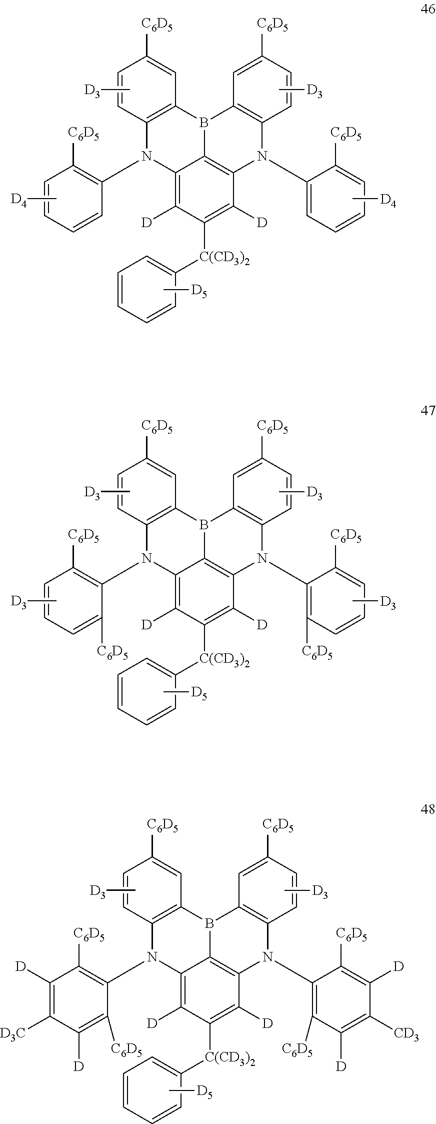

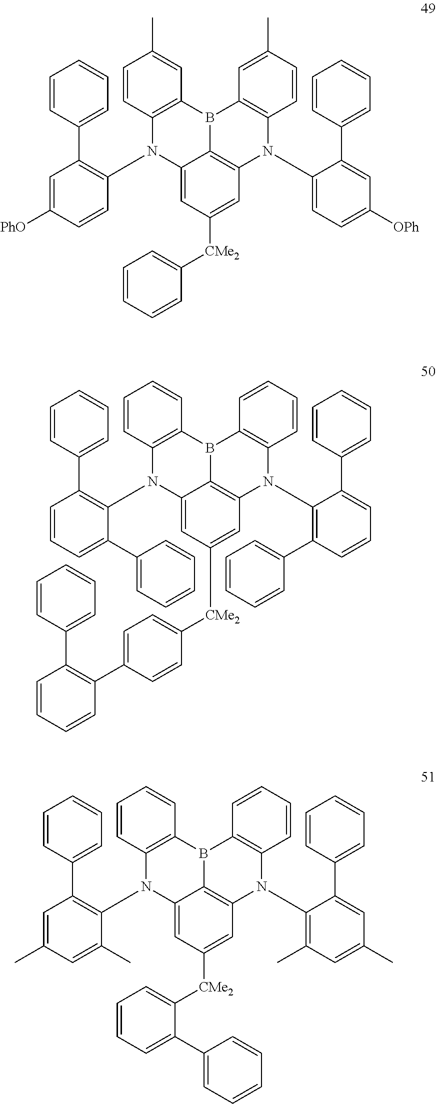

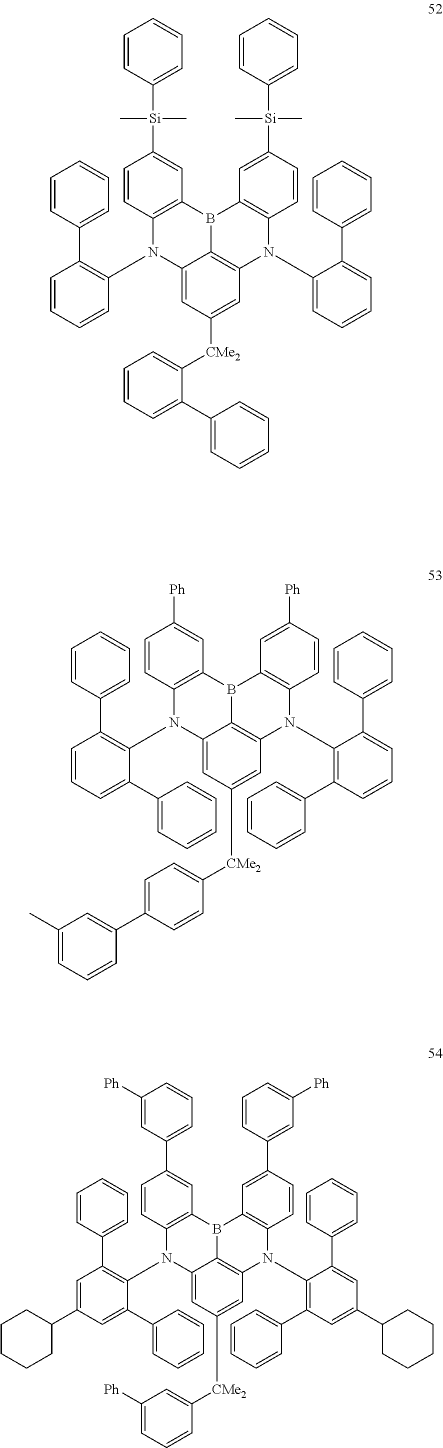

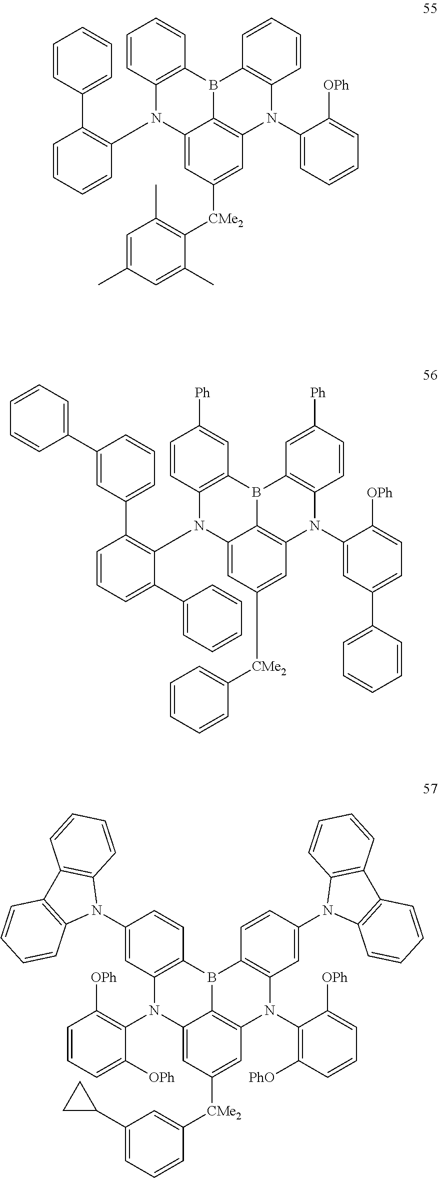

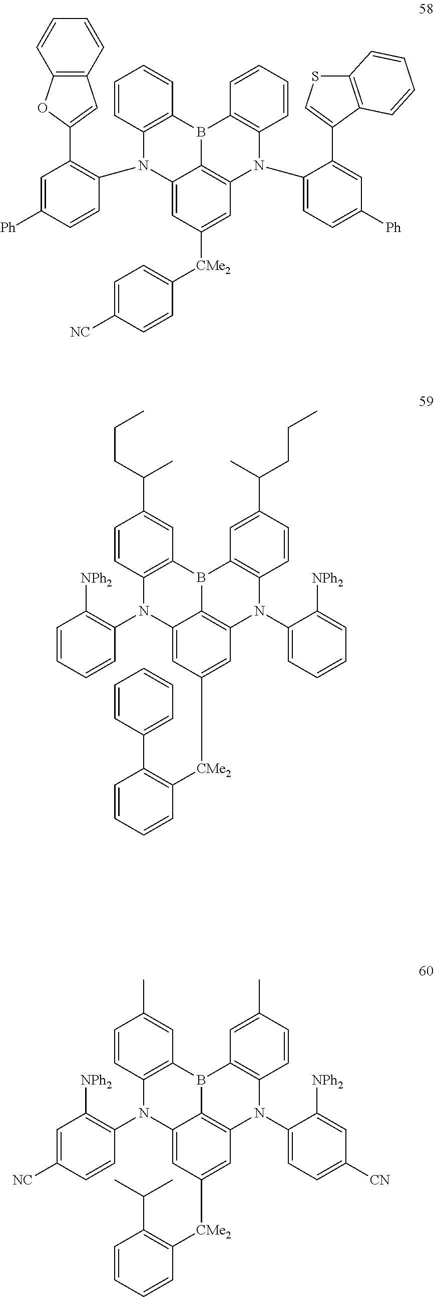

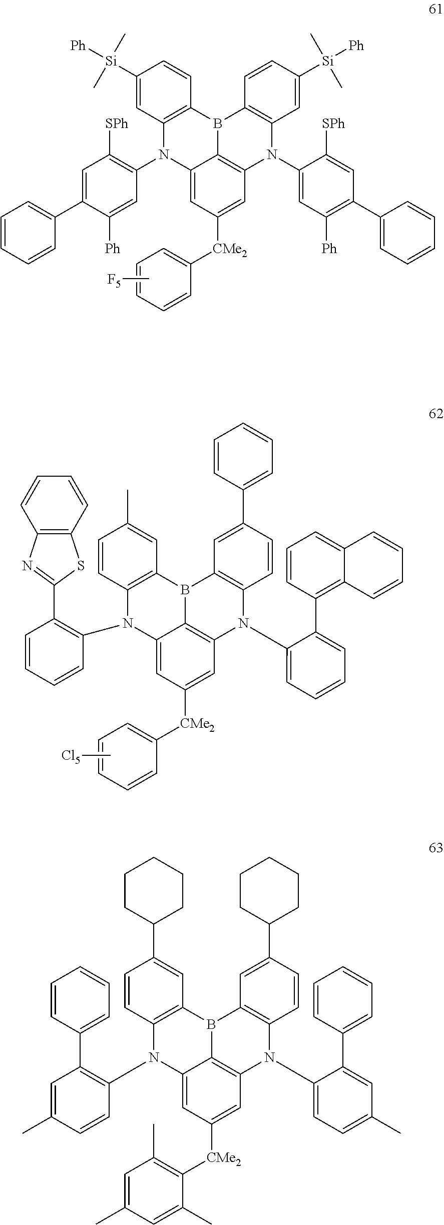

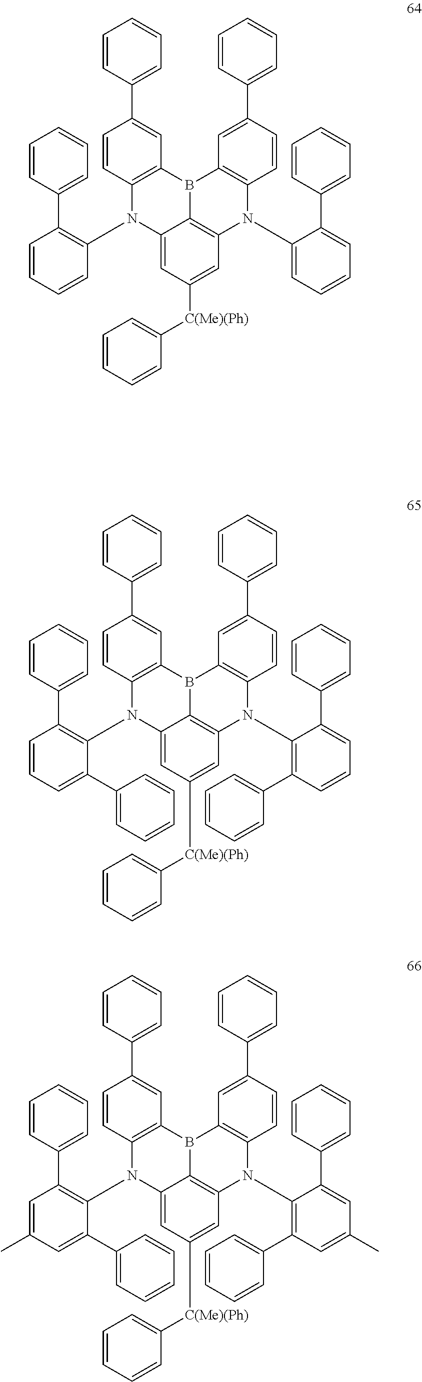

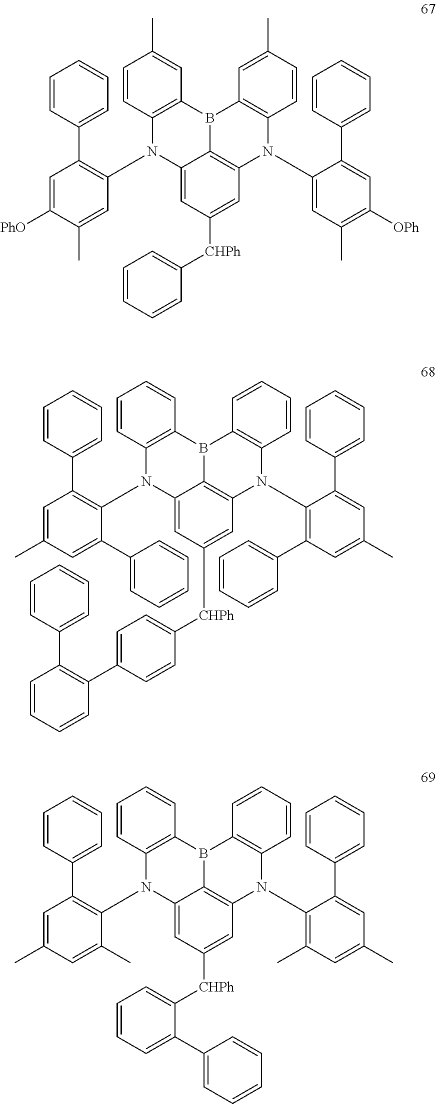

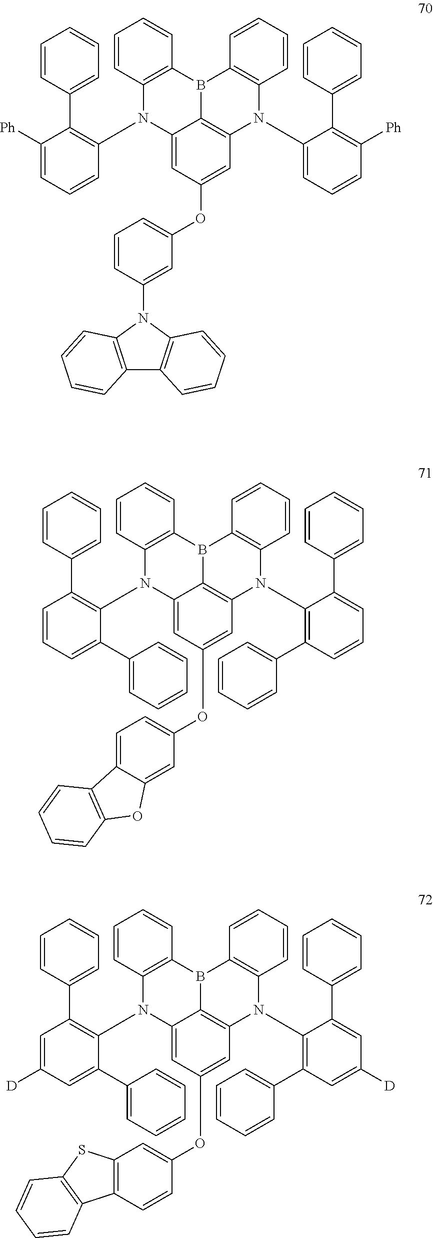 [SMILES: c1ccc(-c2cccc(N3c4ccccc4B4c5ccccc5N(c5cccc(-c6ccccc6)c5-c5ccccc5)c5cc(Oc6cccc(-n7c8ccccc8c8ccccc87)c6)cc3c54)c2-c2ccccc2)cc1 ; c1ccc(-c2cccc(-c3ccccc3)c2N2c3ccccc3B3c4ccccc4N(c4c(-c5ccccc5)cccc4-c4ccccc4)c4cc(Oc5ccc6c(c5)oc5ccccc56)cc2c43)cc1 ; [2H]c1cc(-c2ccccc2)c(N2c3ccccc3B3c4ccccc4N(c4c(-c5ccccc5)cc([2H])cc4-c4ccccc4)c4cc(Oc5ccc6c(c5)sc5ccccc56)cc2c43)c(-c2ccccc2)c1]

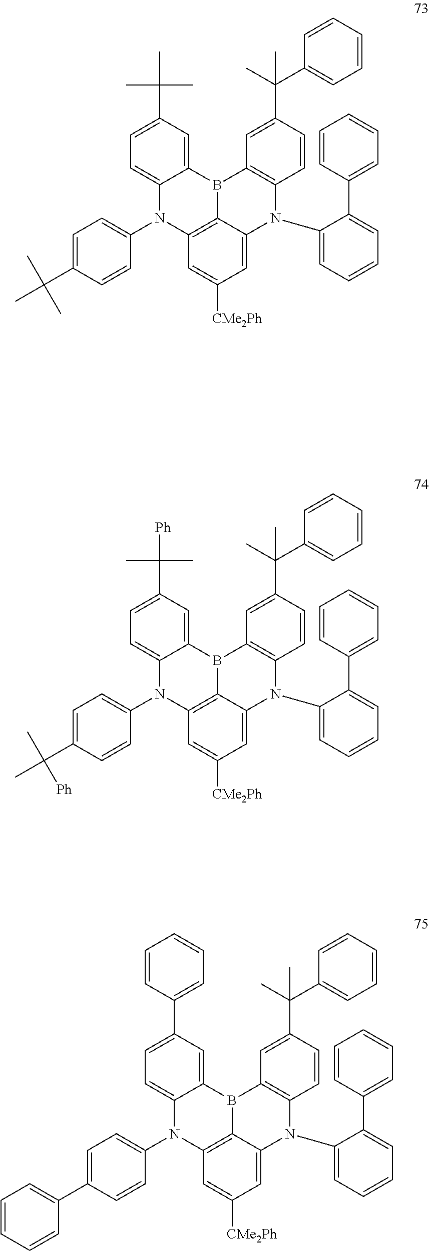

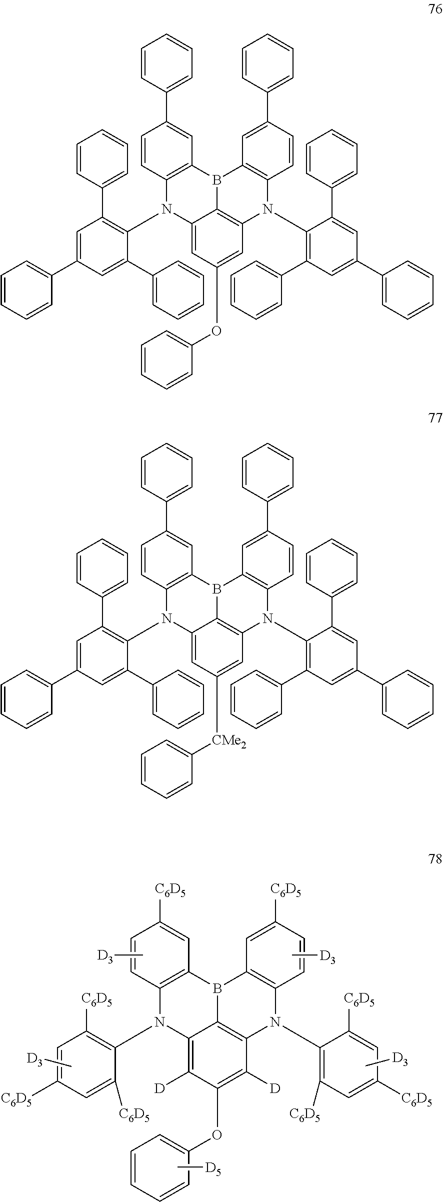

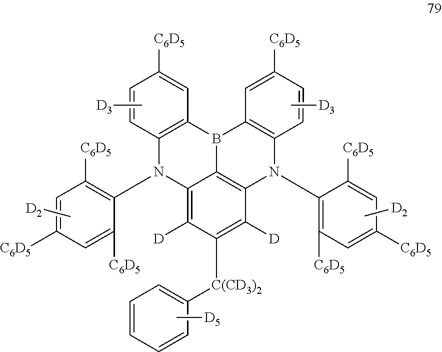

The polycyclic compound according to an embodiment may include a fused ring core including one boron atom and two nitrogen atoms as ring-forming atoms, and may include first and second substituents bonded (e.g., directly bonded or indirectly bonded) to the fused ring core. The polycyclic compound according to an embodiment may protect boron atoms in the core portion as sterically bulky first and second substituents are introduced into the fused ring core. Accordingly, when the polycyclic compound according to an embodiment is applied as a light emitting material, the polycyclic compound may contribute to increasing luminous efficiency and service life of a light emitting element.

In an embodiment, the emission layer EML may include a host and a dopant. The polycyclic compound according to an embodiment may be used as a dopant material of the emission layer EML. The polycyclic compound according to an embodiment may be a thermally activated delayed fluorescent material. The polycyclic compound according to an embodiment may be used as a thermally activated delayed fluorescence (TADF) dopant. For example, in the light emitting element ED according to an embodiment, the emission layer EML may include at least one polycyclic compound selected from Compound Group 1 as a thermally activated delayed fluorescence dopant. However, the use of the polycyclic compound according to an embodiment is not limited thereto.

The polycyclic compound according to an embodiment represented by Formula 1 may be a light emitting material having a central light emitting wavelength in a wavelength in a range of about 430 nm to about 490 nm. For example, the polycyclic compound according to an embodiment may emit blue light. The polycyclic compound according to an embodiment represented by Formula 1 may be a blue thermally activated delayed fluorescence (TADF) dopant. The emission layer EML may include at least one polycyclic compound selected from Compound Group 1 as a thermally activated delayed fluorescence dopant.

In an embodiment, the emission layer EML may include the first compound, which is the polycyclic compound according to an embodiment, and at least one of a second compound, a third compound, and a fourth compound. For example, the emission layer EML may include the first compound, the second compound, and the third compound. In the emission layer EML, the second compound and the third compound may form an exciplex, and energy may be transferred from the exciplex to the first compound to emit light. In an embodiment, the emission layer EML may include the first compound, the second compound, the third compound, and the fourth compound. In the emission layer EML, the second compound and the third compound may form an exciplex, and energy may be transferred from the exciplex to the fourth compound and the first compound to emit light. The fourth compound may be referred to as a phosphorescent sensitizer. The fourth compound may emit phosphorescence or may transfer energy to the first compound as an auxiliary dopant. However, the functions of the compounds are illustrated as examples, and embodiments are not limited thereto.

In the light emitting element ED according to an embodiment, the emission layer EML includes the first compound emitting delayed fluorescence, the second compound and the third compound that are two different hosts, and the fourth compound including an organometallic complex, and may thus exhibit excellent luminous efficiency.

In an embodiment, the second compound may include a substituted or unsubstituted carbazole moiety. The third compound may include a hexagonal ring containing at least one nitrogen atom as a ring-forming atom. The fourth compound may be an organometallic complex compound. The fourth compound may be an organometallic complex compound containing platinum (Pt) as a central metal. For example, the second compound may be represented by Formula HT, and the third compound may be represented by Formula ET. The fourth compound may include platinum (Pt) as a central metal atom and may be represented by Formula PS.

In an embodiment, the second compound may be used as a hole transport host material of the emission layer EML.

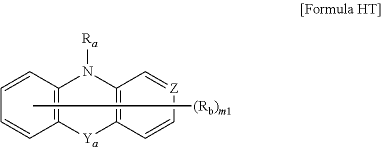

In Formula HT, m1 may be an integer from 0 to 7. When m1 is 2 or greater, multiple R_{b} groups may all be the same or at least one thereof may be different. In Formula HT, R a and R_{b} may each independently be a hydrogen atom, a deuterium atom, a cyano group, a substituted or unsubstituted aryl group having 6 to 60 ring-forming carbon atoms, a substituted or unsubstituted heteroaryl group having 2 to 60 ring-forming carbon atoms, or bonded to an adjacent group to form an aromatic ring. For example, Rₐ may be a substituted phenyl group, an unsubstituted dibenzofuran group, or a substituted fluorenyl group. R_{b} may be a hydrogen atom, a deuterium atom, a substituted or unsubstituted phenyl group, a substituted or unsubstituted carbazole group, or a substituted or unsubstituted fluorenyl group. In an embodiment, two adjacent R_{b} groups may be bonded to each other to form a substituted or unsubstituted heterocycle.

In Formula HT, Y may be a direct linkage, C(R_{y1})(R_{y2}), or Si(R_{y3})(R_{y4}). For example, when Y is a direct linkage, the second compound represented by Formula HT may include a carbazole moiety. In Formula HT, R_{y1} to R_{y4} may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms. For example, R_{y1} to R_{y4} may each independently be a methyl group or a phenyl group.

In Formula HT, Z may be C(R_{z}) or a nitrogen atom (N). For example, when Y is a direct linkage and Z is C(R_{z}), the second compound represented by Formula HT may include a carbazole moiety. For example, when Y is a direct linkage and Z is a nitrogen atom, the second compound represented by Formula HT may include a pyridoindole moiety. In Formula HT, R_{z} may be a hydrogen atom or a deuterium atom.

In an embodiment, the second compound represented by Formula HT may be selected from Compound Group 2 below. In an embodiment, the light emitting element ED, the second compound may include at least one compound selected from Compound Group 2. In Compound Group 2 below, D represents a deuterium atom.

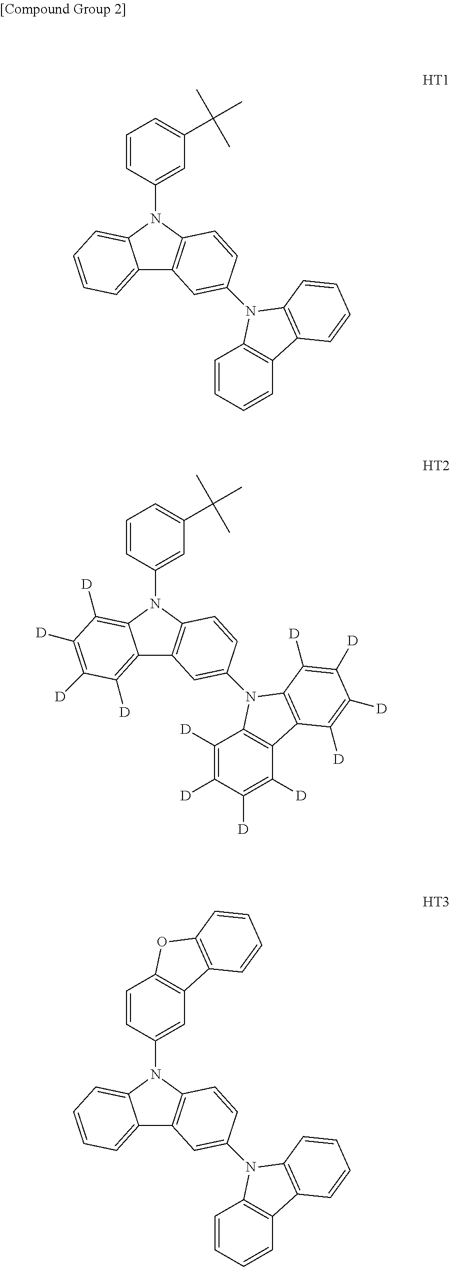 [SMILES: CC(C)(C)c1cccc(-n2c3ccccc3c3cc(-n4c5ccccc5c5ccccc54)ccc32)c1 ; [2H]c1c([2H])c([2H])c2c(c1[2H])c1cc(-n3c4c([2H])c([2H])c([2H])c([2H])c4c4c([2H])c([2H])c([2H])c([2H])c43)ccc1n2-c1cccc(C(C)(C)C)c1 ; c1ccc2c(c1)oc1ccc(-n3c4ccccc4c4cc(-n5c6ccccc6c6ccccc65)ccc43)cc12]

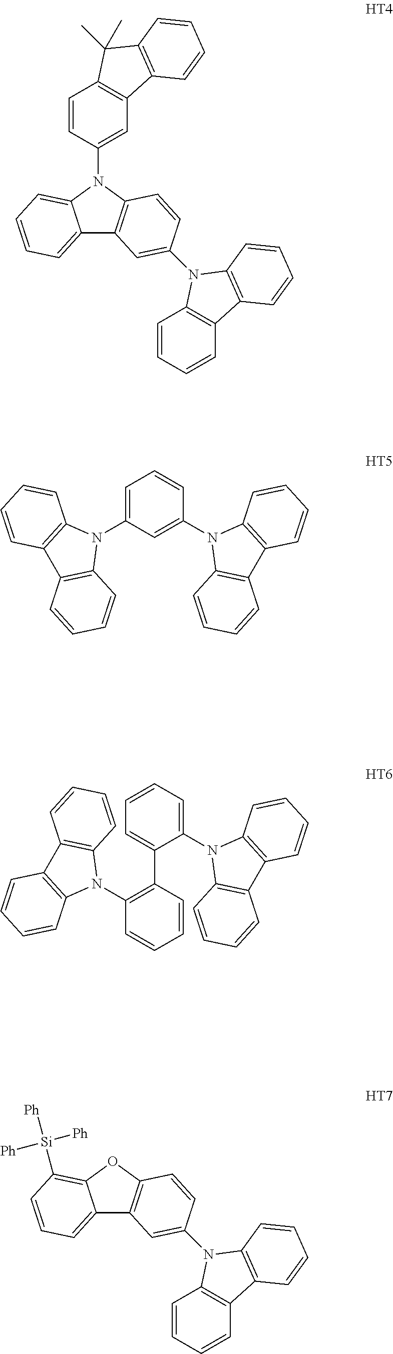 [SMILES: CC1(C)c2ccccc2-c2cc(-n3c4ccccc4c4cc(-n5c6ccccc6c6ccccc65)ccc43)ccc21 ; c1cc(-n2c3ccccc3c3ccccc32)cc(-n2c3ccccc3c3ccccc32)c1 ; c1ccc(-n2c3ccccc3c3ccccc32)c(-c2ccccc2-n2c3ccccc3c3ccccc32)c1 ; c1ccc([Si](c2ccccc2)(c2ccccc2)c2cccc3c2oc2ccc(-n4c5ccccc5c5ccccc54)cc23)cc1]

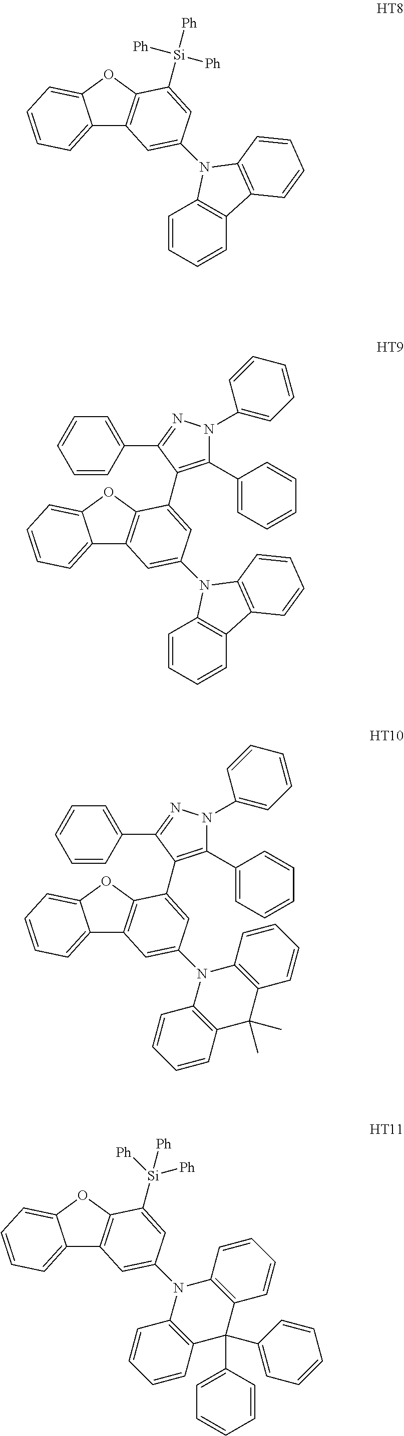 [SMILES: c1ccc([Si](c2ccccc2)(c2ccccc2)c2cc(-n3c4ccccc4c4ccccc43)cc3c2oc2ccccc23)cc1 ; c1ccc(-c2nn(-c3ccccc3)c(-c3ccccc3)c2-c2cc(-n3c4ccccc4c4ccccc43)cc3c2oc2ccccc23)cc1 ; CC1(C)c2ccccc2N(c2cc(-c3c(-c4ccccc4)nn(-c4ccccc4)c3-c3ccccc3)c3oc4ccccc4c3c2)c2ccccc21 ; c1ccc(C2(c3ccccc3)c3ccccc3N(c3cc([Si](c4ccccc4)(c4ccccc4)c4ccccc4)c4oc5ccccc5c4c3)c3ccccc32)cc1]

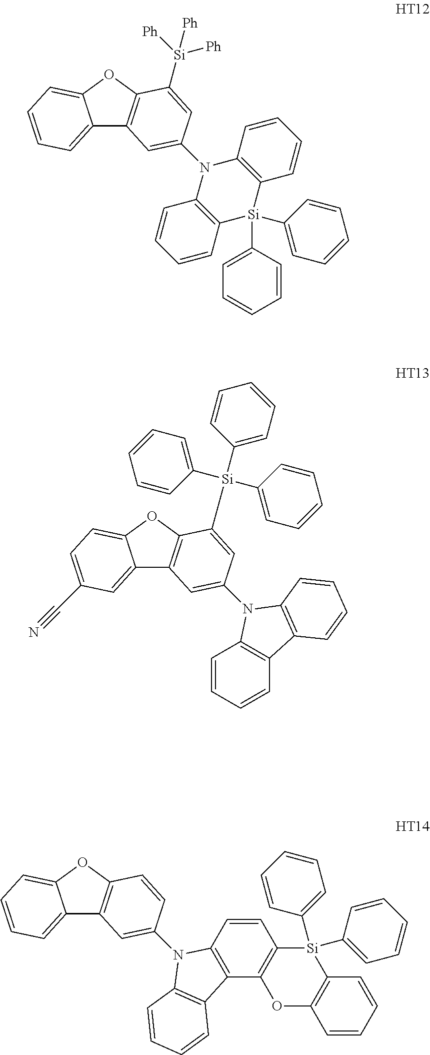 [SMILES: c1ccc([Si]2(c3ccccc3)c3ccccc3N(c3cc([Si](c4ccccc4)(c4ccccc4)c4ccccc4)c4oc5ccccc5c4c3)c3ccccc32)cc1 ; N#Cc1ccc2oc3c([Si](c4ccccc4)(c4ccccc4)c4ccccc4)cc(-n4c5ccccc5c5ccccc54)cc3c2c1 ; c1ccc([Si]2(c3ccccc3)c3ccccc3Oc3c2ccc2c3c3ccccc3n2-c2ccc3oc4ccccc4c3c2)cc1]

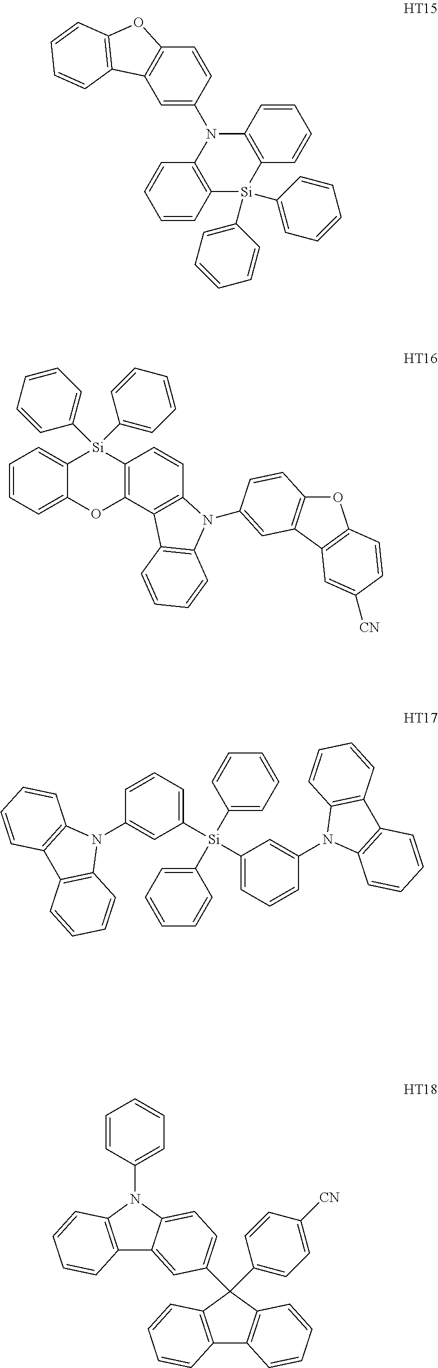 [SMILES: c1ccc([Si]2(c3ccccc3)c3ccccc3N(c3ccc4oc5ccccc5c4c3)c3ccccc32)cc1 ; N#Cc1ccc2oc3ccc(-n4c5ccccc5c5c6c(ccc54)[Si](c4ccccc4)(c4ccccc4)c4ccccc4O6)cc3c2c1 ; c1ccc([Si](c2ccccc2)(c2cccc(-n3c4ccccc4c4ccccc43)c2)c2cccc(-n3c4ccccc4c4ccccc43)c2)cc1 ; N#Cc1ccc(C2(c3ccc4c(c3)c3ccccc3n4-c3ccccc3)c3ccccc3-c3ccccc32)cc1]

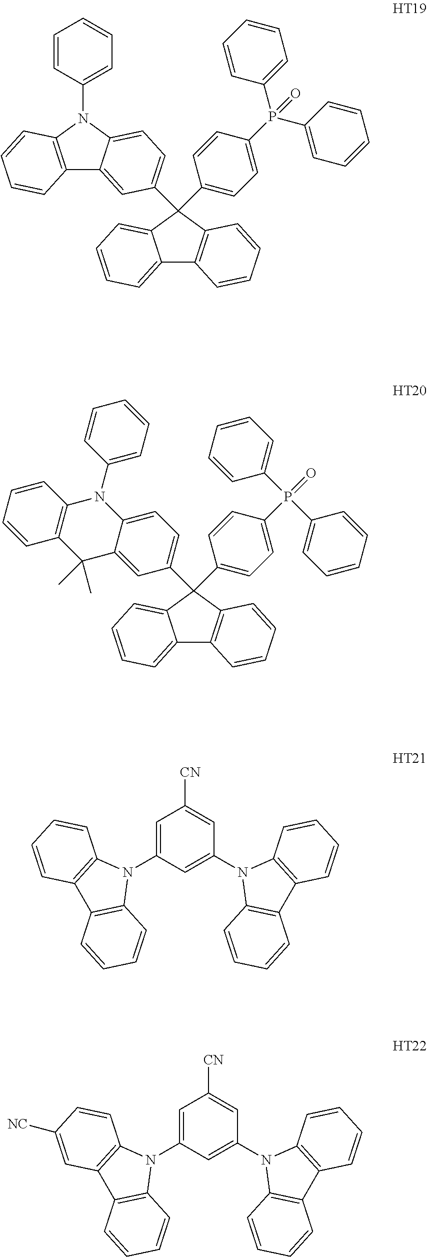 [SMILES: O=P(c1ccccc1)(c1ccccc1)c1ccc(C2(c3ccc4c(c3)c3ccccc3n4-c3ccccc3)c3ccccc3-c3ccccc32)cc1 ; CC1(C)c2ccccc2N(c2ccccc2)c2ccc(C3(c4ccc(P(=O)(c5ccccc5)c5ccccc5)cc4)c4ccccc4-c4ccccc43)cc21 ; N#Cc1cc(-n2c3ccccc3c3ccccc32)cc(-n2c3ccccc3c3ccccc32)c1 ; N#Cc1cc(-n2c3ccccc3c3ccccc32)cc(-n2c3ccccc3c3cc(C#N)ccc32)c1]

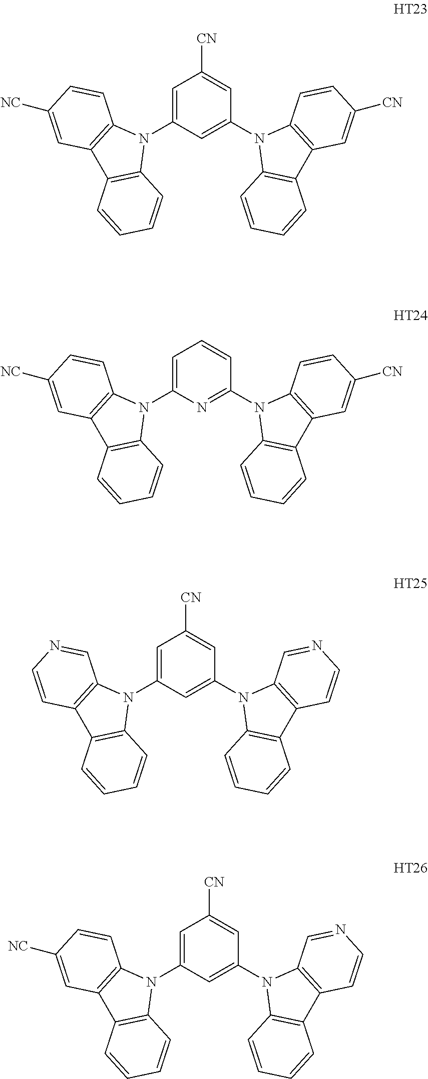 [SMILES: N#Cc1cc(-n2c3ccccc3c3cc(C#N)ccc32)cc(-n2c3ccccc3c3cc(C#N)ccc32)c1 ; N#Cc1ccc2c(c1)c1ccccc1n2-c1cccc(-n2c3ccccc3c3cc(C#N)ccc32)n1 ; N#Cc1cc(-n2c3ccccc3c3ccncc32)cc(-n2c3ccccc3c3ccncc32)c1 ; N#Cc1cc(-n2c3ccccc3c3cc(C#N)ccc32)cc(-n2c3ccccc3c3ccncc32)c1]

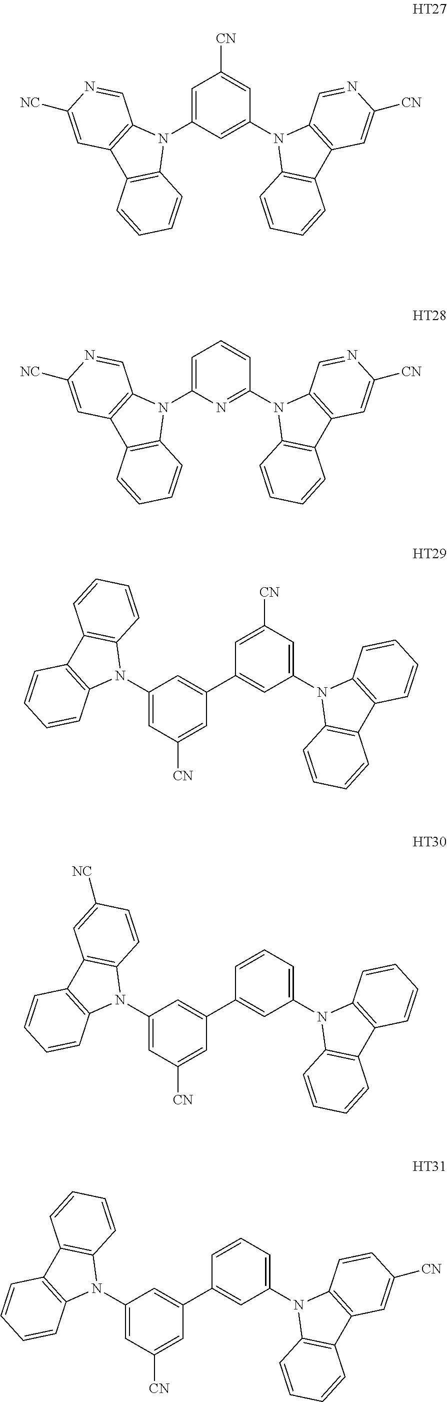 [SMILES: N#Cc1cc(-n2c3ccccc3c3cc(C#N)ncc32)cc(-n2c3ccccc3c3cc(C#N)ncc32)c1 ; N#Cc1cc2c3ccccc3n(-c3cccc(-n4c5ccccc5c5cc(C#N)ncc54)n3)c2cn1 ; N#Cc1cc(-c2cc(C#N)cc(-n3c4ccccc4c4ccccc43)c2)cc(-n2c3ccccc3c3ccccc32)c1 ; N#Cc1cc(-c2cccc(-n3c4ccccc4c4ccccc43)c2)cc(-n2c3ccccc3c3cc(C#N)ccc32)c1 ; N#Cc1cc(-c2cccc(-n3c4ccccc4c4cc(C#N)ccc43)c2)cc(-n2c3ccccc3c3ccccc32)c1]

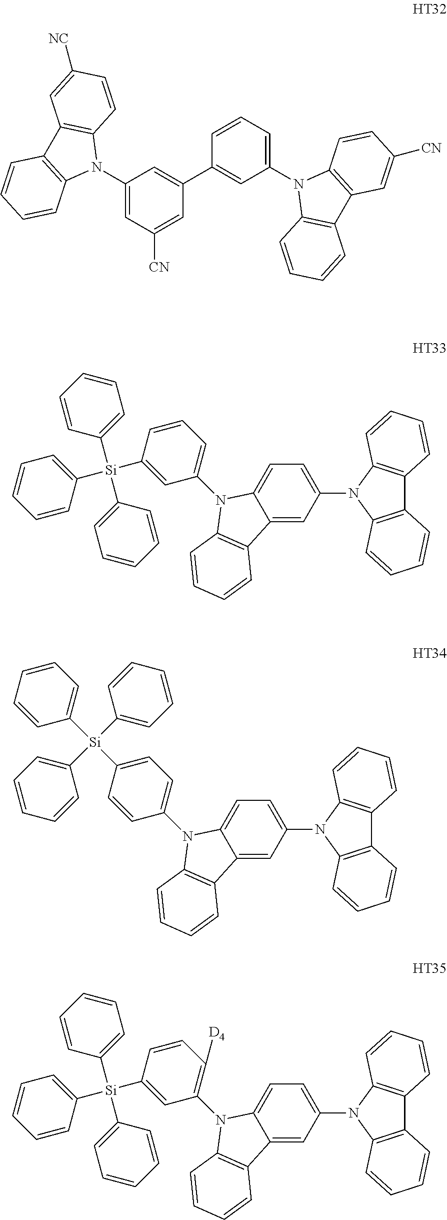

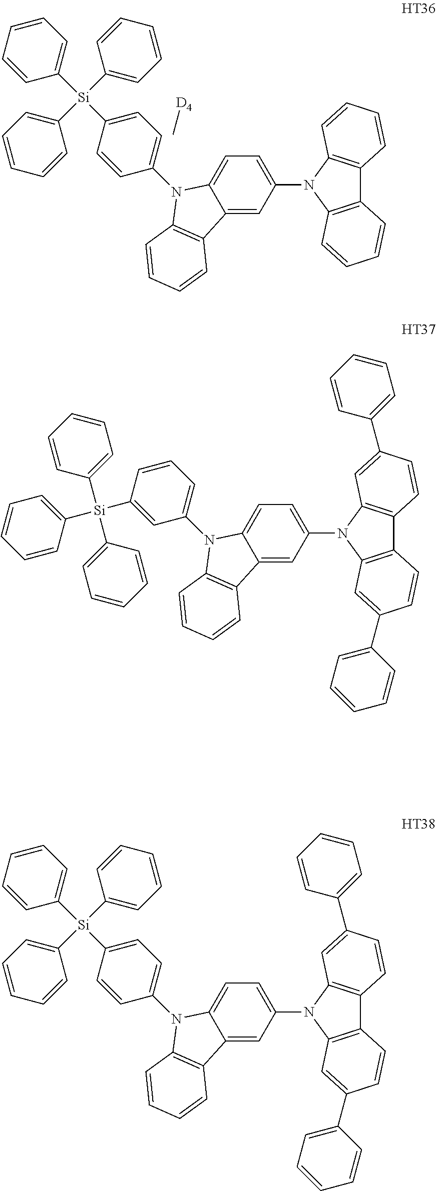

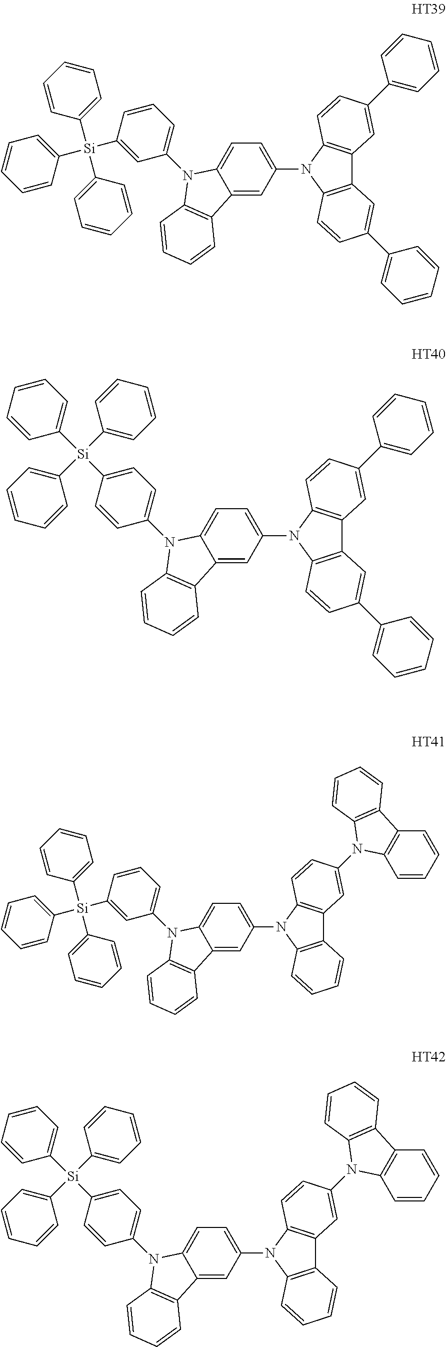 [SMILES: c1ccc(-c2ccc3c(c2)c2cc(-c4ccccc4)ccc2n3-c2ccc3c(c2)c2ccccc2n3-c2cccc([Si](c3ccccc3)(c3ccccc3)c3ccccc3)c2)cc1 ; c1ccc(-c2ccc3c(c2)c2cc(-c4ccccc4)ccc2n3-c2ccc3c(c2)c2ccccc2n3-c2ccc([Si](c3ccccc3)(c3ccccc3)c3ccccc3)cc2)cc1 ; c1ccc([Si](c2ccccc2)(c2ccccc2)c2cccc(-n3c4ccccc4c4cc(-n5c6ccccc6c6cc(-n7c8ccccc8c8ccccc87)ccc65)ccc43)c2)cc1 ; c1ccc([Si](c2ccccc2)(c2ccccc2)c2ccc(-n3c4ccccc4c4cc(-n5c6ccccc6c6cc(-n7c8ccccc8c8ccccc87)ccc65)ccc43)cc2)cc1]

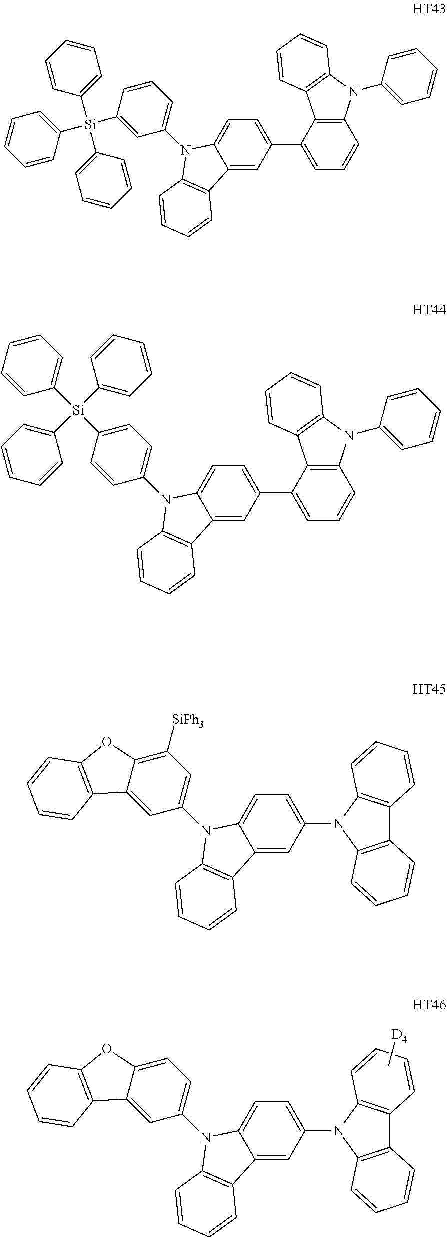

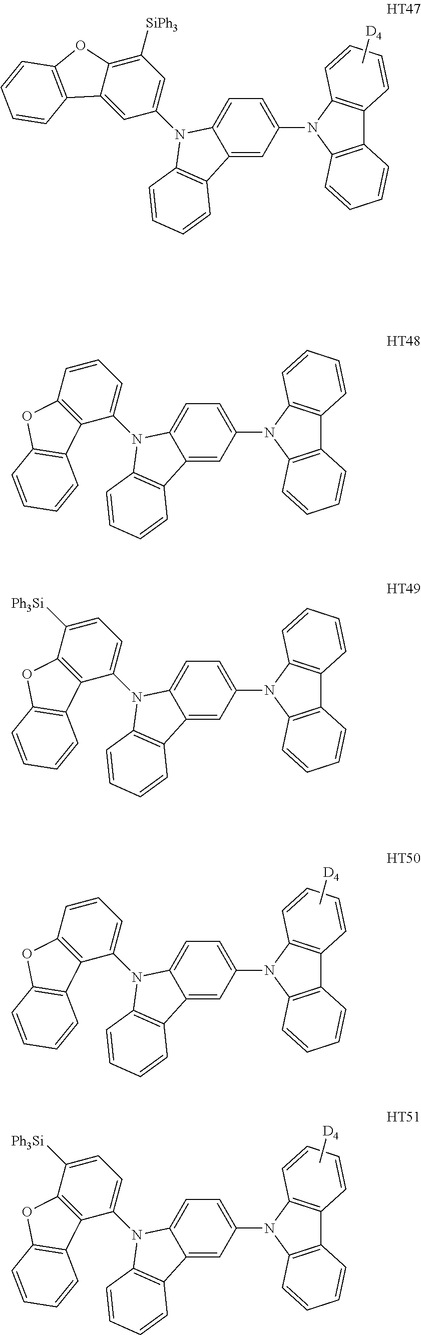

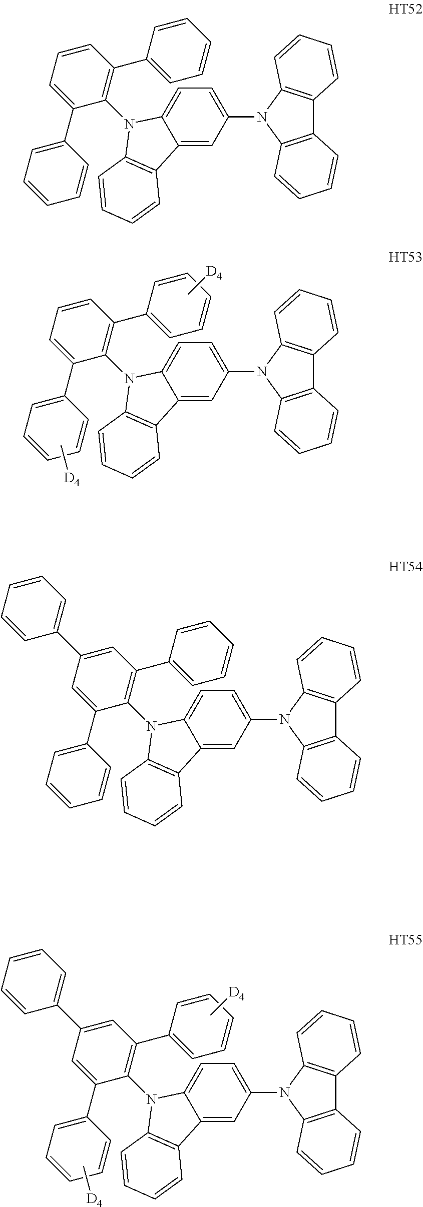

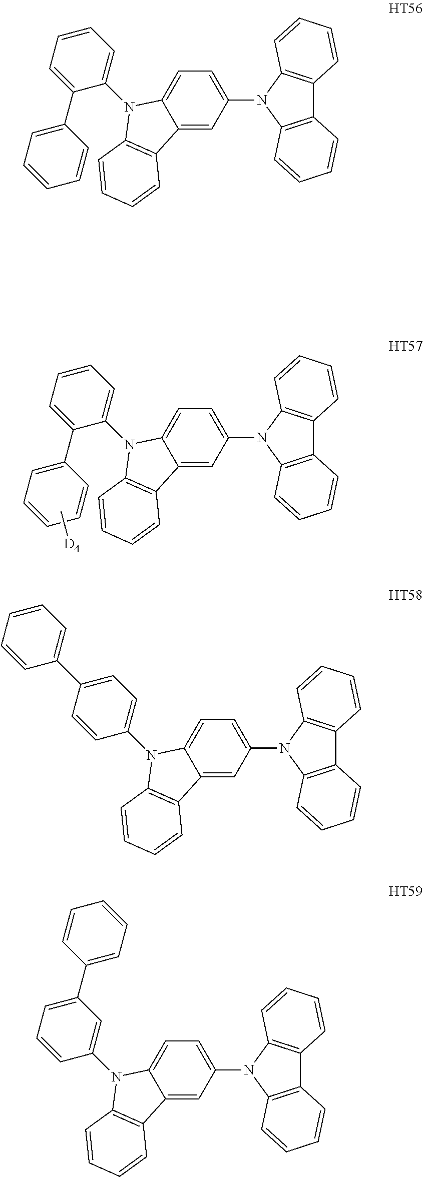

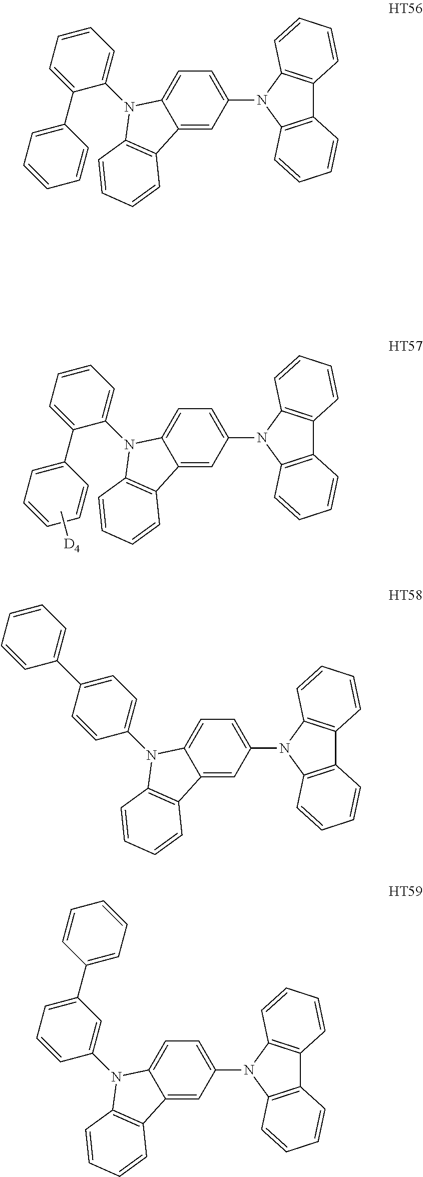

In an embodiment, the emission layer EML may include the third compound represented by Formula ET. In an embodiment, the third compound represented by Formula ET may be used as an electron transporting host material of the emission layer EML.

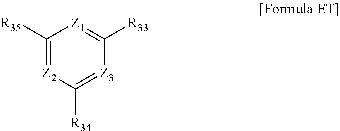

In Formula ET, Z₁ to Z₃ may each independently be N or C(R₃₆), and at least one of Z₁ to Z₃ may each be N. For example, Z₁ to Z₃ may all be N. In an embodiment, any two of Z₁ to Z₃ may be N, and the remainder of Z₁ to Z₃ may be C(R₃₆). In an embodiment, any one of Z₁ to Z₃ may be N, and the remainder of Z₁ to Z₃ may each independently be C(R₃₆).

In Formula ET, R₃₃ to R₃₆ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms, or may be bonded to an adjacent group to form a ring. For example, R₃₃ to R₃₆ may each independently be a substituted or unsubstituted phenyl group, a substituted or unsubstituted carbazole group, or the like, but embodiments are not limited thereto.

In an embodiment, the third compound represented by Formula 3 may be selected from Compound Group 3. In an embodiment, in the emission layer EML, the third compound may include at least one compound selected from Compound Group 3, as an electron transporting host material. In Compound Group 3, D represents a deuterium atom.

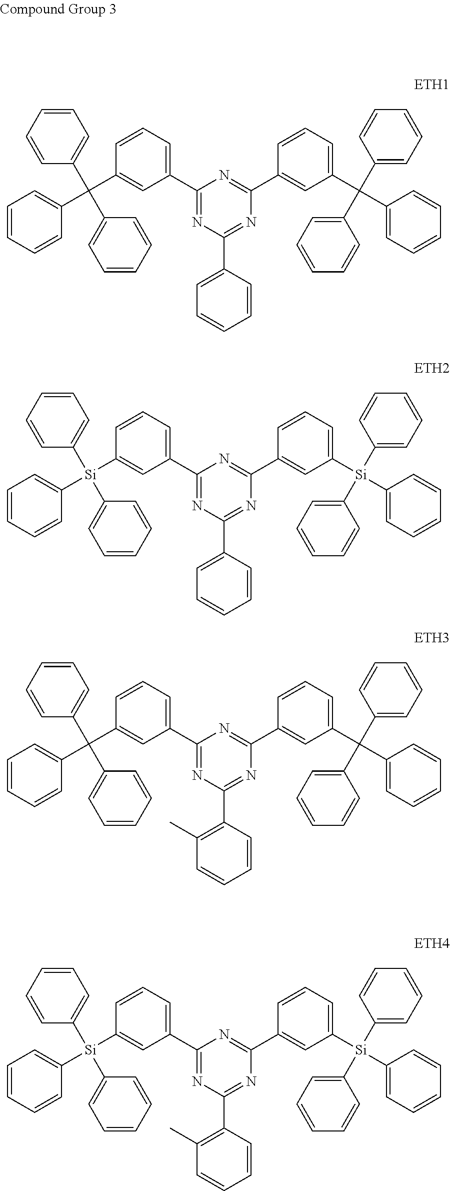 [SMILES: c1ccc(-c2nc(-c3cccc(C(c4ccccc4)(c4ccccc4)c4ccccc4)c3)nc(-c3cccc(C(c4ccccc4)(c4ccccc4)c4ccccc4)c3)n2)cc1 ; c1ccc(-c2nc(-c3cccc([Si](c4ccccc4)(c4ccccc4)c4ccccc4)c3)nc(-c3cccc([Si](c4ccccc4)(c4ccccc4)c4ccccc4)c3)n2)cc1 ; Cc1ccccc1-c1nc(-c2cccc(C(c3ccccc3)(c3ccccc3)c3ccccc3)c2)nc(-c2cccc(C(c3ccccc3)(c3ccccc3)c3ccccc3)c2)n1 ; Cc1ccccc1-c1nc(-c2cccc([Si](c3ccccc3)(c3ccccc3)c3ccccc3)c2)nc(-c2cccc([Si](c3ccccc3)(c3ccccc3)c3ccccc3)c2)n1]

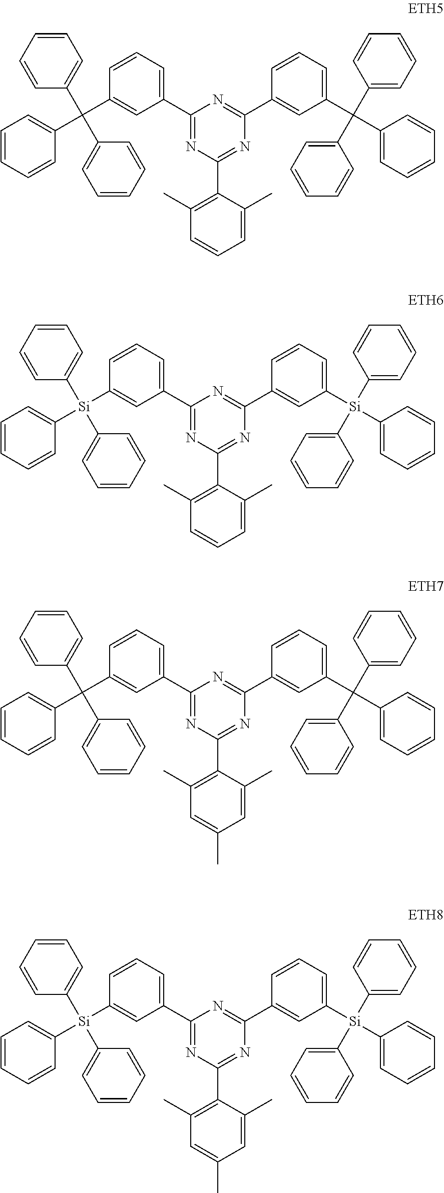 [SMILES: Cc1cccc(C)c1-c1nc(-c2cccc(C(c3ccccc3)(c3ccccc3)c3ccccc3)c2)nc(-c2cccc(C(c3ccccc3)(c3ccccc3)c3ccccc3)c2)n1 ; Cc1cccc(C)c1-c1nc(-c2cccc([Si](c3ccccc3)(c3ccccc3)c3ccccc3)c2)nc(-c2cccc([Si](c3ccccc3)(c3ccccc3)c3ccccc3)c2)n1 ; Cc1cc(C)c(-c2nc(-c3cccc(C(c4ccccc4)(c4ccccc4)c4ccccc4)c3)nc(-c3cccc(C(c4ccccc4)(c4ccccc4)c4ccccc4)c3)n2)c(C)c1 ; Cc1cc(C)c(-c2nc(-c3cccc([Si](c4ccccc4)(c4ccccc4)c4ccccc4)c3)nc(-c3cccc([Si](c4ccccc4)(c4ccccc4)c4ccccc4)c3)n2)c(C)c1]

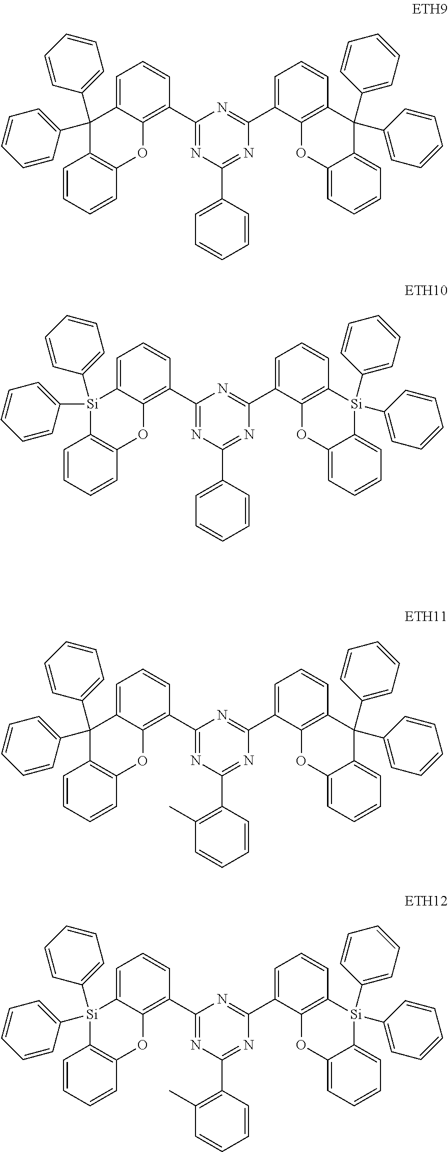 [SMILES: c1ccc(-c2nc(-c3cccc4c3Oc3ccccc3C4(c3ccccc3)c3ccccc3)nc(-c3cccc4c3Oc3ccccc3C4(c3ccccc3)c3ccccc3)n2)cc1 ; c1ccc(-c2nc(-c3cccc4c3Oc3ccccc3[Si]4(c3ccccc3)c3ccccc3)nc(-c3cccc4c3Oc3ccccc3[Si]4(c3ccccc3)c3ccccc3)n2)cc1 ; Cc1ccccc1-c1nc(-c2cccc3c2Oc2ccccc2C3(c2ccccc2)c2ccccc2)nc(-c2cccc3c2Oc2ccccc2C3(c2ccccc2)c2ccccc2)n1 ; Cc1ccccc1-c1nc(-c2cccc3c2Oc2ccccc2[Si]3(c2ccccc2)c2ccccc2)nc(-c2cccc3c2Oc2ccccc2[Si]3(c2ccccc2)c2ccccc2)n1]

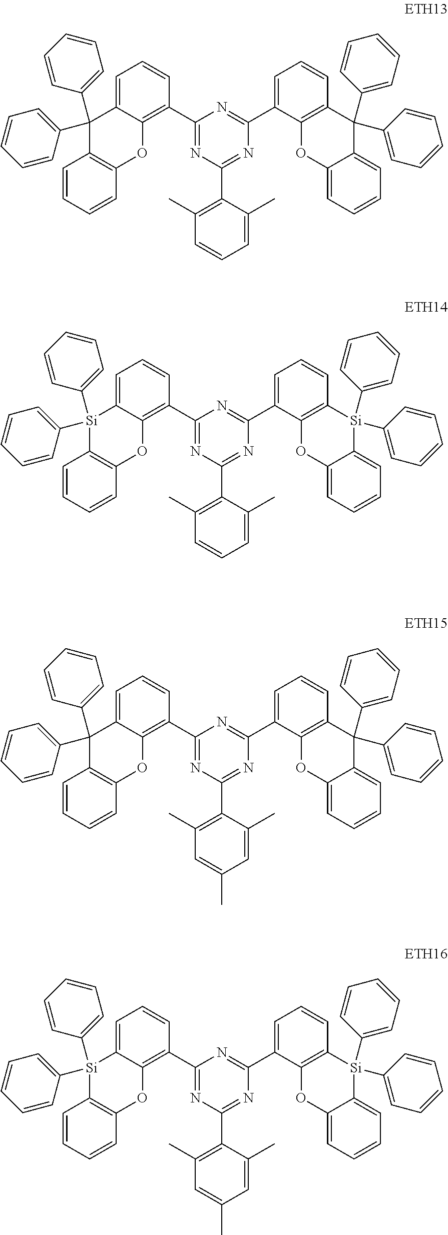 [SMILES: Cc1cccc(C)c1-c1nc(-c2cccc3c2Oc2ccccc2C3(c2ccccc2)c2ccccc2)nc(-c2cccc3c2Oc2ccccc2C3(c2ccccc2)c2ccccc2)n1 ; Cc1cccc(C)c1-c1nc(-c2cccc3c2Oc2ccccc2[Si]3(c2ccccc2)c2ccccc2)nc(-c2cccc3c2Oc2ccccc2[Si]3(c2ccccc2)c2ccccc2)n1 ; Cc1cc(C)c(-c2nc(-c3cccc4c3Oc3ccccc3C4(c3ccccc3)c3ccccc3)nc(-c3cccc4c3Oc3ccccc3C4(c3ccccc3)c3ccccc3)n2)c(C)c1 ; Cc1cc(C)c(-c2nc(-c3cccc4c3Oc3ccccc3[Si]4(c3ccccc3)c3ccccc3)nc(-c3cccc4c3Oc3ccccc3[Si]4(c3ccccc3)c3ccccc3)n2)c(C)c1]

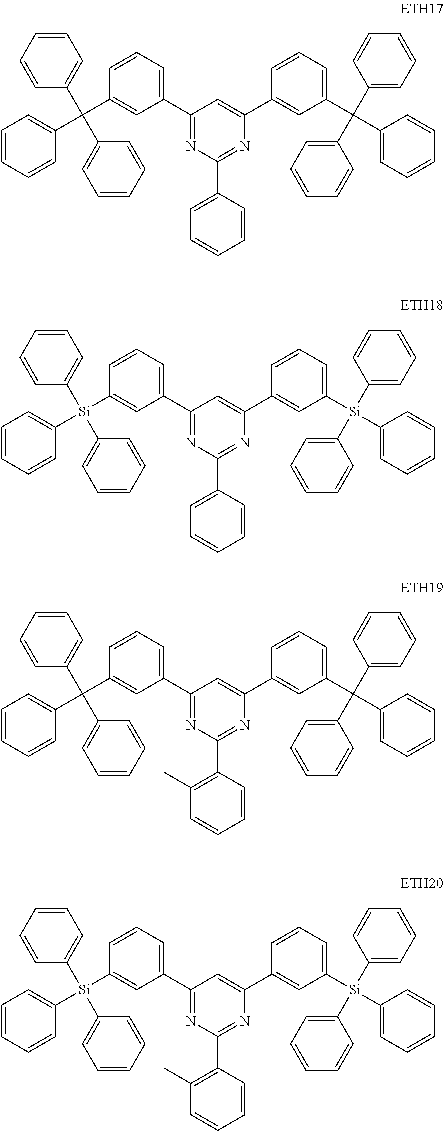 [SMILES: c1ccc(-c2nc(-c3cccc(C(c4ccccc4)(c4ccccc4)c4ccccc4)c3)cc(-c3cccc(C(c4ccccc4)(c4ccccc4)c4ccccc4)c3)n2)cc1 ; c1ccc(-c2nc(-c3cccc([Si](c4ccccc4)(c4ccccc4)c4ccccc4)c3)cc(-c3cccc([Si](c4ccccc4)(c4ccccc4)c4ccccc4)c3)n2)cc1 ; Cc1ccccc1-c1nc(-c2cccc(C(c3ccccc3)(c3ccccc3)c3ccccc3)c2)cc(-c2cccc(C(c3ccccc3)(c3ccccc3)c3ccccc3)c2)n1 ; Cc1ccccc1-c1nc(-c2cccc([Si](c3ccccc3)(c3ccccc3)c3ccccc3)c2)cc(-c2cccc([Si](c3ccccc3)(c3ccccc3)c3ccccc3)c2)n1]

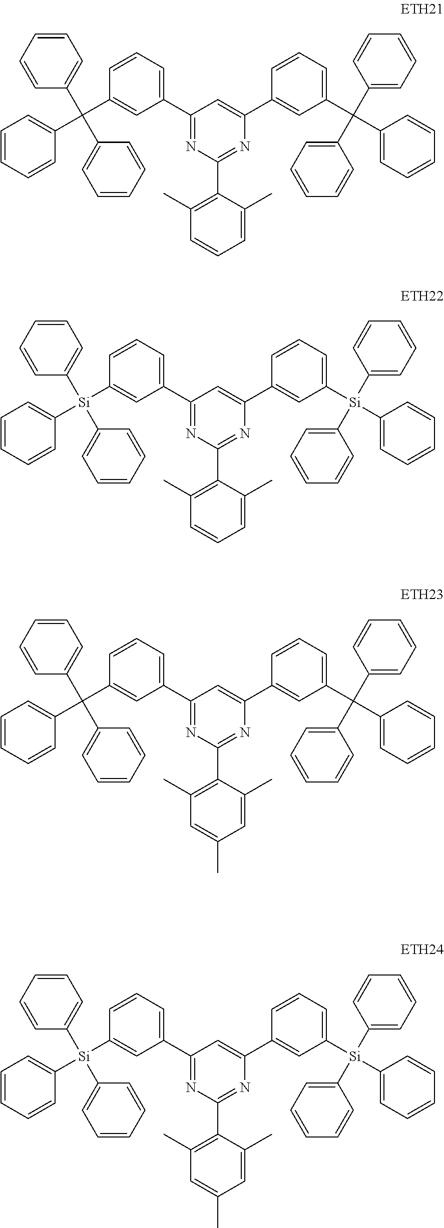 [SMILES: Cc1cccc(C)c1-c1nc(-c2cccc(C(c3ccccc3)(c3ccccc3)c3ccccc3)c2)cc(-c2cccc(C(c3ccccc3)(c3ccccc3)c3ccccc3)c2)n1 ; Cc1cccc(C)c1-c1nc(-c2cccc([Si](c3ccccc3)(c3ccccc3)c3ccccc3)c2)cc(-c2cccc([Si](c3ccccc3)(c3ccccc3)c3ccccc3)c2)n1 ; Cc1cc(C)c(-c2nc(-c3cccc(C(c4ccccc4)(c4ccccc4)c4ccccc4)c3)cc(-c3cccc(C(c4ccccc4)(c4ccccc4)c4ccccc4)c3)n2)c(C)c1 ; Cc1cc(C)c(-c2nc(-c3cccc([Si](c4ccccc4)(c4ccccc4)c4ccccc4)c3)cc(-c3cccc([Si](c4ccccc4)(c4ccccc4)c4ccccc4)c3)n2)c(C)c1]

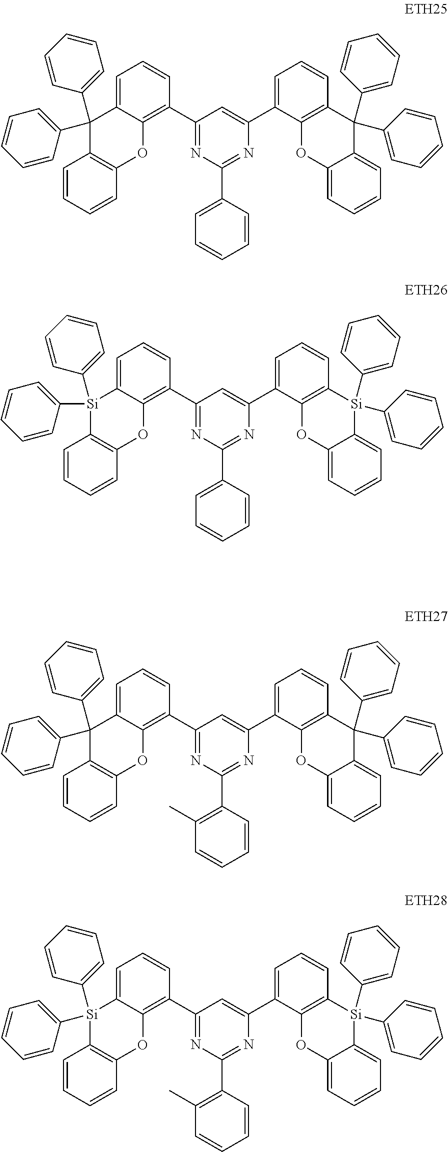 [SMILES: c1ccc(-c2nc(-c3cccc4c3Oc3ccccc3C4(c3ccccc3)c3ccccc3)cc(-c3cccc4c3Oc3ccccc3C4(c3ccccc3)c3ccccc3)n2)cc1 ; c1ccc(-c2nc(-c3cccc4c3Oc3ccccc3[Si]4(c3ccccc3)c3ccccc3)cc(-c3cccc4c3Oc3ccccc3[Si]4(c3ccccc3)c3ccccc3)n2)cc1 ; Cc1ccccc1-c1nc(-c2cccc3c2Oc2ccccc2C3(c2ccccc2)c2ccccc2)cc(-c2cccc3c2Oc2ccccc2C3(c2ccccc2)c2ccccc2)n1 ; Cc1ccccc1-c1nc(-c2cccc3c2Oc2ccccc2[Si]3(c2ccccc2)c2ccccc2)cc(-c2cccc3c2Oc2ccccc2[Si]3(c2ccccc2)c2ccccc2)n1]

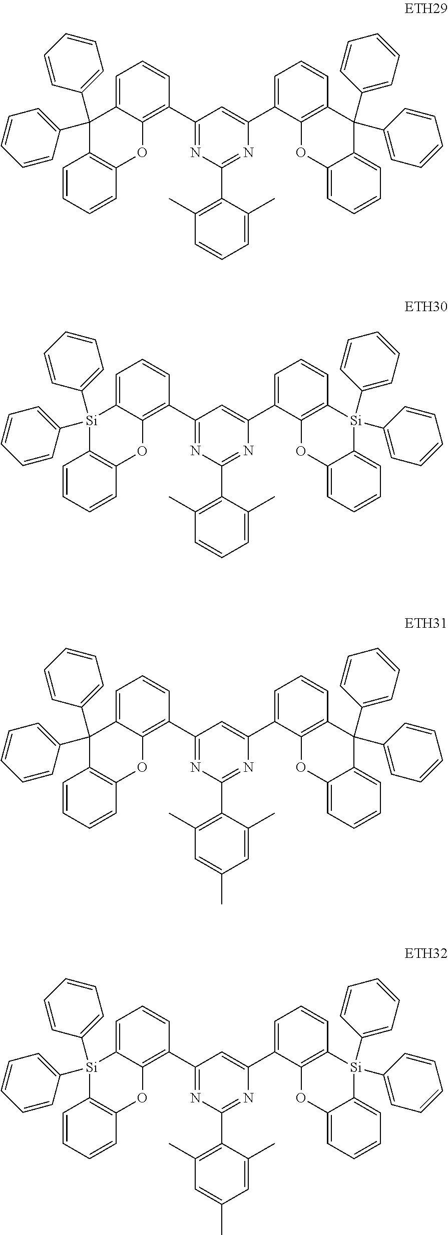 [SMILES: Cc1cccc(C)c1-c1nc(-c2cccc3c2Oc2ccccc2C3(c2ccccc2)c2ccccc2)cc(-c2cccc3c2Oc2ccccc2C3(c2ccccc2)c2ccccc2)n1 ; Cc1cccc(C)c1-c1nc(-c2cccc3c2Oc2ccccc2[Si]3(c2ccccc2)c2ccccc2)cc(-c2cccc3c2Oc2ccccc2[Si]3(c2ccccc2)c2ccccc2)n1 ; Cc1cc(C)c(-c2nc(-c3cccc4c3Oc3ccccc3C4(c3ccccc3)c3ccccc3)cc(-c3cccc4c3Oc3ccccc3C4(c3ccccc3)c3ccccc3)n2)c(C)c1 ; Cc1cc(C)c(-c2nc(-c3cccc4c3Oc3ccccc3[Si]4(c3ccccc3)c3ccccc3)cc(-c3cccc4c3Oc3ccccc3[Si]4(c3ccccc3)c3ccccc3)n2)c(C)c1]

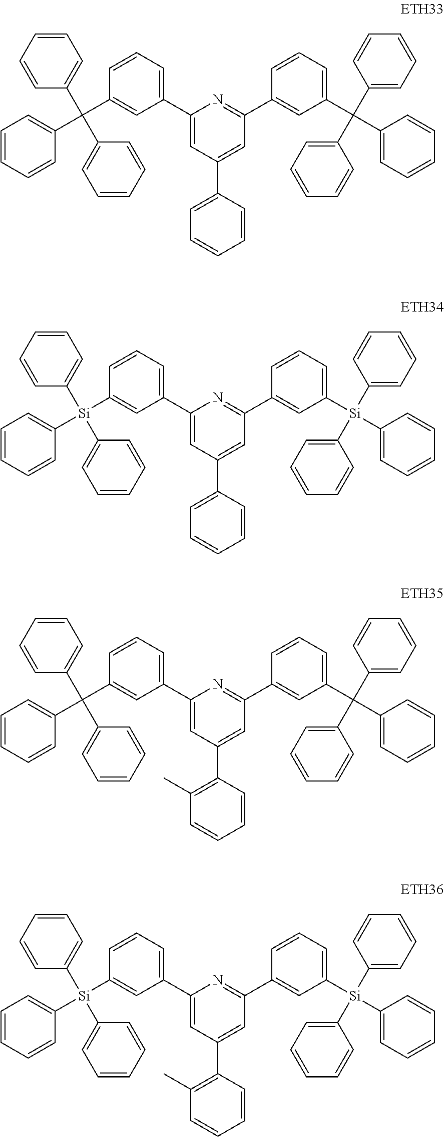 [SMILES: c1ccc(-c2cc(-c3cccc(C(c4ccccc4)(c4ccccc4)c4ccccc4)c3)nc(-c3cccc(C(c4ccccc4)(c4ccccc4)c4ccccc4)c3)c2)cc1 ; c1ccc(-c2cc(-c3cccc([Si](c4ccccc4)(c4ccccc4)c4ccccc4)c3)nc(-c3cccc([Si](c4ccccc4)(c4ccccc4)c4ccccc4)c3)c2)cc1 ; Cc1ccccc1-c1cc(-c2cccc(C(c3ccccc3)(c3ccccc3)c3ccccc3)c2)nc(-c2cccc(C(c3ccccc3)(c3ccccc3)c3ccccc3)c2)c1 ; Cc1ccccc1-c1cc(-c2cccc([Si](c3ccccc3)(c3ccccc3)c3ccccc3)c2)nc(-c2cccc([Si](c3ccccc3)(c3ccccc3)c3ccccc3)c2)c1]

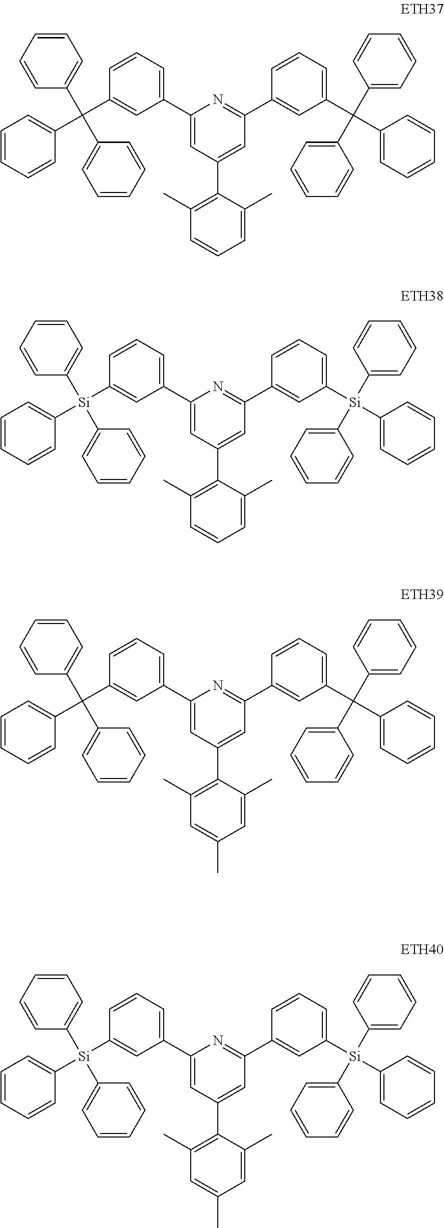 [SMILES: Cc1cccc(C)c1-c1cc(-c2cccc(C(c3ccccc3)(c3ccccc3)c3ccccc3)c2)nc(-c2cccc(C(c3ccccc3)(c3ccccc3)c3ccccc3)c2)c1 ; Cc1cccc(C)c1-c1cc(-c2cccc([Si](c3ccccc3)(c3ccccc3)c3ccccc3)c2)nc(-c2cccc([Si](c3ccccc3)(c3ccccc3)c3ccccc3)c2)c1 ; Cc1cc(C)c(-c2cc(-c3cccc(C(c4ccccc4)(c4ccccc4)c4ccccc4)c3)nc(-c3cccc(C(c4ccccc4)(c4ccccc4)c4ccccc4)c3)c2)c(C)c1 ; Cc1cc(C)c(-c2cc(-c3cccc([Si](c4ccccc4)(c4ccccc4)c4ccccc4)c3)nc(-c3cccc([Si](c4ccccc4)(c4ccccc4)c4ccccc4)c3)c2)c(C)c1]

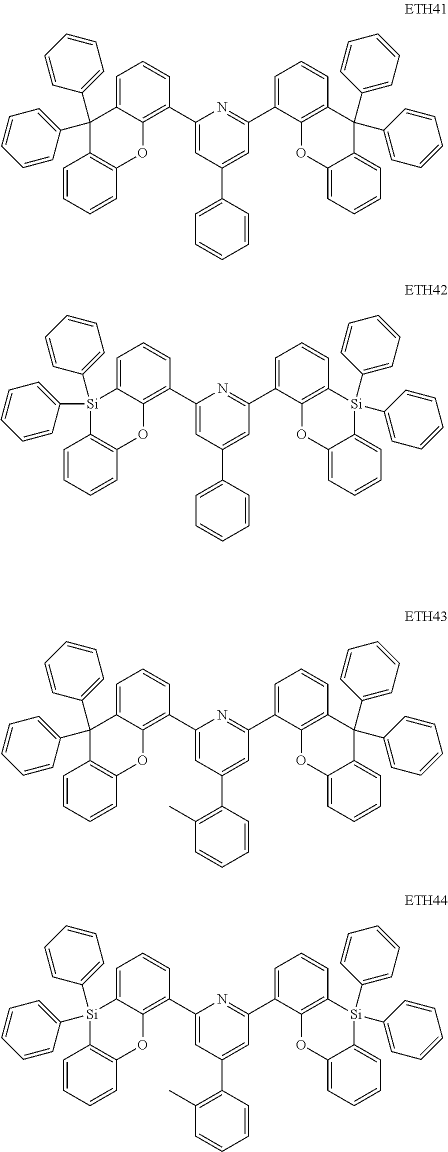 [SMILES: c1ccc(-c2cc(-c3cccc4c3Oc3ccccc3C4(c3ccccc3)c3ccccc3)nc(-c3cccc4c3Oc3ccccc3C4(c3ccccc3)c3ccccc3)c2)cc1 ; c1ccc(-c2cc(-c3cccc4c3Oc3ccccc3[Si]4(c3ccccc3)c3ccccc3)nc(-c3cccc4c3Oc3ccccc3[Si]4(c3ccccc3)c3ccccc3)c2)cc1 ; Cc1ccccc1-c1cc(-c2cccc3c2Oc2ccccc2C3(c2ccccc2)c2ccccc2)nc(-c2cccc3c2Oc2ccccc2C3(c2ccccc2)c2ccccc2)c1 ; Cc1ccccc1-c1cc(-c2cccc3c2Oc2ccccc2[Si]3(c2ccccc2)c2ccccc2)nc(-c2cccc3c2Oc2ccccc2[Si]3(c2ccccc2)c2ccccc2)c1]

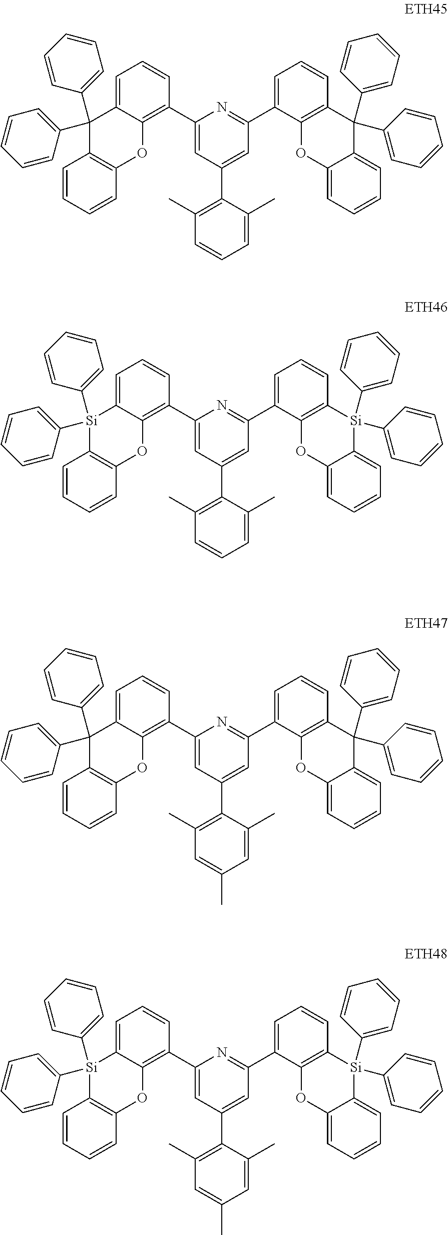 [SMILES: Cc1cccc(C)c1-c1cc(-c2cccc3c2Oc2ccccc2C3(c2ccccc2)c2ccccc2)nc(-c2cccc3c2Oc2ccccc2C3(c2ccccc2)c2ccccc2)c1 ; Cc1cccc(C)c1-c1cc(-c2cccc3c2Oc2ccccc2[Si]3(c2ccccc2)c2ccccc2)nc(-c2cccc3c2Oc2ccccc2[Si]3(c2ccccc2)c2ccccc2)c1 ; Cc1cc(C)c(-c2cc(-c3cccc4c3Oc3ccccc3C4(c3ccccc3)c3ccccc3)nc(-c3cccc4c3Oc3ccccc3C4(c3ccccc3)c3ccccc3)c2)c(C)c1 ; Cc1cc(C)c(-c2cc(-c3cccc4c3Oc3ccccc3[Si]4(c3ccccc3)c3ccccc3)nc(-c3cccc4c3Oc3ccccc3[Si]4(c3ccccc3)c3ccccc3)c2)c(C)c1]

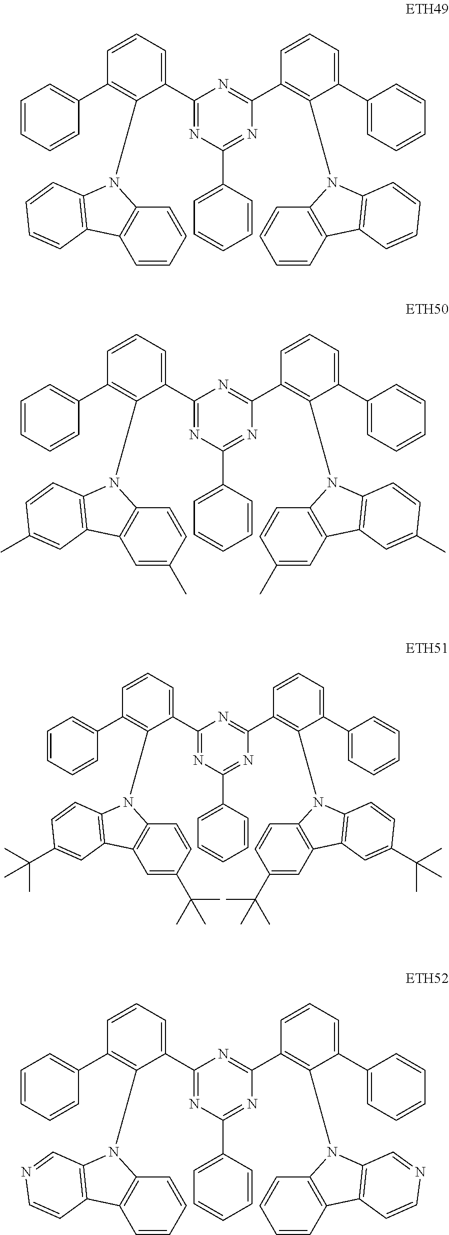

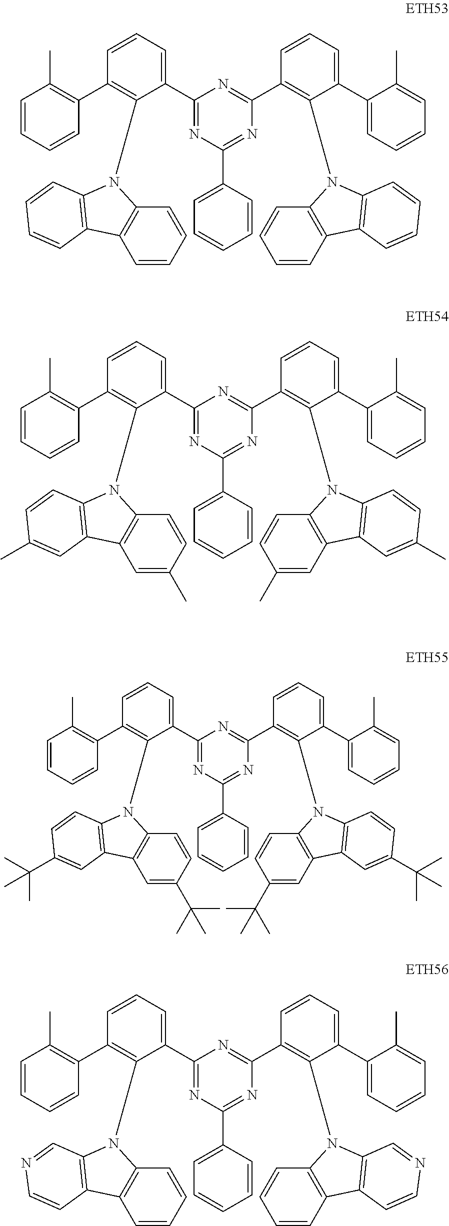

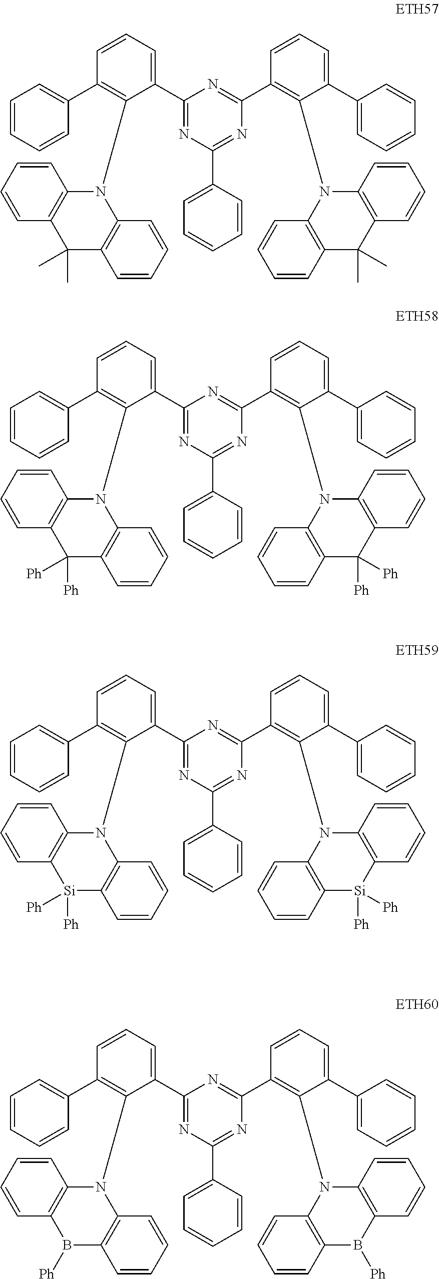

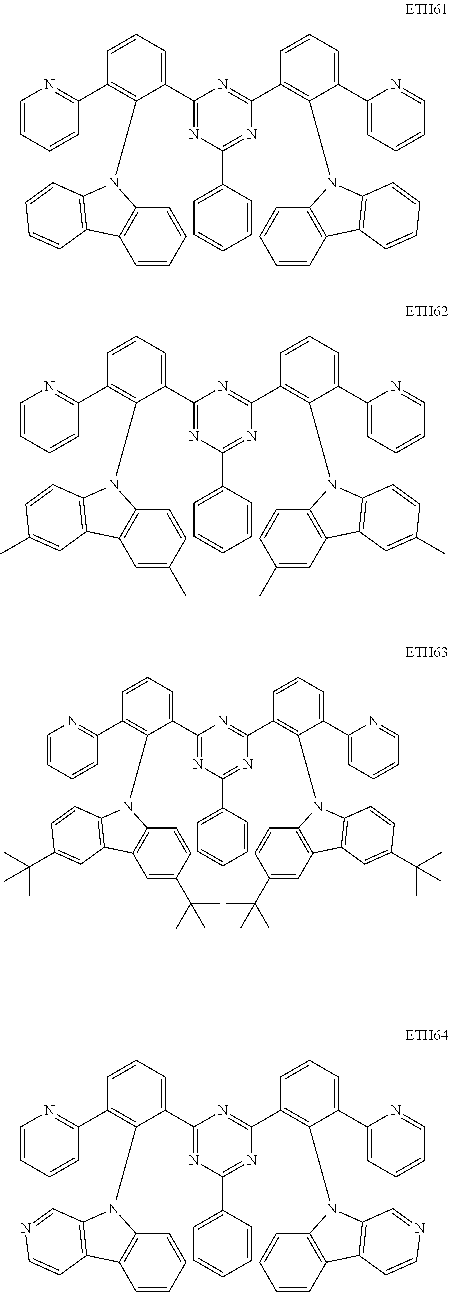

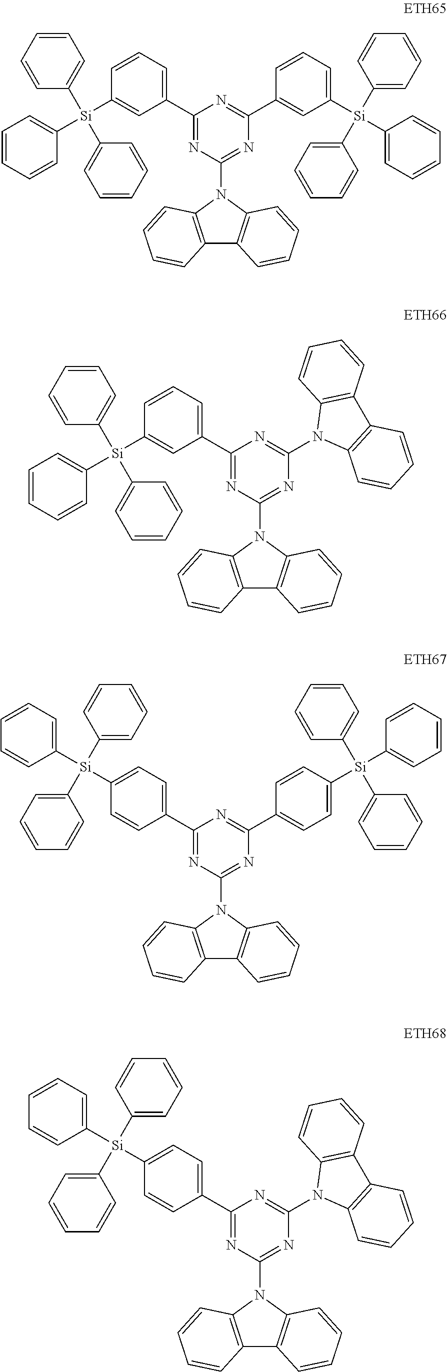 [SMILES: c1ccc([Si](c2ccccc2)(c2ccccc2)c2cccc(-c3nc(-c4cccc([Si](c5ccccc5)(c5ccccc5)c5ccccc5)c4)nc(-n4c5ccccc5c5ccccc54)n3)c2)cc1 ; c1ccc([Si](c2ccccc2)(c2ccccc2)c2cccc(-c3nc(-n4c5ccccc5c5ccccc54)nc(-n4c5ccccc5c5ccccc54)n3)c2)cc1 ; c1ccc([Si](c2ccccc2)(c2ccccc2)c2ccc(-c3nc(-c4ccc([Si](c5ccccc5)(c5ccccc5)c5ccccc5)cc4)nc(-n4c5ccccc5c5ccccc54)n3)cc2)cc1 ; c1ccc([Si](c2ccccc2)(c2ccccc2)c2ccc(-c3nc(-n4c5ccccc5c5ccccc54)nc(-n4c5ccccc5c5ccccc54)n3)cc2)cc1]

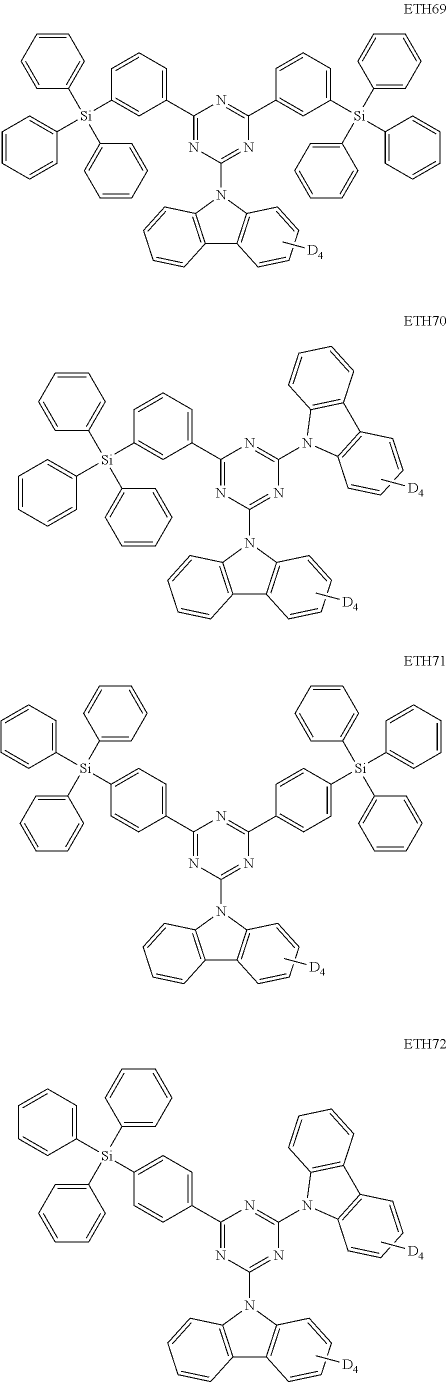

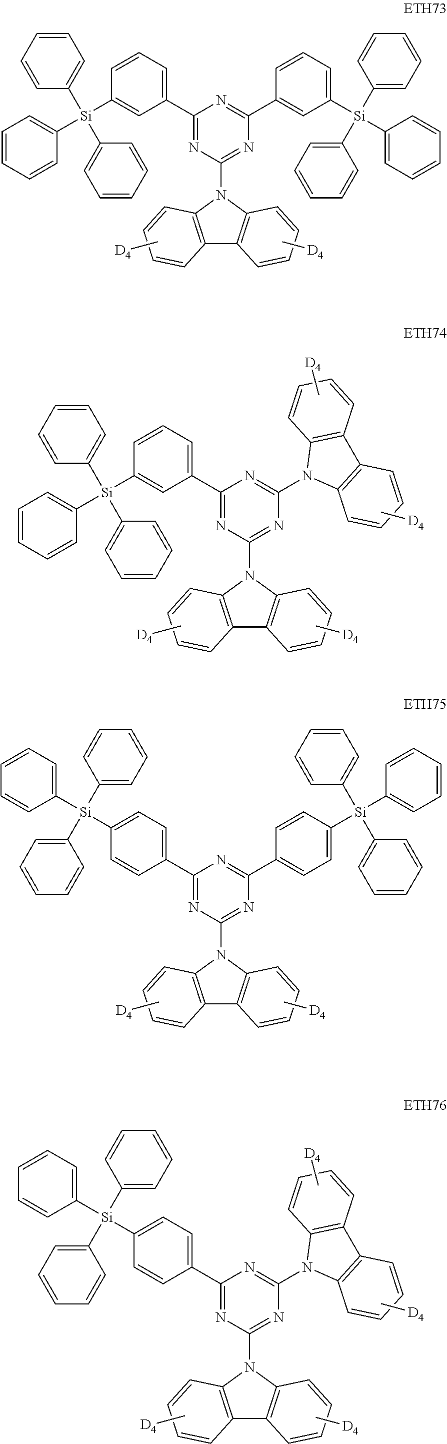

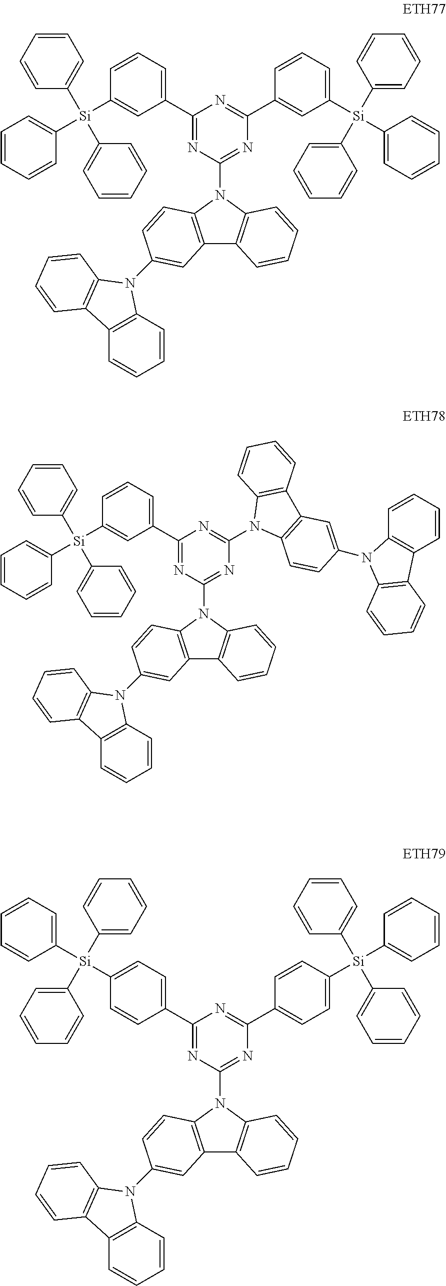 [SMILES: c1ccc([Si](c2ccccc2)(c2ccccc2)c2cccc(-c3nc(-c4cccc([Si](c5ccccc5)(c5ccccc5)c5ccccc5)c4)nc(-n4c5ccccc5c5cc(-n6c7ccccc7c7ccccc76)ccc54)n3)c2)cc1 ; c1ccc([Si](c2ccccc2)(c2ccccc2)c2cccc(-c3nc(-n4c5ccccc5c5cc(-n6c7ccccc7c7ccccc76)ccc54)nc(-n4c5ccccc5c5cc(-n6c7ccccc7c7ccccc76)ccc54)n3)c2)cc1 ; c1ccc([Si](c2ccccc2)(c2ccccc2)c2ccc(-c3nc(-c4ccc([Si](c5ccccc5)(c5ccccc5)c5ccccc5)cc4)nc(-n4c5ccccc5c5cc(-n6c7ccccc7c7ccccc76)ccc54)n3)cc2)cc1]

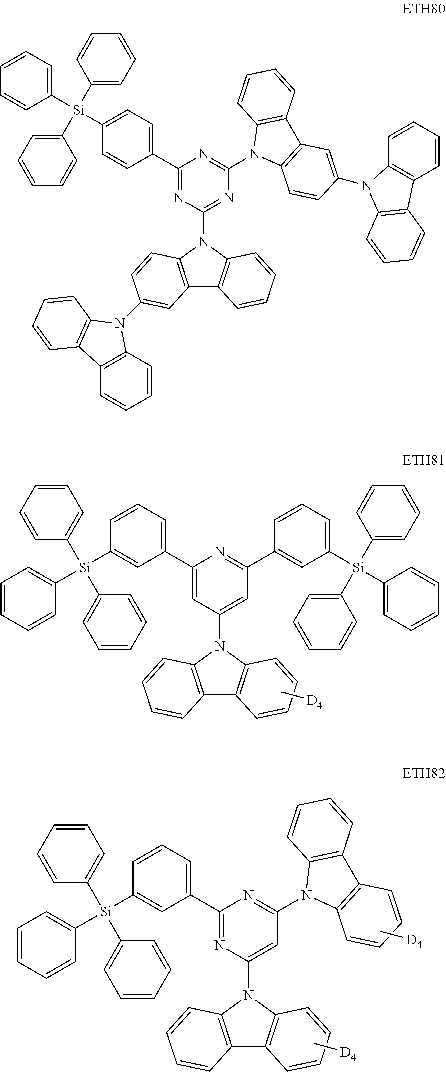

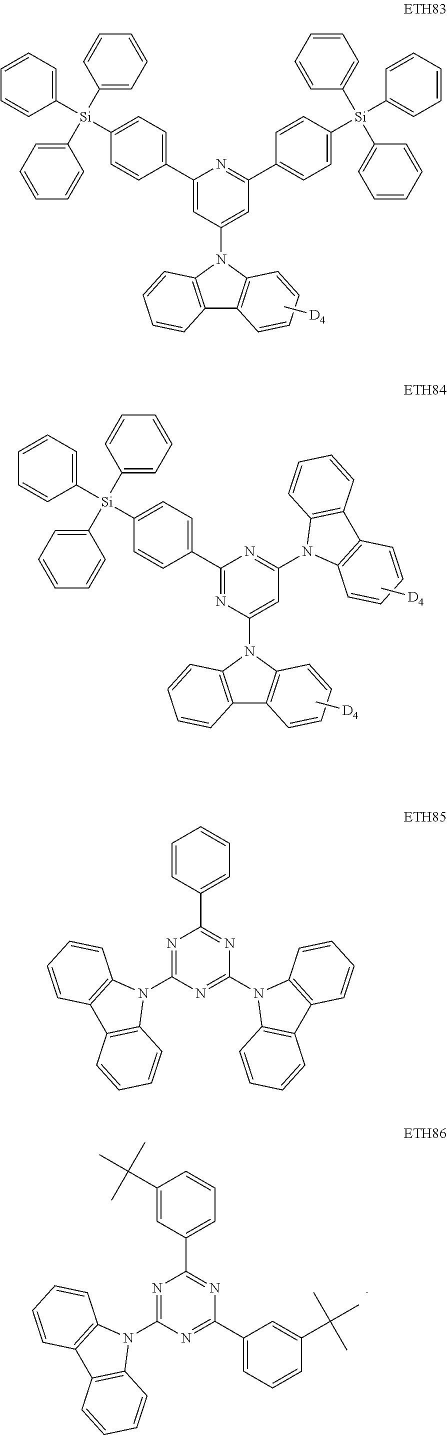

In an embodiment, the emission layer EML may include a second compound and a third compound, and the second compound and the third compound may form an exciplex. In the emission layer EML, the hole transporting host and the electron transporting host may form an exciplex. A triplet energy of the exciplex formed by the hole transporting host and the electron transporting host may correspond to a difference between Lowest Unoccupied Molecular Orbital (LUMO) energy level of the electron transporting host and a Highest Occupied Molecular Orbital (HOMO) energy level of the hole transporting host.

For example, a triplet energy level (T1) of the exciplex formed by the hole transporting host and the electron transporting host may have an absolute value in a range of about 2.4 eV to about 3.0 eV. The triplet energy of the exciplex may have a value smaller than the energy gap of each host material. The exciplex may have a triplet energy equal to or less than about 3.0 eV, which is an energy gap between the hole transporting host and the electron transporting host.

In an embodiment, the emission layer EML may include a fourth compound represented by Formula PS. In an embodiment, the fourth compound represented by Formula PS may be used as a phosphorescent sensitizer of the emission layer EML. Energy may be transferred from the fourth compound to the first compound to emit light.

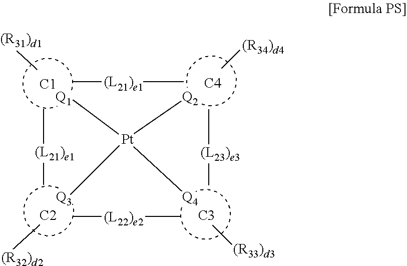

In Formula PS, Q₁ to Q₄ may each independently be C or N; and C1 to C4 may each independently be a substituted or unsubstituted hydrocarbon ring group having 5 to 30 ring-forming carbon atoms, or a substituted or unsubstituted heterocyclic group having 2 to 30 ring-forming carbon atoms.

In Formula PS, e1 to e4 may each independently be 0 or 1; and L₂₁ to L₂₄ may each independently be a direct linkage,

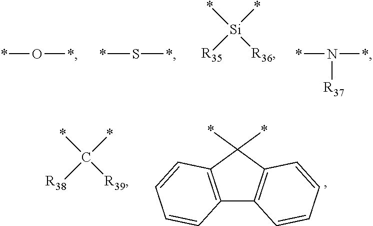

a substituted or unsubstituted divalent alkyl group having 1 to 20 carbon atoms, a substituted or unsubstituted arylene group having 6 to 30 ring-forming carbon atoms, or a substituted or unsubstituted heteroarylene group having 2 to 30 ring-forming carbon atoms.

In Formula PS, d1 to d4 may each independently be an integer from 0 to 4. When d1 is 2 or greater, multiple R₃₁ groups may all be the same or at least one thereof may be different from the others. When d2 is 2 or greater, multiple R₃₂ groups may all be the same or at least one thereof may be different from the others. When d3 is 2 or greater, multiple R₃₃ groups may all be the same or at least one thereof may be different from the others. When d4 is 2 or greater, multiple R₃₄ groups may all be the same or at least one thereof may be different from the others.

In Formula PS, R₃₁ to R₃₉ may each independently be a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, a substituted or unsubstituted heteroaryl group having 2 to 30 ring-forming carbon atoms, or may be bonded to an adjacent group to form a ring.

The fourth compound may be any compound selected from Compound Group 4. The light emitting element ED according to an embodiment may include at least one compound selected from Compound Group 4.

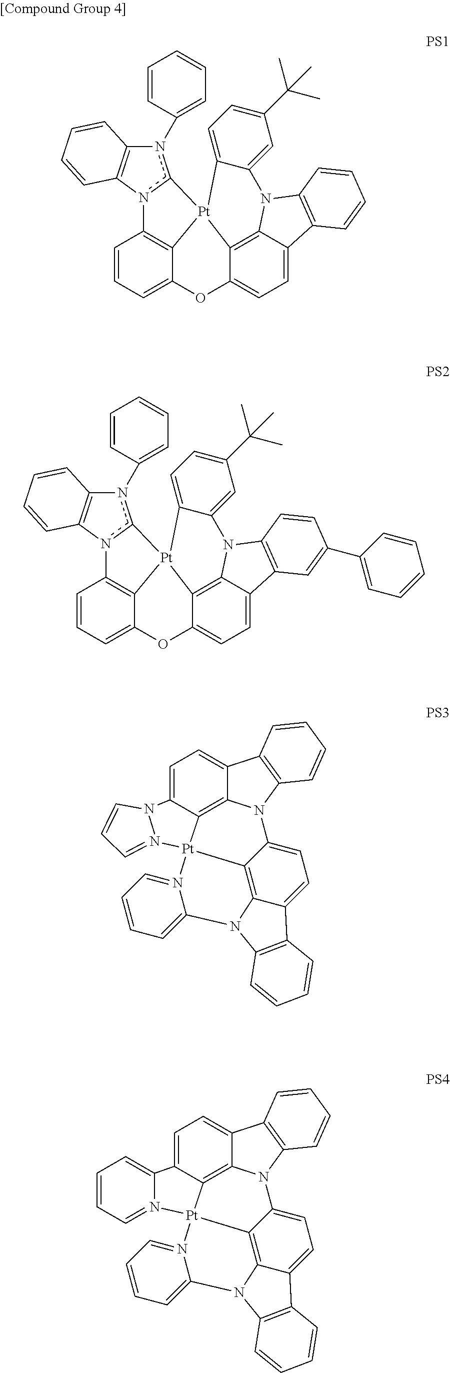

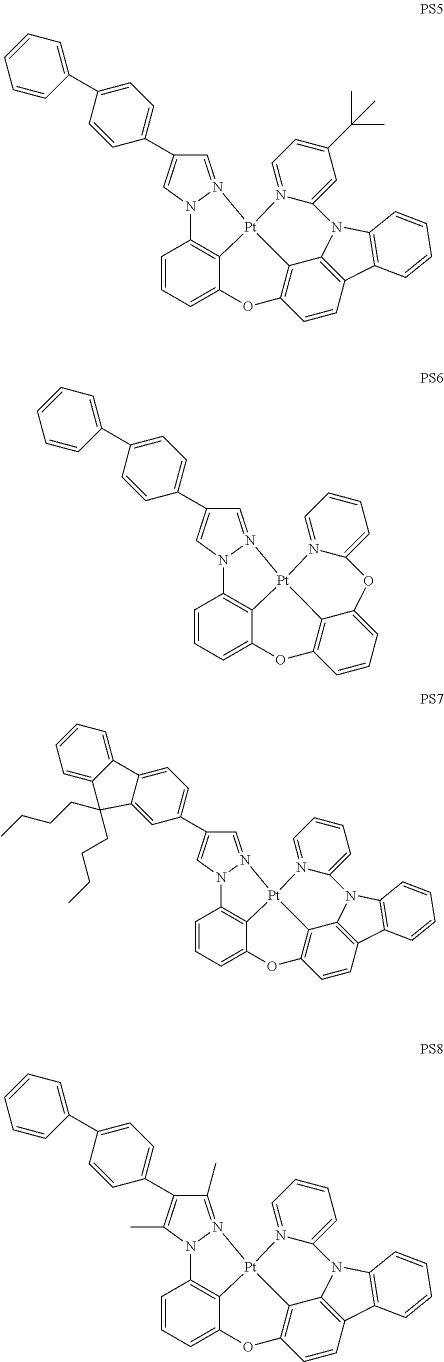

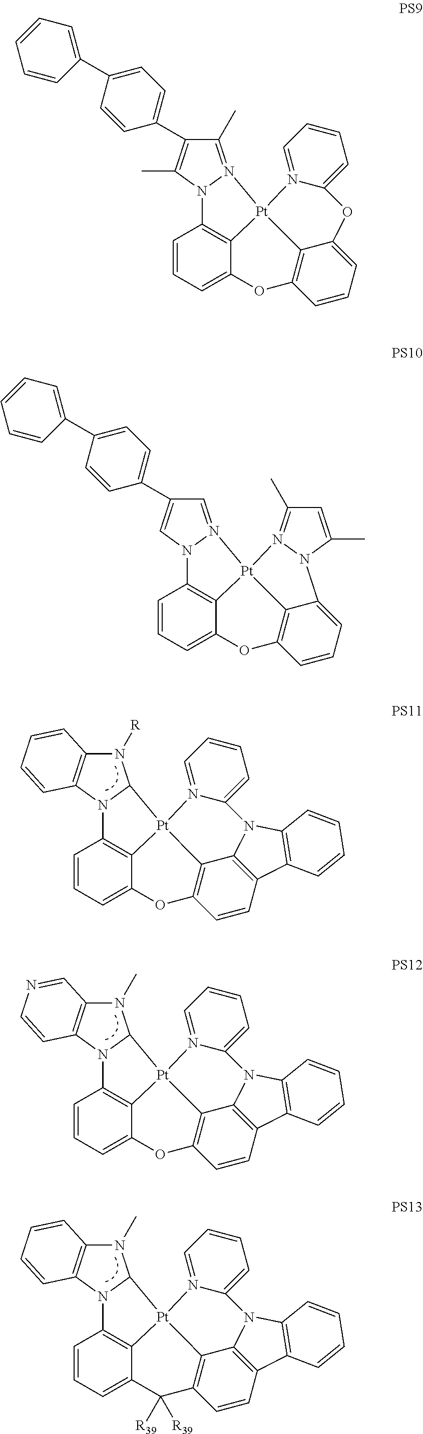

In Compound Group 4, R, R₃₈, and R₃₉ may each independently be a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

The light emitting element ED according to an embodiment may include multiple emission layers. The emission layers may be stacked and provided. In an embodiment, the light emitting element ED including multiple emission layers may emit white light. The light emitting element including multiple emission layers may be a light emitting element having a tandem structure. When the light emitting element ED includes multiple emission layers, at least one emission layer EML may include the first compound represented by Formula 1. When the light emitting element ED includes multiple emission layers, at least one emission layer EML may include all of the first compound, the second compound, the third compound, and the fourth compound as described herein.

When the emission layer EML in the light emitting element ED according to an embodiment includes all of the first compound, the second compound, and the third compound described herein, an amount of the first compound may be in a range of about 0.5 wt % to about 3 wt %, with respect to a total weight of the first compound, the second compound, and the third compound. However, embodiments are not limited thereto. When the amount of the first compound satisfies the above-described ratio, energy transfer from the second compound and the third compound to the first compound may be greater, and accordingly, luminous efficiency and element service life may be increased.

In the emission layer EML, the amount of the second compound and the third compound may be the remainder of the EML excluding the above-described amount of the first compound. For example, in the emission layer EML, a combined amount of the second compound and the third compound may be in a range of about 20 wt % to about 90 wt %, with respect to the total weight of the first compound, the second compound, and the third compound.

A ratio of an amount of the second compound to an amount of the third compound may be in a range of about 3:7 to about 7:3.

When a ratio of an amount of the second compound to an amount of the third compound satisfies the above-described range, charge balance in the emission layer EML may be improved to increase luminous efficiency and element service life. When a ratio of an amount of the second compound to an amount of the third compound is out of the above-described range, charge balance in the emission layer EML may be impaired to reduce luminous efficiency and may readily deteriorate an element.

When the first compound, the second compound, and the third compound included in the emission layer EML satisfy the above-described amounts and ratio ranges, excellent luminous efficiency and long service life may be achieved.

In an embodiment, the emission layer EML may further include an emission layer material other than the first to fourth compounds described herein. In the light emitting element ED according to an embodiment, the emission layer EML may include an anthracene derivative, a pyrene derivative, a fluoranthene derivative, a chrysene derivative, a dihydrobenzanthracene derivative, or a triphenylene derivative. For example, the emission layer EML may include an anthracene derivative or a pyrene derivative.

In the light emitting element ED according to an embodiment shown in FIGS. 3 to 6, the emission layer EML may include a compound represented by Formula E-1. The compound represented by Formula E-1 may be used as a fluorescent host material.

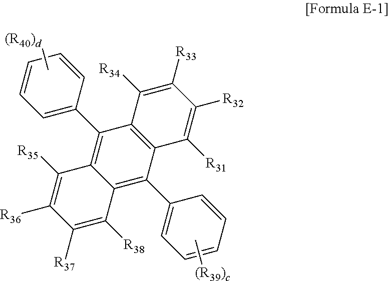

In Formula E-1, R₃₁ to R₄₀ may each independently be a hydrogen atom, a deuterium atom, a halogen atom, a substituted or unsubstituted silyl group, a substituted or unsubstituted thio group, a substituted or unsubstituted oxy group, a substituted or unsubstituted alkyl group having 1 to 10 carbon atoms, a substituted or unsubstituted alkenyl group having 2 to 10 carbon atoms, a substituted or unsubstituted aryl group having 6 to 30 ring-forming carbon atoms, a substituted or unsubstituted heteroaryl group having 2 to 30 ring-forming carbon atoms, or may be bonded to an adjacent group to form a ring. For example, R₃₁ to R₄₀ may be bonded to an adjacent group to form a saturated hydrocarbon ring, an unsaturated hydrocarbon ring, a saturated heterocycle, or an unsaturated heterocycle.

In Formula E-1, c and d may each independently be an integer of 0 to 5.

The compound represented by Formula E-1 may be any compound selected from Compound E1 to Compound E19.

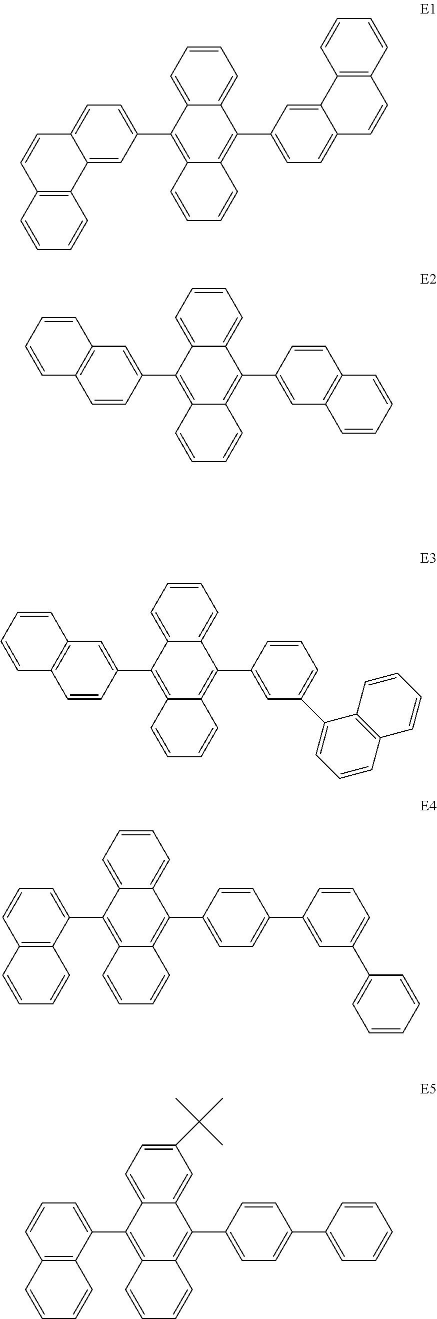

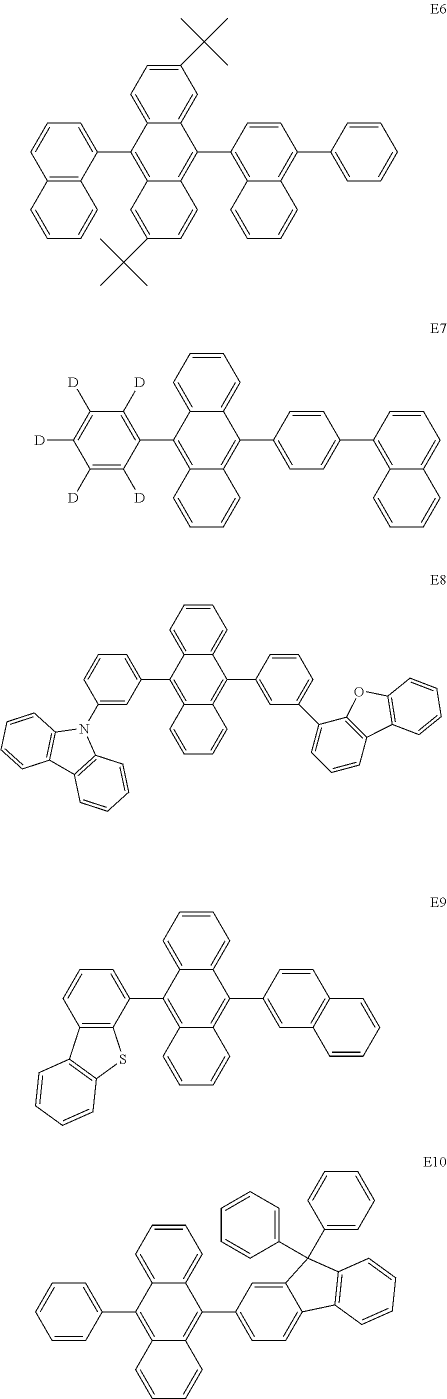

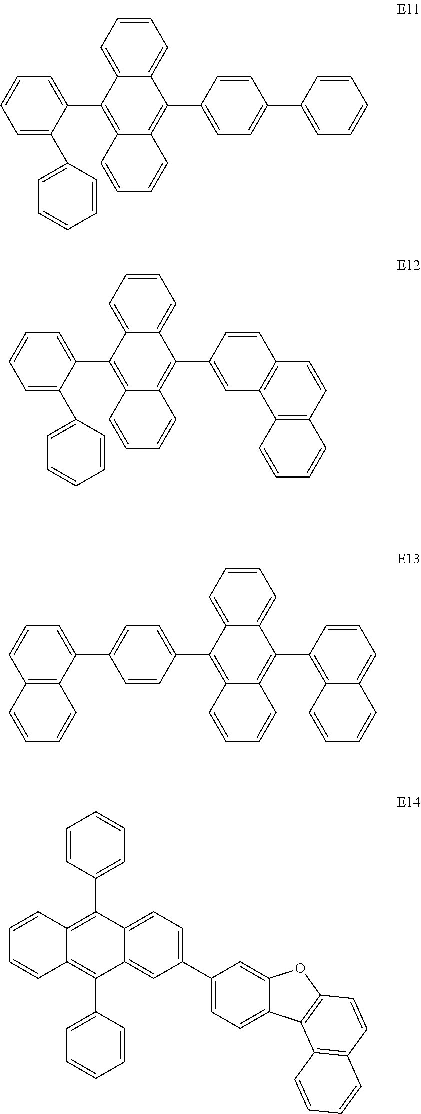

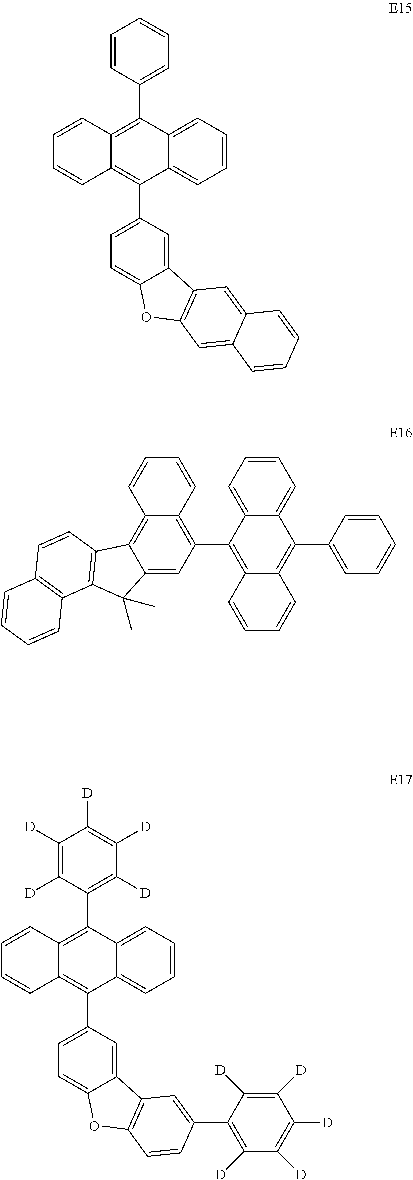

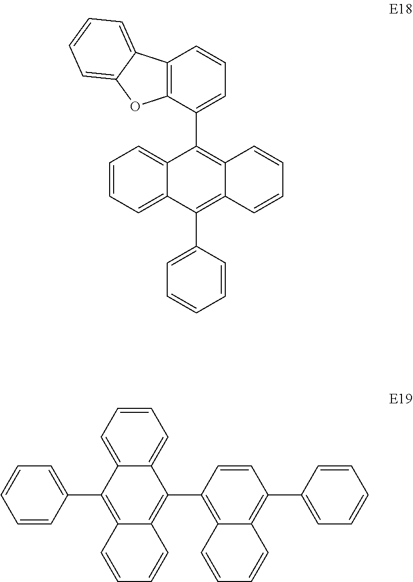

In an embodiment, the emission layer EML may include a compound represented by Formula E-2a or Formula E-2b. The compound represented by Formula E-2a or Formula E-2b may be used as a phosphorescent host material.

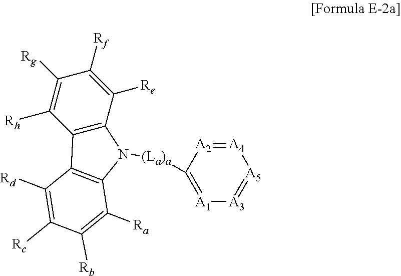

In Formula E-2a, a may be an integer from 0 to 10; and Lₐ may be a direct linkage, a substituted or unsubstituted arylene group having 6 to 30 ring-forming carbon atoms, or a substituted or unsubstituted heteroarylene group having 2 to 30 ring-forming carbon atoms. When a is 2 or greater, multiple Lₐ groups may each independently be a substituted or unsubstituted arylene group having 6 to 30 ring-forming carbon atoms, or a substituted or unsubstituted heteroarylene group having 2 to 30 ring-forming carbon atoms.

In Formula E-2a, A₁ to A₅ may be N or C(Rᵢ). In Formula E-2a, Rₐ to Rᵢ may each independently be a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, a substituted or unsubstituted heteroaryl group having 2 to 30 ring-forming carbon atoms, or may be bonded to an adjacent group to form a ring. For example, Rₐ to Rᵢ may be bonded to an adjacent group to form a hydrocarbon ring or a heterocycle containing N, O, S, and the like as a ring-forming atom.

In Formula E-2a, two or three of A₁ to A₅ may each be N, and the remainder of A₁ to A₅ may each independently be C(Rᵢ).

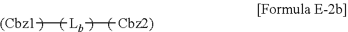

In Formula E-2b, Cbz1 and Cbz2 may each independently be an unsubstituted carbazole group or an aryl-substituted carbazole group having 6 to 30 ring-forming carbon atoms. In Formula E-2b, L_{b} may be a direct linkage, a substituted or unsubstituted arylene group having 6 to 30 ring-forming carbon atoms, or a substituted or unsubstituted heteroarylene group having 2 to 30 ring-forming carbon atoms. In Formula E-2b, b may be an integer from 0 to 10, and when b is 2 or greater, multiple L_{b} groups may each independently be a substituted or unsubstituted arylene group having 6 to 30 ring-forming carbon atoms, or a substituted or unsubstituted heteroarylene group having 2 to 30 ring-forming carbon atoms.

The compound represented by Formula E-2a or Formula E-2b may be any compound selected from Compound Group E-2. However, the compounds listed in Compound Group E-2 are presented as an example, and the compound represented by Formula E-2a or Formula E-2b is not limited to those listed in Compound Group E-2.

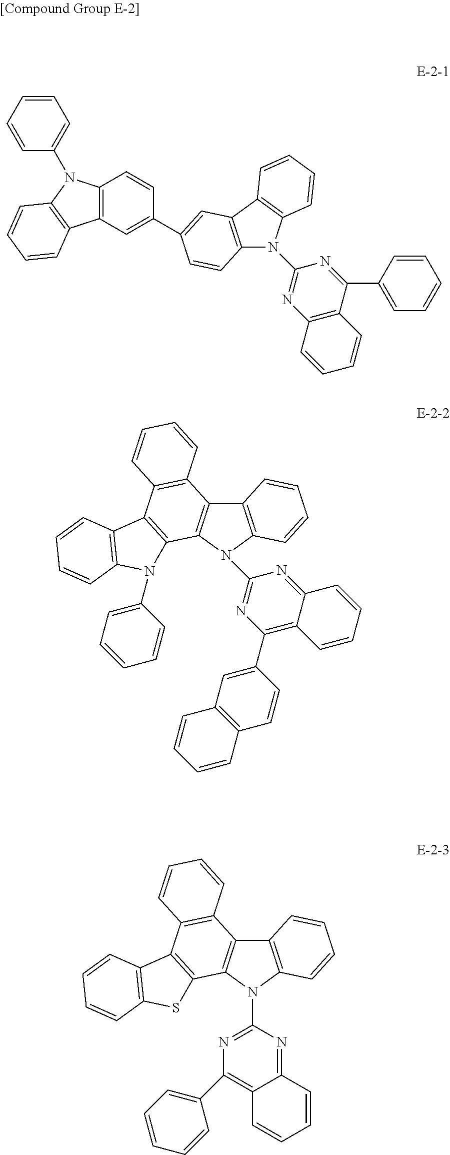 [SMILES: c1ccc(-c2nc(-n3c4ccccc4c4cc(-c5ccc6c(c5)c5ccccc5n6-c5ccccc5)ccc43)nc3ccccc23)cc1 ; c1ccc(-n2c3ccccc3c3c4ccccc4c4c5ccccc5n(-c5nc(-c6ccc7ccccc7c6)c6ccccc6n5)c4c32)cc1 ; c1ccc(-c2nc(-n3c4ccccc4c4c5ccccc5c5c6ccccc6sc5c43)nc3ccccc23)cc1]

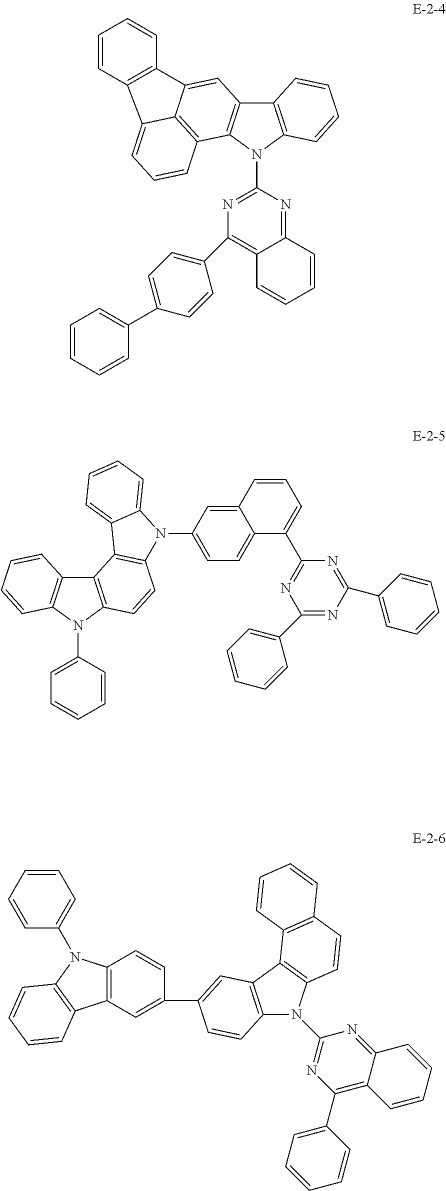 [SMILES: c1ccc(-c2ccc(-c3nc(-n4c5ccccc5c5cc6c7c(cccc7c54)-c4ccccc4-6)nc4ccccc34)cc2)cc1 ; c1ccc(-c2nc(-c3ccccc3)nc(-c3cccc4cc(-n5c6ccccc6c6c7c8ccccc8n(-c8ccccc8)c7ccc65)ccc34)n2)cc1 ; c1ccc(-c2nc(-n3c4ccc(-c5ccc6c(c5)c5ccccc5n6-c5ccccc5)cc4c4c5ccccc5ccc43)nc3ccccc23)cc1]

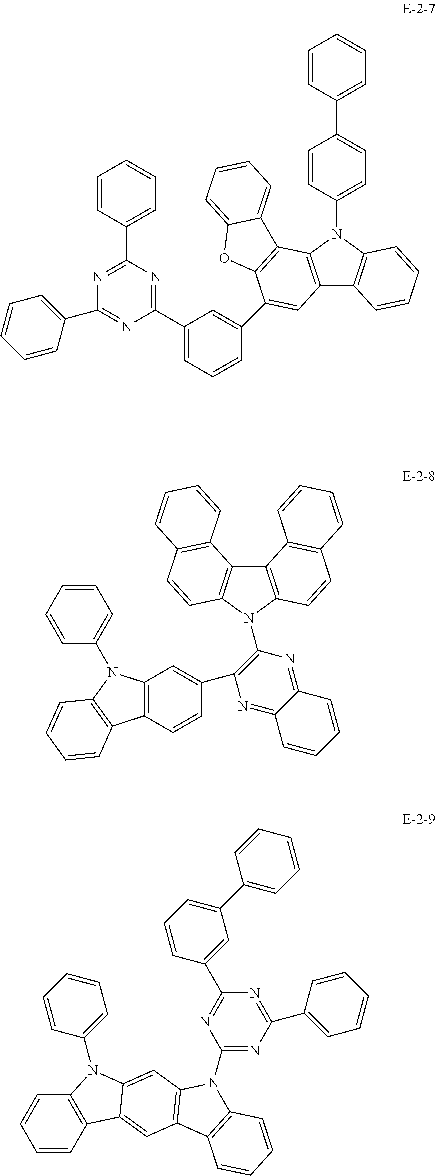 [SMILES: c1ccc(-c2ccc(-n3c4ccccc4c4cc(-c5cccc(-c6nc(-c7ccccc7)nc(-c7ccccc7)n6)c5)c5oc6ccccc6c5c43)cc2)cc1 ; c1ccc(-n2c3ccccc3c3ccc(-c4nc5ccccc5nc4-n4c5ccc6ccccc6c5c5c6ccccc6ccc54)cc32)cc1 ; c1ccc(-c2cccc(-c3nc(-c4ccccc4)nc(-n4c5ccccc5c5cc6c7ccccc7n(-c7ccccc7)c6cc54)n3)c2)cc1]

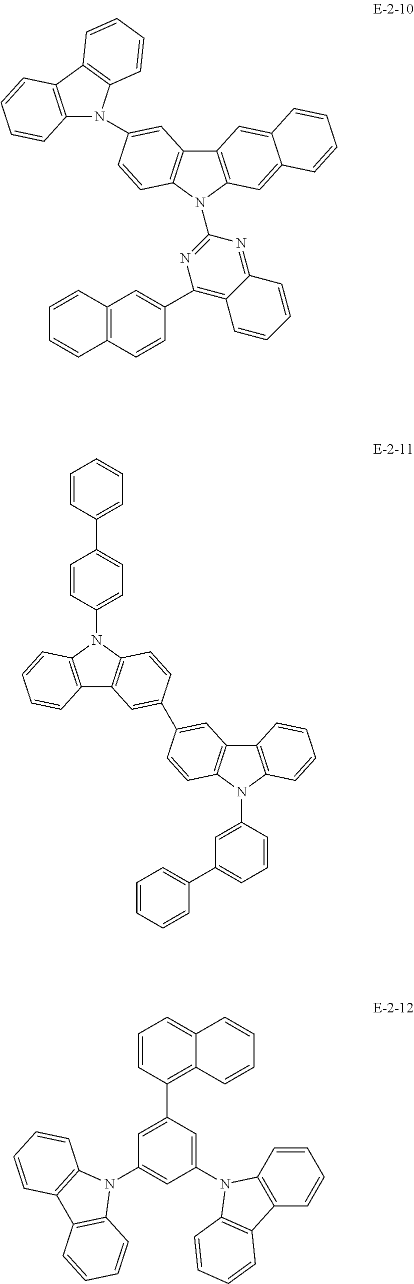 [SMILES: c1ccc2cc(-c3nc(-n4c5ccc(-n6c7ccccc7c7ccccc76)cc5c5cc6ccccc6cc54)nc4ccccc34)ccc2c1 ; c1ccc(-c2ccc(-n3c4ccccc4c4cc(-c5ccc6c(c5)c5ccccc5n6-c5cccc(-c6ccccc6)c5)ccc43)cc2)cc1 ; c1ccc2c(-c3cc(-n4c5ccccc5c5ccccc54)cc(-n4c5ccccc5c5ccccc54)c3)cccc2c1]

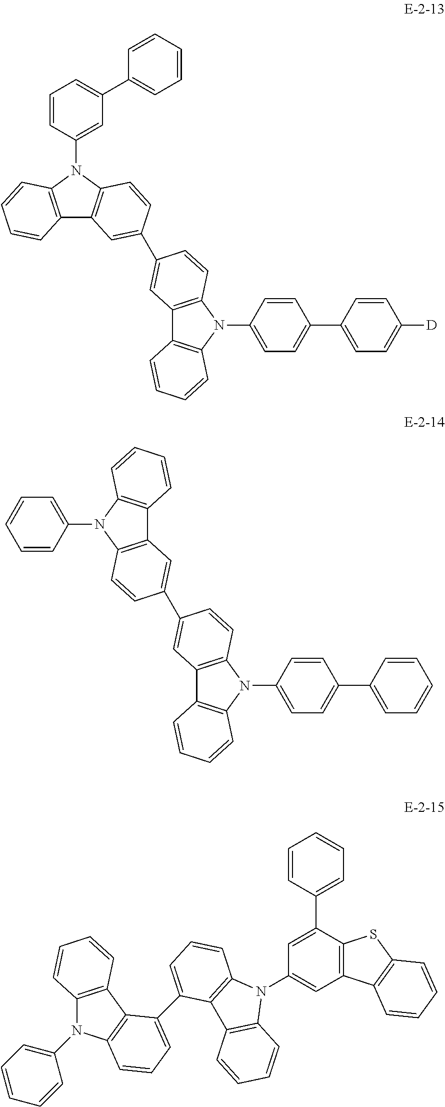 [SMILES: [2H]c1ccc(-c2ccc(-n3c4ccccc4c4cc(-c5ccc6c(c5)c5ccccc5n6-c5cccc(-c6ccccc6)c5)ccc43)cc2)cc1 ; c1ccc(-c2ccc(-n3c4ccccc4c4cc(-c5ccc6c(c5)c5ccccc5n6-c5ccccc5)ccc43)cc2)cc1 ; c1ccc(-c2cc(-n3c4ccccc4c4c(-c5cccc6c5c5ccccc5n6-c5ccccc5)cccc43)cc3c2sc2ccccc23)cc1]

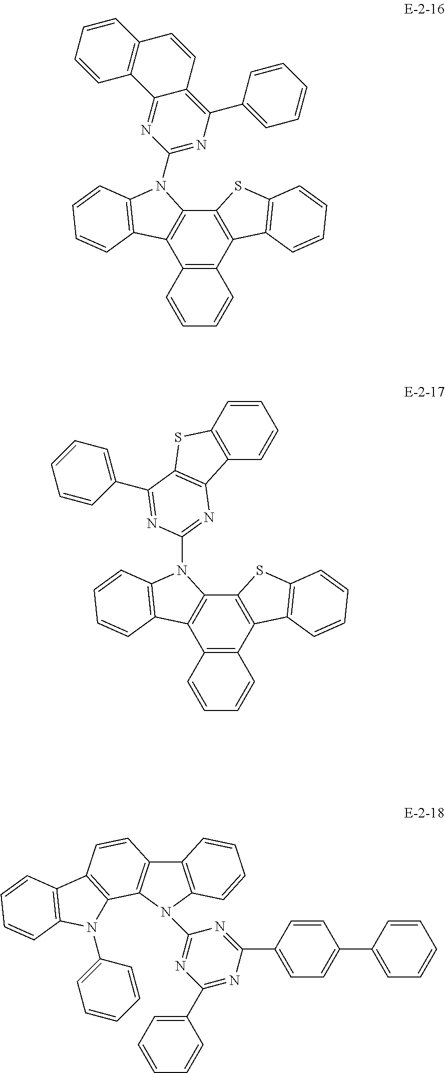 [SMILES: c1ccc(-c2nc(-n3c4ccccc4c4c5ccccc5c5c6ccccc6sc5c43)nc3c2ccc2ccccc23)cc1 ; c1ccc(-c2nc(-n3c4ccccc4c4c5ccccc5c5c6ccccc6sc5c43)nc3c2sc2ccccc23)cc1 ; c1ccc(-c2ccc(-c3nc(-c4ccccc4)nc(-n4c5ccccc5c5ccc6c7ccccc7n(-c7ccccc7)c6c54)n3)cc2)cc1]

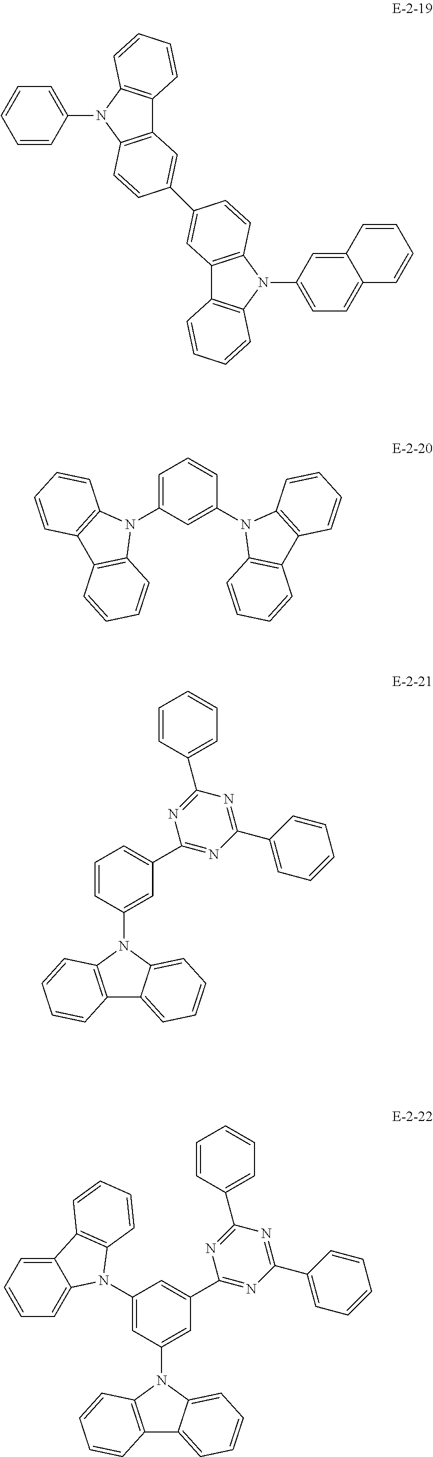 [SMILES: c1ccc(-n2c3ccccc3c3cc(-c4ccc5c(c4)c4ccccc4n5-c4ccc5ccccc5c4)ccc32)cc1 ; c1cc(-n2c3ccccc3c3ccccc32)cc(-n2c3ccccc3c3ccccc32)c1 ; c1ccc(-c2nc(-c3ccccc3)nc(-c3cccc(-n4c5ccccc5c5ccccc54)c3)n2)cc1 ; c1ccc(-c2nc(-c3ccccc3)nc(-c3cc(-n4c5ccccc5c5ccccc54)cc(-n4c5ccccc5c5ccccc54)c3)n2)cc1]

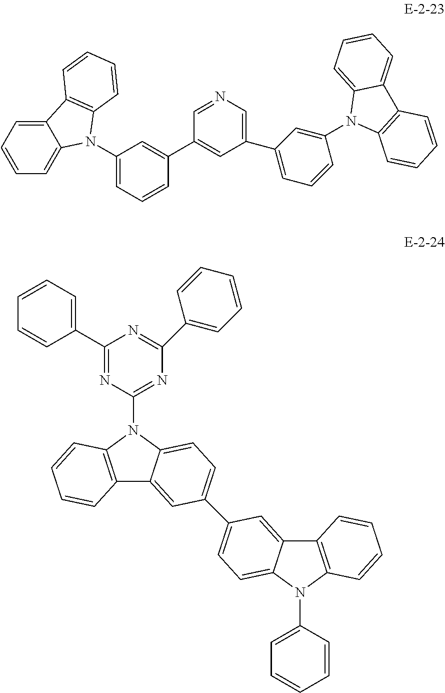 [SMILES: c1cc(-c2cncc(-c3cccc(-n4c5ccccc5c5ccccc54)c3)c2)cc(-n2c3ccccc3c3ccccc32)c1 ; c1ccc(-c2nc(-c3ccccc3)nc(-n3c4ccccc4c4cc(-c5ccc6c(c5)c5ccccc5n6-c5ccccc5)ccc43)n2)cc1]

The emission layer EML may further include a material of the related art as a host material. For example, the emission layer EML may include, as a host material, at least one of bis(4-(9H-carbazol-9-yl)phenyl)diphenylsilane (BCPDS), (4-(1-(4-(diphenylamino)phenyl)cyclohexyl)phenyl)diphenyl-phosphine oxide (POPCPA), bis[2-(diphenylphosphino)phenyl]ether oxide (DPEPO), 3,3′-di(9H-carbazol-9-yl)-1,1′-biphenyl (mCBP), 4,4′-bis(N-carbazolyl)-1,1′-biphenyl (CBP), 1,3-bis(carbazolyl-9-yl)benzene (mCP), 2,8-bis(diphenylphosphoryl)dibenzofuran (PPF), 4,4′,4″-tris(carbazol-9-yl)-triphenylamine (TCTA), and 1,3,5-tris(1-phenyl-1H-benzo[d]imidazol-2-yl)benzene (TPBi). However, embodiments are not limited thereto, and for example, tris(8-hydroxyquinolino)aluminum (Alq₃), 9,10-di(naphthalene-2-yl)anthracene (ADN), 3-tert-butyl-9,10-di(naphth-2-yl)anthracene (TBADN), distyrylarylene (DSA), 4,4′-bis(9-carbazolyl)-2,2′-dimethyl-biphenyl (CDBP), 2-methyl-9,10-bis(naphthalen-2-yl)anthracene (MADN), hexaphenyl cyclotriphosphazene (CP1), 1,4-bis(triphenylsilyl)benzene (UGH2), hexaphenylcyclotrisiloxane (DPSiO₃), octaphenylcyclotetrasiloxane (DPSiO₄), and the like may be used as a host material.

The emission layer EML may include a compound represented by Formula M-a. The compound represented by Formula M-a may be used as a phosphorescent dopant material. In an embodiment, the compound represented by Formula M-a may be used as an auxiliary dopant material.

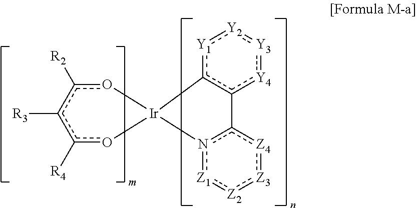

In Formula M-a, Y₁ to Y₄ and Z₁ to Z₄ may each independently be C(R₁) or N; and R₁ to R₄ may each independently be a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, a substituted or unsubstituted heteroaryl group having 2 to 30 ring-forming carbon atoms, or may be bonded to an adjacent group to form a ring. In Formula M-a, m may be 0 or 1, and n may be 2 or 3. In Formula M-a, when m is 0, n may be 3, and when m is 1, n may be 2.

The compound represented by Formula M-a may be represented by any compound selected from Compounds M-a1 to M-a25. However, Compounds M-a1 to M-a25 are presented as an example, and the compound represented by Formula M-a is not limited to Compounds M-a1 to M-a25.

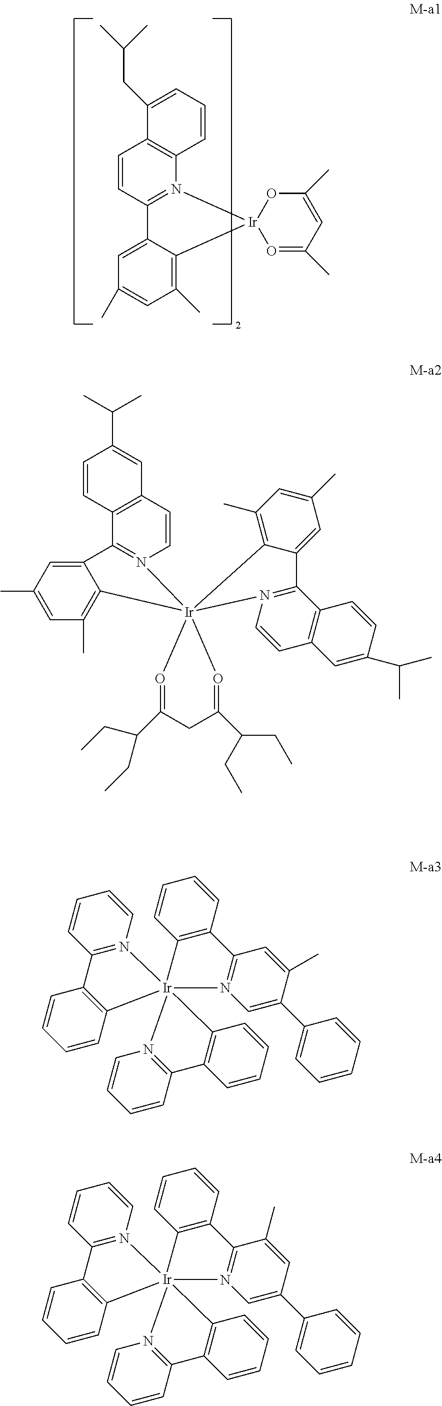

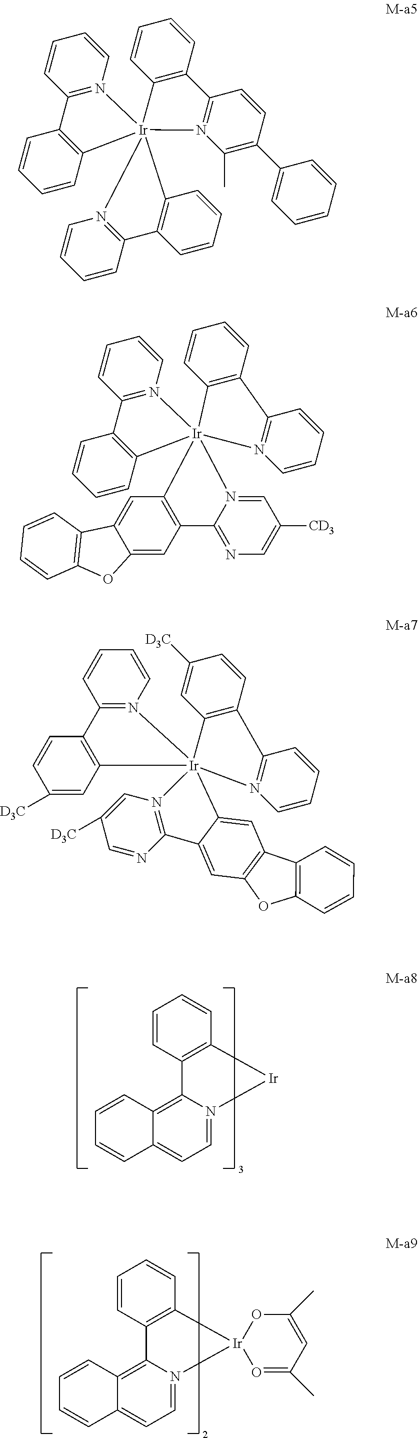

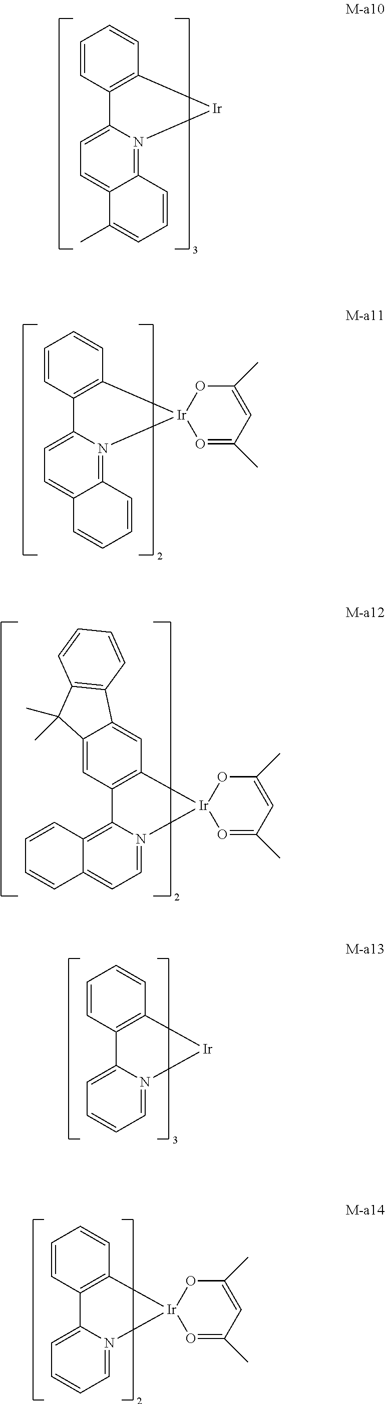

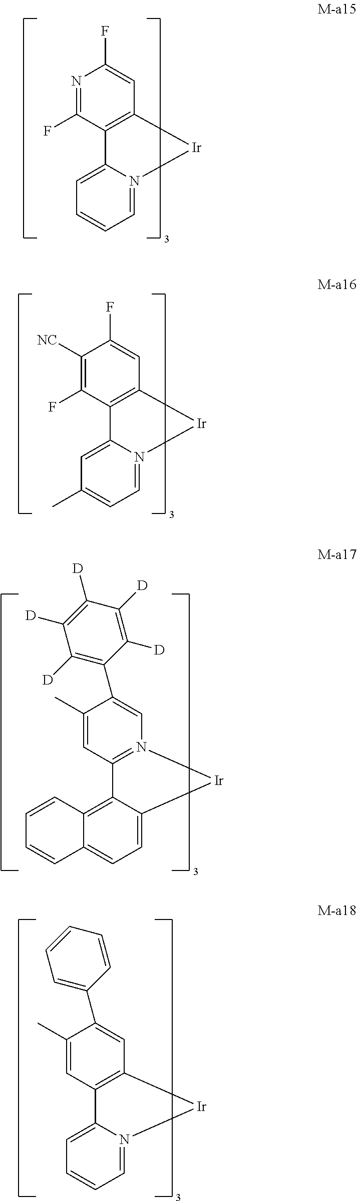

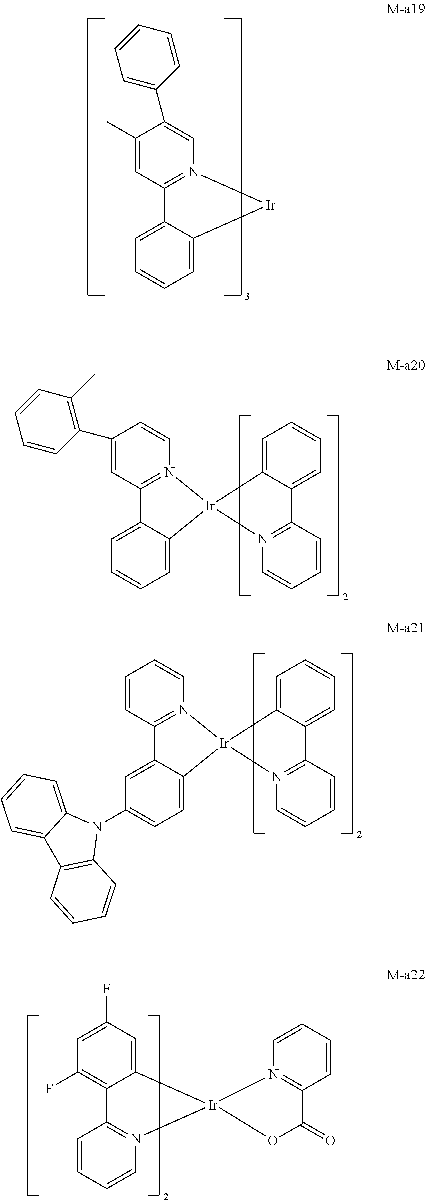

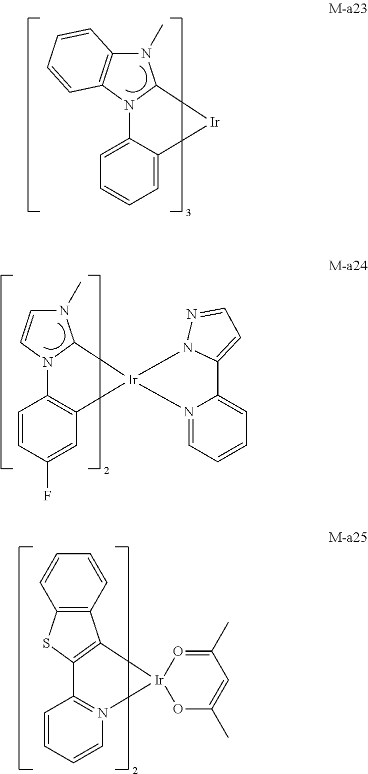

Compounds M-a1 and M-a2 may be used as a red dopant material, and Compounds M-a3 to M-a7 may be used as a green dopant material.

The emission layer EML may further include a compound represented by one of Formulas F-a to F-c. The compounds represented by Formulas F-a to F-c may be used as a fluorescence dopant material.

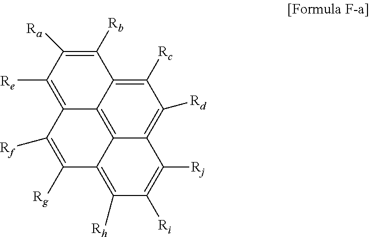

In Formula F-a, two of Rₐ to Rⱼ may each independently be substituted with a group represented by *-NAr₁Ar₂. The remainder of R a to RR which are not substituted with the group represented by *-NAr₁Ar₂ may each independently be a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. In the group represented by *-NAr₁Ar₂, Ar₁ and Ar₂ may each independently be a substituted or unsubstituted aryl group having 6 to 30 ring-forming carbon atoms, or a substituted or unsubstituted heteroaryl group having 2 to 30 ring-forming carbon atoms. For example, at least one of Ar₁ or Ar₂ may be a heteroaryl group containing O or S as a ring-forming atom.

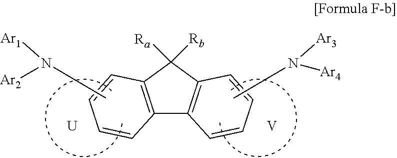

In Formula F-b, Rₐ and R_{b} may each independently be a hydrogen atom, a deuterium atom, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, a substituted or unsubstituted heteroaryl group having 2 to 30 ring-forming carbon atoms, or bonded to an adjacent group to form a ring. In Formula F-b, Ar₁ to Ar₄ may each independently be a substituted or unsubstituted aryl group having 6 to 30 ring-forming carbon atoms, or a substituted or unsubstituted heteroaryl group having 2 to 30 ring-forming carbon atoms.

In Formula F-b, U and V may each independently be a substituted or unsubstituted hydrocarbon ring having 5 to 30 ring-forming carbon atoms, or a substituted or unsubstituted heterocycle having 2 to 30 ring-forming carbon atoms.

In Formula F-b, the number of rings represented by U and V may each independently be 0 or 1. For example, In Formula F-b, when the number of U or V is 1, a fused ring may be present at a portion indicated by U or V, and when the number of U or V is 0, a ring may not be present at the portion indicated by U or V. When the number of U is 0 and the number of V is 1, or when the number of U is 1 and the number of V is 0, a fused ring having a fluorene core of Formula F-b may be a cyclic compound having four rings. When the number of U and V are each 0, a fused ring having a fluorene core of Formula F-b may be a cyclic compound having three rings. When the number of U and V are each 1, a fused ring having a fluorene core of Formula F-b may be a cyclic compound having five rings.

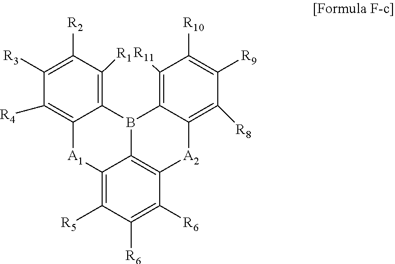

In Formula F-c, A₁ and A₂ may each independently be O, S, Se, or N(Rₘ); and Rₘ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. In Formula F-c, R₁ to R₁₁ may each independently be a hydrogen atom, a deuterium atom, a halogen atom, a cyano group, a substituted or unsubstituted amine group, a substituted or unsubstituted boryl group, a substituted or unsubstituted oxy group, a substituted or unsubstituted thio group, a substituted or unsubstituted alkyl group having 1 to 20 carbon atoms, a substituted or unsubstituted aryl group having 6 to 30 ring-forming carbon atoms, a substituted or unsubstituted heteroaryl group having 2 to 30 ring-forming carbon atoms, or may be bonded to an adjacent group to form a ring.

In Formula F-c, A₁ and A₂ may each independently be bonded to substituents of neighboring rings to form a fused ring. For example, when A₁ and A₂ are each independently N(Rₘ), A₁ may be bonded to R₄ or R₅ to form a ring. For example, A₂ may be bonded to R₇ or R₈ to form a ring.

The emission layer EML may include, as a dopant material of the related art, styryl derivatives (e.g., 1,4-bis[2-(3-N-ethylcarbazoryl)vinyl]benzene (BCzVB), 4-(di-p-tolylamino)-4′-[(di-p-tolylamino)styryl]stilbene (DPAVB), and N-(4-((E)-2-(6-((E)-4-(diphenylamino) styryl)naphthalen-2-yl)vinyl)phenyl)-N-phenylbenzenamine (N-BDAVBi), 4,4′-bis[2-(4-(N,N-diphenylamino)phenyl)vinyl]biphenyl (DPAVBi), perylene and derivatives thereof (e.g., 2,5,8,11-tetra-t-butylperylene (TBP)), pyrene and derivatives thereof (e.g., 1,1-dipyrene, 1,4-dipyrenylbenzene, 1,4-bis(N,N-diphenylamino)pyrene), and the like.

The emission layer EML may further include a phosphorescent dopant material of the related art. For example, a phosphorescent dopant may be a metal complex including iridium (Ir), platinum (Pt), osmium (Os), gold (Au), titanium (Ti), zirconium (Zr), hafnium (Hf), europium (Eu), and terbium (Tb), or thulium (Tm) may be used. For example, iridium(III) bis(4,6-difluorophenylpyridinato-N, C2′)picolinate (FIrpic), bis(2,4-difluorophenylpyridinato)-tetrakis(1-pyrazolyl)borate iridium(III) (Fir6), platinum octaethyl porphyrin (PtOEP), and the like may be used as a phosphorescent dopant. However, embodiments are not limited thereto.

In an embodiment, the emission layer EML may include a quantum dot material. The quantum dot may be selected from a Group II-VI compound, a Group III-VI compound, a Group I-III-VI compound, a Group III-V compound, a Group III-II-V compound, a Group IV-VI compound, a Group IV element, a Group IV compound, or any combination thereof.

The Group II-VI compound may include: a binary compound selected from the group consisting of CdSe, CdTe, CdS, ZnS, ZnSe, ZnTe, ZnO, HgS, HgSe, HgTe, MgSe, MgS, and a mixture thereof; a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a mixture thereof; and a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, HgZnSTe, and any mixture thereof, or any combination thereof.

The Group III-VI compound may include: a binary compound such as In₂S₃ and In₂Se₃; a ternary compound such as InGaS₃ and InGaSe₃; or any combination thereof.

The Group I-III-VI compound may include: a ternary compound selected from the group consisting of AgInS, AgInS₂, CuInS, CuInS₂, AgGaS₂, CuGaS₂ CuGaO₂, AgGaO₂, AgAlO₂, or any mixture thereof; a quaternary compound such as AgInGaS₂ and CuInGaS₂; or any combinations thereof.

The Group III-V compound may include: a binary compound selected from the group consisting of GaN, GaP, GaAs, GaSb, AN, AlP, AlAs, AlSb, InN, InP, InAs, InSb, and any mixture thereof; a ternary compound selected from the group consisting of GaNP, GaNAs, GaNSb, GaPAs, GaPSb, AlNP, AINAs, AlNSb, AlPAs, AlPSb, InGaP, InAlP, InNP, InNAs, InNSb, InPAs, InPSb, and any mixture thereof; and a quaternary compound selected from the group consisting of GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and any mixture thereof; or any combination thereof. The Group III-V compound may further include a Group II metal. For example, InZnP, and the like may be selected as a Group III-II-V compound.

The Group IV-VI compound may include: a binary compound selected from the group consisting of SnS, SnSe, SnTe, PbS, PbSe, PbTe, and any mixture thereof; a ternary compound selected from the group consisting of SnSeS, SnSeTe, SnSTe, PbSeS, PbSeTe, PbSTe, SnPbS, SnPbSe, SnPbTe, and any mixture thereof; a quaternary compound selected from the group consisting of SnPbSSe, SnPbSeTe, SnPbSTe, and any mixture thereof; or any combination thereof. The Group IV element may be Si, Ge, or any mixture thereof. The Group IV compound may include a binary compound selected from the group consisting of SiC, SiGe, and any mixture thereof.

A binary compound, a ternary compound, or a quaternary compound may be present in particles having a uniform concentration distribution, or may be present in the same particles having a partially different concentration distribution. In an embodiment, a quantum dot may have a core/shell structure in which a quantum dot surrounds another quantum dot. A quantum dot having a core/shell structure may have a concentration gradient at an interface between the core and the shell, in which the concentration of a material that is present in the shell decreases towards the core.

In embodiments, a quantum dot may have the core/shell structure including a core having nano-crystals, and a shell surrounding the core, which are described herein. The shell of the quantum dot may serve as a protection layer to prevent the chemical deformation of the core so as to keep semiconductor properties, and/or may serve as a charging layer to impart electrophoresis properties to the quantum dot. The shell may be a single layer or multiple layers. Examples of a shell of a quantum dot may include a metal oxide, a non-metal oxide, a semiconductor compound, or any combination thereof.

Examples of a metal oxide or a non-metal oxide may include: a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, NiO; a ternary compound such as MgAl₂O₄, CoFe₂O₄, NiFe₂O₄, and CoMn₂O₄; or any combination thereof. However, embodiments are not limited thereto.

Examples of a semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, and the like, but embodiments are not limited thereto.

A quantum dot may have a full width of half maximum (FWHM) of a light emitting wavelength spectrum equal to or less than about 45 nm. For example, the quantum dot may have a FWHM of a light emitting wavelength spectrum equal to or less than about 40 nm. For example, the quantum dot may have a FWHM of a light emitting wavelength spectrum equal to or less than about 30. Within these ranges, color purity or color reproducibility may be enhanced in the above ranges. Light emitted through a quantum dot may be emitted in all directions, so that a wide viewing angle may be improved.

The form of a quantum dot is not limited as long as it is a form used in the related art. For example, a quantum dot may have a spherical shape, a pyramidal shape, a multi-arm shape, or a cubic shape, or the quantum dot may be in the form of nanoparticles, nanotubes, nanowires, nanofibers, nanoplatelets, and the like.

A quantum dot may control the colors of emitted light according to a particle size thereof, and thus the quantum dot may have various light emitting colors such as blue, red, green, and the like.

In the light emitting element ED according to an embodiment shown in each of FIGS. 3 to 6, an electron transport region ETR is provided on the emission layer EML. The electron transport region ETR may include at least one of a hole blocking layer HBL, an electron transport layer ETL, and an electron injection layer EIL, but embodiments are not limited thereto.

The electron transport region ETR may be a single layer consisting of a single material, a layer including different materials, or a structure including multiple layers including different materials.

For example, the electron transport region ETR may have a single layer structure of an electron injection layer EIL or an electron transport layer ETL, and may have a single layer structure formed of an electron injection material and an electron transport material. In an embodiment, the electron transport region ETR may have a single layer structure including different materials, or may have a structure in which an electron transport layer ETL/electron injection layer EIL, a hole blocking layer HBL/electron transport layer ETL/electron injection layer EIL, or an electron transport layer ETL/buffer layer (not shown)/electron injection layer EIL are stacked in its respective stated order from an emission layer EML, but embodiments are not limited thereto. The electron transport region ETR may have a thickness in a range of, for example, about 1,000 Å to about 1,500 Å.

The electron transport region ETR may be formed using various methods such as a vacuum deposition method, a spin coating method, a cast method, a Langmuir-Blodgett (LB) method, an inkjet printing method, a laser printing method, and a laser induced thermal imaging (LITI) method.

The electron transport region ETR may include a compound represented by Formula ET-1:

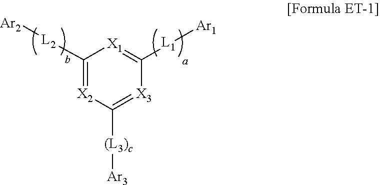

In Formula ET-1, at least one of X₁ to X₃ may each be N and the remainder of X₁ to X₃ may each independently be C(Rₐ). In Formula ET-1, Rₐ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. In Formula ET-1, Ar₁ to Ar₃ may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In Formula ET-1, a to c may each independently be an integer from 0 to 10. In Formula ET-1, L₁ to L₃ may each independently be a direct linkage, a substituted or unsubstituted arylene group having 6 to 30 ring-forming carbon atoms, or a substituted or unsubstituted heteroarylene group having 2 to 30 ring-forming carbon atoms. When a to c are each 2 or greater, L₁ to L₃ may each independently be a substituted or unsubstituted arylene group having 6 to 30 ring-forming carbon atoms, or a substituted or unsubstituted heteroarylene group having 2 to 30 ring-forming carbon atoms.

The electron transport region ETR may include an anthracene-based compound. However, embodiments are not limited thereto, and the electron transport region ETR may include, for example, tris(8-hydroxyquinolinato)aluminum (Alq₃), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzoimidazolyl-1-ylphenyl)-9,10-dinaphthylanthracene, 1,3,5-tri(1-phenyl-1H-benzo[d]imidazol-2-yl)benzene (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,O8)-(1,1′-biphenyl-4-olato)aluminum (BAlq), berylliumbis(benzoquinolin-10-olate (Bebq₂), 9,10-di(naphthalene-2-yl)anthracene (ADN), 1,3-bis[3,5-di(pyridin-3-yl)phenyl]benzene (BmPyPhB), diphenyl(4-(triphenylsilyl)phenyl)phosphine oxide (TSPO1), or any mixture thereof.

In an embodiment, the electron transport region ETR may include at least one compound selected from compounds ET1 to ET36:

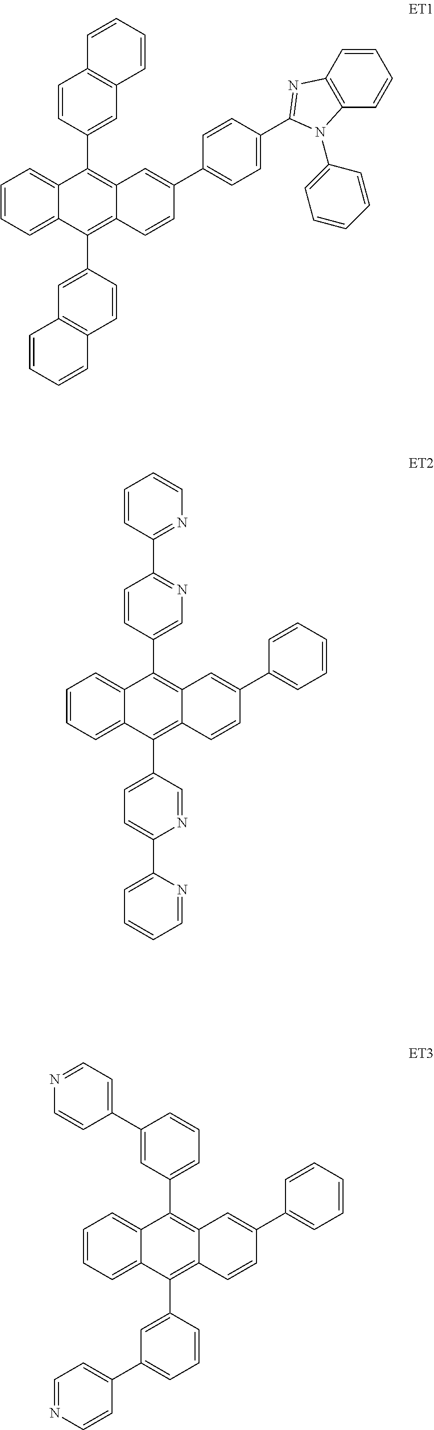 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1]

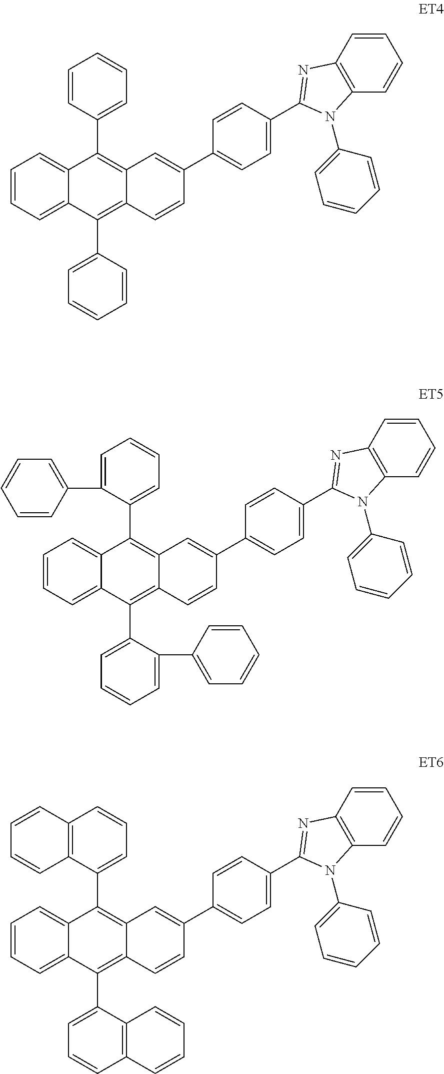 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1]

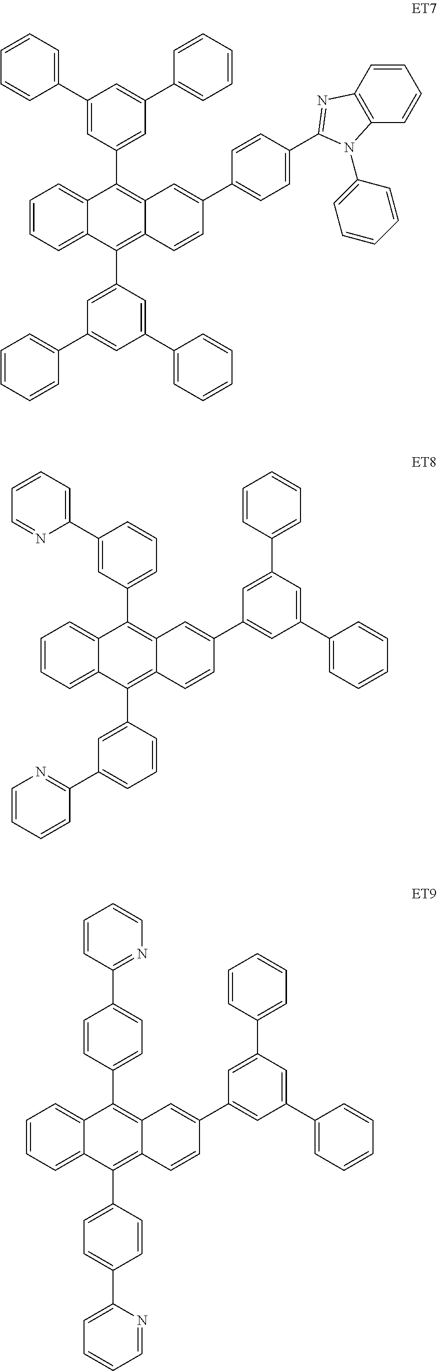 [SMILES: c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1 ; c1ccc(-c2cc(-c3ccccc3)cc(-c3ccc4c(-c5cccc(-c6ccccn6)c5)c5ccccc5c(-c5cccc(-c6ccccn6)c5)c4c3)c2)cc1 ; c1ccc(-c2cc(-c3ccccc3)cc(-c3ccc4c(-c5ccc(-c6ccccn6)cc5)c5ccccc5c(-c5ccc(-c6ccccn6)cc5)c4c3)c2)cc1]

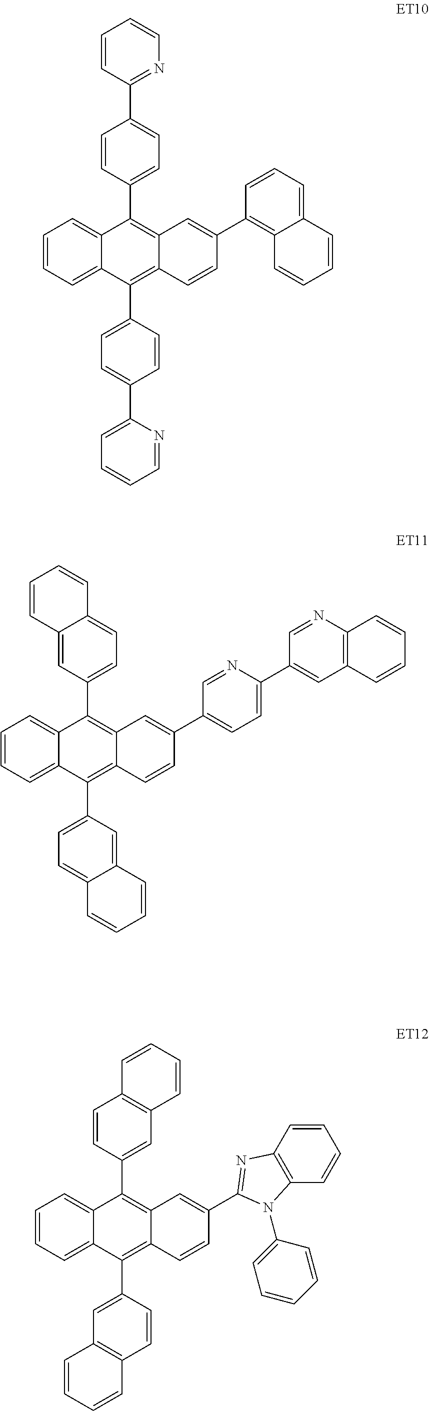 [SMILES: c1ccc(-c2ccc(-c3c4ccccc4c(-c4ccc(-c5ccccn5)cc4)c4cc(-c5cccc6ccccc56)ccc34)cc2)nc1 ; c1ccc2cc(-c3c4ccccc4c(-c4ccc5ccccc5c4)c4cc(-c5ccc(-c6cnc7ccccc7c6)nc5)ccc34)ccc2c1 ; c1ccc(-n2c(-c3ccc4c(-c5ccc6ccccc6c5)c5ccccc5c(-c5ccc6ccccc6c5)c4c3)nc3ccccc32)cc1]

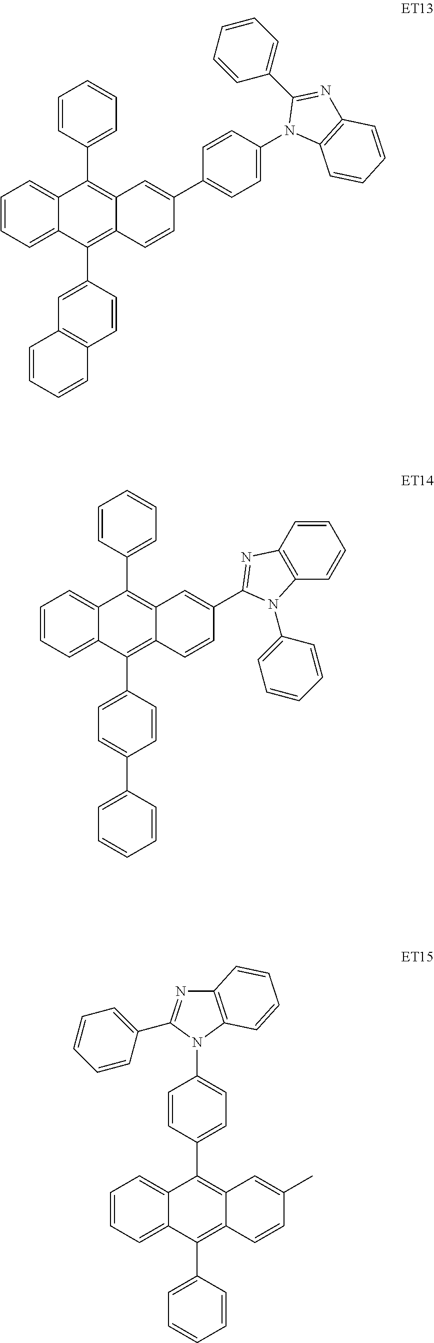 [SMILES: c1ccc(-c2c3ccccc3c(-c3ccc4ccccc4c3)c3ccc(-c4ccc(-n5c(-c6ccccc6)nc6ccccc65)cc4)cc23)cc1 ; c1ccc(-c2ccc(-c3c4ccccc4c(-c4ccccc4)c4cc(-c5nc6ccccc6n5-c5ccccc5)ccc34)cc2)cc1 ; Cc1ccc2c(-c3ccccc3)c3ccccc3c(-c3ccc(-n4c(-c5ccccc5)nc5ccccc54)cc3)c2c1]

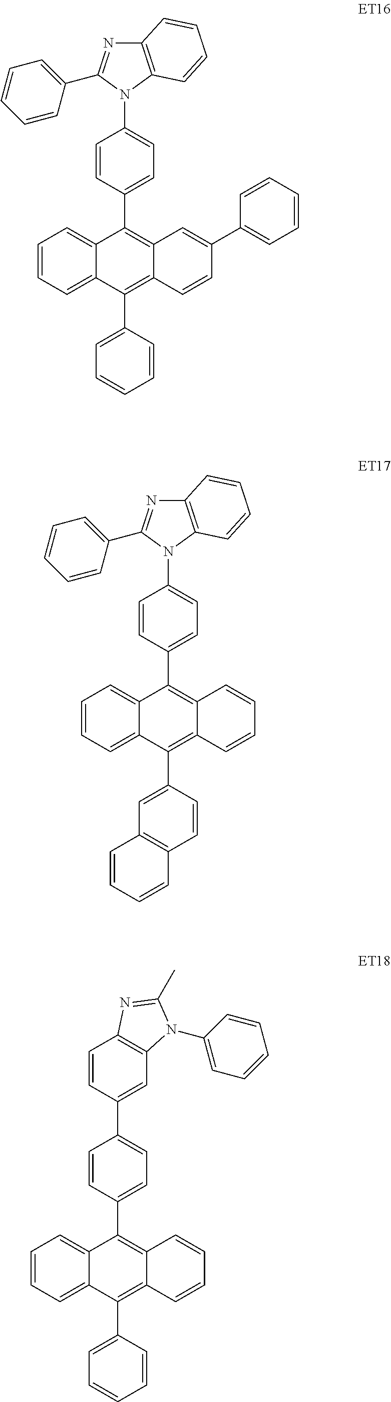 [SMILES: c1ccc(-c2ccc3c(-c4ccccc4)c4ccccc4c(-c4ccc(-n5c(-c6ccccc6)nc6ccccc65)cc4)c3c2)cc1 ; c1ccc(-c2nc3ccccc3n2-c2ccc(-c3c4ccccc4c(-c4ccc5ccccc5c4)c4ccccc34)cc2)cc1 ; Cc1nc2ccc(-c3ccc(-c4c5ccccc5c(-c5ccccc5)c5ccccc45)cc3)cc2n1-c1ccccc1]

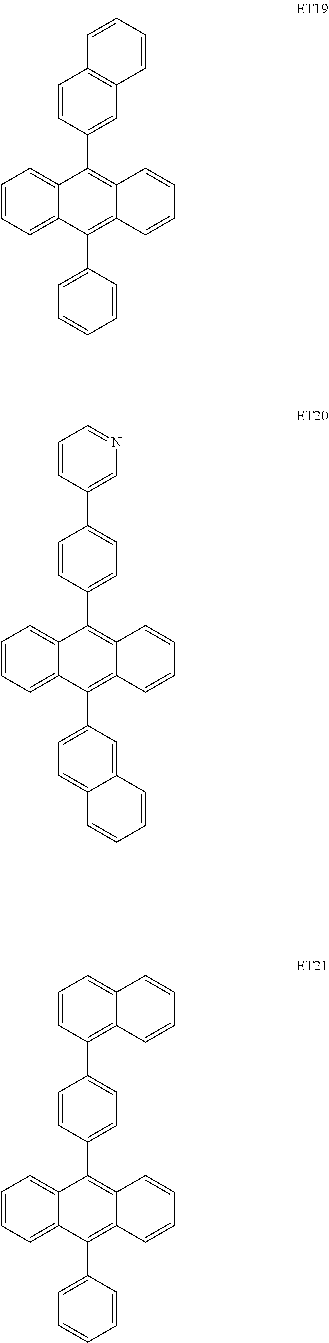

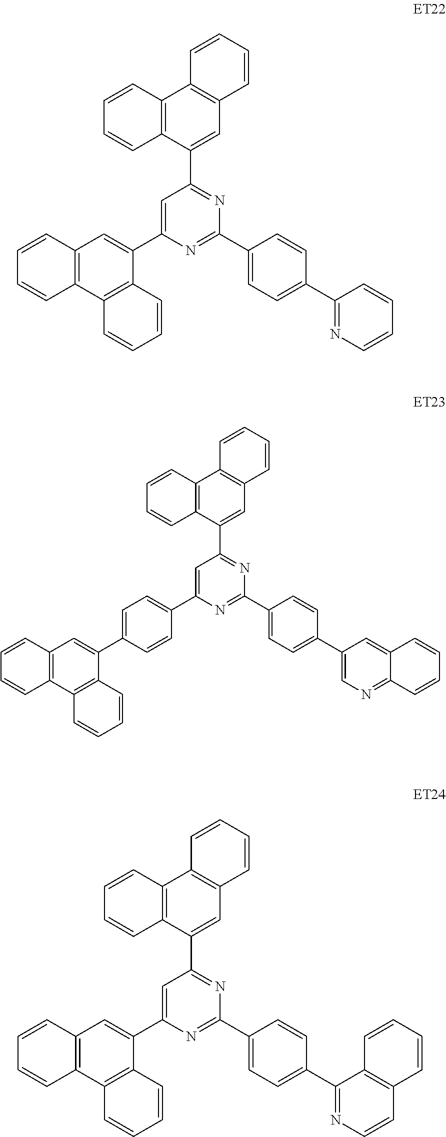 [SMILES: c1ccc(-c2ccc(-c3nc(-c4cc5ccccc5c5ccccc45)cc(-c4cc5ccccc5c5ccccc45)n3)cc2)nc1 ; c1ccc2ncc(-c3ccc(-c4nc(-c5ccc(-c6cc7ccccc7c7ccccc67)cc5)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)nccc2c1]

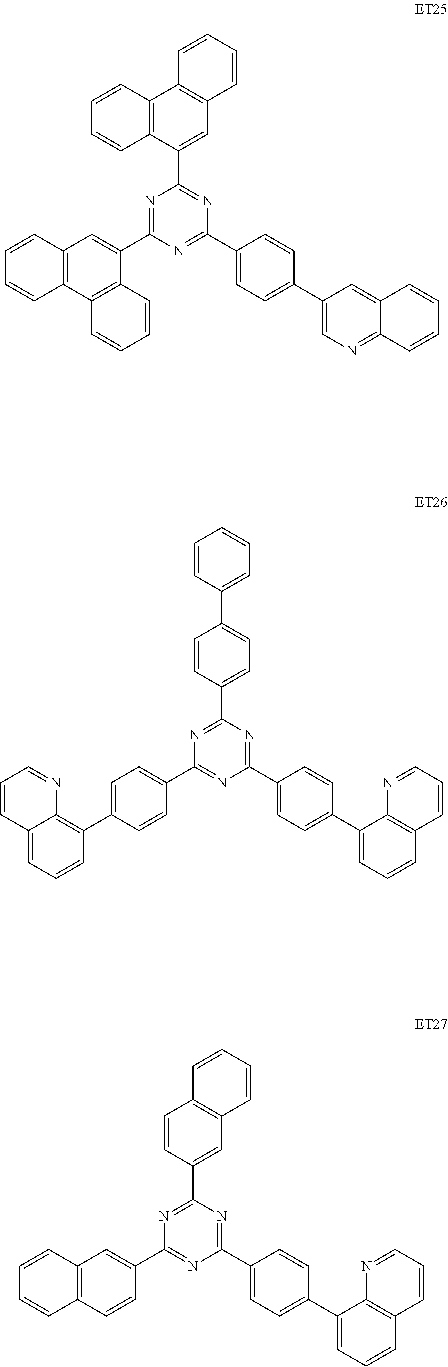 [SMILES: c1ccc2ncc(-c3ccc(-c4nc(-c5cc6ccccc6c6ccccc56)nc(-c5cc6ccccc6c6ccccc56)n4)cc3)cc2c1 ; c1ccc(-c2ccc(-c3nc(-c4ccc(-c5cccc6cccnc56)cc4)nc(-c4ccc(-c5cccc6cccnc56)cc4)n3)cc2)cc1 ; c1ccc2cc(-c3nc(-c4ccc(-c5cccc6cccnc56)cc4)nc(-c4ccc5ccccc5c4)n3)ccc2c1]

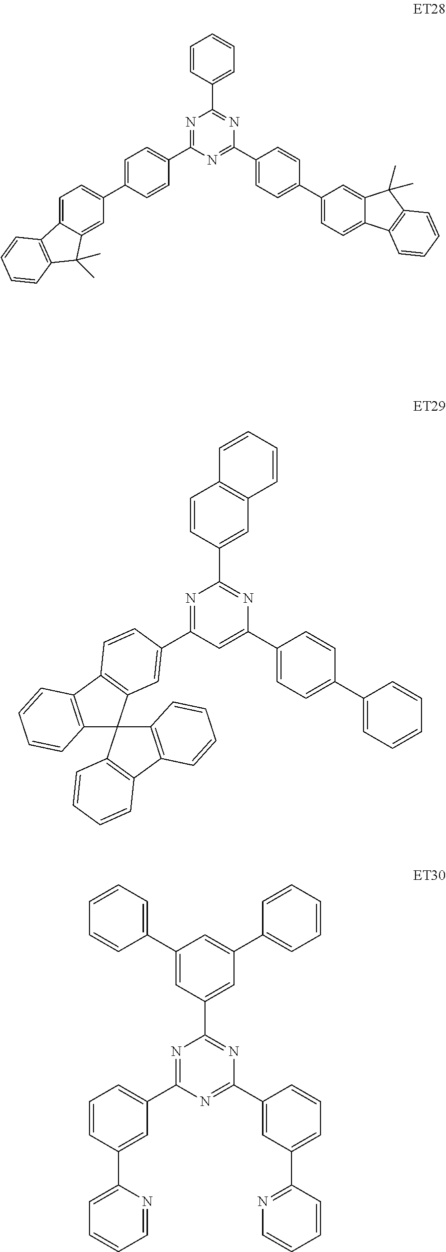 [SMILES: CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21 ; c1ccc(-c2ccc(-c3cc(-c4ccc5c(c4)C4(c6ccccc6-c6ccccc64)c4ccccc4-5)nc(-c4ccc5ccccc5c4)n3)cc2)cc1 ; c1ccc(-c2cc(-c3ccccc3)cc(-c3nc(-c4cccc(-c5ccccn5)c4)nc(-c4cccc(-c5ccccn5)c4)n3)c2)cc1]

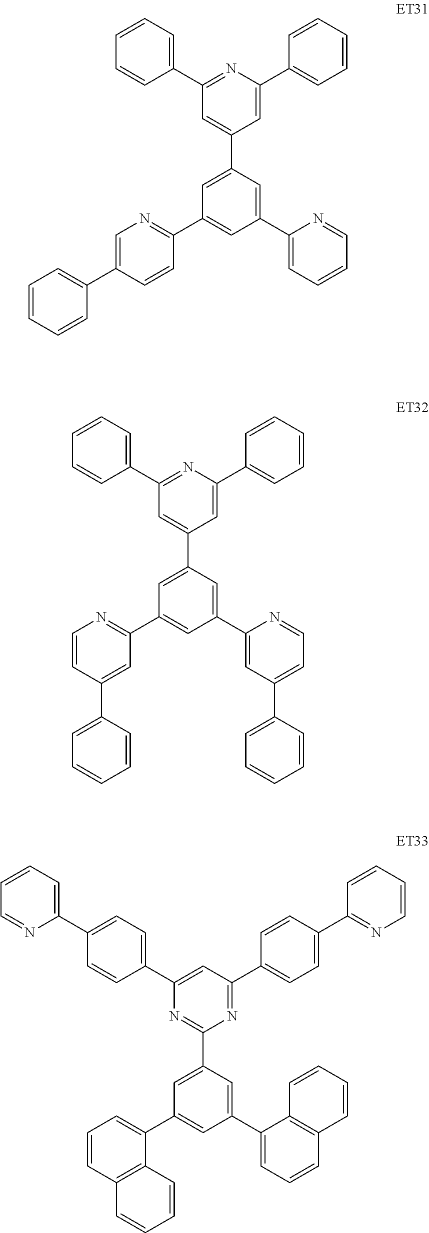 [SMILES: c1ccc(-c2ccc(-c3cc(-c4cc(-c5ccccc5)nc(-c5ccccc5)c4)cc(-c4ccccn4)c3)nc2)cc1 ; c1ccc(-c2ccnc(-c3cc(-c4cc(-c5ccccc5)nc(-c5ccccc5)c4)cc(-c4cc(-c5ccccc5)ccn4)c3)c2)cc1 ; c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1]

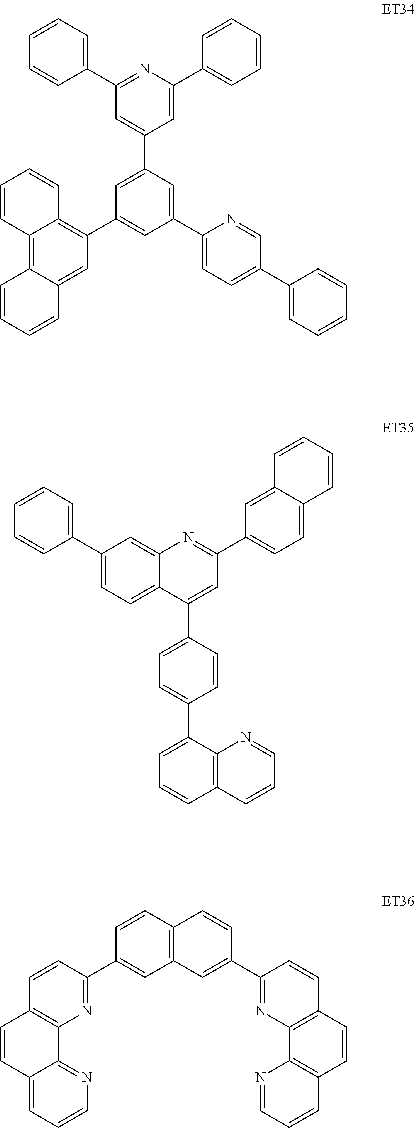 [SMILES: c1ccc(-c2ccc(-c3cc(-c4cc(-c5ccccc5)nc(-c5ccccc5)c4)cc(-c4cc5ccccc5c5ccccc45)c3)nc2)cc1 ; c1ccc(-c2ccc3c(-c4ccc(-c5cccc6cccnc56)cc4)cc(-c4ccc5ccccc5c4)nc3c2)cc1 ; c1cnc2c(c1)ccc1ccc(-c3ccc4ccc(-c5ccc6ccc7cccnc7c6n5)cc4c3)nc12]

In an embodiment, the electron transport region ETR may include: halogenated metals such as LiF, NaCl, CsF, RbCl, RbI, CuI, and KI; lanthanide metals such as Yb; or co-deposited materials of a halogenated metal and a lanthanide metal. For example, the electron transport region ETR may include KI:Yb, RbI:Yb, LiF:Yb, and the like as a co-deposited material. For the electron transport region ETR, a metal oxide such as Li₂O and BaO, or 8-hydroxyl-lithium quinolate (Liq), and the like may be used, but embodiments are not limited thereto. The electron transport region ETR may also be formed of a mixture material of an electron transport material and an insulating organometallic salt. The organometallic salt may be a material having an energy band gap equal to or greater than about 4 eV. For example, the organometallic salt may include metal acetates, metal benzoates, metal acetoacetates, metal acetylacetonates, or metal stearates.

The electron transport region ETR may further include, for example, at least one of 2,9-dimethyl-4,7-diphenyl-1,10-phenanthroline (BCP), diphenyl(4-(triphenylsilyl)phenyl)phosphine oxide (TSPO1), and 4,7-diphenyl-1,10-phenanthroline (Bphen) in addition to the materials described herein, but embodiments are not limited thereto.

The electron transport region ETR may include the compounds of the electron transport region described herein in at least one of the electron injection layer EIL, the electron transport layer ETL, and the hole blocking layer HBL.

When the electron transport region ETR includes an electron transport layer ETL, the electron transport layer ETL may have a thickness in a range of about 100 Å to about 1,000 Å. For example, the thickness of the electron transport layer ETL may have a thickness in a range of about 150 Å to about 500 Å. When the thickness of the electron transport layer ETL satisfies any of the above-described ranges, satisfactory electron transport properties may be obtained without a substantial increase in driving voltage. When the electron transport region ETR includes an electron injection layer EIL, the electron injection layer EIL may have a thickness in a range of about 1 Å to about 100 Å. For example, the electron injection layer EIL may have a thickness in a range of about 3 Å to about 90 Å. When the thickness of the electron injection layer EIL satisfies any of the above-described ranges, satisfactory electron injection properties may be obtained without a substantial increase in driving voltage.

The second electrode EL2 is provided on the electron transport region ETR. The second electrode EL2 may be a common electrode. The second electrode EL2 may be a cathode or an anode but embodiments are not limited thereto. For example, when the first electrode EL1 is an anode, the second electrode EL2 may be a cathode, and when the first electrode EL1 is a cathode, the second electrode EL2 may be an anode. The second electrode may include at least one of Ag, Mg, Cu, Al, Pt, Pd, Au, Ni, Nd, Ir, Cr, Li, Ca, LiF, Mo, Ti, W, In, Sn, Zn, an oxide thereof, a compound thereof, or a mixture thereof.

The second electrode EL2 may be a transmissive electrode, a transflective electrode, or a reflective electrode. When the second electrode EL2 is a transmissive electrode, the second electrode EL2 may be formed of a transparent metal oxide, for example, indium tin oxide (ITO), indium zinc oxide (IZO), zinc oxide (ZnO), indium tin zinc oxide (ITZO), and the like.

When the second electrode EL2 is a transflective electrode or a reflective electrode, the second electrode EL2 may include Ag, Mg, Cu, Al, Pt, Pd, Au, Ni, Nd, Ir, Cr, Li, Ca, LiF/Ca (a stack structure of LiF and Ca), LiF/Al (a stack structure of LiF and Al), Mo, Ti, W, a compound thereof, or a mixture thereof (e.g., AgMg, AgYb, or MgYb). In another embodiment, the second electrode EL2 may have a multilayer structure including a reflective film or a transflective film formed of the above-described metal materials, and a transparent conductive film formed of indium tin oxide (ITO), indium zinc oxide (IZO), zinc oxide (ZnO), indium tin zinc oxide (ITZO), and the like. For example, the second electrode EL2 may include the above-described metal materials, a combination of two or more metal materials selected from the above-described metal materials, or oxides of the above-described metal materials.

Although not shown in the drawings, the second electrode EL2 may be electrically connected to an auxiliary electrode. When the second electrode EL2 is connected to an auxiliary electrode, the resistance of the second electrode EL2 may decrease.

In an embodiment, the light emitting diode may further include a capping layer CPL on the second electrode EL2. The capping layer CPL may be a multilayer or a single layer.

In an embodiment, the capping layer CPL may be an organic layer or an inorganic layer. For example, when the capping layer CPL includes an inorganic material, the inorganic material may include an alkali metal compound such as LiF, an alkaline earth metal compound such as MgF₂, SiON, SiNₓ, SiO_{y}, and the like.

For example, when the capping layer CPL includes an organic material, the organic material may include a-NPD, NPB, TPD, m-MTDATA, Alq₃ CuPc, N4,N4,N4′,N4′-tetra(biphenyl-4-yl) biphenyl-4,4′-diamine (TPD15), 4,4′,4″-tris(carbazol-9-yl)triphenylamine (TCTA), and the like, or may include epoxy resins or acrylates such as methacrylates. However, embodiments are not limited thereto, and the capping layer CPL may include at least one of compounds P1 to P5.

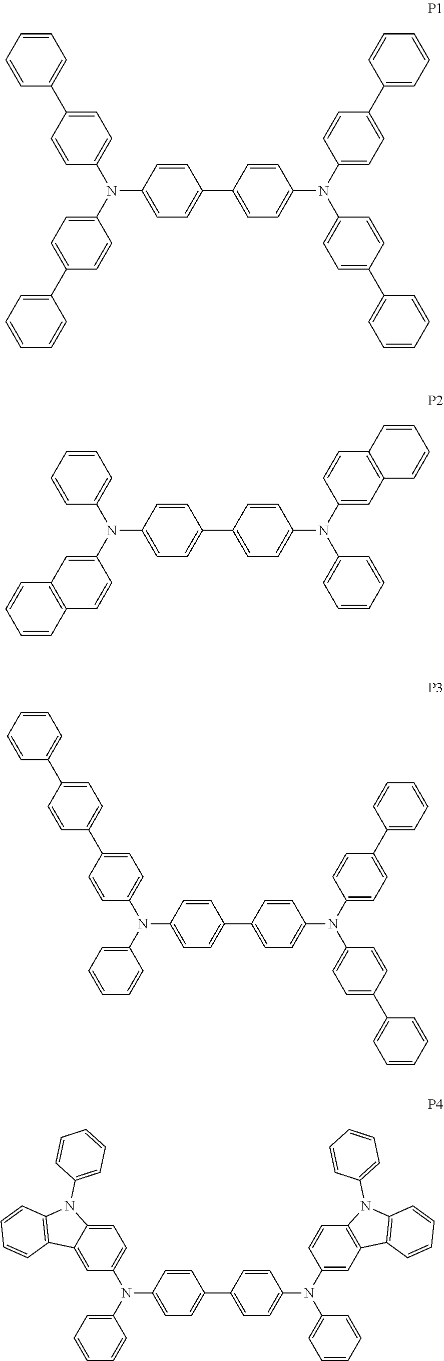 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1 ; c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1]

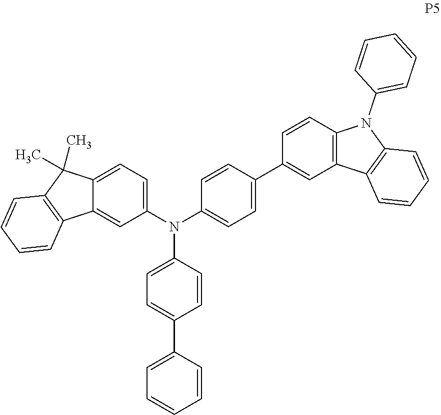 [SMILES: CC1(C)c2ccccc2-c2cc(N(c3ccc(-c4ccccc4)cc3)c3ccc(-c4ccc5c(c4)c4ccccc4n5-c4ccccc4)cc3)ccc21]

A capping layer CPL may have a refractive index equal to or greater than about 1.6. For example, the capping layer CPL may have a refractive index equal to or greater than about 1.6 with respect to light in a wavelength range of about 550 nm to about 660 nm.

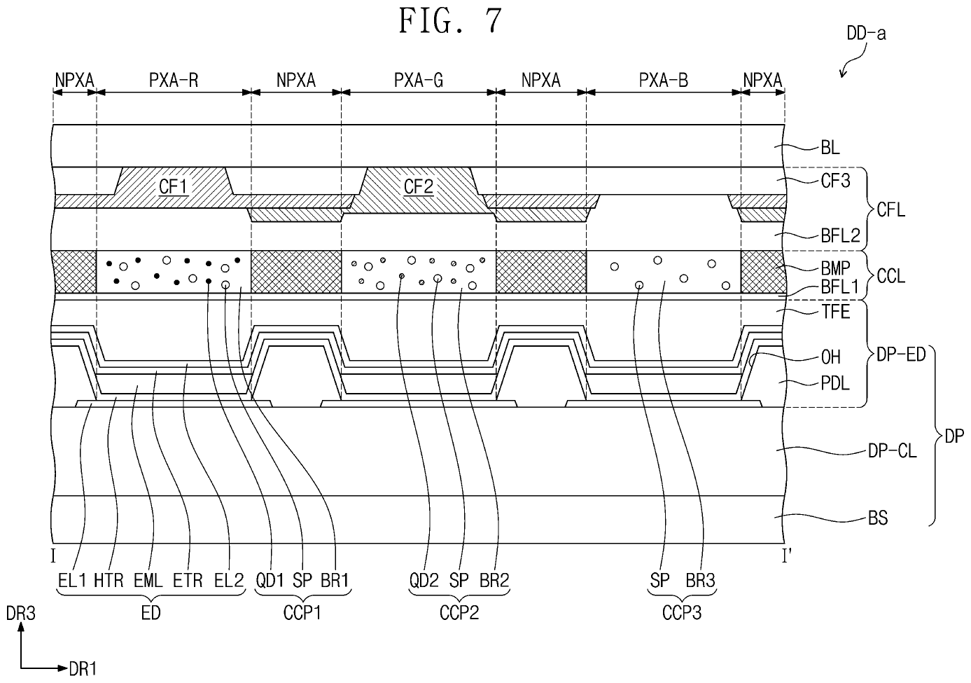

FIGS. 7 to 10 are each a schematic cross-sectional view of a display device according to an embodiment. Hereinafter, in the description of the display device according to an embodiment with reference to FIGS. 7 and 10, features which have been described above with reference to FIGS. 1 to 6 will not be described again, and the differing features will be described.

Referring to FIG. 7, a display device DD-a according to an embodiment may include a display panel DP having a display element layer DP-ED, a light control layer CCL disposed on the display panel DP, and a color filter layer CFL.

In an embodiment shown in FIG. 7, the display panel DP may include a base layer BS, a circuit layer DP-CL provided on the base layer BS, and a display element layer DP-ED, and the element layer DP-ED may include a light emitting element ED.

The light emitting element ED may include a first electrode EL1, a hole transport region HTR disposed on the first electrode EL1, an emission layer EML disposed on the hole transport region HTR, an electron transport region ETR disposed on the emission layer EML, and a second electrode EL2 disposed on the electron transport region ETR. A structure of the light emitting element ED shown in FIG. 7 may be the same as a structure of the light emitting element according to one of FIGS. 3 to 6 as described herein.

In the display device DD-a, the emission layer EML of the light emitting element ED may include the polycyclic compound as described herein.

Referring to FIG. 7, the emission layer EML may be disposed in the openings OH defined in the pixel defining films PDL. For example, the emission layer EML separated by the pixel defining films PDL and provided corresponding to each of the light emitting regions PXA-R, PXA-G, and PXA-B, may each emit light in the same wavelength ranges. In the display device DD-a, the emission layer EML may emit blue light. Although not shown in the drawings, in an embodiment, the emission layer EML may be provided as a common layer throughout the light emitting regions PXA-R, PXA-G, and PXA-B.

The light control layer CCL may be disposed on the display panel DP. The light control layer CCL may include a light converter. The light converter may be quantum dots or phosphors. The light converter may wavelength-convert the provided light and emit the wavelength-converted light. In an embodiment, the light control layer CCL may be a layer containing quantum dots or phosphors.

The light control layer CCL may include light control units CCP1, CCP2, and CCP3. The light control units CCP1, CCP2, and CCP3 may be spaced apart from each other.

Referring to FIG. 7, a division pattern BMP may be disposed between the light control units CCP1, CCP2, and CCP3 spaced apart from each other, but embodiments are not limited thereto. In FIG. 7, it is shown that the division pattern BMP does not overlap the light control units CCP1, CCP2, and CCP3, but edges of the light control units CCP1, CCP2, and CCP3 may overlap at least a portion of the division pattern BMP.

The light control layer CCL may include a first light control unit CCP1 including a first quantum dot QD1 that converts first color light provided from the light emitting element ED into second color light, a second light control unit CCP2 including a second quantum dot QD2 that converts the first color light into third color light, and a third light control unit CCP3 that transmits the first color light.

In an embodiment, the first light control unit CCP1 may provide red light, which may be the second color light, and the second light control unit CCP2 may provide green light, which may be the third color light. The third light control unit CCP3 may transmit and provide blue light, which may be the first color light provided from the light emitting element ED. For example, the first quantum dot QD1 may be a red quantum dot and the second quantum dot QD2 may be a green quantum dot. The quantum dots QD1 and QD2 may each be a quantum dot as described herein.

The light control layer CCL may further include scatterers SP. The first light control unit CCP1 may include the first quantum dot QD1 and the scatterers SP, the second light control unit CCP2 may include the second quantum dot QD2 and the scatterers SP, and the third light control unit CCP3 may not include a quantum dot but may include the scatterers SP.

The scatterers SP may be inorganic particles. For example, the scatterers SP may include at least one of TiO₂, ZnO, Al₂O₃, SiO₂, or hollow silica. The scatterers SP may include any one of TiO₂, ZnO, Al₂O₃, SiO₂, or hollow silica, or the scatters SP may be a mixture of two or more materials selected from TiO₂, ZnO, Al₂O₃, SiO₂, and hollow silica.

The first light control unit CCP1, the second light control unit CCP2, and the third light control unit CCP3 may each include base resins BR1, BR2, and BR3 in which the quantum dots QD1 and QD2 and the scatterers SP are dispersed. In an embodiment, the first light control unit CCP1 may include the first quantum dot QD1 and the scatterers SP dispersed in the first base resin BR1, the second light control unit CCP2 may include the second quantum dot QD2 and the scatterers SP dispersed in the second base resin BR2, and the third light control unit CCP3 may include the scatterers SP dispersed in the third base resin BR3.

The base resins BR1, BR2, and BR3 may each be a medium in which the quantum dots QD1 and QD2 and the scatterers SP are dispersed, and may be formed of various resin compositions, which may be generally referred to as a binder. For example, the base resins BR1, BR2, and BR3 may be an acrylic resin, a urethane-based resin, a silicone-based resin, an epoxy-based resin, and the like. The base resins BR1, BR2, and BR3 may each be a transparent resin. In an embodiment, the first base resin BR1, the second base resin BR2, and the third base resin BR3 may each be the same as or different from each other.

The light control layer CCL may include a barrier layer BFL1. The barrier layer BFL1 may serve to prevent moisture and/or oxygen (hereinafter referred to as “moisture/oxygen”) from being introduced. The barrier layer BFL1 may be disposed on the light control units CCP1, CCP2, and CCP3 to prevent the light control units CCP1, CCP2, and CCP3 from being exposed to moisture/oxygen. The barrier layer BFL1 may cover the light control units CCP1, CCP2, and CCP3. A barrier layer BFL2 may be provided between the light control units CCP1, CCP2, and CCP3 and the filters CF1, CF2, and CF3.

The barrier layers BFL1 and BFL2 may include at least one inorganic layer. For example, the barrier layers BFL1 and BFL2 may each independently include an inorganic material. For example, the barrier layers BFL1 and BFL2 may each independently include silicon nitride, aluminum nitride, zirconium nitride, titanium nitride, hafnium nitride, tantalum nitride, silicon oxide, aluminum oxide, titanium oxide, tin oxide, cerium oxide, silicon oxynitride, or a metal thin film in which light transmittance is secured, and the like. The barrier layers BFL1 and BFL2 may further include an organic film. The barrier layers BFL1 and BFL2 may each independently formed of a single layer or multiple layers.

In the display device DD-a, the color filter layer CFL may be disposed on the light control layer CCL. In an embodiment, the color filter layer CFL may be disposed (e.g., directly disposed) on the light control layer CCL. For example, the barrier layer BFL2 may be omitted.

The color filter layer CFL may include filters CF1, CF2, and CF3. For example, the color filter layer CFL may include a first filter CF1 transmitting second color light, a second filter CF2 transmitting third color light, and a third filter CF3 transmitting first color light. For example, the first filter CF1 may be a red filter, the second filter CF2 may be a green filter, and the third filter CF3 may be a blue filter. The filters CF1, CF2, and CF3 may each include a polymer photosensitive resin, and a pigment or a dye. The first filter CF1 may include a red pigment or a red dye, the second filter CF2 may include a green pigment or a green dye, and the third filter CF3 may include a blue pigment or a blue dye. However, embodiments are not limited thereto, and the third filter CF3 may not include a pigment or a dye. The third filter CF3 may include a polymer photosensitive resin, but may not include a pigment or a dye. The third filter CF3 may be transparent. The third filter CF3 may be formed of a transparent photosensitive resin.

In an embodiment, the first filter CF1 and the second filter CF2 may each be yellow filters. The first filter CF1 and the second filter CF2 may not be separated and may be provided as a single body. The first to third filters CF1, CF2, and CF3 may be disposed to respectively correspond to the red light emitting region PXA-R, the green light emitting region PXA-G, and the blue light emitting region PXA-B.

Although not shown in the drawings, the color filter layer CFL may include a light blocking unit (not shown). The color filter layer CFL may include the light blocking unit (not shown) disposed to overlap the boundaries of the neighboring filters CF1, CF2, and CF3. The light blocking unit (not shown) may be a black matrix. The light blocking unit (not shown) may be formed including an organic light blocking material or an inorganic light blocking material, both including a black pigment or a black dye. The light blocking unit (not shown) may separate boundaries between the adjacent filters CF1, CF2, and CF3. In an embodiment, the light blocking unit (not shown) may be formed of a blue filter.

A base substrate BL may be disposed on the color filter layer CFL. The base substrate BL may provide a base surface on which the color filter layer CFL and the light control layer CCL are disposed. The base substrate BL may be a glass substrate, a metal substrate, a plastic substrate, and the like. However, embodiments are not limited thereto, and the base substrate BL may be an inorganic layer, an organic layer, or a composite material layer. Although not shown in the drawings, in an embodiment, the base substrate BL may be omitted.

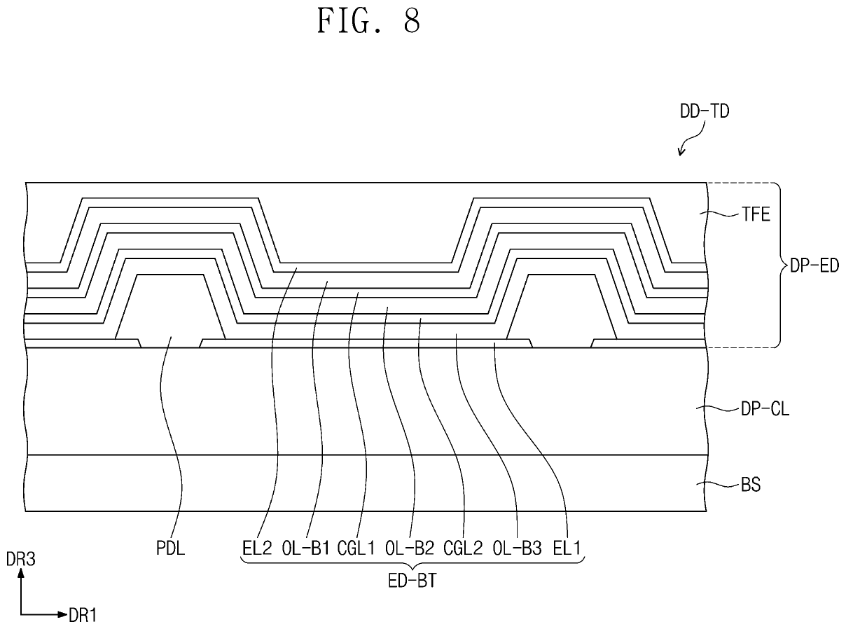

FIG. 8 is a schematic cross-sectional view showing a portion of a display device according to an embodiment that corresponds to a portion of the display panel DP of FIG. 7. In a display device DD-TD according to an embodiment, a light emitting element ED-BT may include multiple light emitting structures OL-B1, OL-B2, and OL-B3. The light emitting element ED-BT may include the first electrode EL1 and the second electrode EL2 facing each other, and the light emitting structures OL-B1, OL-B2, and OL-B3 may be stacked in a thickness direction between the first electrode EL1 and the second electrode EL2. At least one of the light emitting structures OL-B1, OL-B2, and OL-B3 may include the polycyclic compound according to an embodiment. The light emitting structures OL-B1, OL-B2, and OL-B3 each may include the emission layer EML (FIG. 7), a hole transport region HTR and an electron transport region ETR disposed with the emission layer EML (FIG. 7) therebetween.

In an embodiment, the light emitting element ED-BT included in the display device DD-TD may be a light emitting element having a tandem structure and including multiple emission layers.

In an embodiment shown in FIG. 8, light emitted from each of the light emitting structures OL-B1, OL-B2, and OL-B3 may all be blue light. However, embodiments are not limited thereto, and wavelength ranges of the light emitted from each of the light emitting structures OL-B1, OL-B2, and OL-B3 may be different from each other. For example, the light emitting element ED-BT which includes the light emitting structures OL-B1, OL-B2, and OL-B3 that emit light having different wavelength ranges from each other, may emit white light.

Charge generation layers CGL1 and CGL2 may each be disposed between neighboring light emitting structures OL-B1, OL-B2, and OL-B3. The charge generation layers CGL1 and CGL2 may each independently include a p-type charge generation layer and/or an n-type charge generation layer.

At least one of the light emitting structures OL-B1, OL-B2, and OL-B3 included in the display device DD-TD according to an embodiment may include the polycyclic compound. For example, at least one of the emission layers included in the light emitting element ED-BT may each independently include a polycyclic compound.

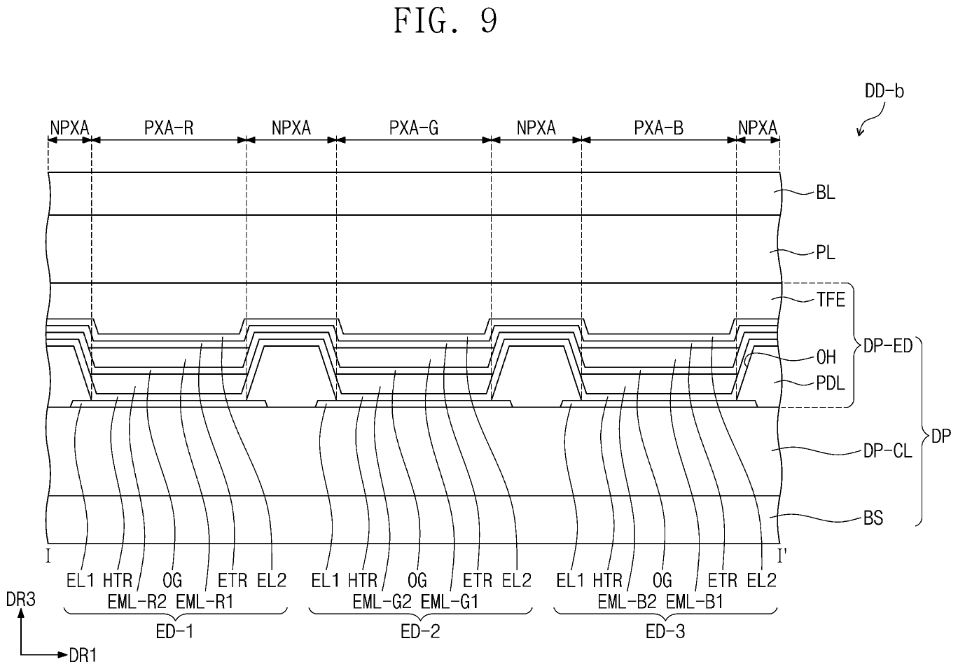

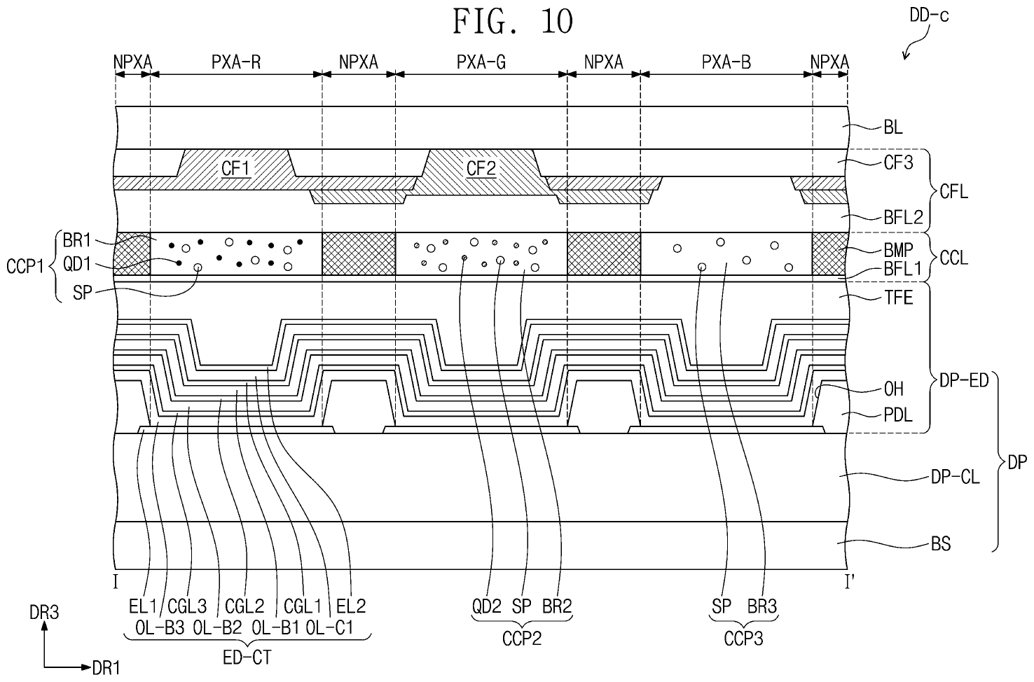

Referring to FIG. 9, a display device DD-b according to an embodiment may include light emitting elements ED-1, ED-2, and ED-3 in which two emission layers are stacked. In comparison the display device DD shown in FIG. 2, the embodiment shown in FIG. 9 is different at least in that the first to third light emitting elements ED-1, ED-2, and ED-3 each include two emission layers that are stacked in a thickness direction. In each of the first to third light emitting elements ED-1, ED-2, and ED-3, the two emission layers may emit light in a same wavelength range.

The first light emitting element ED-1 may include a first red emission layer EML-R1 and a second red emission layer EML-R2. The second light emitting element ED-2 may include a first green emission layer EML-G1 and a second green emission layer EML-G2. The third light emitting element ED-3 may include a first blue emission layer EML-B1 and a second blue emission layer EML-B2. A light emitting auxiliary portion OG may be disposed between the first red emission layer EML-R1 and the second red emission layer EML-R2, between the first green emission layer EML-G1 and the second green emission layer EML-G2, and between the first blue emission layer EML-B1 and the second blue emission layer EML-B2.

The light emitting auxiliary portion OG may include a single layer or multiple layers. The light emitting auxiliary portion OG may include a charge generation layer. For example, the light emitting auxiliary portion OG may include an electron transport region, a charge generation layer, and a hole transport region that are sequentially stacked. The light emitting auxiliary portion OG may be provided as a common layer throughout the first to third light emitting elements ED-1, ED-2, and ED-3. However, embodiments are not limited thereto, and the light emitting auxiliary portion OG may be provided to be patterned inside the openings OH defined in the pixel defining films PDL.

The first red emission layer EML-R1, the first green emission layer EML-G1, and the first blue emission layer EML-B1 may each be disposed between the emission auxiliary portion OG and the electron transport region ETR. The second red emission layer EML-R2, the second green emission layer EML-G2, and the second blue emission layer EML-B2 may be disposed between the emission auxiliary portion OG and the hole transport region HTR.

In an embodiment, the light emitting element ED-1 may include the first electrode EL1, the hole transport region HTR, the second red emission layer EML-R2, the emission auxiliary portion OG, the first red emission layer EML-R1, the electron transport region ETR, and the second electrode EL2, which are stacked in that order. The second light emitting element ED-2 may include the first electrode EL1, the hole transport region HTR, the second green emission layer EML-G2, the emission auxiliary portion OG, the first green emission layer EML-G1, the electron transport region ETR, and the second electrode EL2, which are stacked in that order. The third light emitting element ED-3 may include the first electrode EL1, the hole transport region HTR, the second blue emission layer EML-B2, the emission auxiliary portion OG, the first blue emission layer EML-B1, the electron transport region ETR, and the second electrode EL2, which are stacked in that order.

An optical auxiliary layer PL may be disposed on the display element layer DP-ED. The optical auxiliary layer PL may include a polarizing layer. The optical auxiliary layer PL may be disposed on the display panel DP to control light reflected in the display panel DP due to an external light. Although not shown in the drawings, in an embodiment, the optical auxiliary layer PL may be omitted in the display device DD-b.

At least one emission layer included in a display device DD-b according to an embodiment shown in FIG. 9 may include the polycyclic compound as described herein. For example, at least one of the first blue emission layer EML-B1 or the second blue emission layer EML-B2 may include the polycyclic compound.

In contrast to FIGS. 8 and 9, FIG. 10 shows a display device DD-c that is different at least in that it includes four light emitting structures OL-B1, OL-B2, OL-B3, and OL-C1. The light emitting element ED-BT may include the first electrode EL1 and the second electrode EL2 facing each other, and the first to fourth light emitting structures OL-B1, OL-B2, OL-B3, and OL-C1 that are stacked in a thickness direction between the first electrode EL1 and the second electrode EL2. Charge generation layers CGL1, CGL2, and CGL3 may be disposed between the first to fourth light emitting structures OL-B1, OL-B2, OL-B3, and OL-C1. Among the four light emitting structures, the first to third light emitting structures OL-B1, OL-B2, and OL-B3 may each emit blue light, and the fourth light emitting structure OL-C1 may emit green light. However, embodiments are not limited thereto, and the first to fourth light emitting structures OL-B1, OL-B2, OL-B3, and OL-C1 may emit light having different wavelength ranges from each other.

The charge generation layers CGL1, CGL2, and CGL3 which are disposed between the neighboring light emitting structures OL-B1, OL-B2, OL-B3, and OL-C1 may each independently include a p-type charge generation layer and/or an n-type charge generation layer.

In the display device DD-c, at least one of the light emitting structures OL-B1, OL-B2, OL-B3, and OL-C1 may each independently include the polycyclic compound as described herein. For example, in an embodiment, at least one of the first to third light emitting structures OL-B1, OL-B2, and OL-B3 may include a polycyclic compound.

The light emitting element ED according to an embodiment may include the polycyclic compound according to an embodiment in at least one functional layer disposed between the first electrode EL1 and the second electrode EL2, and may thus exhibit excellent luminous efficiency and improved lifespan characteristics. For example, the EML of the light emitting element ED may include the polycyclic compound, and the light emitting element ED according to an embodiment may exhibit a long lifespan.

Hereinafter, a polycyclic compound and a light emitting element according to an embodiment will be described with reference to the Examples and the Comparative Examples. The Examples shown below are only provided as illustrations for understanding the disclosure, and the scope thereof is not limited thereto.

### EXAMPLES

### 1. Synthesis of Polycyclic Compounds

A process of synthesizing polycyclic compounds according to an embodiment will be described in detail by presenting a process of synthesizing Compounds 1, 2, 23, 24, 44, 73, and 77 as an example. A process of synthesizing polycyclic compounds, which will be described hereinafter, is provided as an example, and thus a process of synthesizing polycyclic compounds is not limited to the Examples below.

### (1) Synthesis of Compounds 1, 2, 23, 24, and 44

Compounds 1, 2, 23, 24, and 44 according to an embodiment may be synthesized using intermediate compounds synthesized by, for example, Intermediate Reaction Formula.

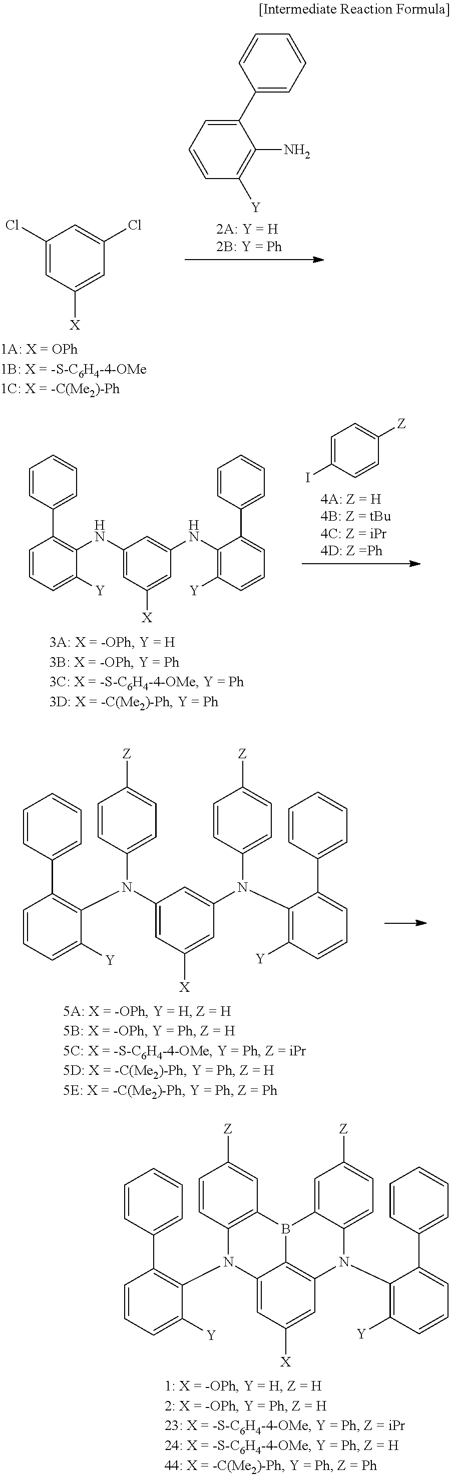

Intermediate 1A was synthesized with reference to a method described in Reference 1 (Tetrahedron Letters (2014), 55(30), 4185-4188). Intermediate 1B was synthesized with reference to a method described in Reference 2 (Chem. Commun., 2012, 48, 8440-8442). Intermediate 1C was synthesized with reference to a method described in Reference 3 (Mendeleev Communications (1998), (5), 195-196). For Intermediate 2A and Intermediate 2B, commercially available reagents were used as they were.

### 1) Synthesis of Intermediate 3A to Intermediate 3D

Intermediate 3A was synthesized in the following procedure. In an argon (Ar) atmosphere, Intermediate 1A (47.8 g), Intermediate 2A (81.1 g), bis(dibenzylideneacetone)palladium(0) (Pd(dba)₂, 2.12 g), 2-dicyclohexylphosphino-2′,6′-dimethoxybiphenyl (SPhos, 1.56 g), and sodium tert-butoxide (NaOtBu, 33.7 g) were added to a three-neck flask (2000 mL), and the mixture was dissolved in toluene (1000 ml) and heated to reflux for 2 hours. After returning to room temperature, water was added thereto to extract a product using CH₂Cl₂ and an organic layer was dried using MgSO₄, and a solvent was distilled off under reduced pressure. The obtained crude product was purified through silica gel column chromatography to obtain Intermediate 3A (88.9 g, yield: 88%). The mass number of Intermediate 3A as determined through Fast atom bombardment mass spectrometry (FAB-MS) was 504.

Intermediate 3B (111.5 g, yield: 85%) was obtained in the same manner as in the synthesis of Intermediate 3A, using Intermediate 2B (117.6 g) instead of Intermediate 2A. The mass number of Intermediate 3B as determined through FAB-MS was 656.

Intermediate 3C (113.9 g, yield: 81%) was obtained in the same manner as in the synthesis of Intermediate 3A, using Intermediate 1B (57.0 g) and Intermediate 2B (110.2 g) instead of Intermediate 1A and Intermediate 2A. The mass number of Intermediate 3C as determined through FAB-MS was 702.

Intermediate 3D (126.9 g, yield: 89%) was obtained in the same manner as in the synthesis of Intermediate 3A, using Intermediate 1C (53.0 g) and Intermediate 2B (110.2 g) instead of Intermediate 1A and Intermediate 2A. The mass number of Intermediate 3D as determined through FAB-MS was 712.

### 2) Synthesis of Intermediate 5A to Intermediate 5E

Intermediate 5A was synthesized in the following procedure. In an argon (Ar) atmosphere, Intermediate 3A (88.9 g), iodobenzene Intermediate 4A (204.3 g), CuI (76.1 g), Cs₂CO₃ (261 g), and 1,10-phenanthroline (16 g) were added to a three-neck flask (1000 mL), and heated and stirred at 190° C. for 96 hours. After returning to room temperature, water was added thereto to extract a product using CH₂Cl₂ and an organic layer was dried using MgSO₄, and a solvent was distilled off under reduced pressure. The resulting product was purified through silica gel column chromatography to obtain Intermediate 5A (97.4 g, yield: 72%). The mass number of Intermediate 5A as determined through FAB-MS was 656.

Intermediate 5B (96.3 g, yield: 70%) was obtained in the same manner as in the synthesis of Intermediate 5A, using Intermediate 3B (117.6 g) instead of Intermediate 3A. The mass number of Intermediate 5B as determined through FAB-MS was 808.

Intermediate 5C (49.4 g, yield: 65%) was obtained in the same manner as in the synthesis of Intermediate 5A, using Intermediate 3C (57.0 g) and Intermediate 4C (120.1 g) instead of Intermediate 3A and Intermediate 4A. The mass number of Intermediate 5C as determined through FAB-MS was 938.

Intermediate 5D (43.6 g, yield: 63%) was obtained in the same manner as in the synthesis of Intermediate 5A, using Intermediate 3C (57.0 g) and Intermediate 4A (110.2 g) instead of Intermediate 4A. The mass number of Intermediate 5D as determined through FAB-MS was 854.

Intermediate 5E (66.7 g, yield: 38%) was obtained in the same manner as in the synthesis of Intermediate 5A, with Intermediate 3D (126.9 g) and Intermediate 4D (281.6 g) instead of Intermediate 3A and Intermediate 4A being subjected to a reaction at 220° C. The mass number of Intermediate 5E as determined through FAB-MS was 986.

### 3) Synthesis of Compound 1

In an argon (Ar) atmosphere, Intermediate 5A (101.7 g) was added to a three-neck flask (1000 mL), dissolved in o-dichlorobenzene (ODCB, 200 mL), and cooled to 0° C. using ice water, and boron triiodide (BI₃, 148.8 g) was added thereto, and the mixture was heated and stirred at 180° C. for 18 hours and cooled to 0° C. using ice water, and triethylamine (100 mL) was added thereto. After returning to room temperature, the reaction solution was filtered using silica gel, and the filtration solvent was distilled off under reduced pressure. The obtained crude product was purified through silica gel column chromatography, preparative HPLC (eluent: CHCI₃), and recrystallization of toluene to obtain Compound 1 (14.4 g yield: 14%). A molecular weight of Compound 1 as determined through FAB-MS was 664.

### 4) Synthesis of Compound 2

Compound 2 (10.7 g, yield: 11%) was obtained in the same manner as in the synthesis of Compound 1, using Intermediate 5B (96.3 g) instead of Intermediate 5A. A molecular weight of Compound 2 as determined through FAB-MS was 816.

### 5) Synthesis of Compound 23

Compound 23 (7.9 g, yield: 16%) was obtained in the same manner as in the synthesis of Compound 1, using Intermediate 5C (49.4 g) instead of Intermediate 5A. A molecular weight of Compound 23 as determined through FAB-MS was 946.

### 6) Synthesis of Compound 24

Compound 24 (3.9 g, yield: 9%) was obtained in the same manner as in the synthesis of Compound 1, using Intermediate 5D (43.6 g) instead of Intermediate 5A. A molecular weight of Compound 24 as determined through FAB-MS was 862.

### 7) Synthesis of Compound 44

Compound 44 (2.7 g, yield: 4%) was obtained in the same manner as in the synthesis of Compound 1, using Intermediate 5E (66.7 g) instead of Intermediate 5A. A molecular weight of Compound 44 as determined through FAB-MS was 994.

### (2) Synthesis of Compound 73

Compound 73 according to an embodiment may be synthesized by, for example, Reaction Formula 1.

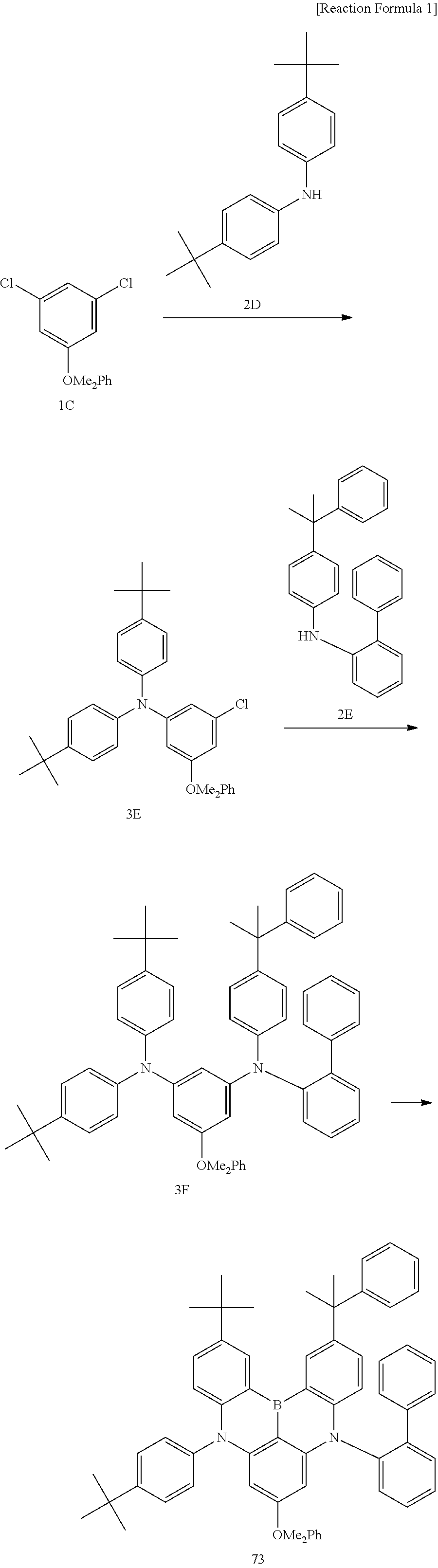

### 1) Synthesis of Intermediate 2E

Intermediate 2E was synthesized in the following procedure. In an argon (Ar) atmosphere, 4-(1-methyl-1-phenylethyl)benzenamine (H₂N—C₆H₄-4-CMe₂Ph, 42.2 g), 2-bromobiphenyl (C₆H₄-1-Ph-2-Br, 46.6 g), Pd(dba)₂ (2.12 g), SPhos (1.56 g), and NaOtBu (16.7 g) were added to a three-neck flask (2000 mL), and the mixture was dissolved in toluene (1000 ml) and heated to reflux for 1 hour. After returning to room temperature, water was added thereto to extract a product using CH₂Cl₂ and an organic layer was dried using MgSO₄, and a solvent was distilled off under reduced pressure. The obtained crude product was purified through silica gel column chromatography to obtain Intermediate 2E (60.4 g, yield: 83%). The mass number of Intermediate 2E as determined through FAB-MS was 363.

### 2) Synthesis of Intermediate 3E

Intermediate 3E was synthesized in the following procedure. In an argon (Ar) atmosphere, Intermediate 1C (53.0 g), Intermediate 2A (56.2 g), Pd(dba) 2 (2.12 g), SPhos (1.56 g), and NaOtBu (16.7 g) were added to a three-neck flask (2000 mL), and the mixture was dissolved in toluene (1000 ml) and heated to reflux for 2 hours. After returning to room temperature, water was added thereto to extract a product using CH₂Cl₂ and an organic layer was dried using MgSO₄, and a solvent was distilled off under reduced pressure. The obtained crude product was purified through silica gel column chromatography to obtain Intermediate 3E (81.6 g, yield: 83%). The mass number of Intermediate 3E as determined through FAB-MS was 509.

### 3) Synthesis of Intermediate 3F

Intermediate 3F was synthesized in the following procedure. In an argon (Ar) atmosphere, Intermediate 3E (81.6 g), Intermediate 2E (59.2 g), Pd(dba) 2 (1.70 g), SPhos (1.25 g), and NaOtBu (14.6 g) were added to a three-neck flask (2000 mL), and the mixture was dissolved in toluene (900 ml) and heated to reflux for 3 hours. After returning to room temperature, water was added thereto to extract a product using CH₂Cl₂ and an organic layer was dried using MgSO₄, and a solvent was distilled off under reduced pressure. The obtained crude product was purified through silica gel column chromatography to obtain Intermediate 3F (101.8 g, yield: 76%). The mass number of Intermediate 3F as determined through FAB-MS was 837.

### 4) Synthesis of Compound 73

Compound 73 (4.1 g, yield: 5%) was obtained in the same manner as in the synthesis of Compound 1, using Intermediate 3F (83.7 g) instead of Intermediate 5A. A molecular weight of Compound 73 as determined through FAB-MS was 844.

### (3) Synthesis of Compound 77

Compound 77 according to an embodiment may be synthesized by, for example, Reaction Formula 2.

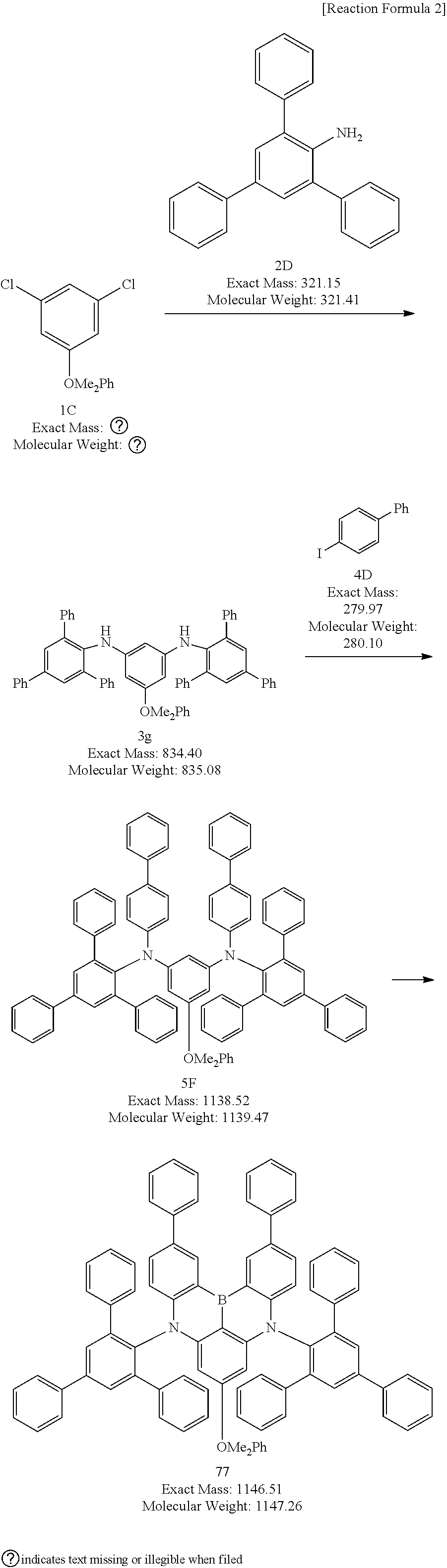

### 1) Synthesis of Intermediate 3G

Intermediate 3G (135.3 g, yield: 81%) was obtained in the same manner as in the synthesis of Intermediate 3A, using Intermediate 1C (53.0 g) and Intermediate 2B (130.2 g) instead of Intermediate 1A and Intermediate 2A. The mass number of Intermediate 3G as determined through FAB-MS was 834.

### 2) Synthesis of Intermediate 5F

Intermediate 5F (75.7 g, yield: 41%) was obtained in the same manner as in the synthesis of Intermediate 5A, with Intermediate 3G (135.3 g) and Intermediate 4D (291.5 g) instead of Intermediate 3A and Intermediate 4A being subjected to a reaction at 220° C. The mass number of Intermediate 5F as determined through FAB-MS was 1139.

### 3) Synthesis of Compound 77

Compound 77 (3.7 g, yield: 5%) was obtained in the same manner as in the synthesis of Compound 1, using Intermediate 5F (75.7 g) instead of Intermediate 5A. A molecular weight of Compound 77 as determined through FAB-MS was 1147.

### 2. Preparation and Evaluation of Light Emitting Elements

Light emitting elements including polycyclic compounds according to an embodiment or Comparative Example compounds were prepared through a method described below. Light emitting elements of Examples 1 to Example 7 were prepared using Compounds 1, 2, 23, 24, 44, 73, and 77, which are polycyclic compounds according to an embodiment as dopant materials of emission layers. Light emitting elements of Comparative Examples 1 to 10 were each prepared using Comparative Example Compounds X-1 to X-10 as dopant materials of emission layers.

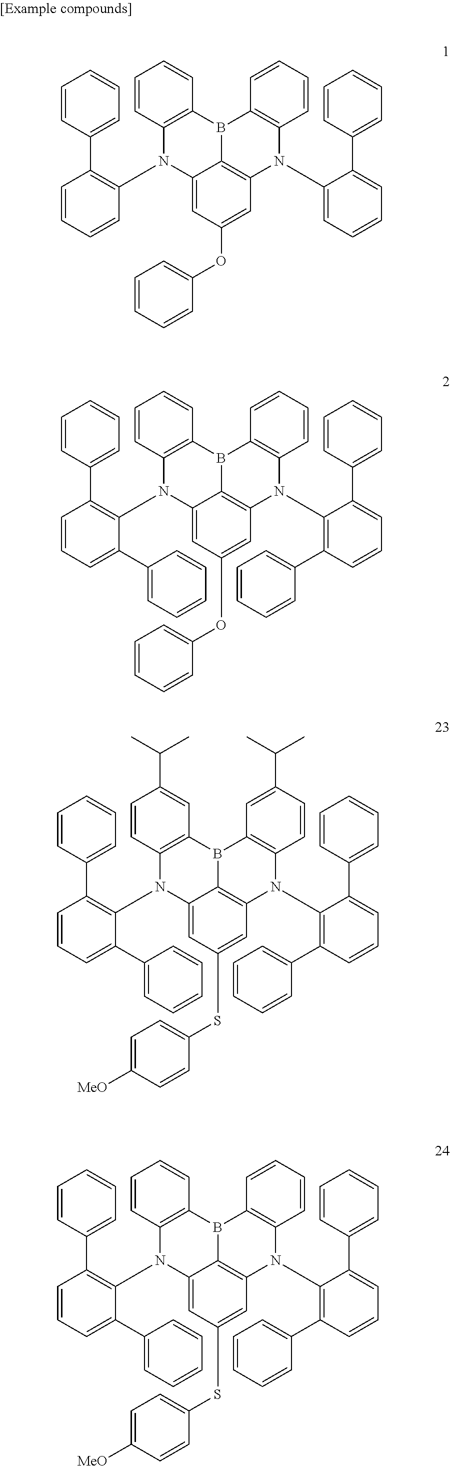 [SMILES: c1ccc(Oc2cc3c4c(c2)N(c2ccccc2-c2ccccc2)c2ccccc2B4c2ccccc2N3c2ccccc2-c2ccccc2)cc1 ; c1ccc(Oc2cc3c4c(c2)N(c2c(-c5ccccc5)cccc2-c2ccccc2)c2ccccc2B4c2ccccc2N3c2c(-c3ccccc3)cccc2-c2ccccc2)cc1 ; COc1ccc(Sc2cc3c4c(c2)N(c2c(-c5ccccc5)cccc2-c2ccccc2)c2ccc(C(C)C)cc2B4c2cc(C(C)C)ccc2N3c2c(-c3ccccc3)cccc2-c2ccccc2)cc1 ; COc1ccc(Sc2cc3c4c(c2)N(c2c(-c5ccccc5)cccc2-c2ccccc2)c2ccccc2B4c2ccccc2N3c2c(-c3ccccc3)cccc2-c2ccccc2)cc1]

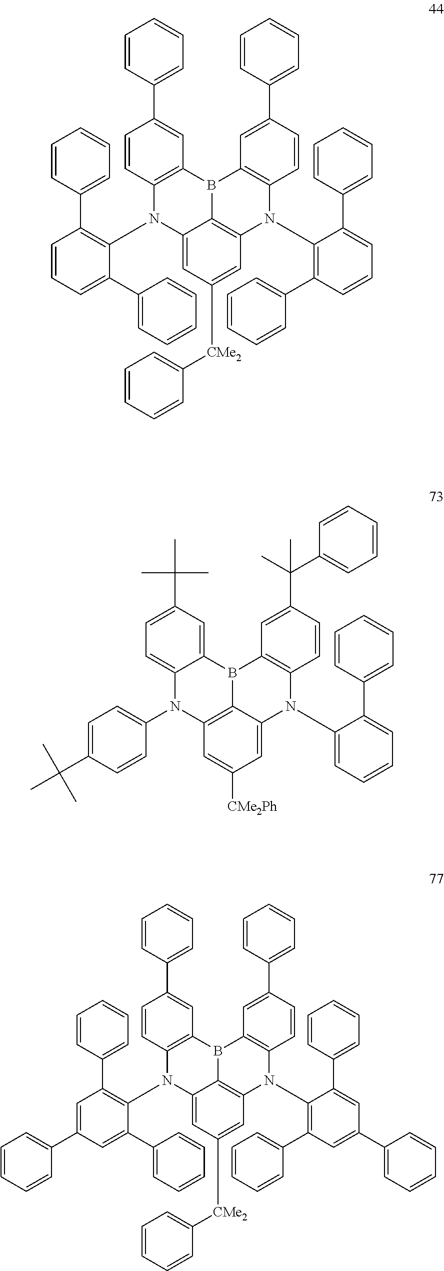

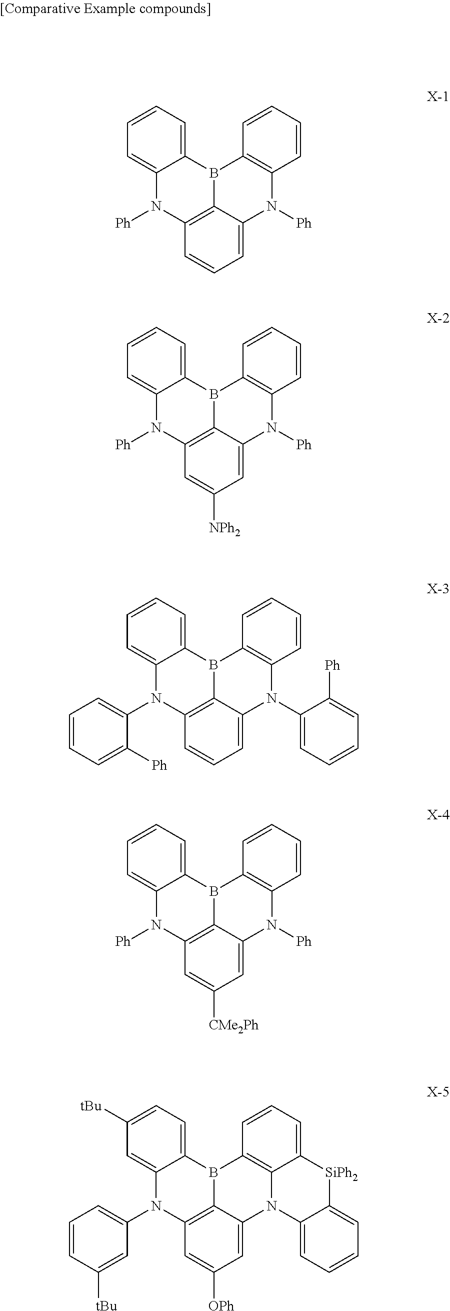

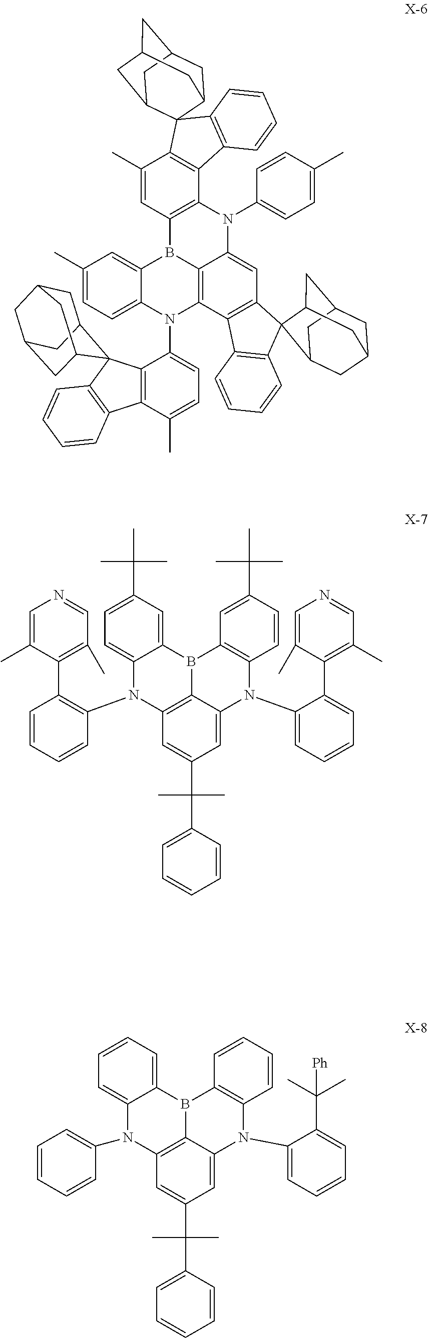

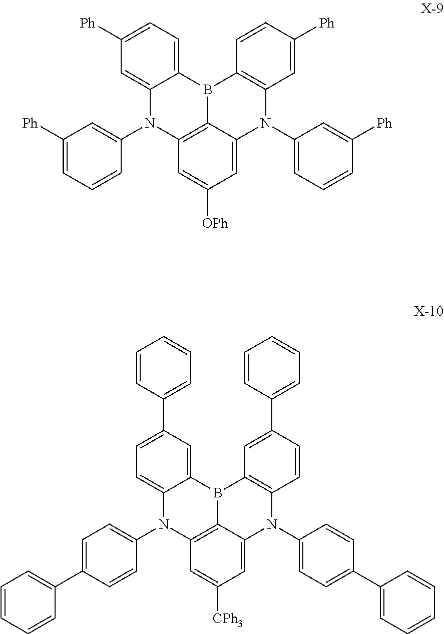

### (1) Preparation of Light Emitting Elements

A 150 nm-thick first electrode was formed using ITO, a hole injection layer having a thickness of 10 nm was formed using HATCN (dipyrazino[2,3-f: 2′,3′-h]quinoxaline-2,3,6,7,10,11-hexacarbonitrile), a hole transport layer having a thickness of 80 nm was formed on the hole injection layer, using NPD (N,N′-Di(1-naphthyl)-N,N′-diphenyl-(1,1″-biphenyl)-4,4″-diamine), a light emitting auxiliary layer having a thickness of 5 nm was formed on the hole transport layer, using mCP (1,3-bis(N-carbazolyl)benzene), a 20 nm-thick emission layer doped with 1% of Example compounds or Comparative Example compounds was formed on the light emitting auxiliary layer, using mCBP (3,3′-Di(9H-carbazol-9-yl)-1,1′-biphenyl), an electron transport layer having a thickness of 30 nm was formed on the emission layer, using TPBi (2,2′,2″-(1,3,5-Benzinetriyl)-tris(1-phenyl-1-H-benzimidazole)), an electron injection layer having a thickness of 0.5 nm was formed on the electron transport layer, using LiF, and a second electrode having a thickness of 300 nm was formed on the electron injection layer, using Al. Each layer was formed through vapor deposition in a vacuum atmosphere.

The compounds used in the preparation of the light emitting elements of Examples and Comparative Examples are disclosed herein. The following materials are materials of the related art, and were used for the preparation of elements after sublimation-purifying commercially available products.

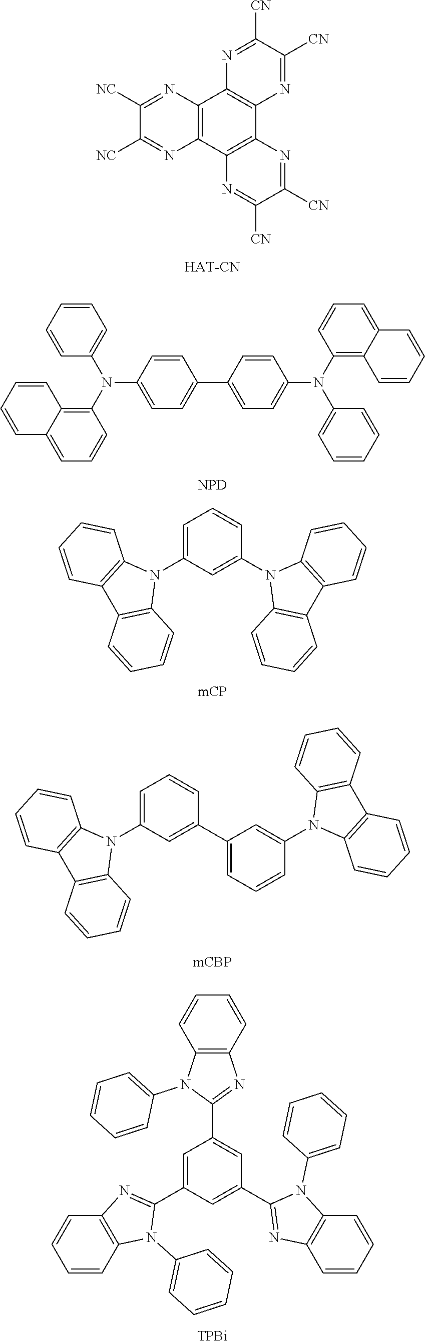

### (2) Characteristics Evaluation of Light Emitting Elements

Table 1 shows results of evaluation on characteristics of light emitting elements of Examples 1 to 7 and Comparative Examples 1 to 10. In the evaluation of the light emitting elements, external luminous efficiency and service life of the light emitting elements at a luminance of 800 cd/m² were measured. In Table 1, LT₅₀ refers to luminance half-life at an initial luminance of 800 cd/m². Regarding service life and external luminous efficiency, Table 1 shows relative values with respect to Comparative Example 1.

TABLE 1

| Example of | | Relative | Relative |
|---|---|---|---|
| prepared | | element service | external luminous |
| element | Dopant | life LT₅₀ | efficiency EQE_{800 nit} |
| Example 1 | Example | 1.6 | 3.8 |
| | Compound 1 | | |
| Example 2 | Example | 1.5 | 3.2 |
| | Compound 2 | | |
| Example 3 | Example | 2.3 | 5.1 |
| | Compound 23 | | |
| Example 4 | Example | 3.1 | 2.9 |
| | Compound 24 | | |
| Example 5 | Example | 3.9 | 5.5 |
| | Compound 44 | | |
| Example 6 | Example | 1.9 | 4.0 |
| | Compound 73 | | |
| Example 7 | Example | 4.0 | 5.5 |
| | Compound 77 | | |
| Comparative | Comparative | 1.0 | 1.0 |
| Example 1 | Example | | |
| | Compound X-1 | | |
| Comparative | Comparative | 0.5 | 0.9 |
| Example 2 | Example | | |
| | Compound X-2 | | |
| Comparative | Comparative | 1.2 | 1.1 |
| Example 3 | Example | | |
| | Compound X-3 | | |
| Comparative | Comparative | 1.1 | 1.2 |
| Example 4 | Example | | |
| | Compound X-4 | | |
| Comparative | Comparative | 1.3 | 2.1 |
| Example 5 | Example | | |
| | Compound X-5 | | |
| Comparative | Comparative | 1.4 | 2.2 |
| Example 6 | Example | | |
| | Compound X-6 | | |
| Comparative | Comparative | 0.1 | 1.3 |
| Example 7 | Example | | |
| | Compound X-7 | | |
| Comparative | Comparative | 0.9 | 1.1 |
| Example 8 | Example | | |
| | Compound X-8 | | |
| Comparative | Comparative | 1.2 | 1.5 |
| Example 9 | Example | | |
| | Compound X-9 | | |
| Comparative | Comparative | 0.8 | 1.7 |
| Example 10 | Example | | |
| | Compound X-10 | | |

Referring to the results of Table 1, it may be seen that the light emitting elements of Examples using the polycyclic compound according to an embodiment of the disclosure as light emitting materials had greater luminous efficiency and element service life than the light emitting elements of Comparative Examples.

Based on the results of Table 1, it may be seen that the compounds of Examples contributed to the improvement of the luminous efficiency and service life of light emitting elements as sterically bulky substituents were introduced at specific positions of a core portion. It may be that the excellent effect of Examples 1 to 7 was achieved as sterically bulky substituents were introduced into the polycyclic compound according to an embodiment to effectively separate a boron atom portion, which is a light emitting portion of a dopant, from other element constituent materials in the light emitting elements. For example, in the polycyclic compounds according to an embodiment of the disclosure, the light emitting portion was protected through the sterically bulky substituents to be hardly affected by water or oxygen present in a trace amount in the light emitting elements, and to hardly have intermolecular interaction with other element constituent materials as well, resulting in effective inhibition in the process of loss of luminescence activity.

On the other hand, Comparative Examples 1 to 4 exhibited lower service life and luminous efficiency than Examples. It may be seen that Comparative Example Compounds X-1 and X-2 included in Comparative Examples 1 and 2 did not include first and second substituents included in the polycyclic compound according to an embodiment, and thus had reduced luminous efficiency and service life compared to Examples. Comparative Example Compounds X-3 and X-4 included in Comparative Examples 3 and 4 include only a substituent corresponding to any one of the first and second substituents of the polycyclic compound according to an embodiment. Based on the results of Comparative Examples 3 and 4, it may be seen that introducing any one of the ortho-biphenyl group corresponding to the first substituent and —CMe₂Ph corresponding to the second substituent to protect the boron atom portion with a sterically bulky substituent was not enough to exhibit greater luminous efficiency and long life.

In Comparative Examples 5, 6, 7, and 8, it may be confirmed that the improvement in element service life and luminous efficiency is insignificant compared to the light emitting elements of Examples. Comparative Example Compounds X-5 and X-6 included in Comparative Examples 5 and 6 use a fused ring structure to have molecules in a planar state, and thus has a structure in which the steric effect of the polycyclic compound according to the embodiment is not shown. For Comparative Example Compounds X-7 and X-8 included in Comparative Examples 7 and 8, the portion corresponding to Y of the polycyclic compound represented by Formula 1 is an alkyl group or includes a pyrimidine group substituted with an alkyl group to hardly secure stability, thereby failing to obtain improved element service life. This may be because the alkyl group was sterically bulky or became a portion that is highly vulnerable to oxidative deterioration in an element. It may be seen that Comparative Example Compound X-8 includes a CMe₂Ph group in molecules as in Example Compound 73, but includes a —CMe₂Ph group (alkyl group) at the position corresponding to Y in Formula 1, thereby failing to contribute to improvement in element service life and efficiency.

The characteristics of the light emitting elements of Comparative Examples 9 and 10 are shown to be poorer than those of Examples. It may be seen that Comparative Example Compounds X-9 and X-10 included in Comparative Examples 9 and 10 have different bonding positions of the substituents corresponding to Y in Formula 1, resulting in no improvement in efficiency and service life. Comparing Example 6 with Comparative Example 8, both are elements using a material having a —CMe₂Ph group in molecules, but Example 6 achieved longer service life and higher efficiency. This indicates that for Comparative Example 8, when the —CMe₂Ph group (alkyl group) is present in the portion corresponding to the substituent Y of the disclosure, the effect shown by Example 6 is not produced.

A light emitting element according to an embodiment may include a polycyclic compound according to an embodiment, and may thus exhibit high efficiency and longer service life characteristics.

A polycyclic compound according to an embodiment may be used as a light emitting material for achieving improved light emitting element characteristics such as high efficiency and long lifespan.

Embodiments have been disclosed herein, and although terms are employed, they are used and are to be interpreted in a generic and descriptive sense only and not for the purposes of limitation. In some instances, as would be apparent by one of ordinary skill in the art, features, characteristics, and/or elements described in connection with an embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the disclosure as set forth in the claims.

What is claimed is:

1. A light emitting element comprising:
a first electrode;
a second electrode disposed on the first electrode; and
an emission layer disposed between the first electrode and the second electrode, wherein
the emission layer includes a polycyclic compound represented by Formula 1: 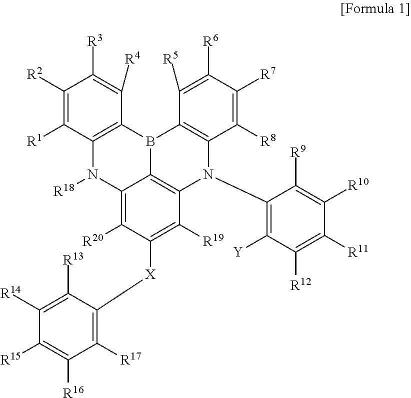
wherein in Formula 1,
X is O, S, or C(R²¹)(R²²),
R¹ to R²² are each independently a hydrogen atom, a deuterium atom, a halogen atom, a cyano group, a hydroxy group, a substituted or unsubstituted thio group, a substituted or unsubstituted oxy group, a substituted or unsubstituted silyl group, a substituted or unsubstituted amino group, a substituted or unsubstituted alkyl group having 1 to 20 carbon atoms, a substituted or unsubstituted alkenyl group having 2 to 20 carbon atoms, a substituted or unsubstituted cycloalkyl group having 3 to 30 ring-forming carbon atoms, a substituted or unsubstituted aryl group having 6 to 30 ring-forming carbon atoms, or a substituted or unsubstituted heteroaryl group having 2 to 30 ring-forming carbon atoms, or are bonded to an adjacent group to form a ring,
Y is a hydroxy group, a substituted or unsubstituted thio group, a substituted or unsubstituted oxy group, a substituted or unsubstituted arylthioxy group, a substituted or unsubstituted silyl group, a substituted or unsubstituted amine group, a substituted or unsubstituted cycloalkyl group having 3 to 30 ring-forming carbon atoms, a substituted or unsubstituted aryl group having 6 to 30 ring-forming carbon atoms, or a substituted or unsubstituted heteroaryl group having 2 to 30 ring-forming carbon atoms, and
a case where Y is a dimethylpyridine group is excluded, and
a case where R¹⁸ is bonded to R¹ or R²⁰ to form a ring is excluded.

2. The light emitting element of claim 1, wherein the polycyclic compound is represented by Formula 2: 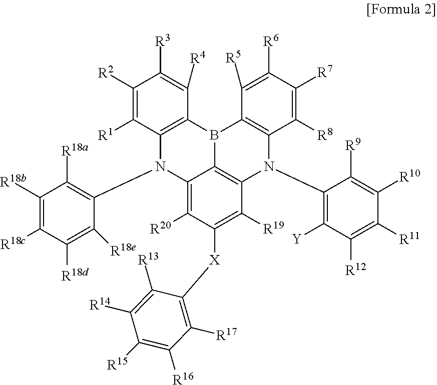
wherein in Formula 2,
R^{18a} to R^{18e} are each independently a hydrogen atom, a deuterium atom, a cyano group, a substituted or unsubstituted thio group, a substituted or unsubstituted oxy group, a substituted or unsubstituted amino group, a substituted or unsubstituted alkyl group having 1 to 10 carbon atoms, a substituted or unsubstituted cycloalkyl group having 3 to 10 ring-forming carbon atoms, a substituted or unsubstituted aryl group having 6 to 10 ring-forming carbon atoms, or a substituted or unsubstituted heteroaryl group having 2 to 10 ring-forming carbon atoms, and
X, Y, R¹ to R¹⁷, R¹⁹, and R²⁰ are the same as defined in Formula 1.

3. The light emitting element of claim 2, wherein the polycyclic compound is represented by Formula 2-a or Formula 2-b: 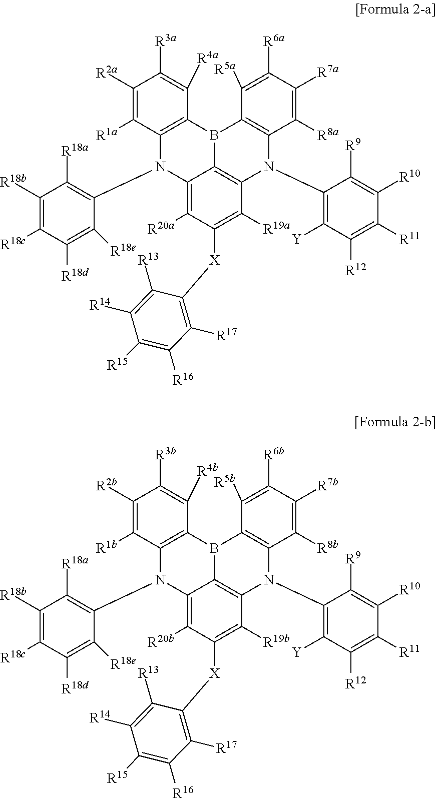
wherein in Formulas 2-a and 2-b, R^{1a}, R^{2a}, R^{4a}, R^{5a}, R^{7a}, R^{8a}, R^{19a}, R^{20a}, R^{1b}, R^{3b}, R^{4b}, R^{5b}, R^{6b}, R^{8b}, R^{19b}, and R^{20b} are each independently a hydrogen atom or a deuterium atom,
R^{3a}, R^{6a}, R^{2b}, and R^{7b} are each independently a hydrogen atom, a deuterium atom, a substituted or unsubstituted silyl group, a substituted or unsubstituted alkyl group having 1 to 10 carbon atoms, a substituted or unsubstituted cycloalkyl group having 3 to 15 ring-forming carbon atoms, a substituted or unsubstituted aryl group having 6 to 15 ring-forming carbon atoms, or a substituted or unsubstituted heteroaryl group having 2 to 15 ring-forming carbon atoms, and
X, Y, R⁹ to R¹⁷, and R^{18a} to R^{18e} are the same as defined in Formulas 1 and 2.

4. The light emitting element of claim 1, wherein Y is a substituted or unsubstituted phenylthio group, a substituted or unsubstituted phenoxy group, a substituted or unsubstituted methoxy group, a substituted or unsubstituted t-butoxy group, a substituted or unsubstituted diethylamino group, a substituted or unsubstituted diphenylamino group, a substituted or unsubstituted cyclohexyl group, a substituted or unsubstituted phenyl group, a substituted or unsubstituted naphthyl group, a substituted or unsubstituted benzothiazole group, a substituted or unsubstituted benzoxazole group, a substituted or unsubstituted indole group, a substituted or unsubstituted benzothiophene group, or a substituted or unsubstituted benzofuran group.

5. The light emitting element of claim 1, wherein the polycyclic compound is represented by Formula 3: 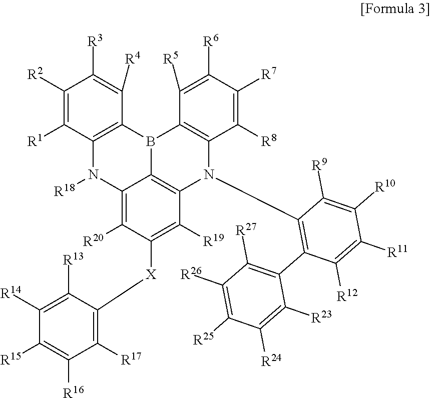
wherein in Formula 3,
R²³ to R²⁷ are each independently a hydrogen atom or a deuterium atom, and
X and R¹ to R²⁰ are the same as defined in Formula 1.

6. The light emitting element of claim 1, wherein at least one of Y and R¹ to R²² is a deuterium atom or comprises a substituent including a deuterium atom.

7. The light emitting element of claim 1, wherein the polycyclic compound is represented by one of Formulas 4-1 to 4-3: 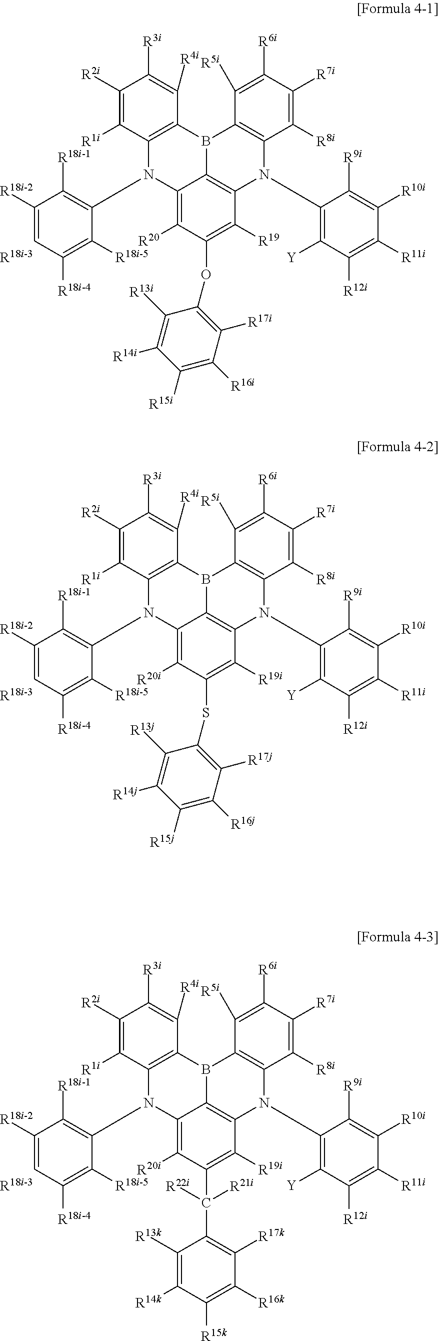
wherein in Formula 4-1,
R¹³ⁱ to R¹⁷ⁱ are each independently a hydrogen atom, a deuterium atom, a halogen atom, a substituted or unsubstituted alkyl group having 1 to 10 carbon atoms, a substituted or unsubstituted aryl group having 6 to 15 ring-forming carbon atoms, or a substituted or unsubstituted heteroaryl group having 2 to 15 ring-forming carbon atoms, or are bonded to an adjacent group to form a ring;
wherein in Formula 4-2,
R^{13j} to R^{17j} are each independently a hydrogen atom, a deuterium atom, a halogen atom, a cyano group, a substituted or unsubstituted oxy group, a substituted or unsubstituted alkyl group having 1 to 10 carbon atoms, or a substituted or unsubstituted aryl group having 6 to 15 ring-forming carbon atoms;
wherein in Formula 4-3,
R^{13k} to R^{17k} are each independently a hydrogen atom, a deuterium atom, a halogen atom, a cyano group, a substituted or unsubstituted alkyl group having 1 to 10 carbon atoms, a substituted or unsubstituted cycloalkyl group having 3 to 10 ring-forming carbon atoms, or a substituted or unsubstituted aryl group having 6 to 15 ring-forming carbon atoms, and
R²¹ⁱ and R²²ⁱ are each independently a hydrogen atom, a deuterium atom, a substituted or unsubstituted alkyl group having 1 to 10 carbon atoms, or a substituted or unsubstituted aryl group having 6 to 15 ring-forming carbon atoms; and
wherein in Formulas 4-1 to 4-3,
R¹ⁱ to R⁸ⁱ are each independently a hydrogen atom, a deuterium atom, a substituted or unsubstituted silyl group, a substituted or unsubstituted alkyl group having 1 to 20 carbon atoms, a substituted or unsubstituted cycloalkyl group having 3 to 30 ring-forming carbon atoms, a substituted or unsubstituted aryl group having 6 to 30 ring-forming carbon atoms, or a substituted or unsubstituted heteroaryl group having 2 to 30 ring-forming carbon atoms,
R⁹ⁱ to R¹²ⁱ are each independently a hydrogen atom, a deuterium atom, a cyano group, a substituted or unsubstituted oxy group, a substituted or unsubstituted alkyl group having 1 to 20 carbon atoms, a substituted or unsubstituted cycloalkyl group having 3 to 30 ring-forming carbon atoms, or a substituted or unsubstituted aryl group having 6 to 30 ring-forming carbon atoms,
R¹⁸ⁱ⁻¹ to R¹⁸ⁱ⁻⁵ are each independently a hydrogen atom, a deuterium atom, a cyano group, a substituted or unsubstituted thio group, a substituted or unsubstituted oxy group, a substituted or unsubstituted amino group, a substituted or unsubstituted alkyl group having 1 to 20 carbon atoms, a substituted or unsubstituted cycloalkyl group having 3 to 30 ring-forming carbon atoms, a substituted or unsubstituted aryl group having 6 to 30 ring-forming carbon atoms, or a substituted or unsubstituted heteroaryl group having 2 to 30 ring-forming carbon atoms,
R¹⁹ⁱ and R²⁰ⁱ are each independently a hydrogen atom or a deuterium atom, and
Y is the same as defined in Formula 1.

8. The light emitting element of claim 1, wherein R¹ to R⁸ are each independently a hydrogen atom, a deuterium atom, a substituted or unsubstituted silyl group, a substituted or unsubstituted methyl group, a substituted or unsubstituted i-propyl group, a substituted or unsubstituted t-butyl group, a substituted or unsubstituted pentyl group, a substituted or unsubstituted cyclohexyl group, a substituted or unsubstituted phenyl group, a substituted or unsubstituted naphthyl group, or a substituted or unsubstituted carbazole group.

9. The light emitting element of claim 1, wherein R¹³ to R¹⁷ are each independently a hydrogen atom, a deuterium atom, a halogen atom, a cyano group, a substituted or unsubstituted methoxy group, a substituted or unsubstituted methyl group, a substituted or unsubstituted i-propyl group, a substituted or unsubstituted t-butyl group, a substituted or unsubstituted cyclopropyl group, a substituted or unsubstituted phenyl group, or a substituted or unsubstituted carbazole group, or are bonded to an adjacent group to form a dibenzothiophene group or a dibenzofuran group.

10. The light emitting element of claim 1, wherein
at least one of R²¹ or R²² is a substituted or unsubstituted alkyl group having 1 to 10 carbon atoms, or a substituted or unsubstituted aryl group having 6 to 10 ring-forming carbon atoms, and
the remainder of R²¹ or R²² is a hydrogen atom or a deuterium atom.

11. The light emitting element of claim 1, wherein
the emission layer comprises a dopant and a host, and
the dopant comprises the polycyclic compound.

12. The light emitting element of claim 1, wherein the polycyclic compound includes at least one compound selected from Compound Group 1: 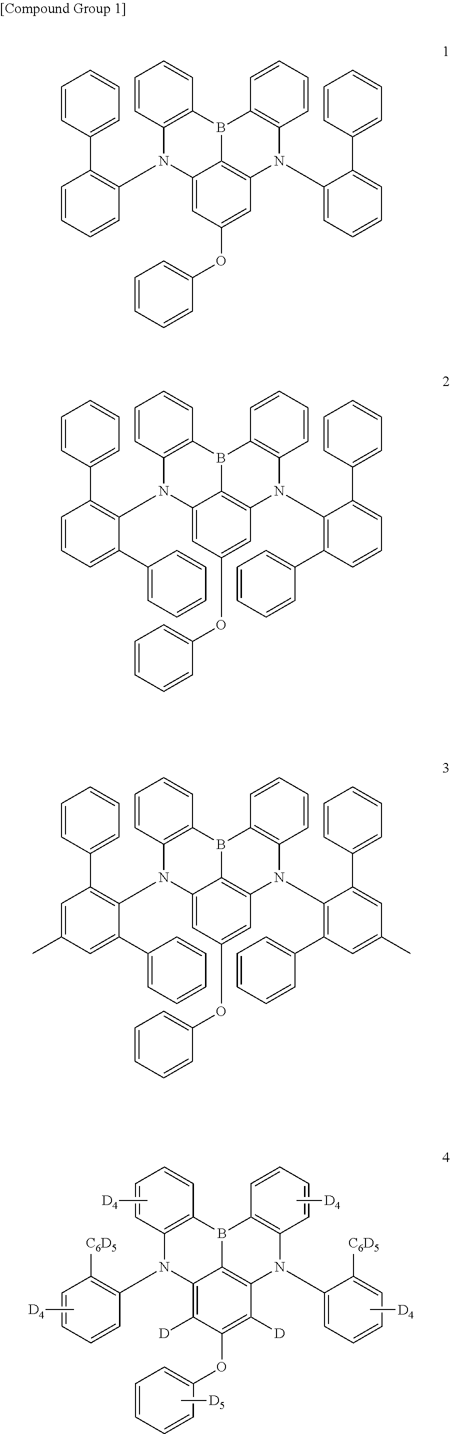 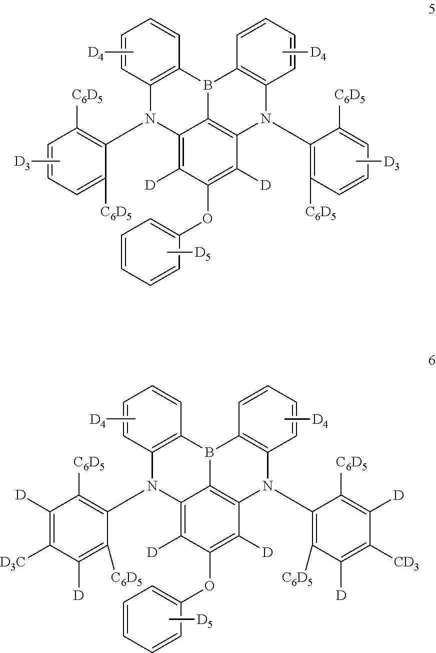 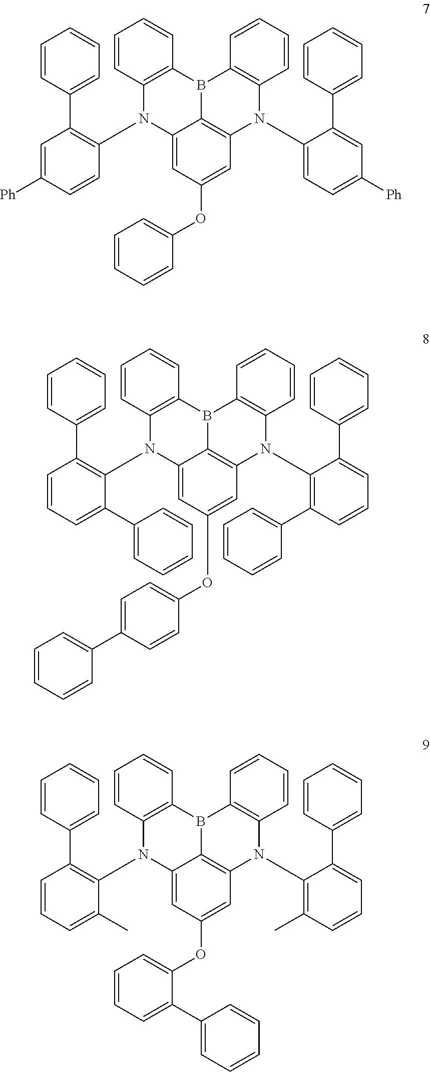 [SMILES: c1ccc(Oc2cc3c4c(c2)N(c2ccc(-c5ccccc5)cc2-c2ccccc2)c2ccccc2B4c2ccccc2N3c2ccc(-c3ccccc3)cc2-c2ccccc2)cc1 ; c1ccc(-c2ccc(Oc3cc4c5c(c3)N(c3c(-c6ccccc6)cccc3-c3ccccc3)c3ccccc3B5c3ccccc3N4c3c(-c4ccccc4)cccc3-c3ccccc3)cc2)cc1 ; Cc1cccc(-c2ccccc2)c1N1c2ccccc2B2c3ccccc3N(c3c(C)cccc3-c3ccccc3)c3cc(Oc4ccccc4-c4ccccc4)cc1c32] 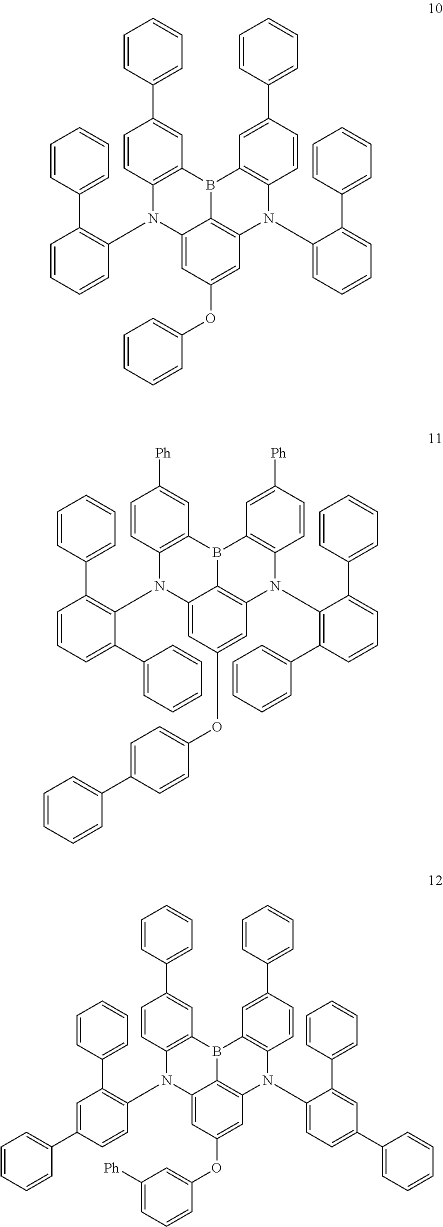 [SMILES: c1ccc(Oc2cc3c4c(c2)N(c2ccccc2-c2ccccc2)c2ccc(-c5ccccc5)cc2B4c2cc(-c4ccccc4)ccc2N3c2ccccc2-c2ccccc2)cc1 ; c1ccc(-c2ccc(Oc3cc4c5c(c3)N(c3c(-c6ccccc6)cccc3-c3ccccc3)c3ccc(-c6ccccc6)cc3B5c3cc(-c5ccccc5)ccc3N4c3c(-c4ccccc4)cccc3-c3ccccc3)cc2)cc1 ; c1ccc(-c2cccc(Oc3cc4c5c(c3)N(c3ccc(-c6ccccc6)cc3-c3ccccc3)c3ccc(-c6ccccc6)cc3B5c3cc(-c5ccccc5)ccc3N4c3ccc(-c4ccccc4)cc3-c3ccccc3)c2)cc1] 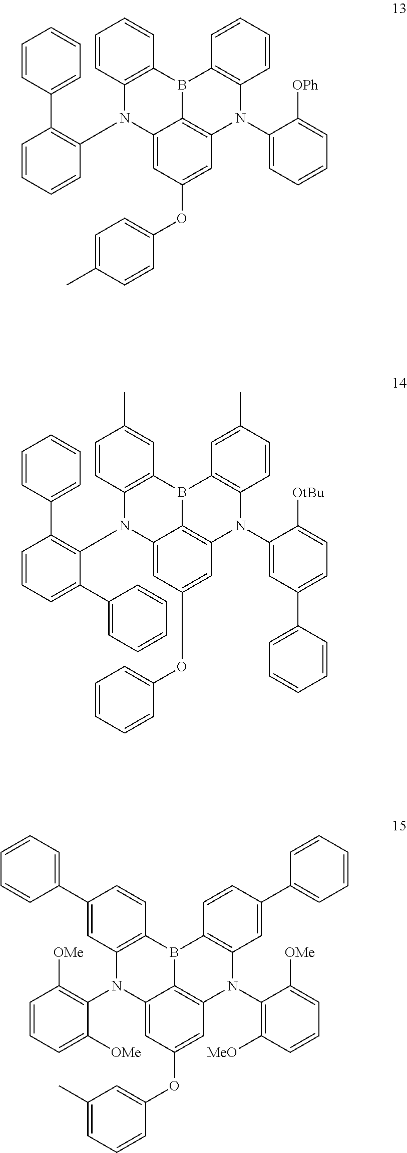 [SMILES: Cc1ccc(Oc2cc3c4c(c2)N(c2ccccc2-c2ccccc2)c2ccccc2B4c2ccccc2N3c2ccccc2Oc2ccccc2)cc1 ; Cc1ccc2c(c1)B1c3cc(C)ccc3N(c3c(-c4ccccc4)cccc3-c3ccccc3)c3cc(Oc4ccccc4)cc(c31)N2c1cc(-c2ccccc2)ccc1OC(C)(C)C ; COc1cccc(OC)c1N1c2cc(-c3ccccc3)ccc2B2c3ccc(-c4ccccc4)cc3N(c3c(OC)cccc3OC)c3cc(Oc4cccc(C)c4)cc1c32] 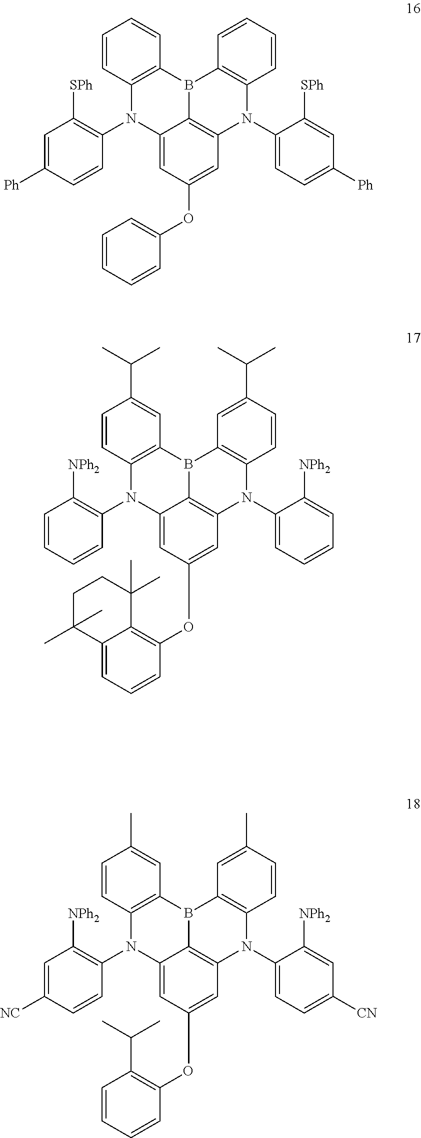 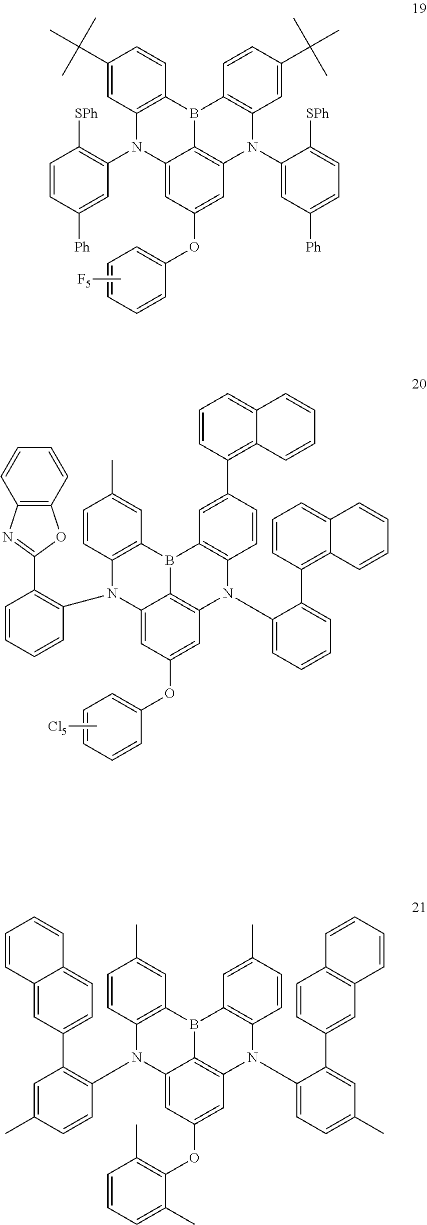 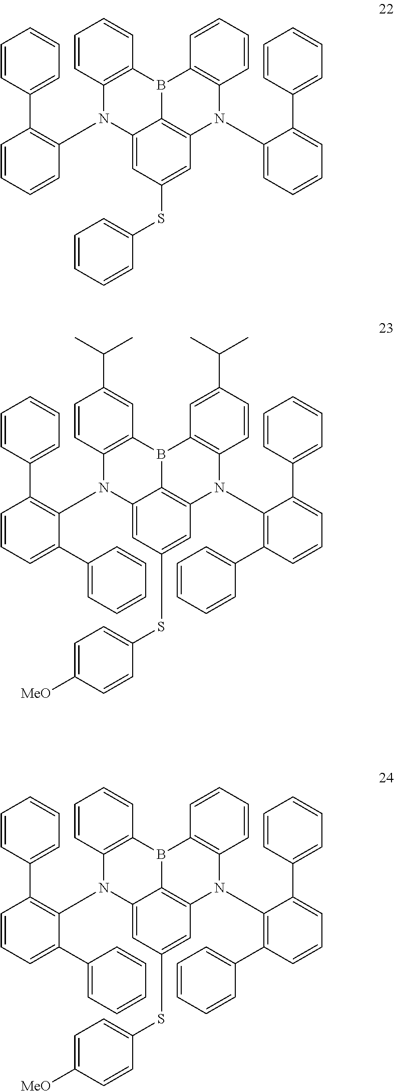 [SMILES: c1ccc(Sc2cc3c4c(c2)N(c2ccccc2-c2ccccc2)c2ccccc2B4c2ccccc2N3c2ccccc2-c2ccccc2)cc1 ; COc1ccc(Sc2cc3c4c(c2)N(c2c(-c5ccccc5)cccc2-c2ccccc2)c2ccc(C(C)C)cc2B4c2cc(C(C)C)ccc2N3c2c(-c3ccccc3)cccc2-c2ccccc2)cc1 ; COc1ccc(Sc2cc3c4c(c2)N(c2c(-c5ccccc5)cccc2-c2ccccc2)c2ccccc2B4c2ccccc2N3c2c(-c3ccccc3)cccc2-c2ccccc2)cc1] 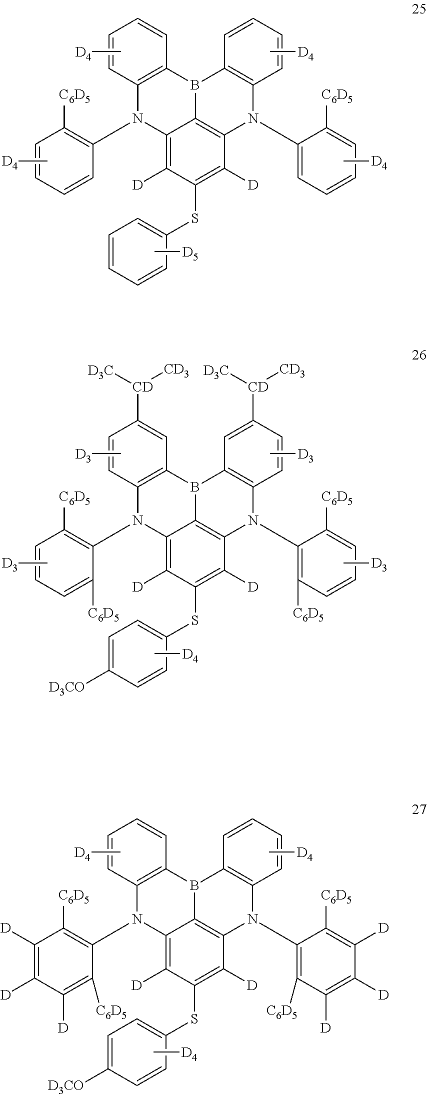 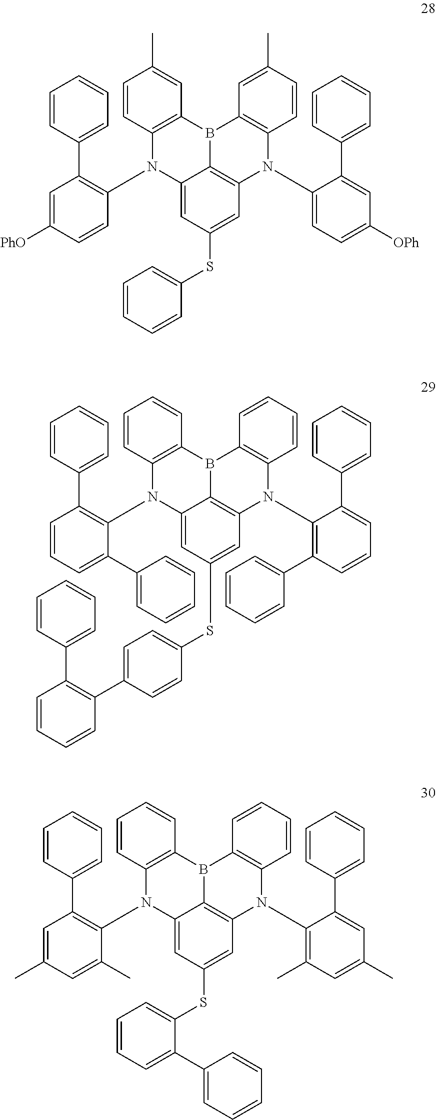 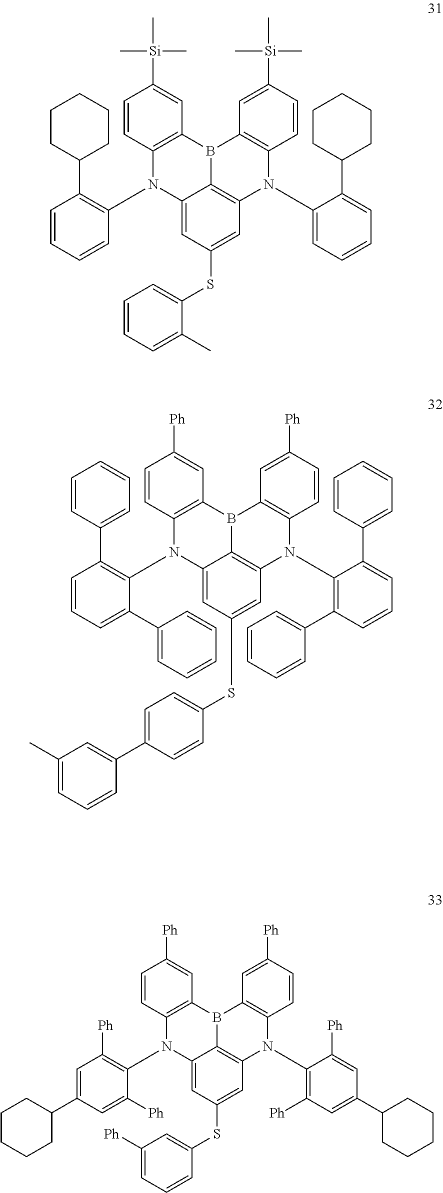 [SMILES: Cc1ccccc1Sc1cc2c3c(c1)N(c1ccccc1C1CCCCC1)c1ccc([Si](C)(C)C)cc1B3c1cc([Si](C)(C)C)ccc1N2c1ccccc1C1CCCCC1 ; Cc1cccc(-c2ccc(Sc3cc4c5c(c3)N(c3c(-c6ccccc6)cccc3-c3ccccc3)c3ccc(-c6ccccc6)cc3B5c3cc(-c5ccccc5)ccc3N4c3c(-c4ccccc4)cccc3-c3ccccc3)cc2)c1 ; c1ccc(-c2cccc(Sc3cc4c5c(c3)N(c3c(-c6ccccc6)cc(C6CCCCC6)cc3-c3ccccc3)c3ccc(-c6ccccc6)cc3B5c3cc(-c5ccccc5)ccc3N4c3c(-c4ccccc4)cc(C4CCCCC4)cc3-c3ccccc3)c2)cc1] 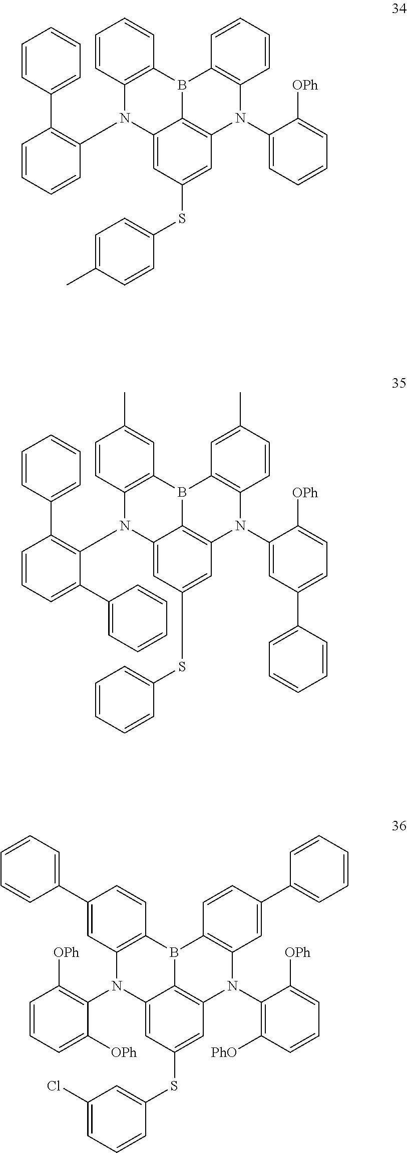 [SMILES: Cc1ccc(Sc2cc3c4c(c2)N(c2ccccc2-c2ccccc2)c2ccccc2B4c2ccccc2N3c2ccccc2Oc2ccccc2)cc1 ; Cc1ccc2c(c1)B1c3cc(C)ccc3N(c3c(-c4ccccc4)cccc3-c3ccccc3)c3cc(Sc4ccccc4)cc(c31)N2c1cc(-c2ccccc2)ccc1Oc1ccccc1 ; Clc1cccc(Sc2cc3c4c(c2)N(c2c(Oc5ccccc5)cccc2Oc2ccccc2)c2cc(-c5ccccc5)ccc2B4c2ccc(-c4ccccc4)cc2N3c2c(Oc3ccccc3)cccc2Oc2ccccc2)c1] 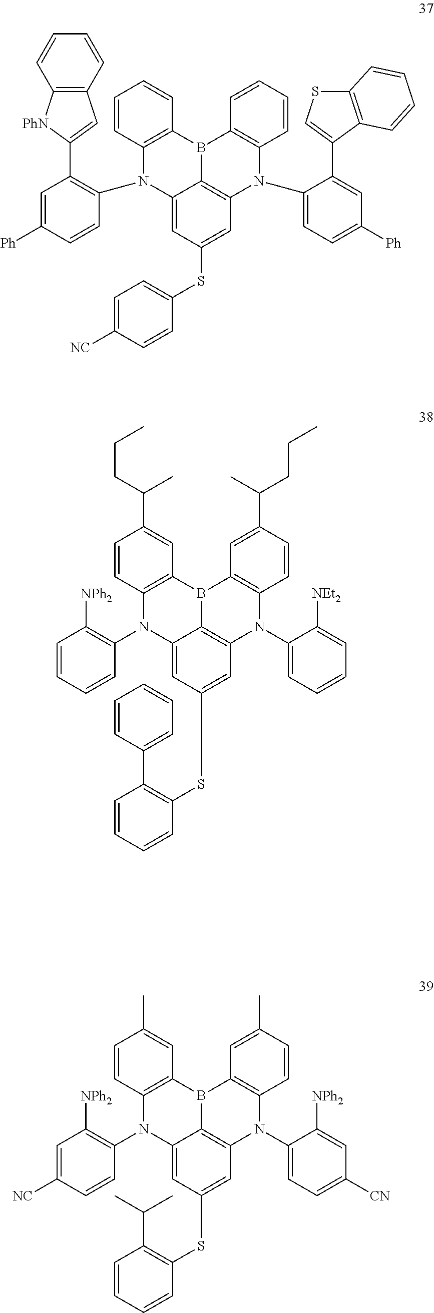 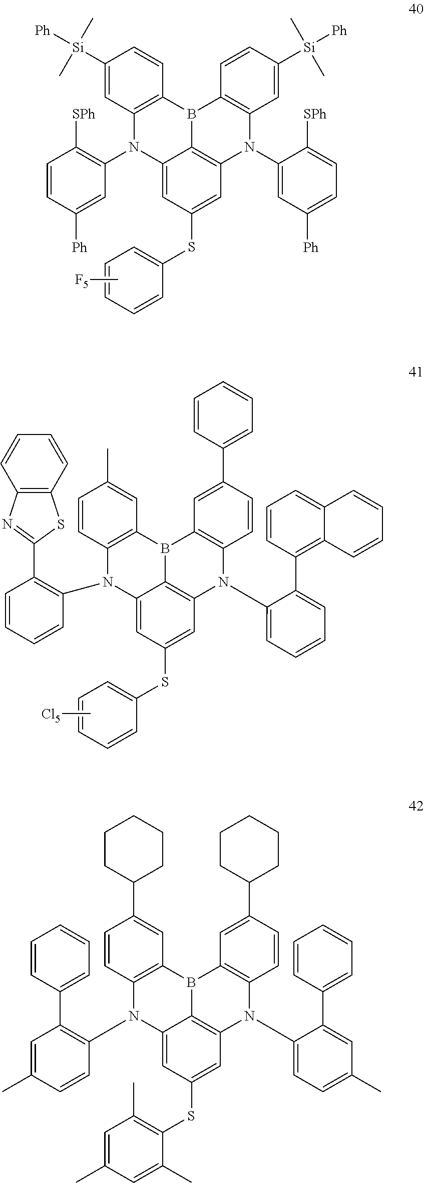 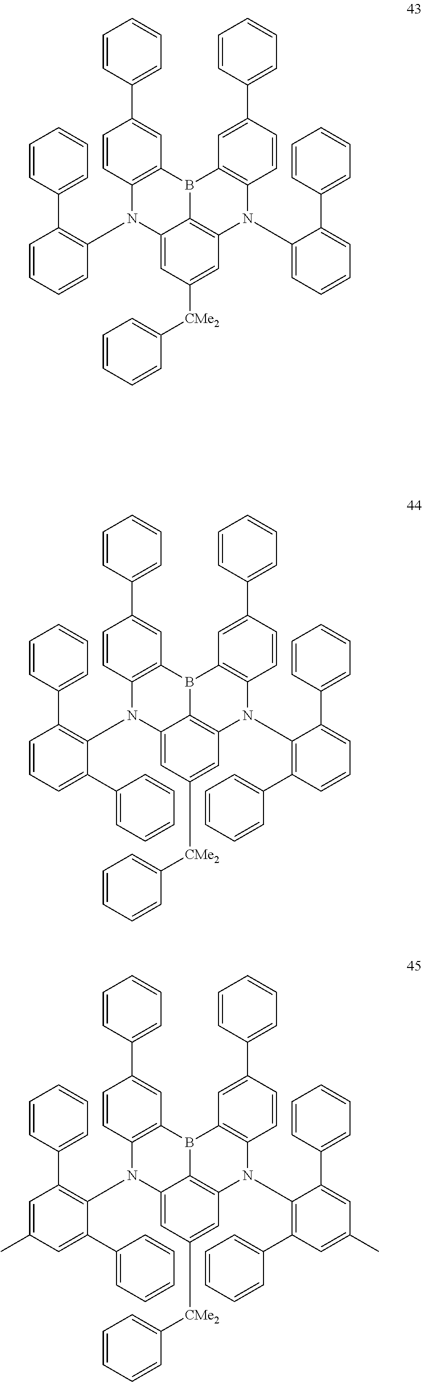 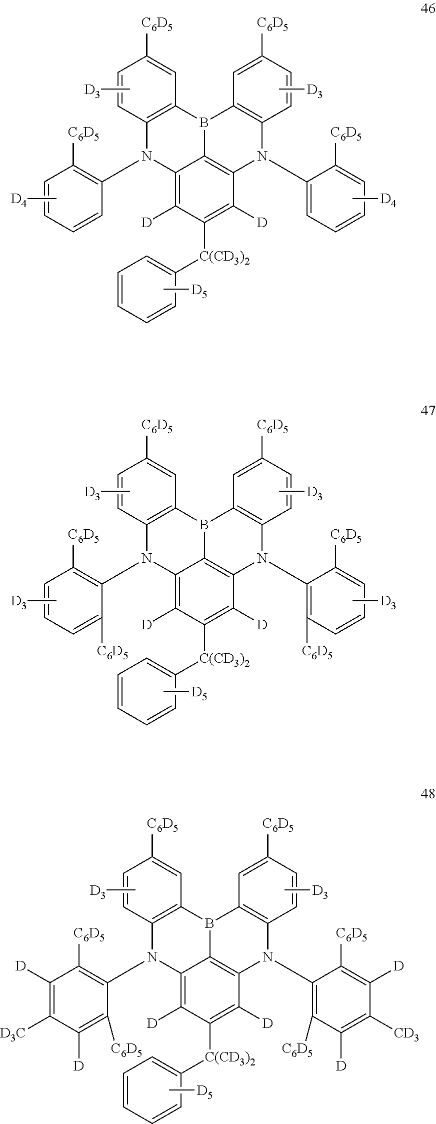 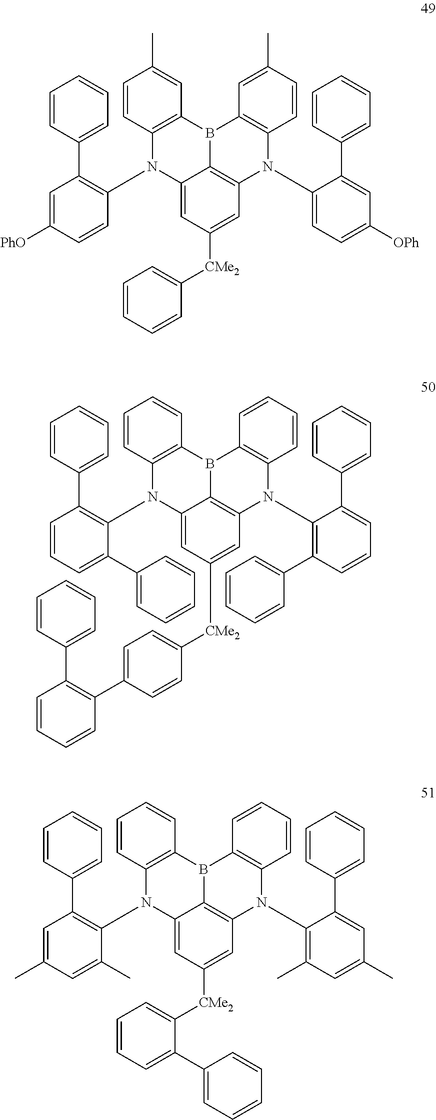 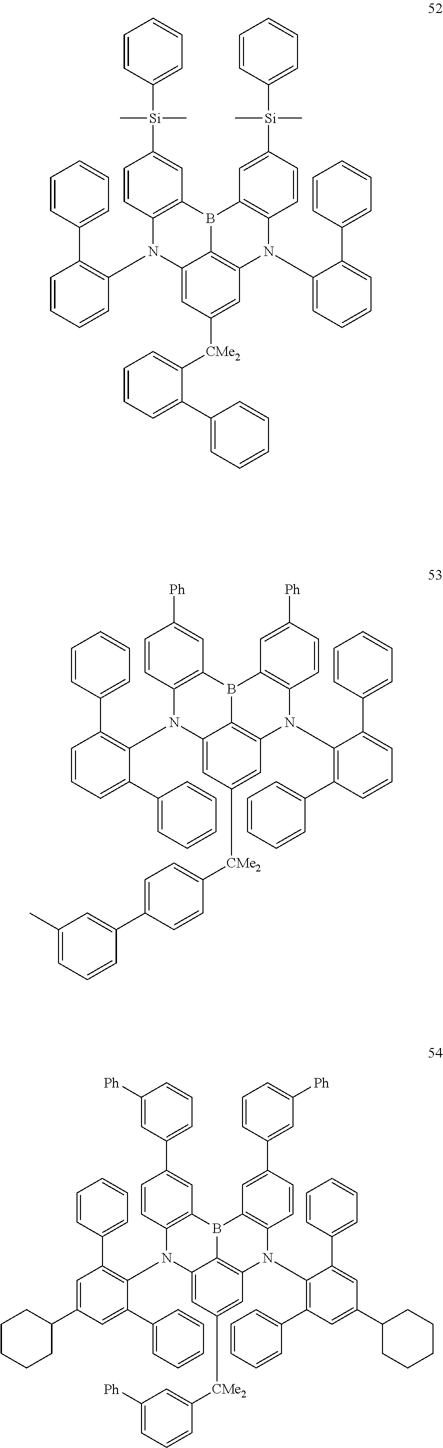 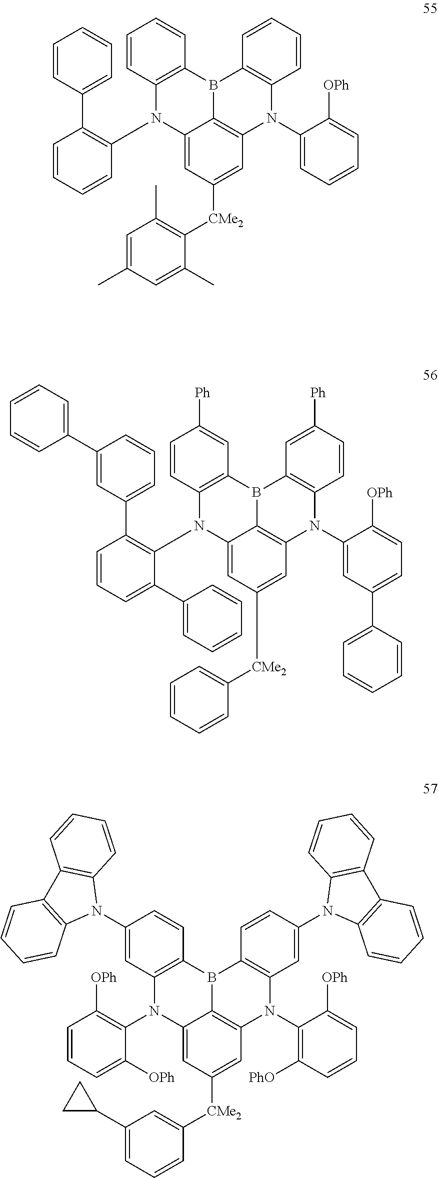 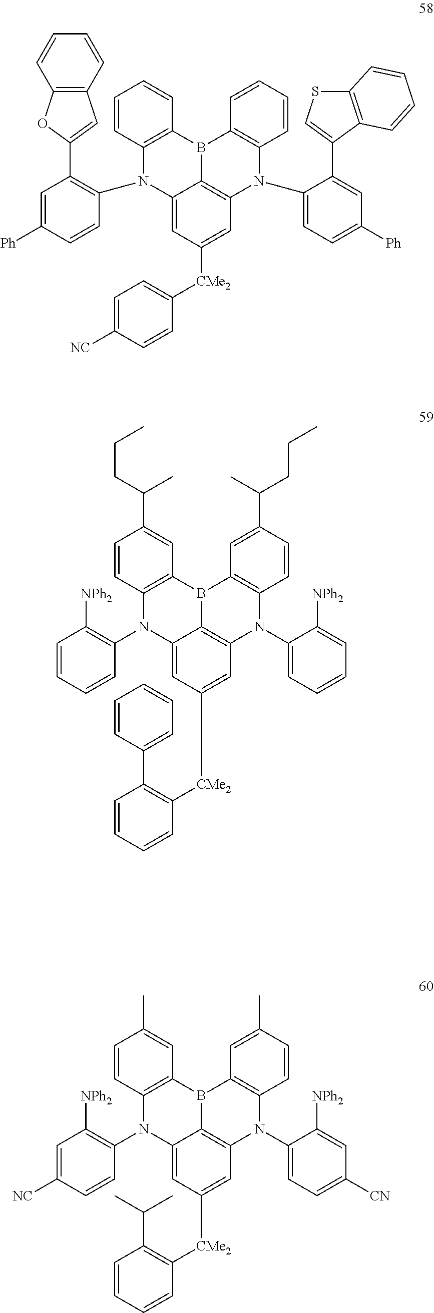 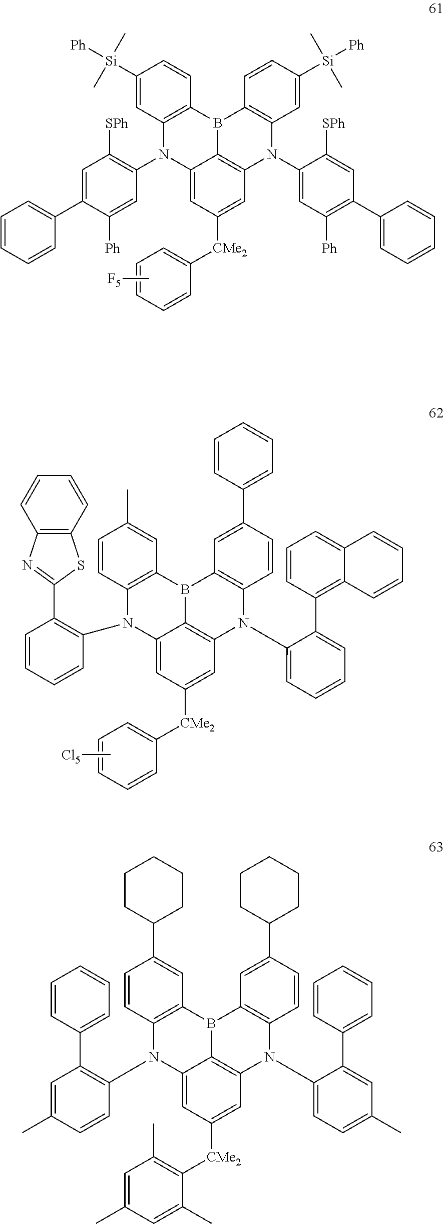 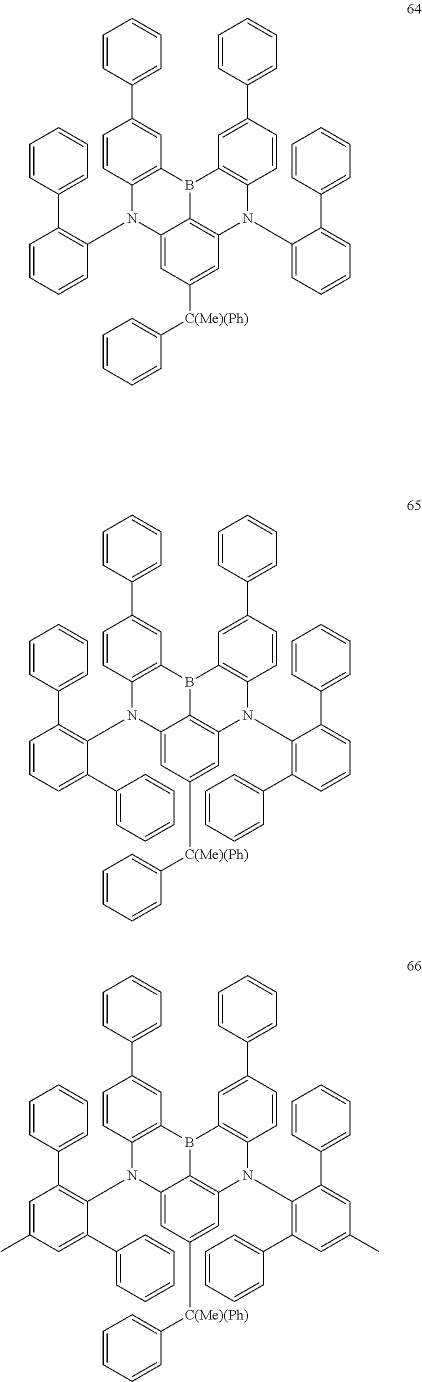 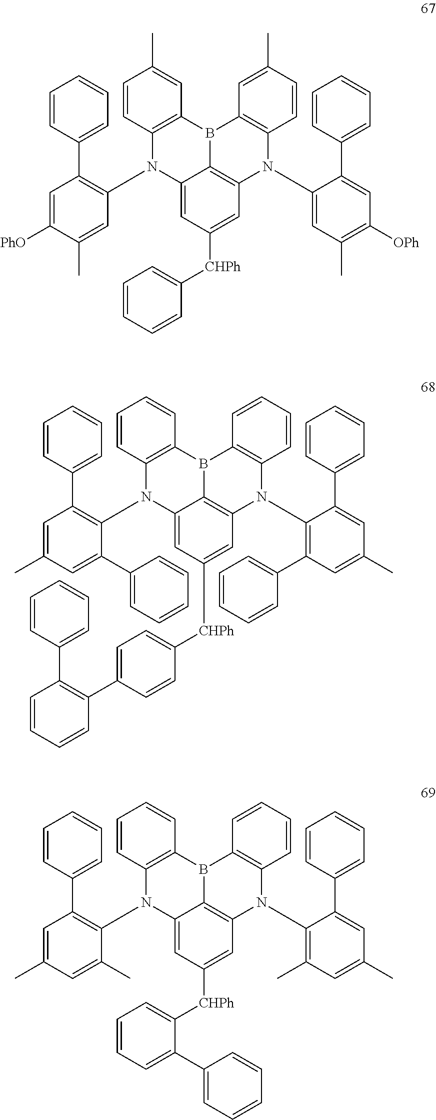 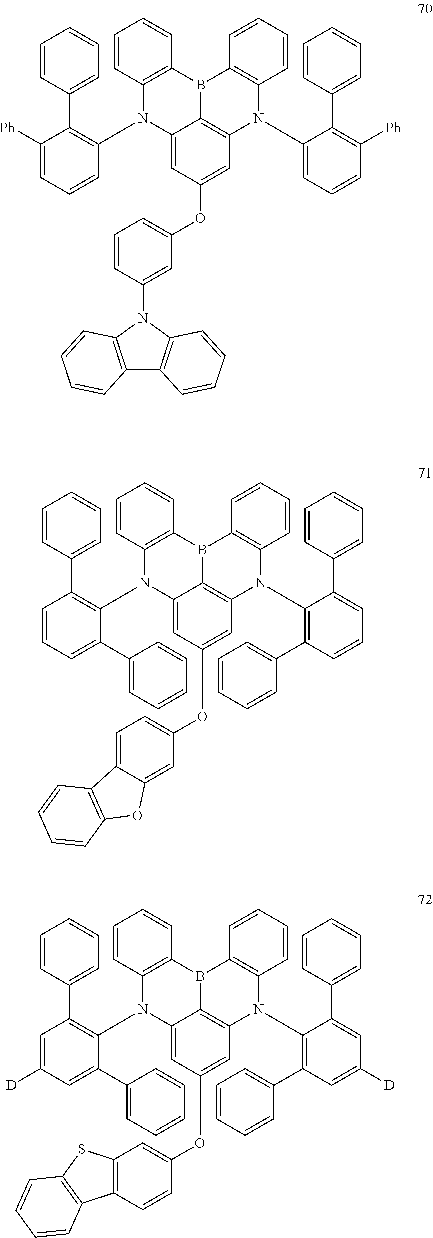 [SMILES: c1ccc(-c2cccc(N3c4ccccc4B4c5ccccc5N(c5cccc(-c6ccccc6)c5-c5ccccc5)c5cc(Oc6cccc(-n7c8ccccc8c8ccccc87)c6)cc3c54)c2-c2ccccc2)cc1 ; c1ccc(-c2cccc(-c3ccccc3)c2N2c3ccccc3B3c4ccccc4N(c4c(-c5ccccc5)cccc4-c4ccccc4)c4cc(Oc5ccc6c(c5)oc5ccccc56)cc2c43)cc1 ; [2H]c1cc(-c2ccccc2)c(N2c3ccccc3B3c4ccccc4N(c4c(-c5ccccc5)cc([2H])cc4-c4ccccc4)c4cc(Oc5ccc6c(c5)sc5ccccc56)cc2c43)c(-c2ccccc2)c1] 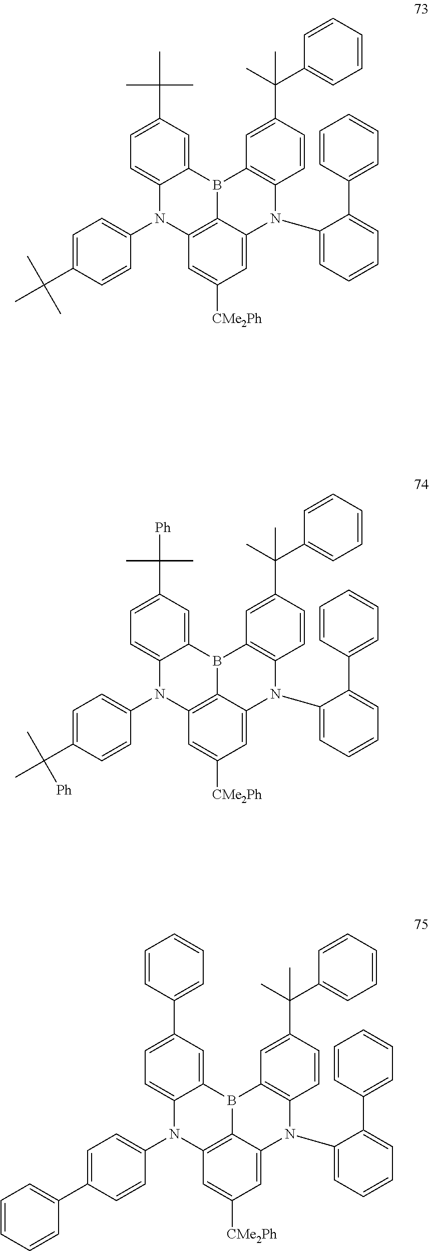 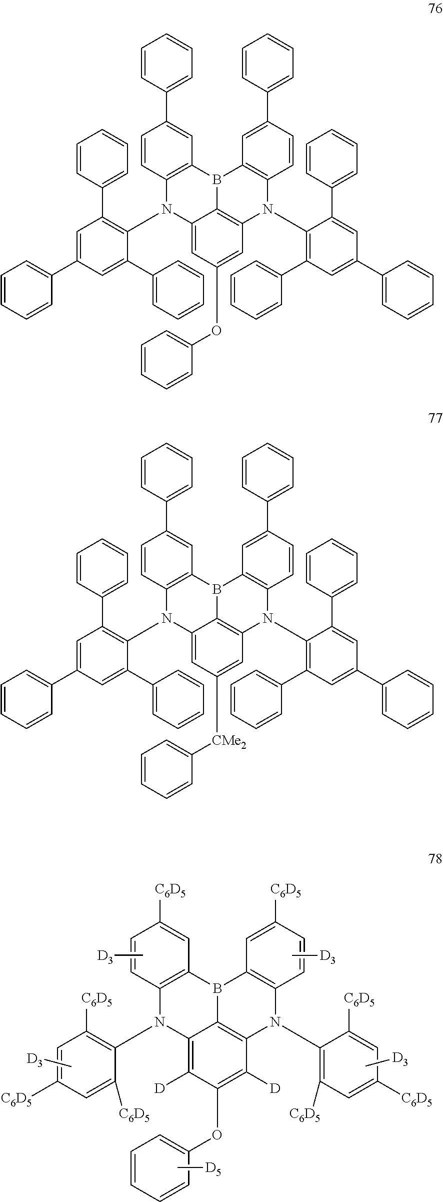 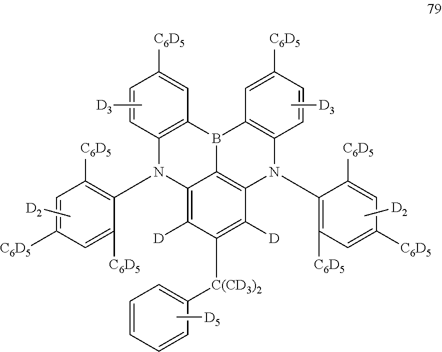
wherein in Compound Group 1,
D represents a deuterium atom,
Me represents a methyl group,
Et represents an ethyl group,
F represents a fluorine atom,
Cl represents a chlorine atom, and
Ph represents a phenyl group.

13. A polycyclic compound represented by Formula 1: 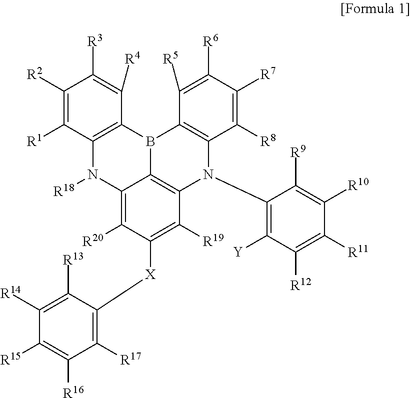
wherein in Formula 1,
X is O, S, or C(R²¹)(R²²),
R¹ to R²² are each independently a hydrogen atom, a deuterium atom, a halogen atom, a cyano group, a hydroxy group, a substituted or unsubstituted thio group, a substituted or unsubstituted oxy group, a substituted or unsubstituted silyl group, a substituted or unsubstituted amino group, a substituted or unsubstituted alkyl group having 1 to 20 carbon atoms, a substituted or unsubstituted alkenyl group having 2 to 20 carbon atoms, a substituted or unsubstituted cycloalkyl group having 3 to 30 ring-forming carbon atoms, a substituted or unsubstituted aryl group having 6 to 30 ring-forming carbon atoms, or a substituted or unsubstituted heteroaryl group having 2 to 30 ring-forming carbon atoms, or are bonded to an adjacent group to form a ring,
Y is a hydroxy group, a substituted or unsubstituted thio group, a substituted or unsubstituted oxy group, a substituted or unsubstituted arylthioxy group, a substituted or unsubstituted silyl group, a substituted or unsubstituted amine group, a substituted or unsubstituted cycloalkyl group having 3 to 30 ring-forming carbon atoms, a substituted or unsubstituted aryl group having 6 to 30 ring-forming carbon atoms, or a substituted or unsubstituted heteroaryl group having 2 to 30 ring-forming carbon atoms,
a case where Y is a dimethylpyridine group is excluded, and
a case where R¹⁸ is bonded to R¹ or R²⁰ to form a ring is excluded.

14. The polycyclic compound of claim 13, wherein Formula 1 is represented by Formula 2: 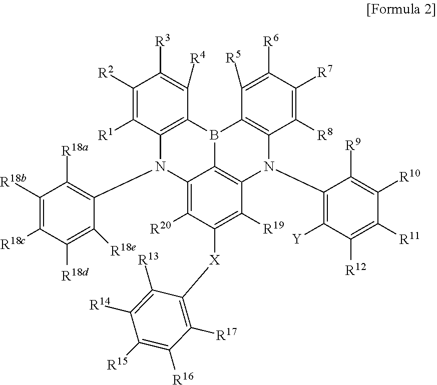
wherein in Formula 2,
R^{18a} to R^{18e} are each independently a hydrogen atom, a deuterium atom, a cyano group, a substituted or unsubstituted thio group, a substituted or unsubstituted oxy group, a substituted or unsubstituted amino group, a substituted or unsubstituted alkyl group having 1 to 10 carbon atoms, a substituted or unsubstituted cycloalkyl group having 3 to 10 ring-forming carbon atoms, a substituted or unsubstituted aryl group having 6 to 10 ring-forming carbon atoms, or a substituted or unsubstituted heteroaryl group having 2 to 10 ring-forming carbon atoms, and
X, Y, R¹ to R¹⁷, R¹⁹, and R²⁰ are the same as defined in Formula 1.

15. The polycyclic compound of claim 14, wherein Formula 2 is represented by Formula 2-a or Formula 2-b: 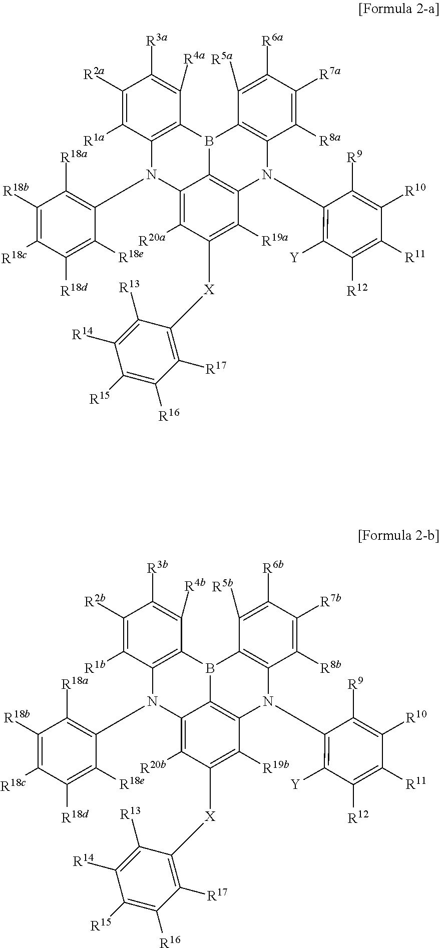
wherein in Formulas 2-a and 2-b,
R^{1a}, R^{2a}, R^{4a}, R^{5a}, R^{7a}, R^{8a}, R^{19a}, R^{20a}, R^{1b}, R^{3b} to R^{6b}, R^{8b}, R^{19b}, and R^{20b} are each independently a hydrogen atom or a deuterium atom,
R^{3a}, R^{6a}, R^{2b}, and R^{7b} are each independently a hydrogen atom, a deuterium atom, a substituted or unsubstituted silyl group, a substituted or unsubstituted alkyl group having 1 to 10 carbon atoms, a substituted or unsubstituted cycloalkyl group having 3 to 15 ring-forming carbon atoms, a substituted or unsubstituted aryl group having 6 to 15 ring-forming carbon atoms, or a substituted or unsubstituted heteroaryl group having 2 to 10 ring-forming carbon atoms, and
X, Y, R⁹ to R¹⁷, and R^{18a} to R^{18e} are the same as defined in Formulas 1 and 2.

16. The polycyclic compound of claim 13, wherein Y is a substituted or unsubstituted phenylthio group, a substituted or unsubstituted phenoxy group, a substituted or unsubstituted methoxy group, a substituted or unsubstituted t-butoxy group, a substituted or unsubstituted diethylamino group, a substituted or unsubstituted diphenylamino group, a substituted or unsubstituted cyclohexyl group, a substituted or unsubstituted phenyl group, a substituted or unsubstituted naphthyl group, a substituted or unsubstituted benzothiazole group, a substituted or unsubstituted benzoxazole group, a substituted or unsubstituted indole group, a substituted or unsubstituted benzothiophene group, or a substituted or unsubstituted benzofuran group.

17. The polycyclic compound of claim 13, wherein Formula 1 is represented by Formula 3: 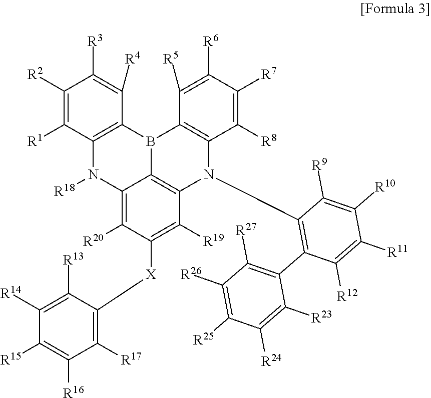
wherein in Formula 3,
R²³ to R²⁷ are each independently a hydrogen atom or a deuterium atom, and
X and R¹ to R²⁰ are the same as defined in Formula 1.

18. The polycyclic compound of claim 13, wherein Formula 1 above is represented by one of Formulas 4-1 to 4-3: 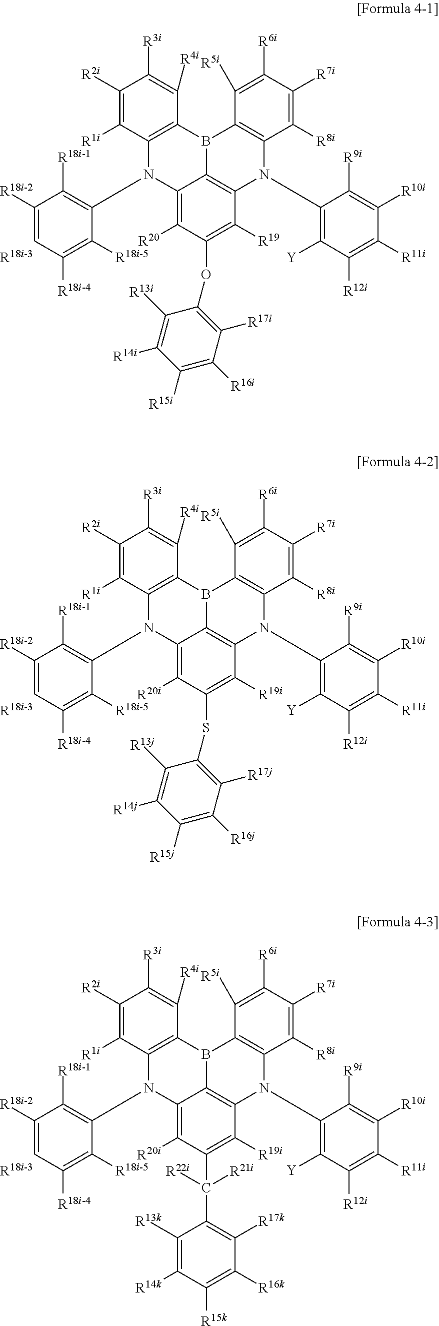
wherein in Formula 4-1,
R¹³ⁱ to R¹⁷ⁱ are each independently a hydrogen atom, a deuterium atom, a halogen atom, a substituted or unsubstituted alkyl group having 1 to 10 carbon atoms, a substituted or unsubstituted aryl group having 6 to 15 ring-forming carbon atoms, or a substituted or unsubstituted heteroaryl group having 2 to 15 ring-forming carbon atoms, or are bonded to an adjacent group to form a ring;
wherein in Formula 4-2,
R^{13j} to R^{17j} are each independently a hydrogen atom, a deuterium atom, a halogen atom, a cyano group, a substituted or unsubstituted oxy group, a substituted or unsubstituted alkyl group having 1 to 10 carbon atoms, or a substituted or unsubstituted aryl group having 6 to 15 ring-forming carbon atoms;
wherein in Formula 4-3,
R^{13k} to R^{17k} are each independently a hydrogen atom, a deuterium atom, a halogen atom, a cyano group, a substituted or unsubstituted alkyl group having 1 to 10 carbon atoms, a substituted or unsubstituted cycloalkyl group having 3 to 10 ring-forming carbon atoms, or a substituted or unsubstituted aryl group having 6 to 15 ring-forming carbon atoms, and
R²¹ⁱ and R²²ⁱ are each independently a hydrogen atom, a deuterium atom, a substituted or unsubstituted alkyl group having 1 to 10 carbon atoms, or a substituted or unsubstituted aryl group having 6 to 15 ring-forming carbon atoms; and
wherein in Formulas 4-1 to 4-3,
R¹ⁱ to R⁸ⁱ are each independently a hydrogen atom, a deuterium atom, a substituted or unsubstituted silyl group, a substituted or unsubstituted alkyl group having 1 to 20 carbon atoms, a substituted or unsubstituted cycloalkyl group having 3 to 30 ring-forming carbon atoms, a substituted or unsubstituted aryl group having 6 to 30 ring-forming carbon atoms, or a substituted or unsubstituted heteroaryl group having 2 to 30 ring-forming carbon atoms,
R⁹ⁱ to R¹²ⁱ are each independently a hydrogen atom, a deuterium atom, a cyano group, a substituted or unsubstituted oxy group, a substituted or unsubstituted alkyl group having 1 to 20 carbon atoms, a substituted or unsubstituted cycloalkyl group having 3 to 30 ring-forming carbon atoms, or a substituted or unsubstituted aryl group having 6 to 30 ring-forming carbon atoms,
R¹⁸ⁱ⁻¹ to R¹⁸ⁱ⁻⁵ are each independently a hydrogen atom, a deuterium atom, a cyano group, a substituted or unsubstituted thio group, a substituted or unsubstituted oxy group, a substituted or unsubstituted amino group, a substituted or unsubstituted alkyl group having 1 to 20 carbon atoms, a substituted or unsubstituted cycloalkyl group having 3 to 30 ring-forming carbon atoms, a substituted or unsubstituted aryl group having 6 to 30 ring-forming carbon atoms, or a substituted or unsubstituted heteroaryl group having 2 to 30 ring-forming carbon atoms,
R¹⁹ⁱ and R²⁰ⁱ are each independently a hydrogen atom or a deuterium atom, and
Y is the same as defined in Formula 1.

19. The polycyclic compound of claim 13, wherein R¹³ to R¹⁷ are each independently a hydrogen atom, a deuterium atom, a halogen atom, a cyano group, a substituted or unsubstituted methoxy group, a substituted or unsubstituted methyl group, a substituted or unsubstituted i-propyl group, a substituted or unsubstituted t-butyl group, a substituted or unsubstituted cyclopropyl group, a substituted or unsubstituted phenyl group, a substituted or unsubstituted carbazole group, or are bonded to an adjacent group to form a dibenzothiophene group or a dibenzofuran group.

20. The polycyclic compound of claim 13, wherein the polycyclic compound is selected from Compound Group 1: 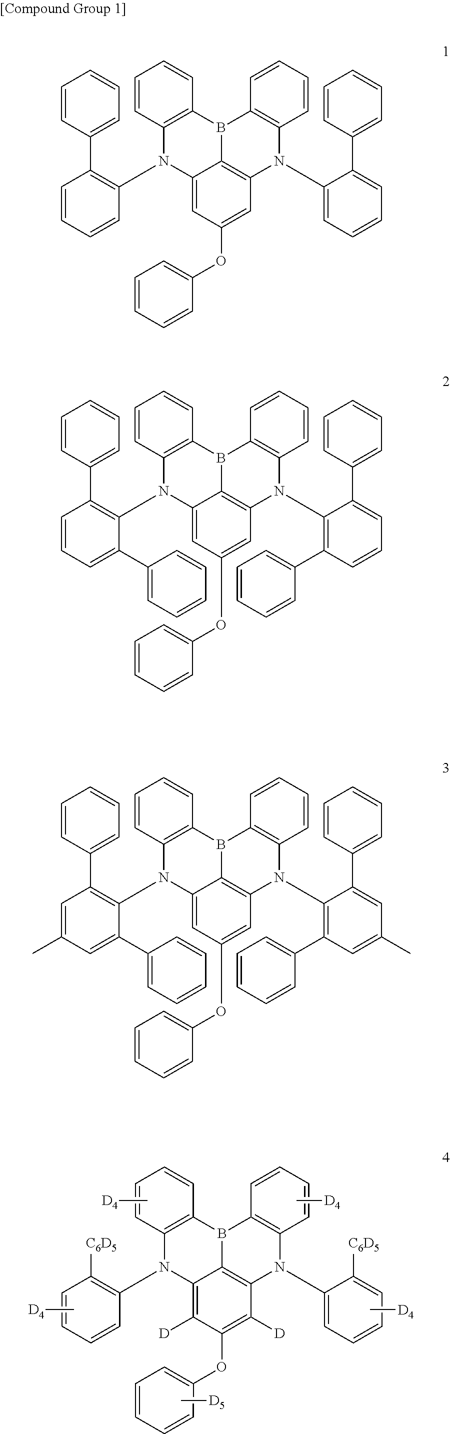 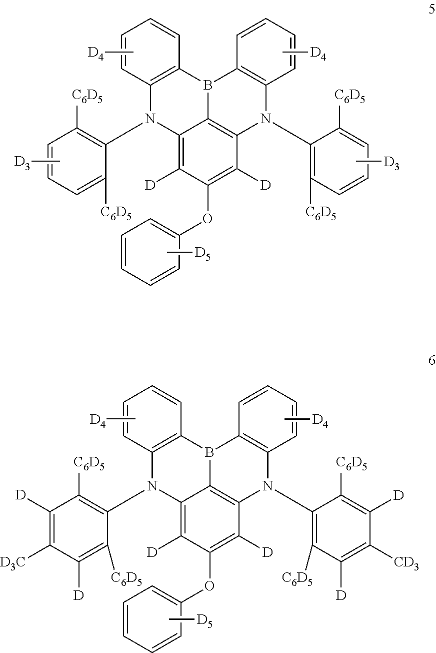 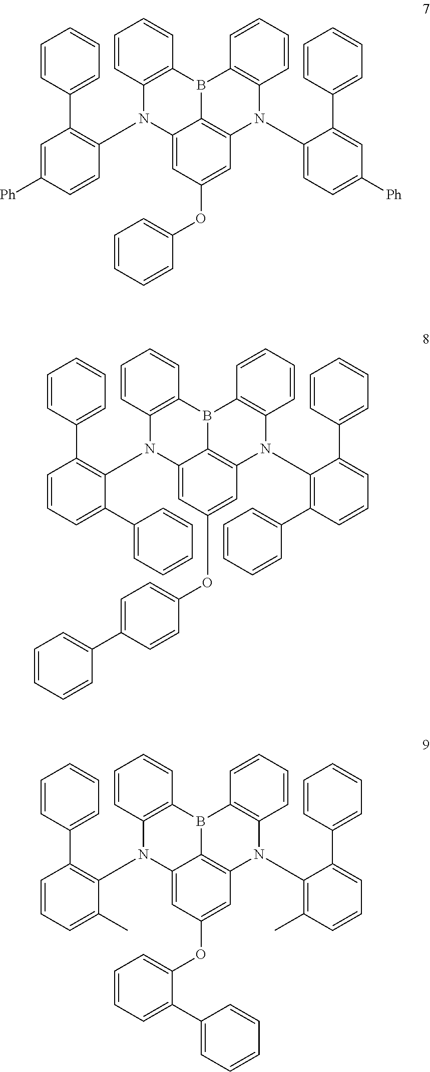 [SMILES: c1ccc(Oc2cc3c4c(c2)N(c2ccc(-c5ccccc5)cc2-c2ccccc2)c2ccccc2B4c2ccccc2N3c2ccc(-c3ccccc3)cc2-c2ccccc2)cc1 ; c1ccc(-c2ccc(Oc3cc4c5c(c3)N(c3c(-c6ccccc6)cccc3-c3ccccc3)c3ccccc3B5c3ccccc3N4c3c(-c4ccccc4)cccc3-c3ccccc3)cc2)cc1 ; Cc1cccc(-c2ccccc2)c1N1c2ccccc2B2c3ccccc3N(c3c(C)cccc3-c3ccccc3)c3cc(Oc4ccccc4-c4ccccc4)cc1c32] 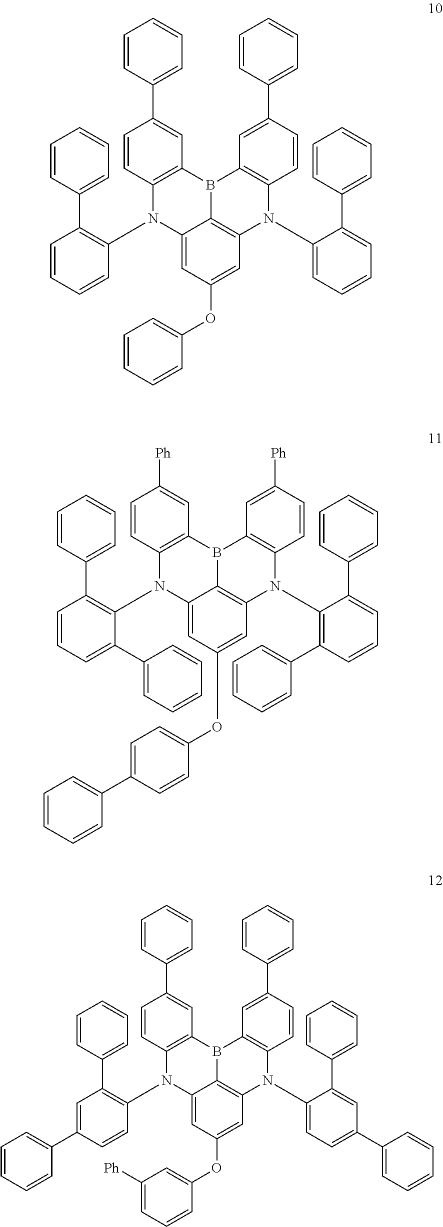 [SMILES: c1ccc(Oc2cc3c4c(c2)N(c2ccccc2-c2ccccc2)c2ccc(-c5ccccc5)cc2B4c2cc(-c4ccccc4)ccc2N3c2ccccc2-c2ccccc2)cc1 ; c1ccc(-c2ccc(Oc3cc4c5c(c3)N(c3c(-c6ccccc6)cccc3-c3ccccc3)c3ccc(-c6ccccc6)cc3B5c3cc(-c5ccccc5)ccc3N4c3c(-c4ccccc4)cccc3-c3ccccc3)cc2)cc1 ; c1ccc(-c2cccc(Oc3cc4c5c(c3)N(c3ccc(-c6ccccc6)cc3-c3ccccc3)c3ccc(-c6ccccc6)cc3B5c3cc(-c5ccccc5)ccc3N4c3ccc(-c4ccccc4)cc3-c3ccccc3)c2)cc1] 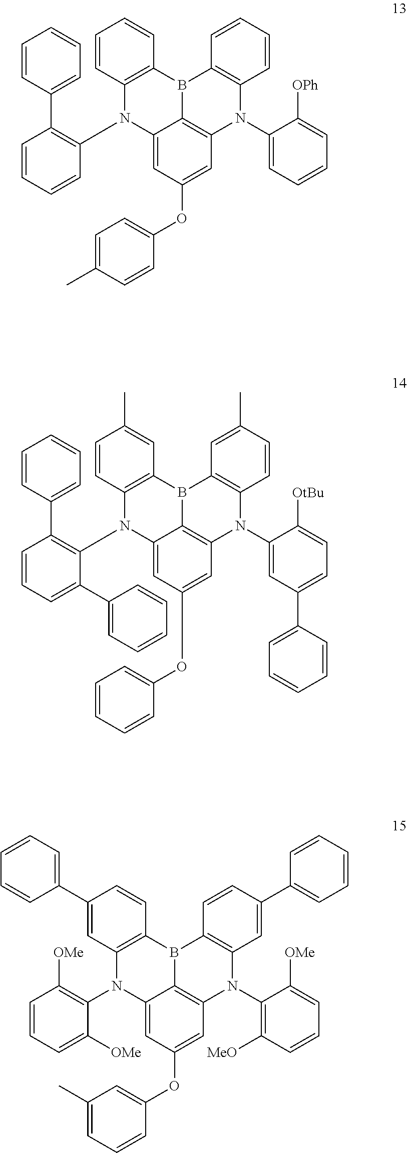 [SMILES: Cc1ccc(Oc2cc3c4c(c2)N(c2ccccc2-c2ccccc2)c2ccccc2B4c2ccccc2N3c2ccccc2Oc2ccccc2)cc1 ; Cc1ccc2c(c1)B1c3cc(C)ccc3N(c3c(-c4ccccc4)cccc3-c3ccccc3)c3cc(Oc4ccccc4)cc(c31)N2c1cc(-c2ccccc2)ccc1OC(C)(C)C ; COc1cccc(OC)c1N1c2cc(-c3ccccc3)ccc2B2c3ccc(-c4ccccc4)cc3N(c3c(OC)cccc3OC)c3cc(Oc4cccc(C)c4)cc1c32] 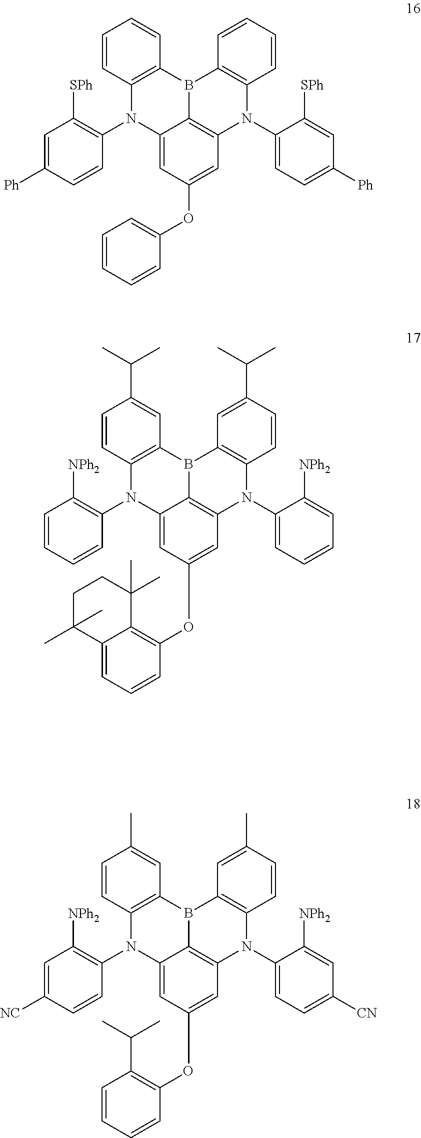 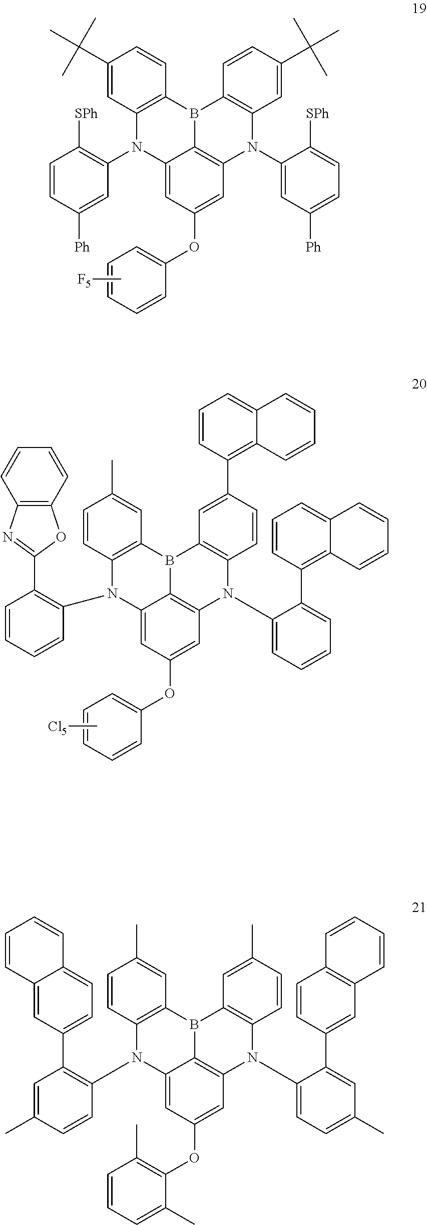 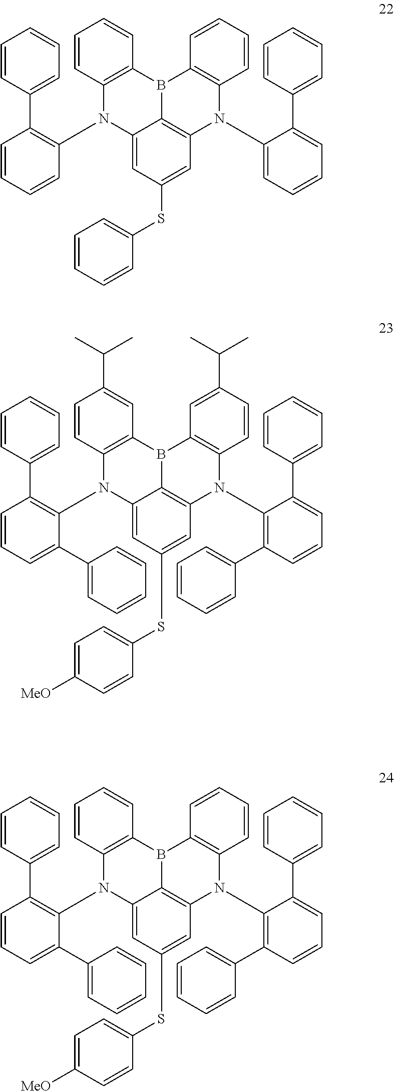 [SMILES: c1ccc(Sc2cc3c4c(c2)N(c2ccccc2-c2ccccc2)c2ccccc2B4c2ccccc2N3c2ccccc2-c2ccccc2)cc1 ; COc1ccc(Sc2cc3c4c(c2)N(c2c(-c5ccccc5)cccc2-c2ccccc2)c2ccc(C(C)C)cc2B4c2cc(C(C)C)ccc2N3c2c(-c3ccccc3)cccc2-c2ccccc2)cc1 ; COc1ccc(Sc2cc3c4c(c2)N(c2c(-c5ccccc5)cccc2-c2ccccc2)c2ccccc2B4c2ccccc2N3c2c(-c3ccccc3)cccc2-c2ccccc2)cc1] 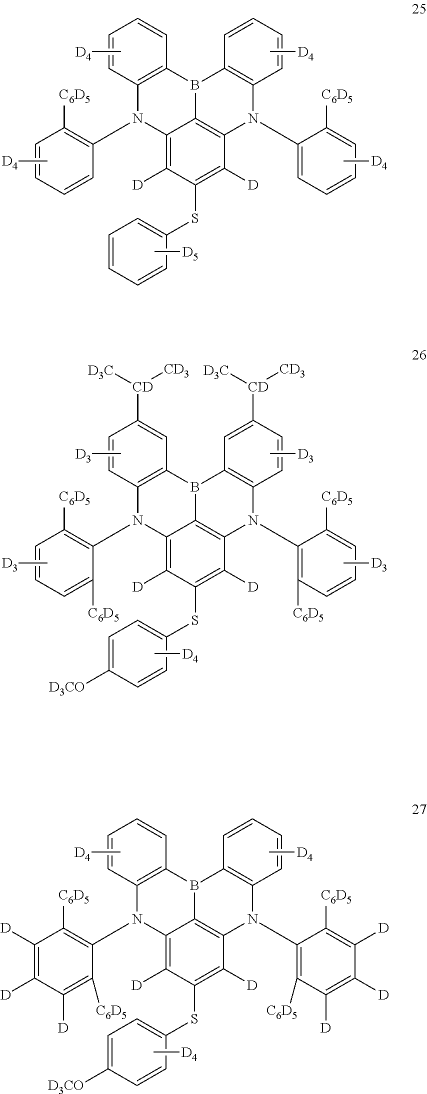 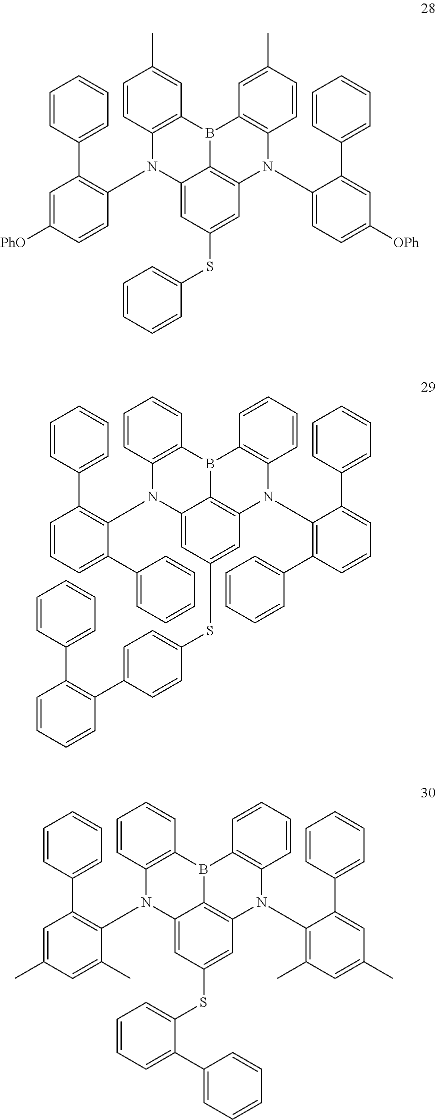 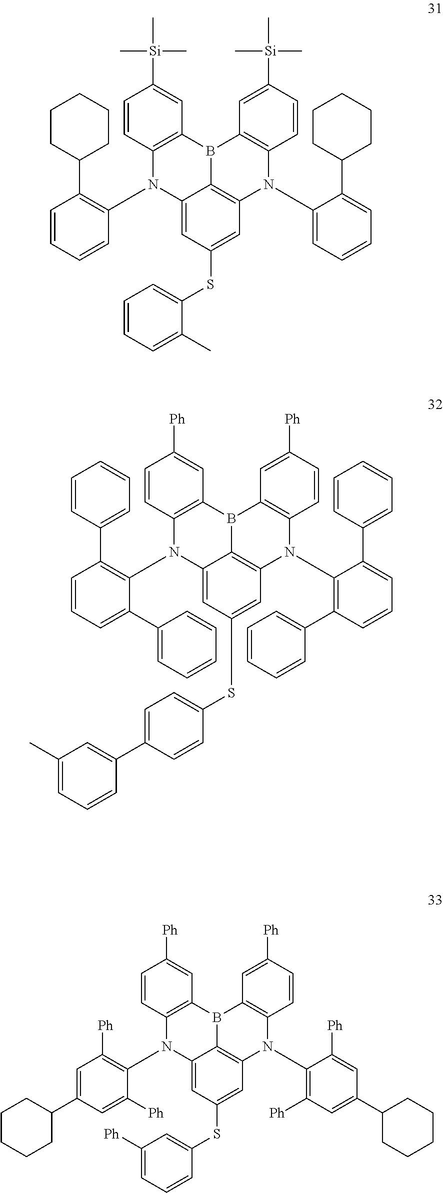 [SMILES: Cc1ccccc1Sc1cc2c3c(c1)N(c1ccccc1C1CCCCC1)c1ccc([Si](C)(C)C)cc1B3c1cc([Si](C)(C)C)ccc1N2c1ccccc1C1CCCCC1 ; Cc1cccc(-c2ccc(Sc3cc4c5c(c3)N(c3c(-c6ccccc6)cccc3-c3ccccc3)c3ccc(-c6ccccc6)cc3B5c3cc(-c5ccccc5)ccc3N4c3c(-c4ccccc4)cccc3-c3ccccc3)cc2)c1 ; c1ccc(-c2cccc(Sc3cc4c5c(c3)N(c3c(-c6ccccc6)cc(C6CCCCC6)cc3-c3ccccc3)c3ccc(-c6ccccc6)cc3B5c3cc(-c5ccccc5)ccc3N4c3c(-c4ccccc4)cc(C4CCCCC4)cc3-c3ccccc3)c2)cc1] 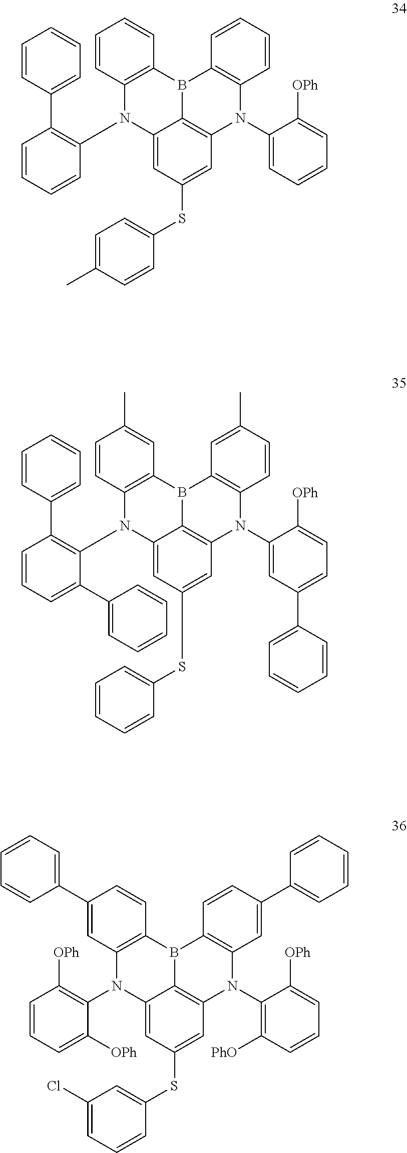 [SMILES: Cc1ccc(Sc2cc3c4c(c2)N(c2ccccc2-c2ccccc2)c2ccccc2B4c2ccccc2N3c2ccccc2Oc2ccccc2)cc1 ; Cc1ccc2c(c1)B1c3cc(C)ccc3N(c3c(-c4ccccc4)cccc3-c3ccccc3)c3cc(Sc4ccccc4)cc(c31)N2c1cc(-c2ccccc2)ccc1Oc1ccccc1 ; Clc1cccc(Sc2cc3c4c(c2)N(c2c(Oc5ccccc5)cccc2Oc2ccccc2)c2cc(-c5ccccc5)ccc2B4c2ccc(-c4ccccc4)cc2N3c2c(Oc3ccccc3)cccc2Oc2ccccc2)c1] 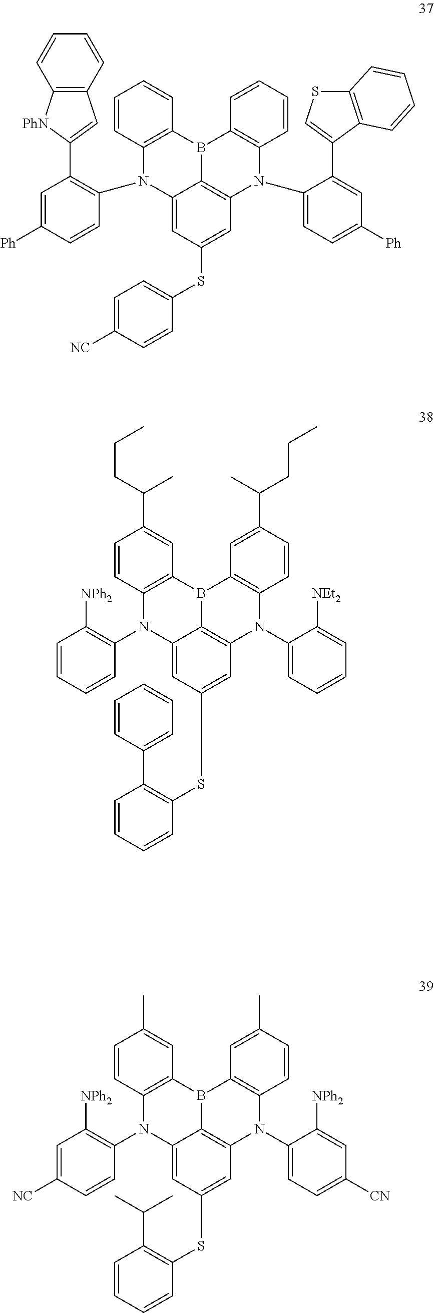 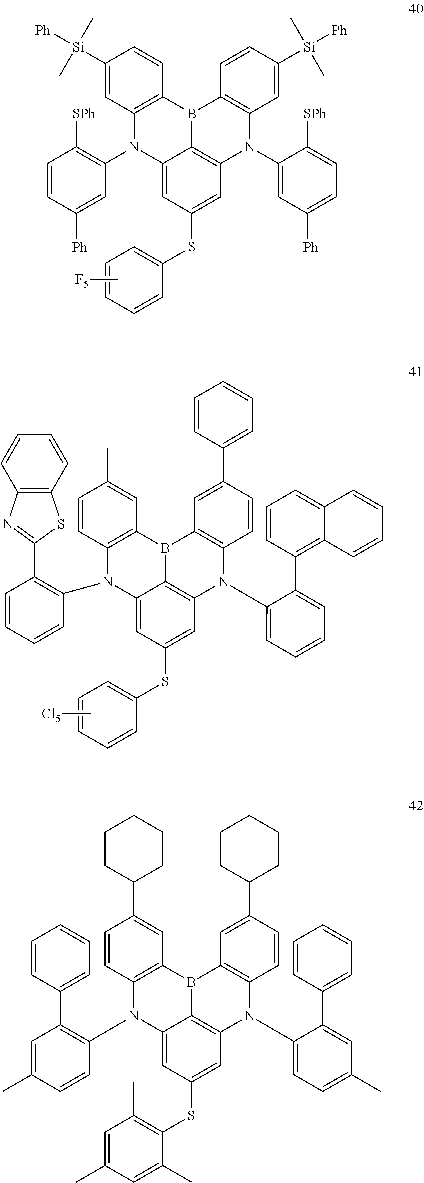 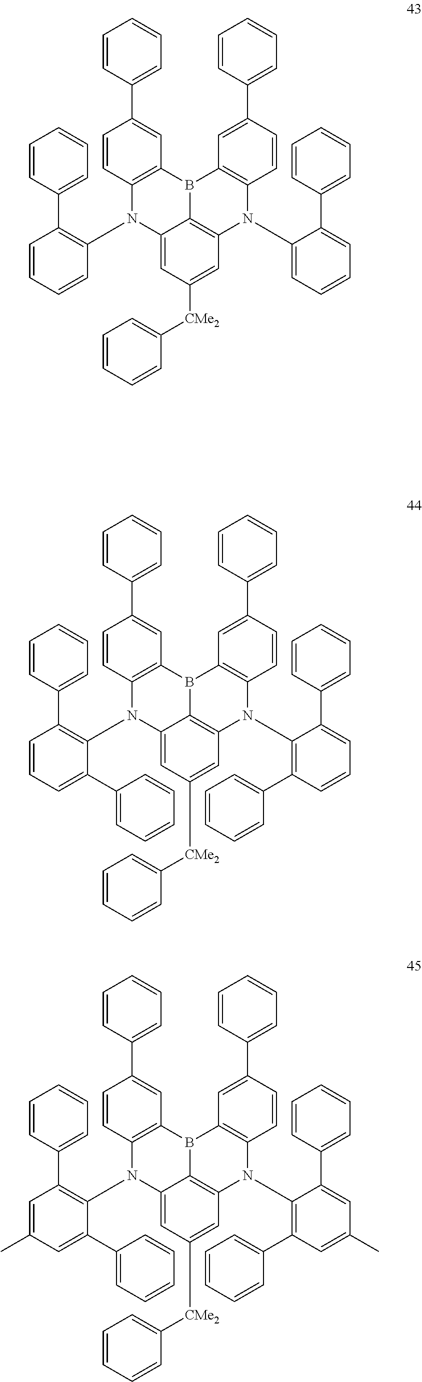 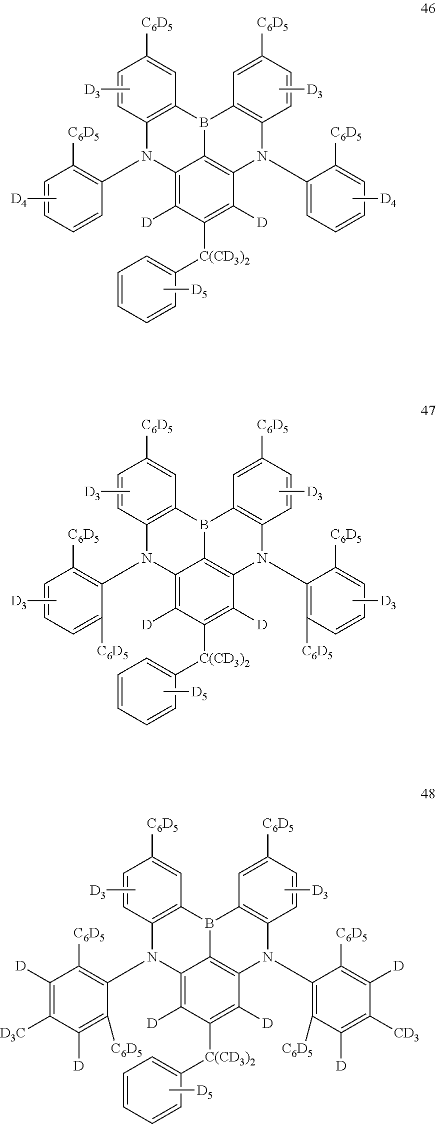 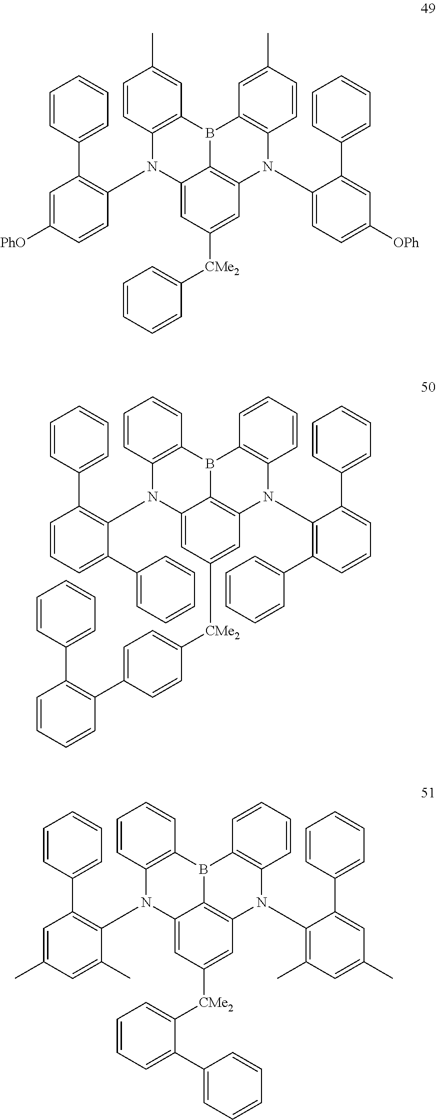 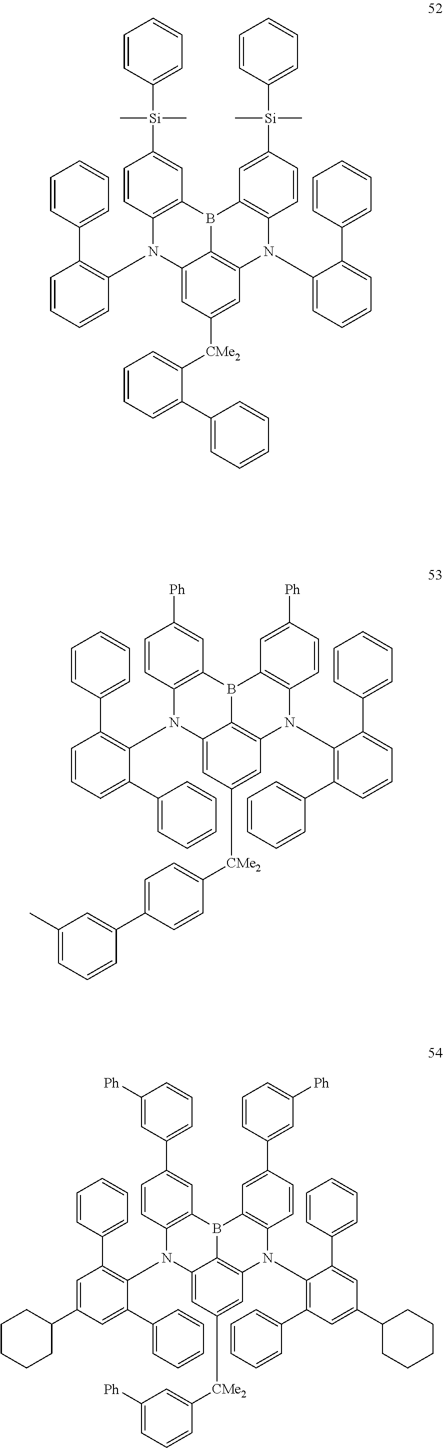 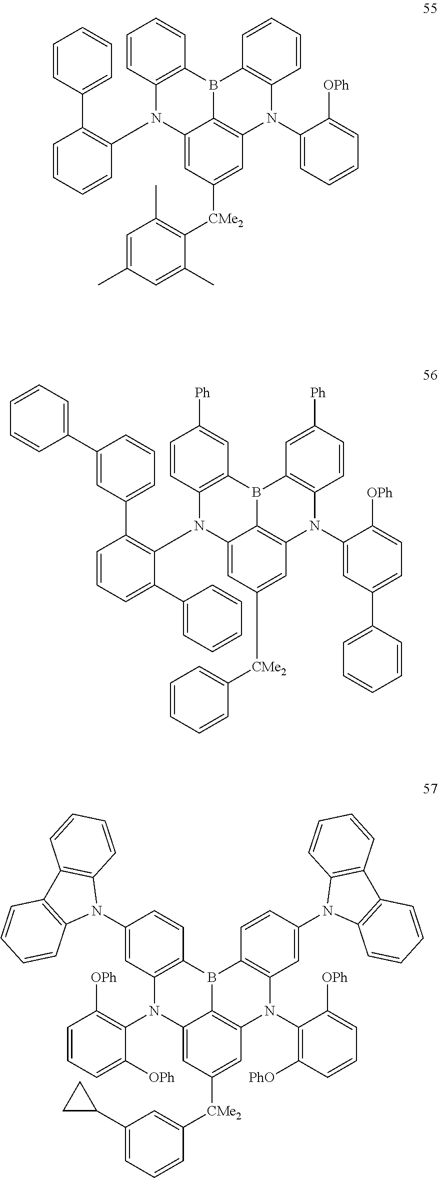 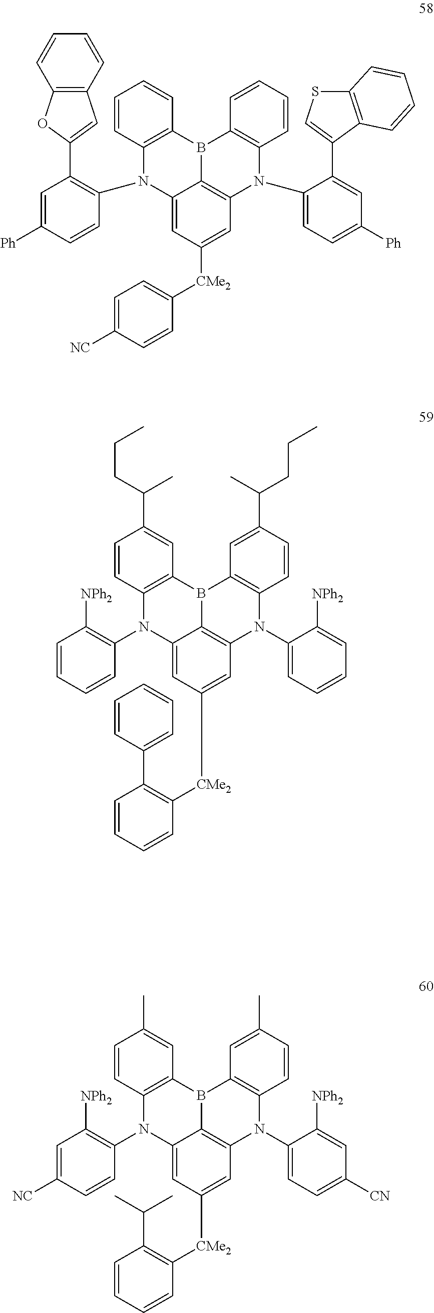 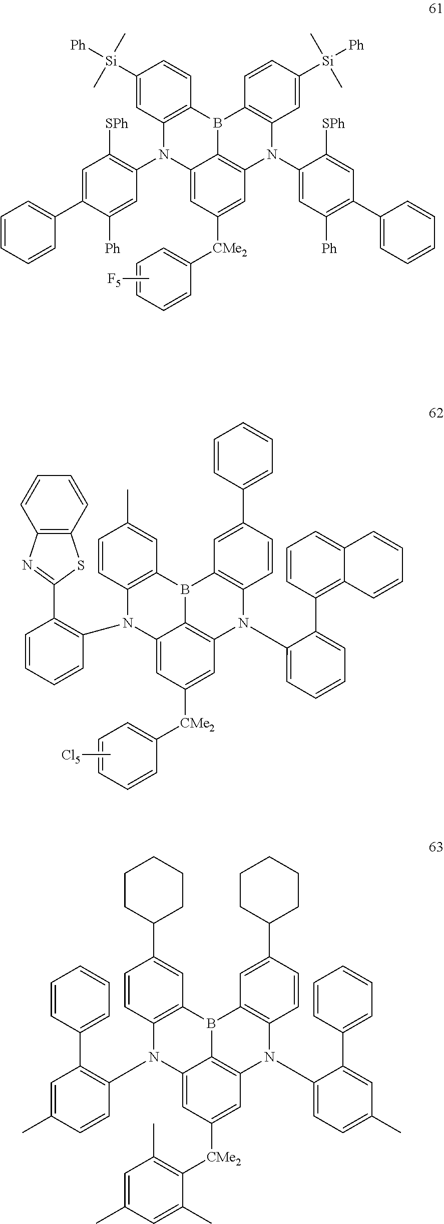 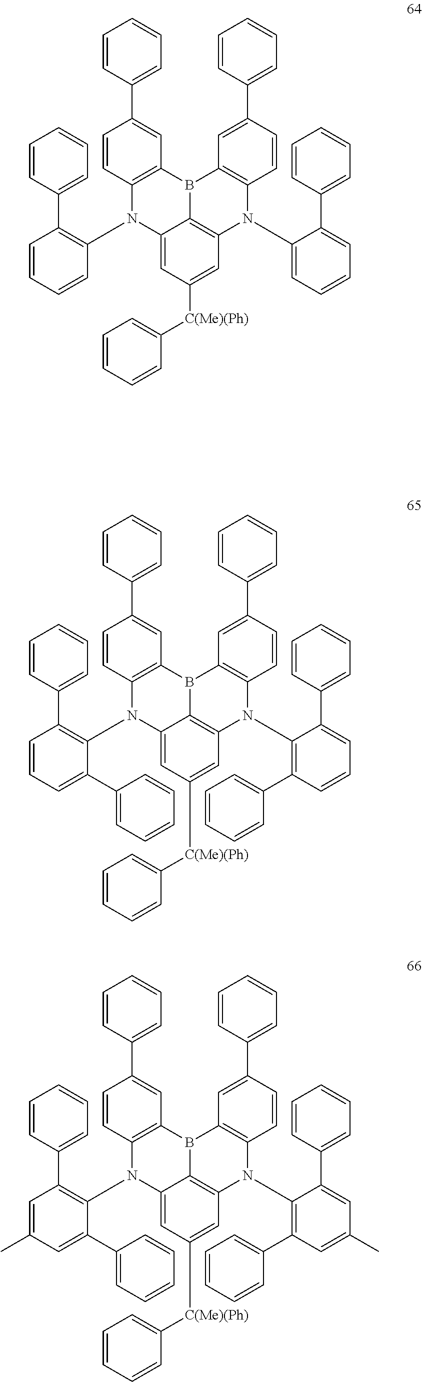 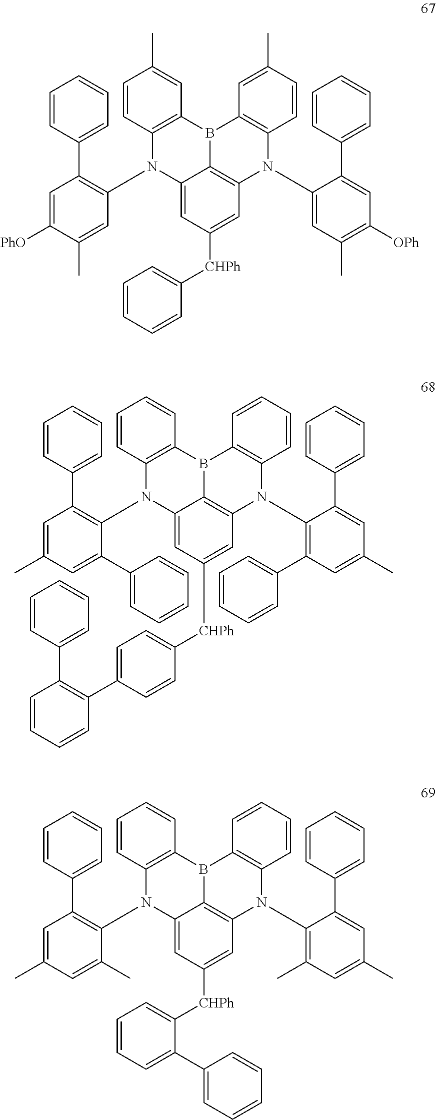 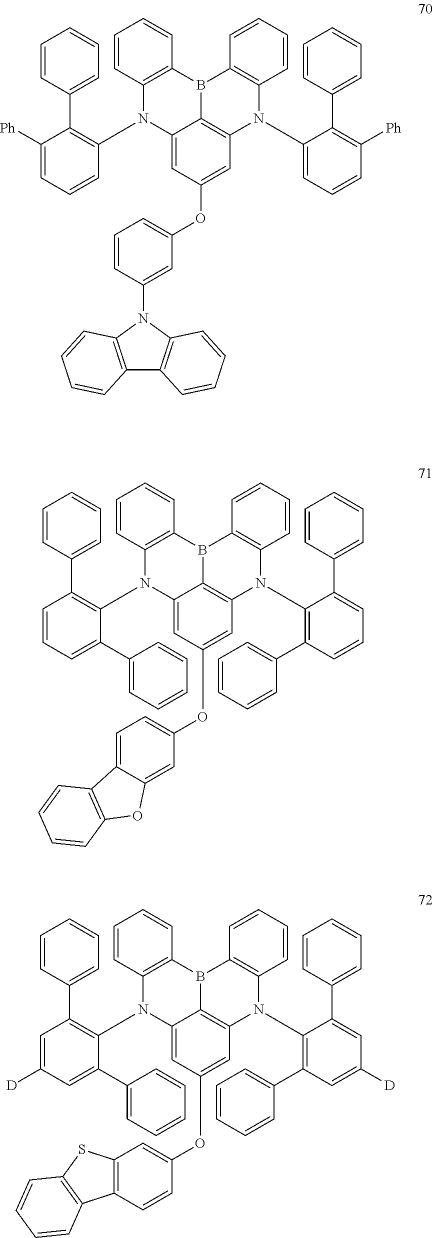 [SMILES: c1ccc(-c2cccc(N3c4ccccc4B4c5ccccc5N(c5cccc(-c6ccccc6)c5-c5ccccc5)c5cc(Oc6cccc(-n7c8ccccc8c8ccccc87)c6)cc3c54)c2-c2ccccc2)cc1 ; c1ccc(-c2cccc(-c3ccccc3)c2N2c3ccccc3B3c4ccccc4N(c4c(-c5ccccc5)cccc4-c4ccccc4)c4cc(Oc5ccc6c(c5)oc5ccccc56)cc2c43)cc1 ; [2H]c1cc(-c2ccccc2)c(N2c3ccccc3B3c4ccccc4N(c4c(-c5ccccc5)cc([2H])cc4-c4ccccc4)c4cc(Oc5ccc6c(c5)sc5ccccc56)cc2c43)c(-c2ccccc2)c1] 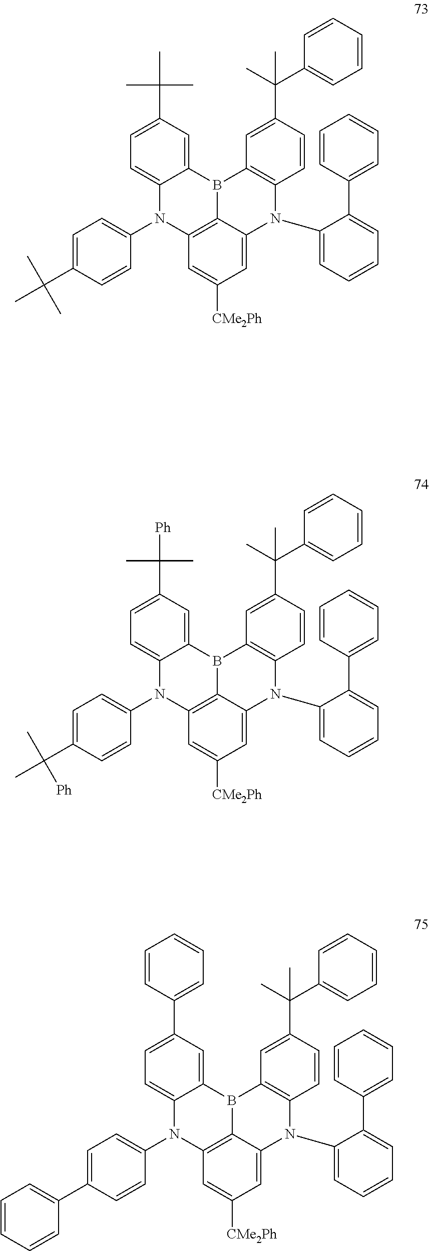 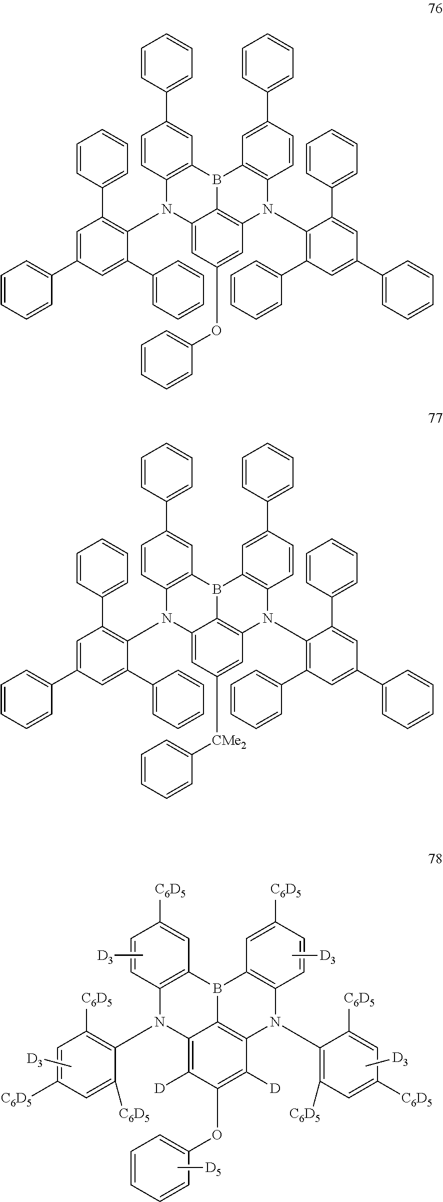 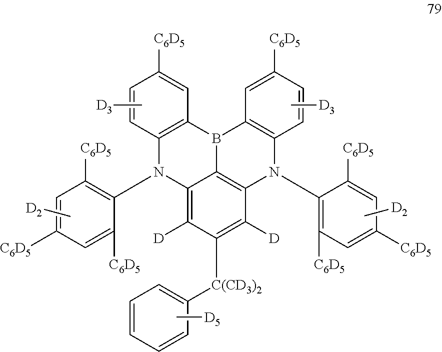
wherein in Compound Group 1,
D represents a deuterium atom,
Me represents a methyl group,
Et represents an ethyl group,
F represents a fluorine atom,
Cl represents a chlorine atom, and
Ph represents a phenyl group.
